(19) United States
(12) Patent Application Publication
(10) Pub. No.: US 2024/0361692 A1
(43) Pub. Date: Oct. 31, 2024

(54) POSITIVE RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Masaki Ohashi, Joetsu-shi (JP)

(73) Assignee: Shin-Etsu Chemical Co., Ltd., Tokyo (JP)

(21) Appl. No.: 18/630,566

(22) Filed: Apr. 9, 2024

(30) Foreign Application Priority Data
Apr. 19, 2023 (JP) 2023-068697

(51) Int. Cl. G03F 7/039; G03F 7/004

(52) U.S. Cl. CPC G03F 7/0397; G03F 7/0045

(57) ABSTRACT

There is provided a positive resist composition that exhibits higher sensitivity and resolution than those of conventional positive resist compositions, has reduced edge roughness (LWR), has satisfactory dimensional uniformity (CDU), and has a satisfactory pattern profile after exposure, and to provide a pattern forming process. The positive resist composition comprises a base polymer containing repeat units (a) having a sulfonium salt structure or an iodonium salt structure of trihydrocarbylsulfonylmethide acid free of a fluorine atom on a carbon atom bonded to a sulfonyl group.

### CROSS-REFERENCE TO RELATED APPLICATIONS

This non-provisional application claims priority under 35 U.S.C. § 119 (a) on Patent Application No. 2023-068697 filed in Japan on Apr. 19, 2023, the entire contents of which are hereby incorporated by reference.

### TECHNICAL FIELD

The present invention relates to a positive resist composition and a pattern forming process.

### BACKGROUND ART

To meet the demand for higher integration density and higher operating speed of LSIs, the effort to reduce the pattern rule is in rapid progress. As the use of 5G high-speed communications and artificial intelligence (AI) is widely spreading, high-performance devices are needed for their processing. As the most advanced miniaturization technology, mass production of microelectronic devices at the 5-nm node by the lithography using extreme ultraviolet (EUV) having a wavelength of 13.5 nm has been implemented. Studies are made on the application of EUV lithography to 3-nm node devices of the next generation and 2-nm node devices of the next-but-one generation.

As the feature size reduces, image blurs due to acid diffusion become a problem. To ensure resolution for fine patterns of sub-45-nm size, not only an improvement in dissolution contrast is important as previously reported, but also the control of acid diffusion is important as reported in Non-Patent Document 1. Since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

A triangular tradeoff relationship among sensitivity, resolution, and edge roughness has been pointed out. Specifically, a resolution improvement requires to reduce acid diffusion whereas a short acid diffusion distance leads to a decline of sensitivity.

The addition of an acid generator capable of generating a bulky acid is an effective means for reducing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond and capable of generating a specific sulfonic acid. Patent Document 2 discloses a sulfonium salt having a sulfonic acid directly bonded to the backbone.

In order to reduce acid diffusion, a resist composition containing a polymer-bound quencher and containing, as a base polymer, a sulfonium salt of a weak acid having a polymerizable group and having a pKa value of −0.8 or more has been proposed in Patent Documents 3 to 5. In Patent Document 3, examples of the weak acid include carboxylic acid, sulfonamide, phenol, and hexafluoroalcohol.

A methide acid having a hydrocarbylsulfonyl group not substituted with a fluorine atom is a weak acid, and a resist composition containing, as a quencher, a sulfonium salt of the methide acid has been proposed in Patent Document 6.

### CITATION LIST

Patent Document 1: JP-A 2006-045311
Patent Document 2: JP-A 2006-178317
Patent Document 3: WO 2019/167737
Patent Document 4: WO 2022/264845
Patent Document 5: JP-A 2022-115072
Patent Document 6: JP-A 2020-055797

### SUMMARY OF THE INVENTION

The present invention has been made in view of the above circumstances, and an object of the present invention is to provide a positive resist composition that exhibits higher sensitivity and resolution than those of conventional positive resist compositions, has reduced edge roughness (LWR), has satisfactory dimensional uniformity (CDU), and has a satisfactory pattern profile after exposure, and to provide a pattern forming process.

The present inventors have intensively studied to achieve a positive resist composition having high resolution, low LWR, and satisfactory CDU, which are desired in recent years. As a result, the present inventors have found that it is necessary to shorten the acid diffusion distance to the limit, and to make the acid diffusion distance uniform at the molecular level. The present inventors have found that the acid diffusion is minimized by using, as a base polymer, a polymer containing repeat units having a sulfonium salt structure or an iodonium salt structure of trihydrocarbylsulfonylmethide acid free of a fluorine atom on a carbon atom at an α-position of a sulfonyl group, and that two effects including an effect of uniformizing the acid diffusion distance and a low swelling effect are obtained due to the low swelling characteristic in an alkaline developer of the sulfonium salt structure or the iodonium salt structure of trihydrocarbylsulfonylmethide acid free of a fluorine atom on a carbon atom at an α-position of a sulfonyl group that is generated by exposure. Thus, the present inventors have found that the above polymer is useful as a base polymer of a chemically amplified positive resist composition having satisfactory LWR and CDU.

Furthermore, the present inventors have found that it is possible to achieve a positive resist composition that is particularly suitable as a micropatterning material for the fabrication of VLSIs and photomasks by introducing, in order to improve the dissolution contrast, repeat units in which a hydrogen atom of a carboxy group or a phenolic hydroxy group is substituted with an acid labile group. The positive resist composition has high sensitivity, has significantly high alkali dissolution rate contrast before and after exposure, has high sensitivity and a strong effect of reducing acid diffusion, and has high resolution and a satisfactory pattern profile after exposure as well as reduced edge roughness and small variation of dimension, thereby completing the present invention.

That is, the present invention provides the following positive resist composition and pattern forming process.

1. A positive resist composition comprising a base polymer containing repeat units (a) having a sulfonium salt structure or an iodonium salt structure of trihydrocarbylsulfonylmethide acid free of a fluorine atom on a carbon atom at an α-position of a sulfonyl group.

2. The positive resist composition of item 1, wherein the repeat units (a) are repeat units (a1) having formula (a1) or repeat units (a2) having formula (a2):

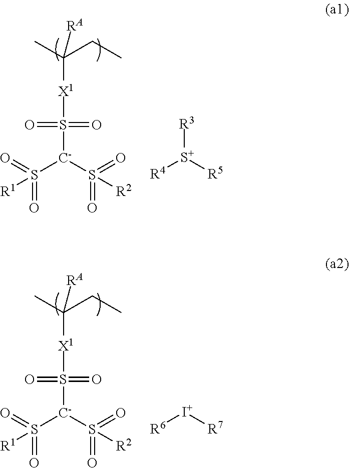

wherein R^{A} is a hydrogen atom or a methyl group,
X¹ is each independently a single bond, a phenylene group, or a C₁-C₂₀ linking group containing at least one moiety selected from an ester bond, an ether bond, a urethane bond, a lactone ring, and a halogen atom,
R¹ and R² are each independently a C₁-C₂₀ hydrocarbyl group which may contain a heteroatom, but are free of a fluorine atom on a carbon atom bonded to a sulfonyl group, and
R³ to R⁷ are each independently a halogen atom or a C₁-C₂₀ hydrocarbyl group which may contain a heteroatom, and R³ and R⁴ may bond together to form a ring with a sulfur atom to which they are bonded.

3. The positive resist composition of item 1 or 2, further comprising at least one kind selected from repeat units (b1) in which a hydrogen atom of a carboxy group is substituted with an acid labile group and repeat units (b2) in which a hydrogen atom of a phenolic hydroxy group is substituted with an acid labile group.

4. The positive resist composition of item 3, wherein the repeat units (b1) have formula (b1) and the repeat units (b2) have formula (b2):

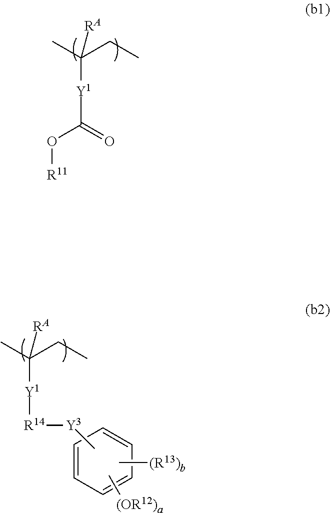

wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, and a lactone ring, and the phenylene group, the naphthylene group, and the linking group may have at least one moiety selected from a hydroxy group, a C₁-C₈ saturated hydrocarbyloxy group, and a C₂-C₈ saturated hydrocarbylcarbonyloxy group,
Y² is a single bond, an ester bond, or an amide bond,
Y³ is a single bond, an ether bond, or an ester bond,
R¹¹ and R¹² are acid labile groups,
R¹³ is a fluorine atom, a trifluoromethyl group, a cyano group, or a C₁-C₆ saturated hydrocarbyl group,
R¹⁴ is a single bond or a C₁-C₆ alkanediyl group in which some constituent —CH₂— may be substituted with an ether bond or an ester bond, and
a is 1 or 2, and b is an integer of 0 to 4, provided that 1≤a+b≤5.

5. The positive resist composition of any one of items 1 to 4, wherein the base polymer further contains repeat units (c) having an adhesive group selected from a hydroxy group, a carboxy group, a lactone ring, a carbonate bond, a thiocarbonate bond, a carbonyl group, a cyclic acetal group, an ether bond, an ester bond, a sulfonic ester bond, a cyano group, an amide bond, —O—C(═O)—S—, and —O—C(═O)—NH—.

6. The positive resist composition of any one of items 1 to 5, wherein the base polymer further contains at least one kind selected from repeat units having formulae (d1) to (d3):

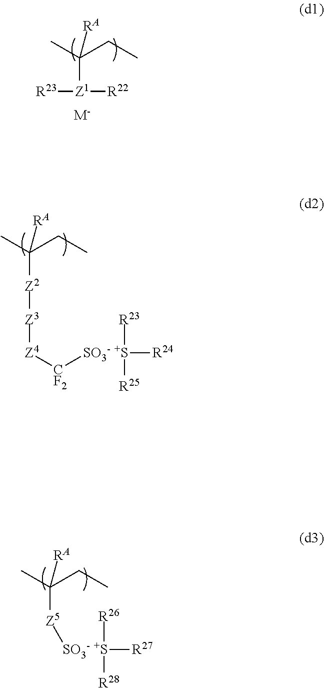

wherein R^{A} is each independently a hydrogen atom or a methyl group,
Z¹ is a single bond, a C₁-C₆ aliphatic hydrocarbylene group, a phenylene group, a naphthylene group, a C₇-C₁₈ group obtained by combining the foregoing, —O—Z¹¹—, —C(═O)—O—Z¹¹—, or —C(═O)—NH—Z¹¹—, wherein Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group,
Z² is a single bond or an ester bond,
Z³ is a single bond, —Z³¹—C(═O)—O—, —Z³¹—O—, or —Z³¹—O—C(═O)—, wherein Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom,
Z⁴ is a methylene group, a 2,2,2-trifluoro-1,1-ethanediyl group, or a carbonyl group,
Z⁵ is a single bond, a methylene group, an ethylene group, a phenylene group, a fluorinated phenylene group, a trifluoromethyl-substituted phenylene group, —O—Z⁵¹—, C(═O)—O—Z⁵¹—, or —C(═O)—NH—Z⁵¹—, wherein Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a hydroxy group, or a halogen atom,
R²¹ to R²⁸ are each independently a halogen atom or a C₁-C₂₀ hydrocarbyl group which may contain a heteroatom, and R²³ and R²⁴ or R²⁶ and R²⁷ may bond together to form a ring with a sulfur atom to which they are bonded, and
M⁻ is a non-nucleophilic counter ion.

7. The positive resist composition of any one of items 1 to 6, further comprising an acid generator.

8. The positive resist composition of any one of items 1 to 7, further comprising an organic solvent.

9. The positive resist composition of any one of items 1 to 8, further comprising a quencher.

10. The positive resist composition of any one of items 1 to 9, further comprising a surfactant.

11. A pattern forming process comprising the steps of:
applying the positive resist composition of any one of items 1 to 10 onto a substrate to form a resist film on the substrate,
exposing the resist film to high-energy radiation, and
developing the exposed resist film in a developer.

12. The pattern forming process of item 11, wherein the high-energy radiation is i-line, KrF excimer laser, ArF excimer laser, electron beam (EB), or EUV having a wavelength of 3 to 15 nm.

### Advantageous Effects of the Invention

Since the acid generator in the positive resist composition of the present invention can be decomposed efficiently, the positive resist composition has a strong effect of reducing acid diffusion, has high sensitivity and high resolution, and has a satisfactory pattern profile after exposure as well as reduced edge roughness and small variation of dimension. Therefore, since the positive resist composition has these excellent characteristics, it is highly practical, and is particularly suitable as a micropatterning material for the fabrication of VLSIs and photomasks by the EB or EUV lithography. The positive resist composition of the present invention is used not only in the lithography for forming semiconductor circuits, but also in the formation of mask circuit patterns, micromachines, and thin-film magnetic head circuits.

### DETAILED DESCRIPTION OF THE INVENTION

### [Base Polymer]

The resist composition of the present invention contains a base polymer containing repeat units (a) having a sulfonium salt structure or an iodonium salt structure of trihydrocarbylsulfonylmethide acid free of a fluorine atom on a carbon atom at an α-position of a sulfonyl group.

The repeat units (a) preferably have formula (a1) (hereinafter, the repeat units are also referred to as repeat units (a1)) or formula (a2) (hereinafter, the repeat units are also referred to as repeat units (a2)).

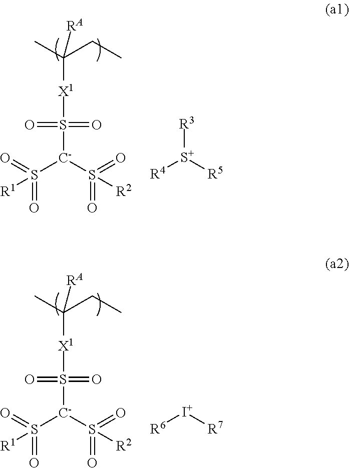

In formulae (a1) and (a2), R^{A} is a hydrogen atom or a methyl group.

In formulae (a1) and (a2), X¹ is each independently a single bond, a phenylene group, or a C₁-C₂₀ linking group containing at least one moiety selected from an ester bond, an ether bond, a urethane bond, a lactone ring, and a halogen atom.

In formulae (a1) and (a2), R¹ and R² are each independently a C₁-C₂₀ hydrocarbyl group which may contain a heteroatom, but are free of a fluorine atom on a carbon atom bonded to a sulfonyl group. The hydrocarbyl group may be saturated or unsaturated, and may be linear, branched, or cyclic. Specific examples thereof include C₁-C₂₀ alkyl groups such as a methyl group, an ethyl group, a n-propyl group, an isopropyl group, a n-butyl group, an isobutyl group, a sec-butyl group, a tert-butyl group, a n-pentyl group, a n-hexyl group, a n-octyl group, a n-nonyl group, a n-decyl group, an undecyl group, a dodecyl group, a tridecyl group, a tetradecyl group, a pentadecyl group, a heptadecyl group, an octadecyl group, a nonadecyl group, and an icosyl group; C₃-C₂₀ cyclic saturated hydrocarbyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; C₂-C₂₀ alkenyl groups such as a vinyl group, a propenyl group, a butenyl group, and a hexenyl group; C₂-C₂₀ alkynyl groups such as an ethynyl group, a propynyl group, and a butynyl group; C₃-C₂₀ cyclic unsaturated aliphatic hydrocarbyl groups such as a cyclohexenyl group and a norbornenyl group; C₆-C₂₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, and a tert-butylnaphthyl group; C₇-C₂₀ aralkyl groups such as a benzyl group and a phenethyl group; and groups obtained by combining the foregoing. Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a mercapto group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group.

Examples of an anion in the monomer from which the repeat units (a1) and (a2) are derived include those shown below, but are not limited thereto. In the formulae. R^{A} is as defined above.

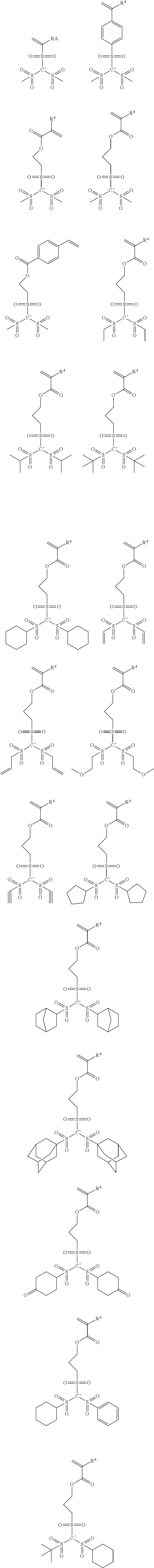

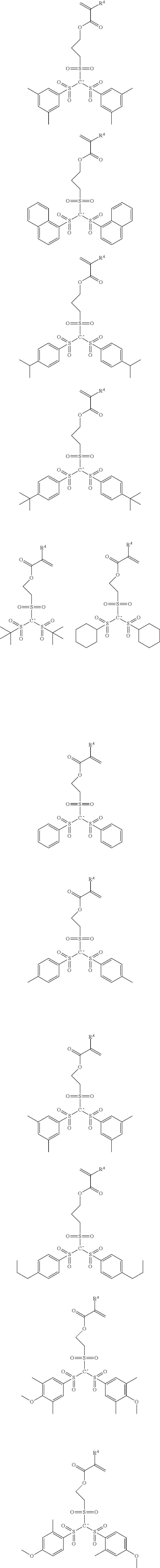

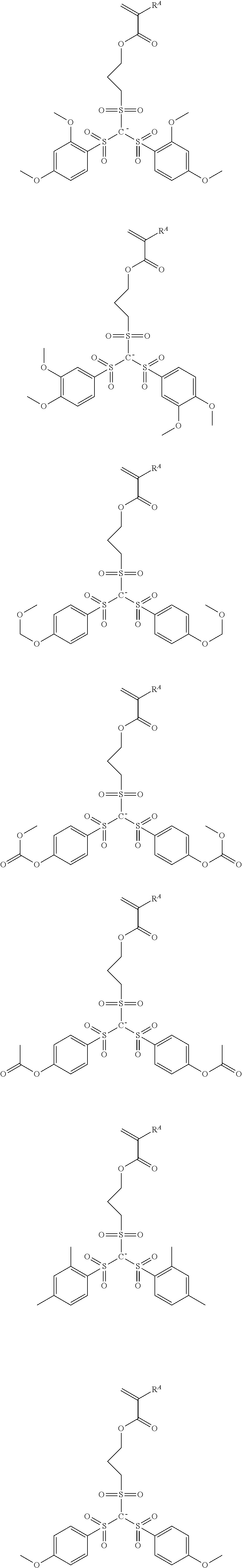

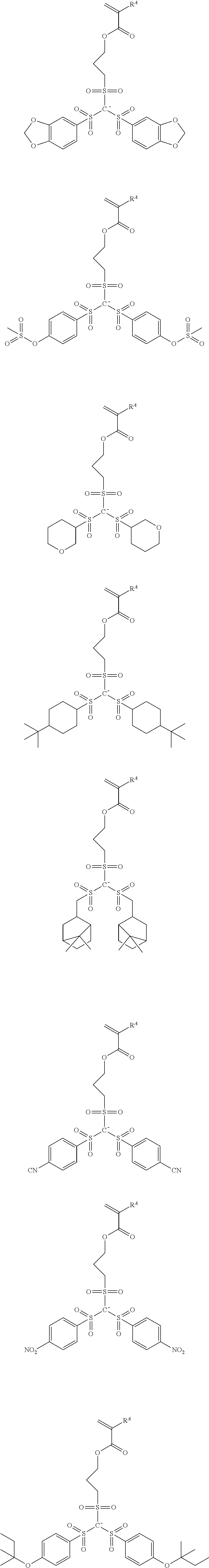

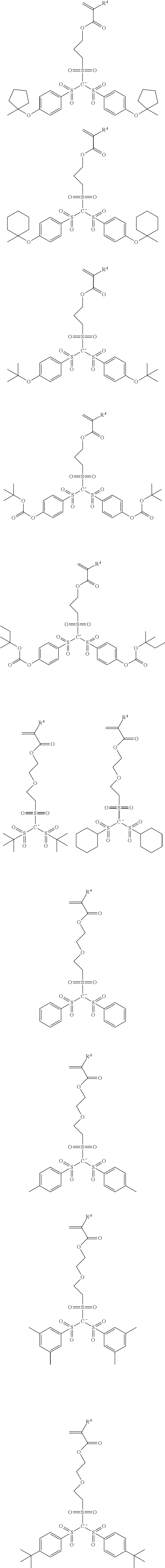

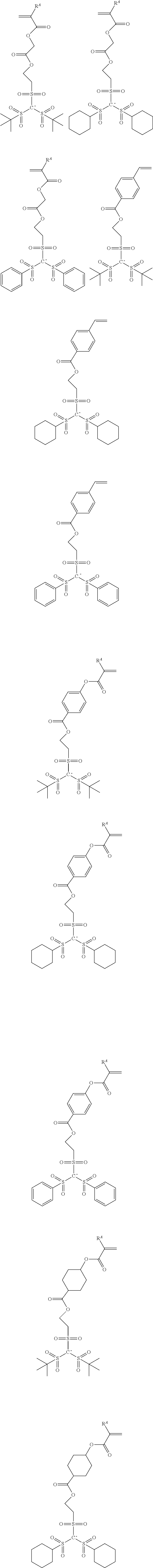

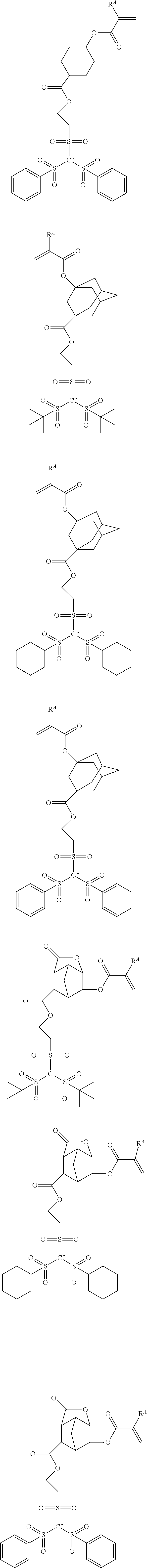

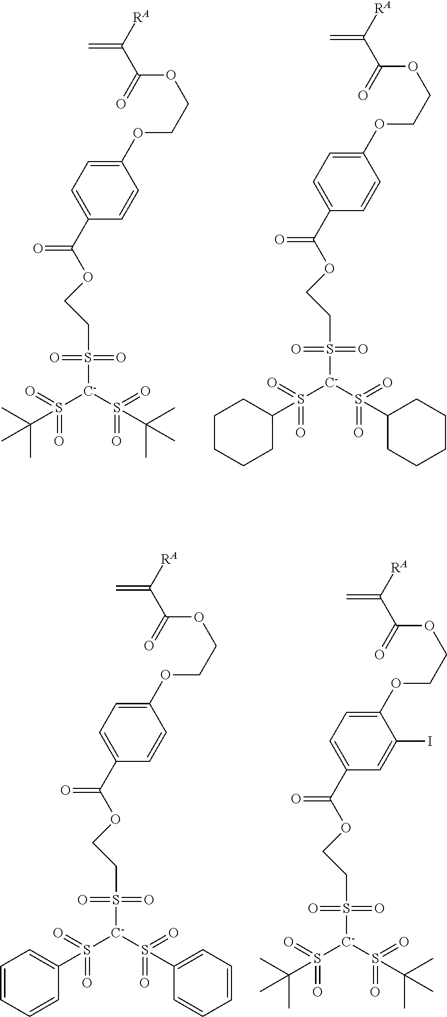

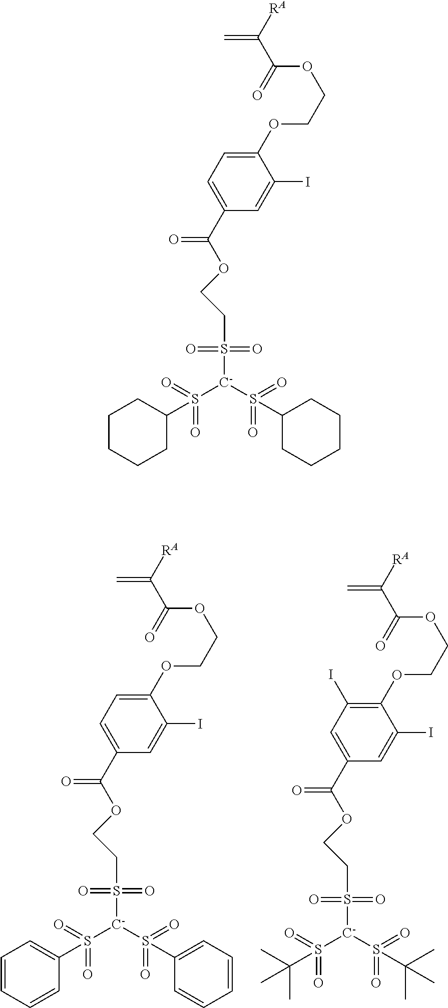

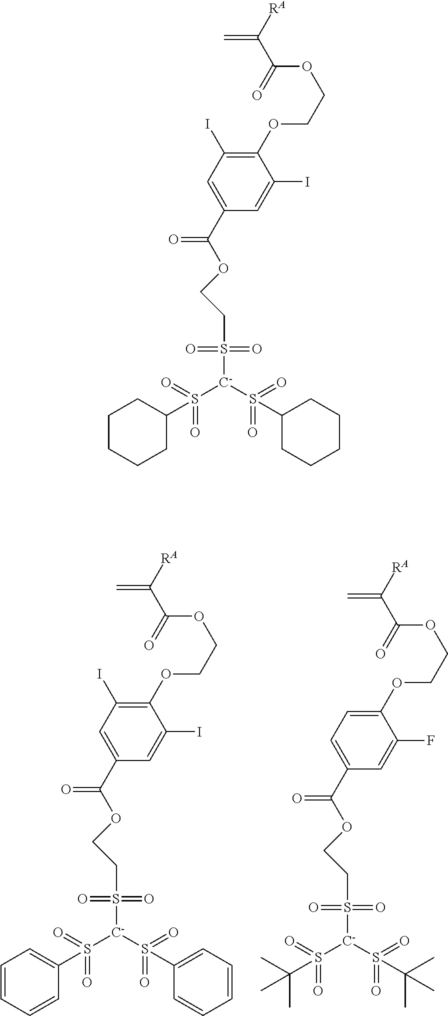

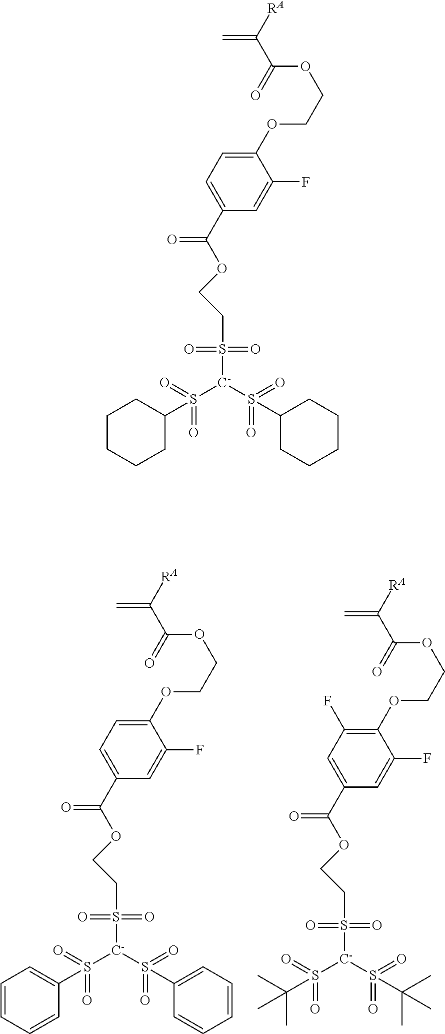

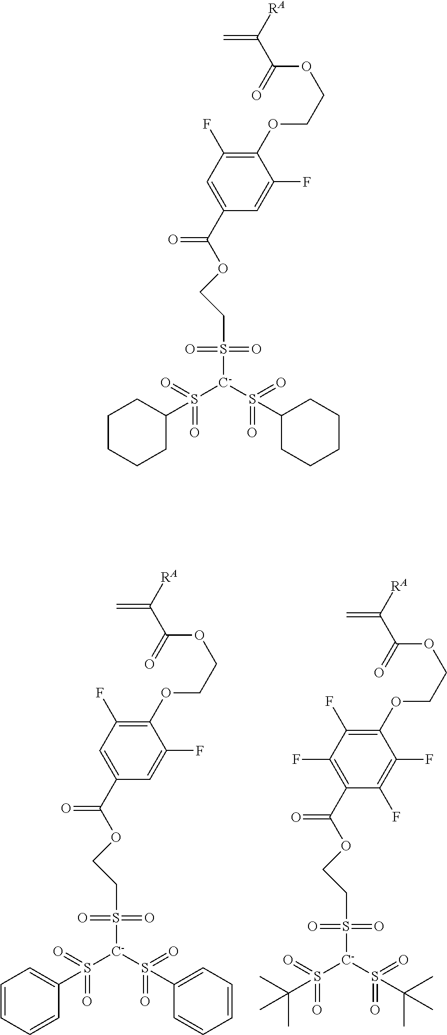

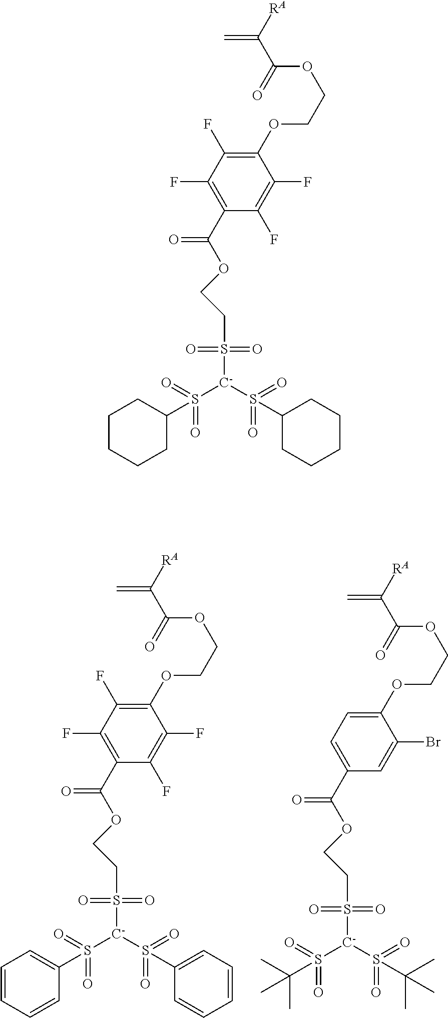

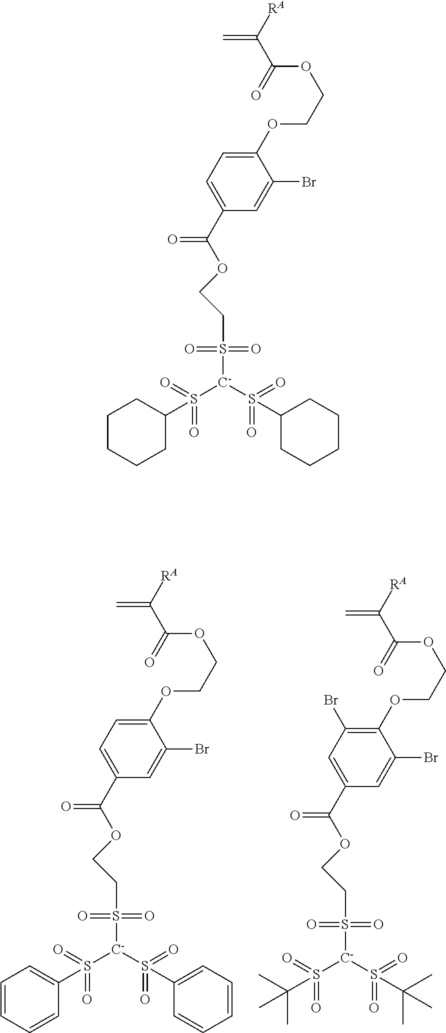

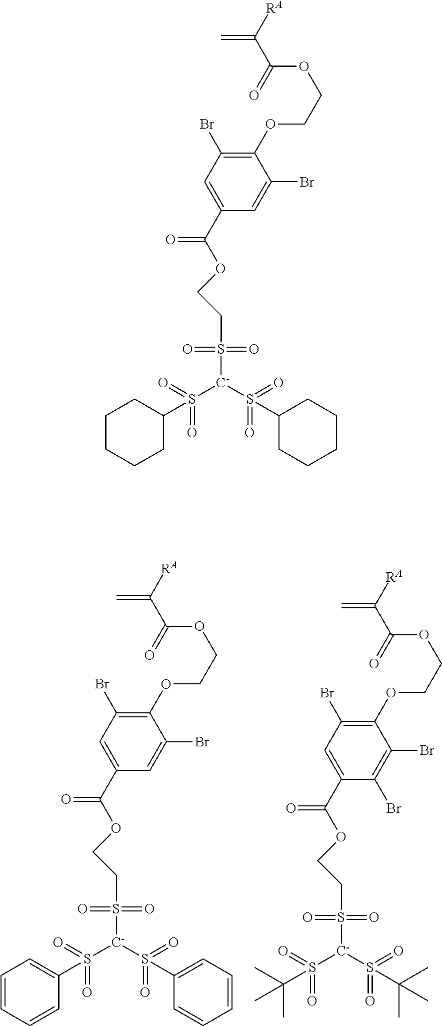

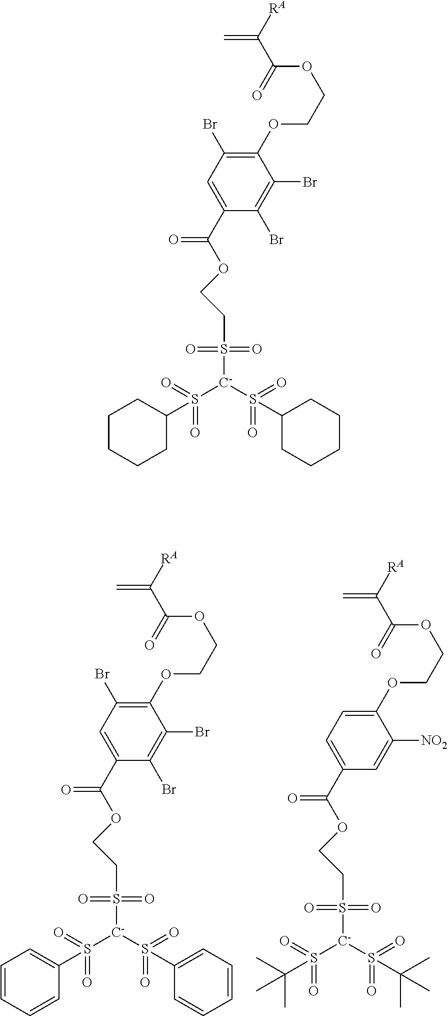

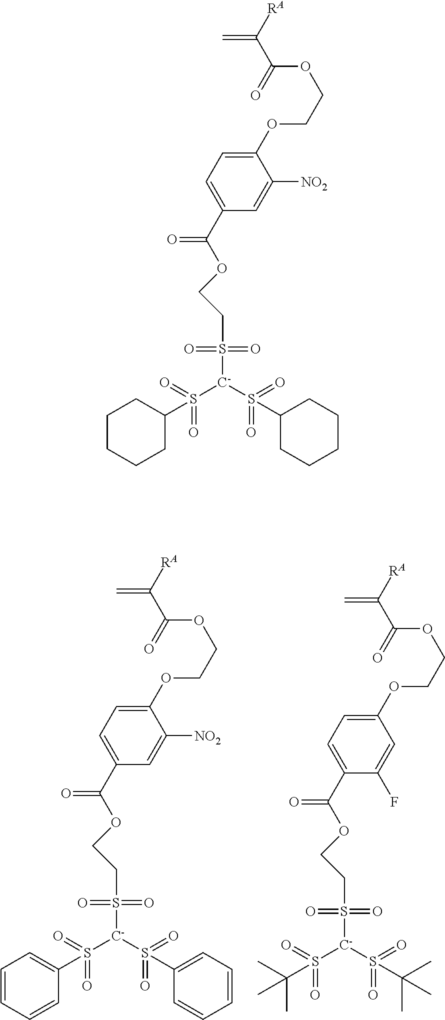

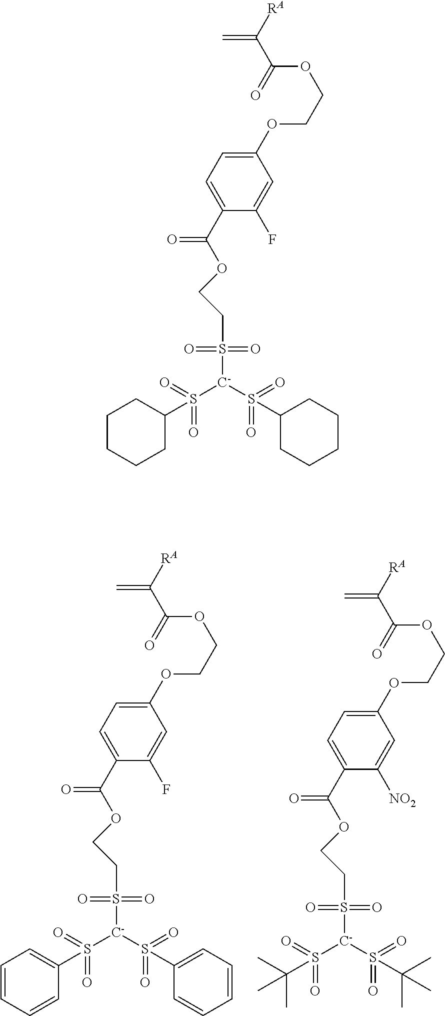

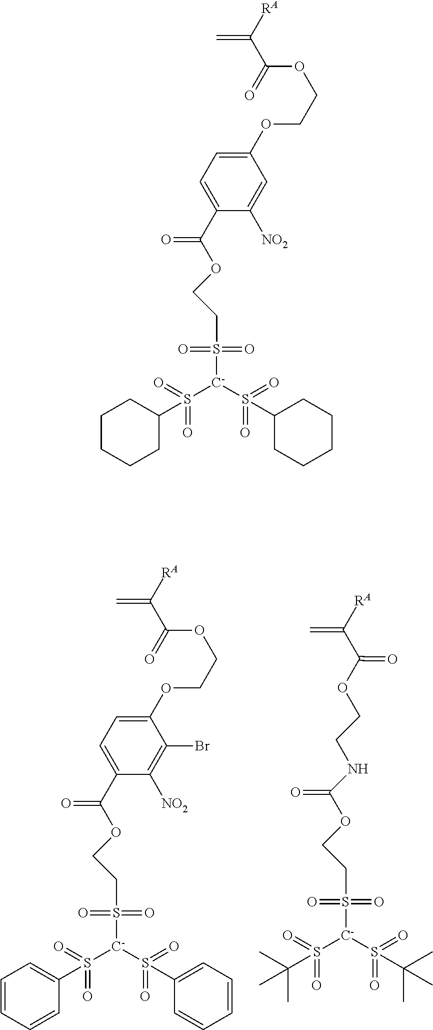

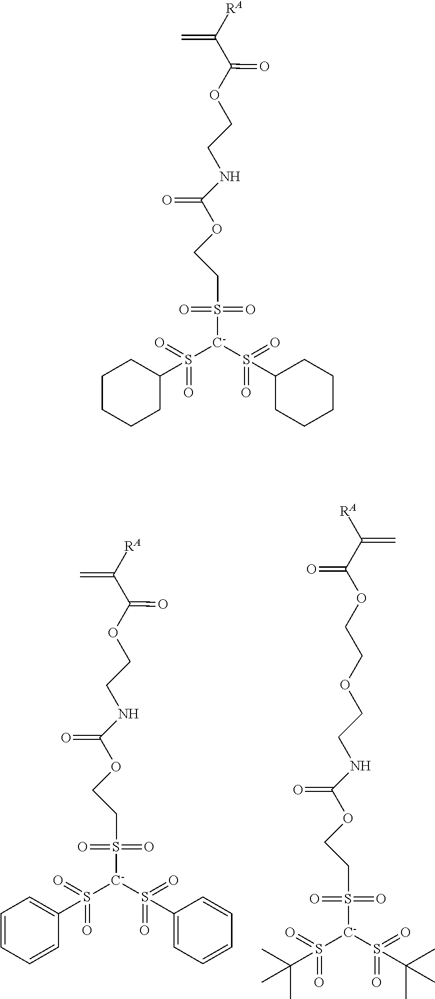

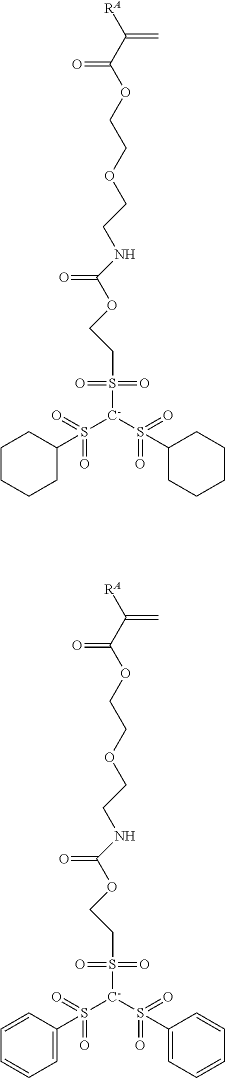

In formulae (a1) and (a2), R³ to R⁷ are each independently a halogen atom or a C₁-C₂₀ hydrocarbyl group which may contain a heteroatom. The hydrocarbyl group may be saturated or unsaturated, and may be linear, branched, or cyclic. Specific examples thereof include those groups mentioned as the C₁-C₂₀ hydrocarbyl group represented by R¹ and R².

R³ and R⁴ may bond together to form a ring with a sulfur atom to which they are bonded. The ring preferably has the following structure.

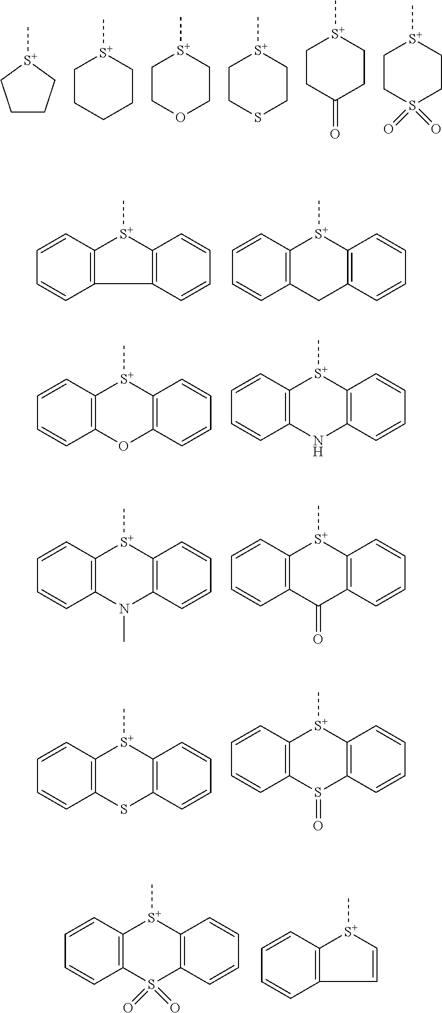

In the formulae, a broken line designates a bond with R⁵.

Examples of a sulfonium cation in the repeat units (a1) include those shown below, but are not limited thereto.

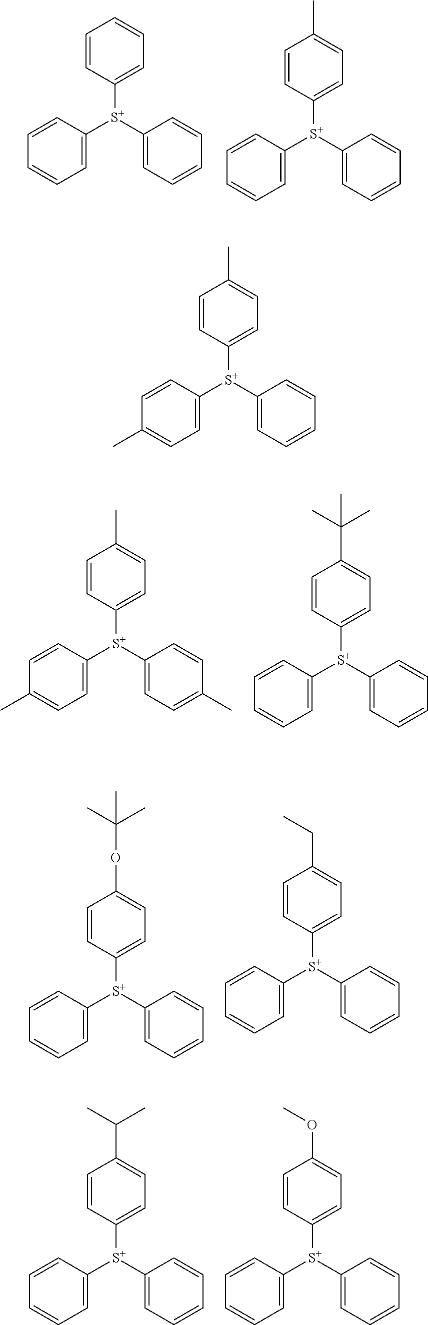

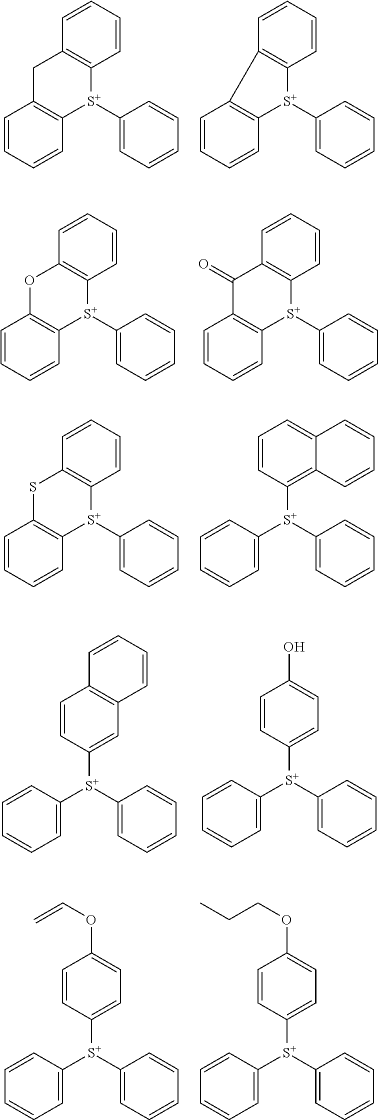

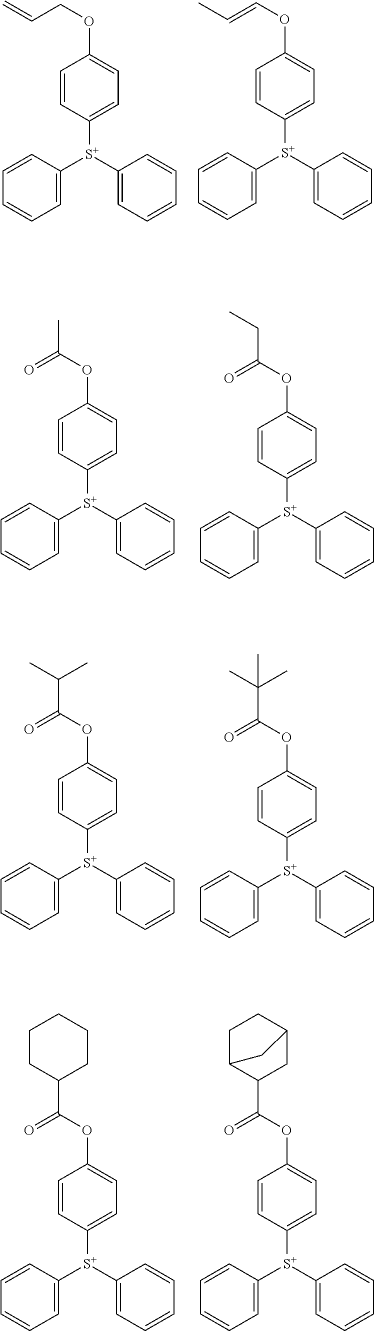

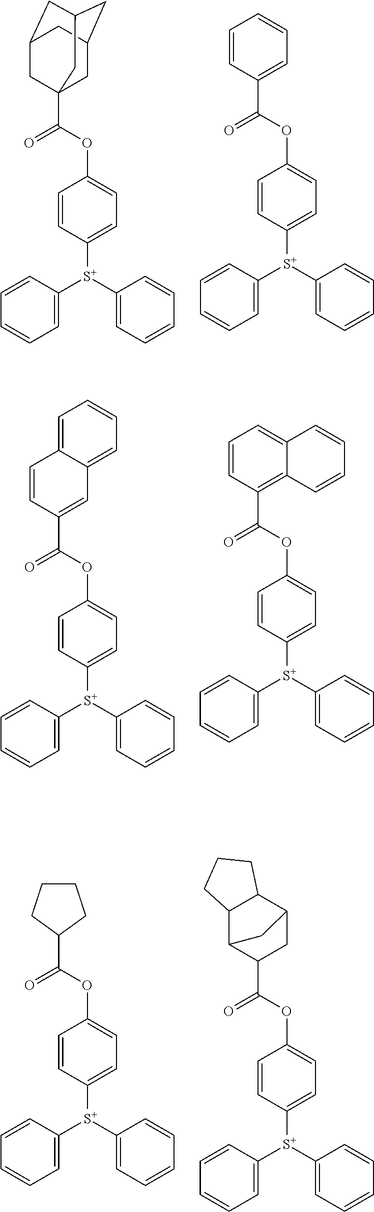

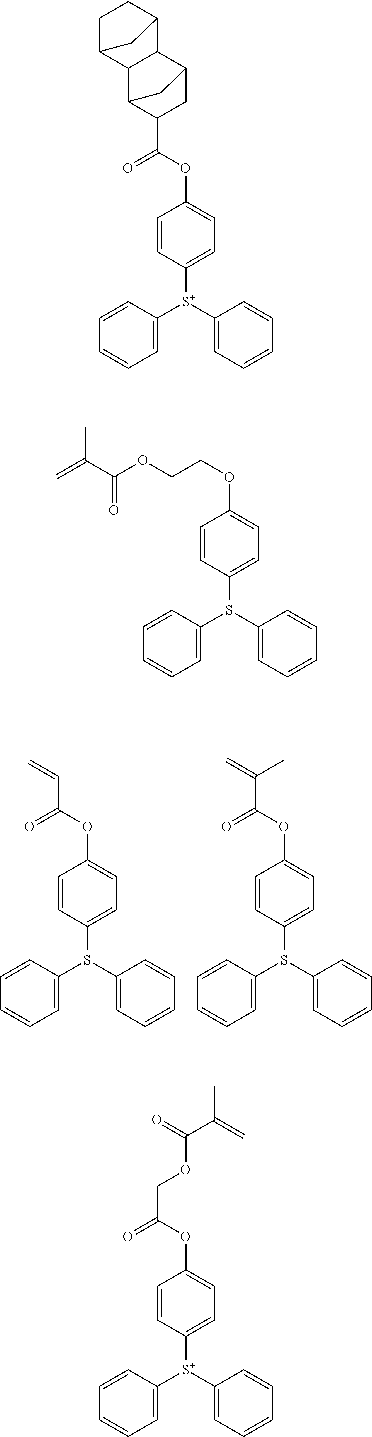

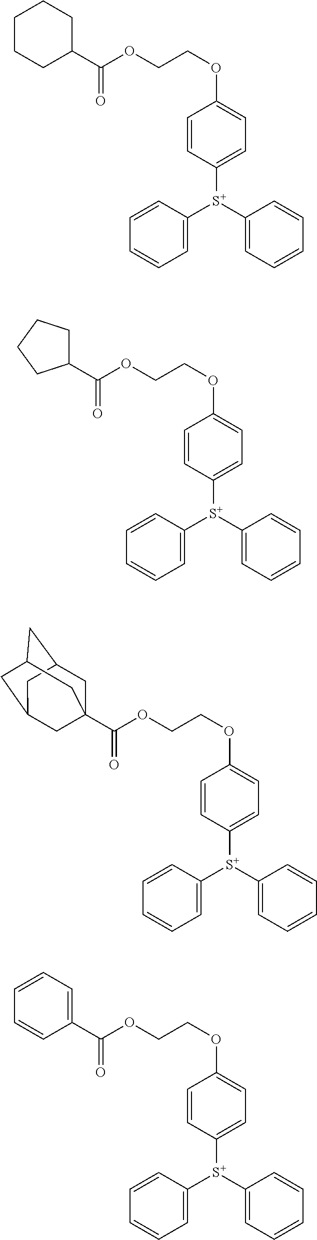

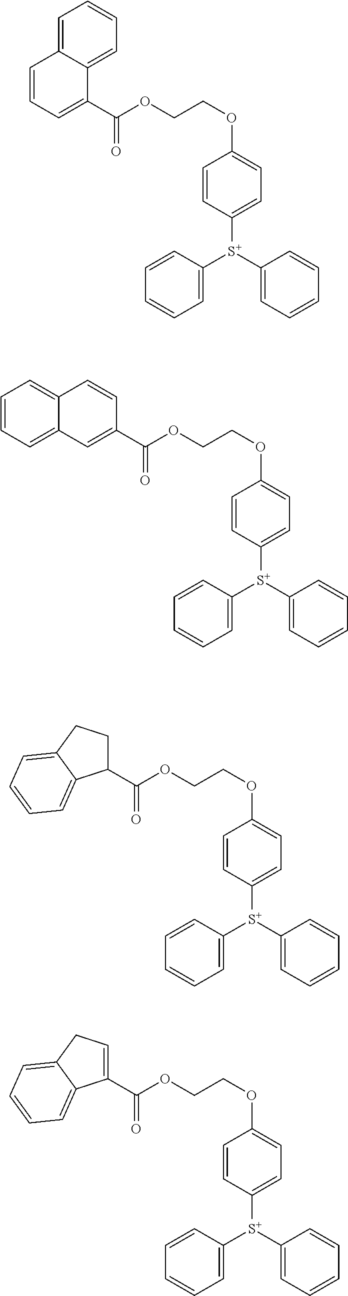

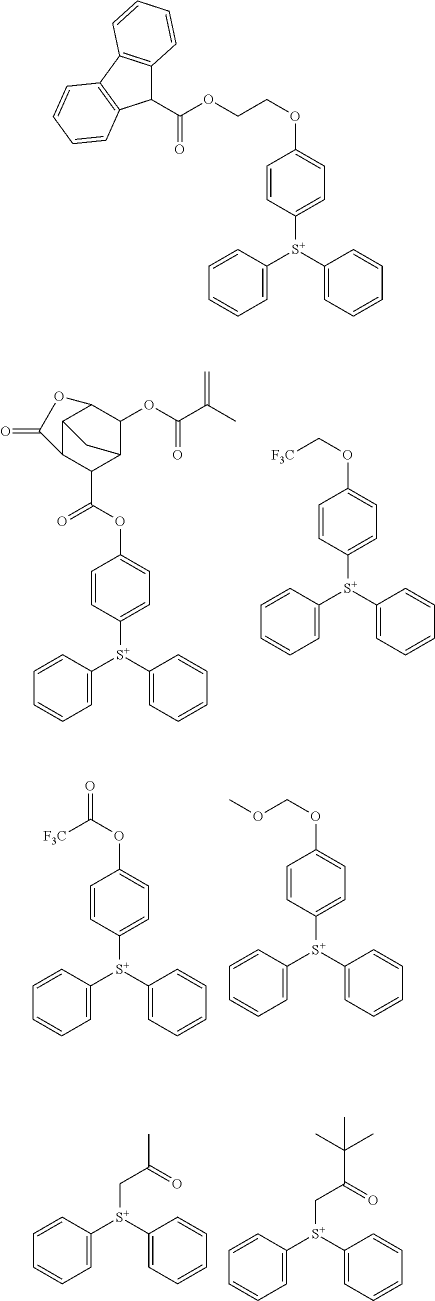

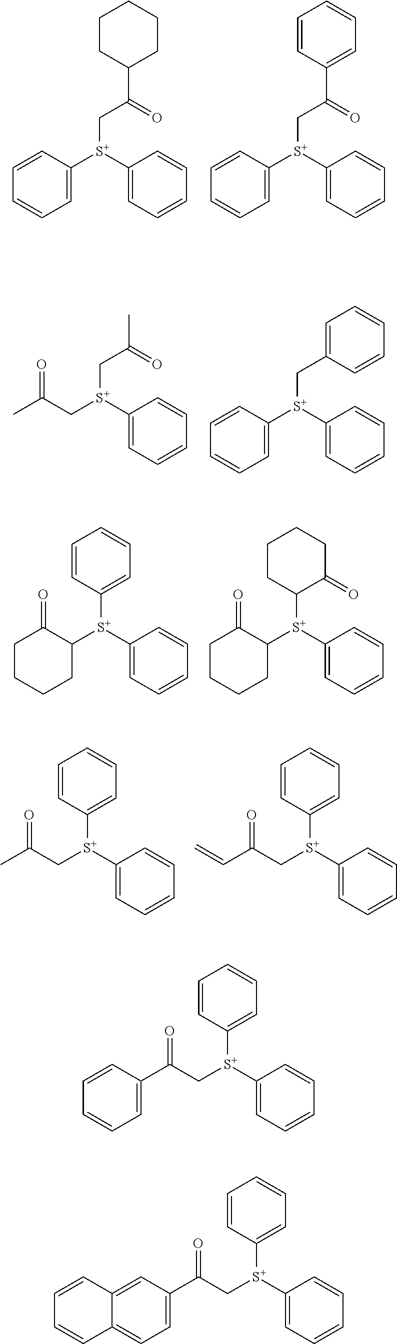

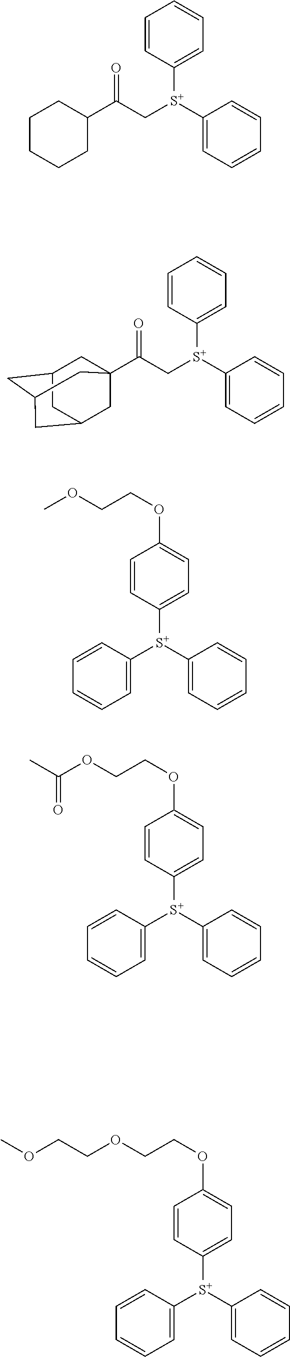

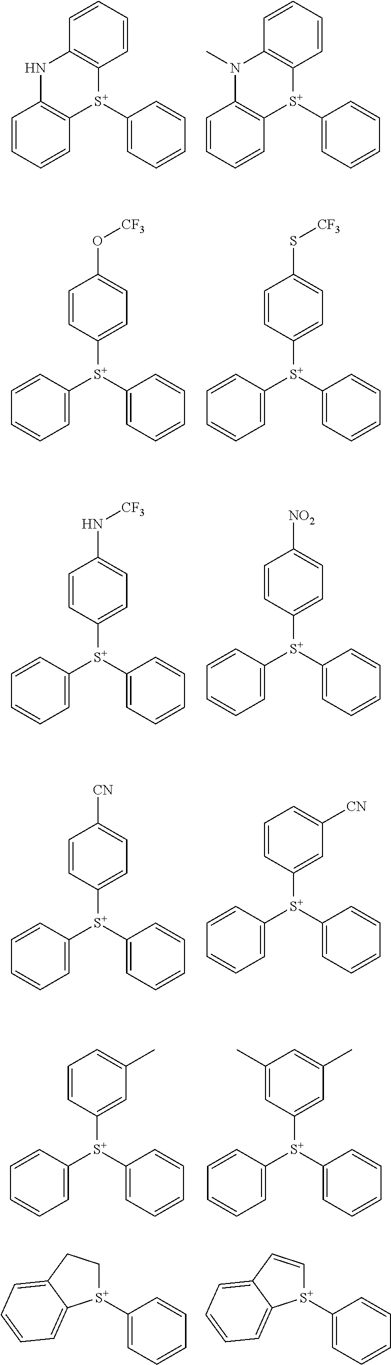

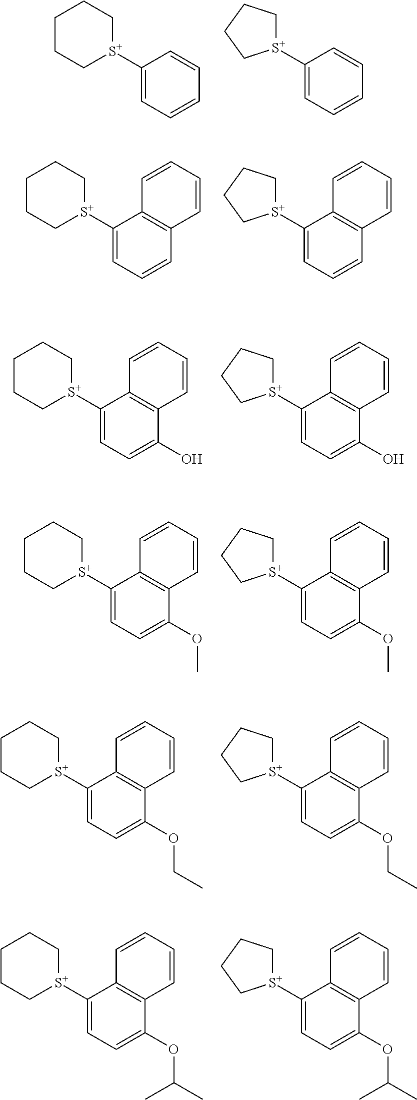

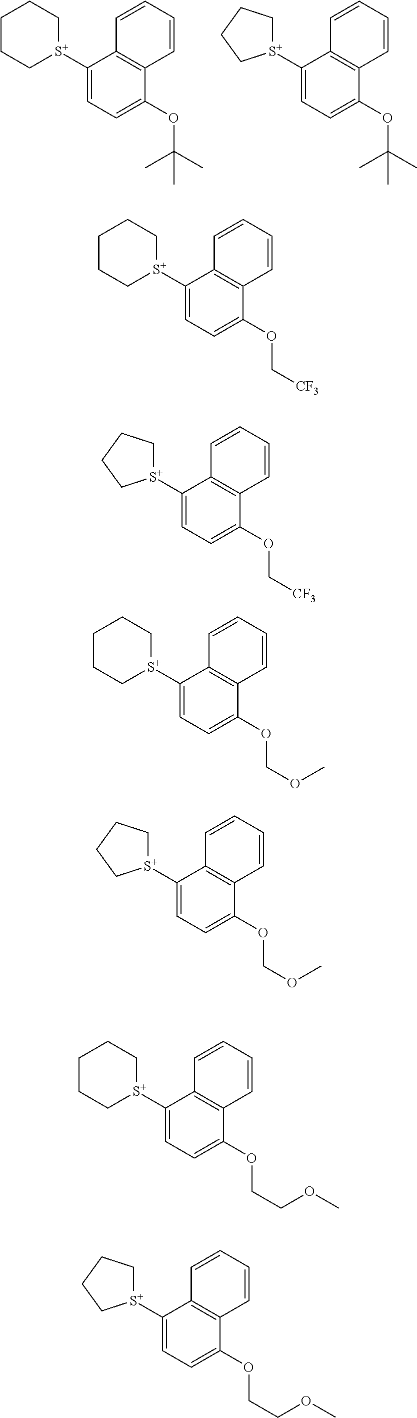

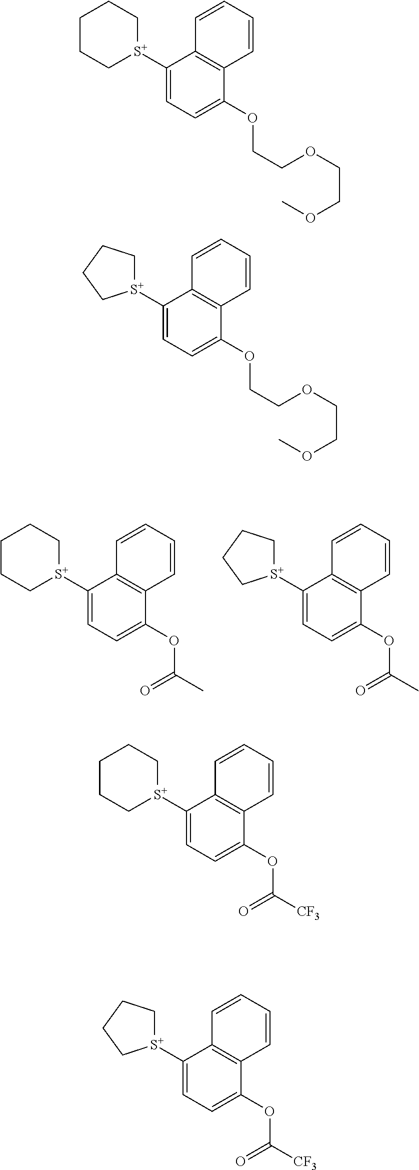

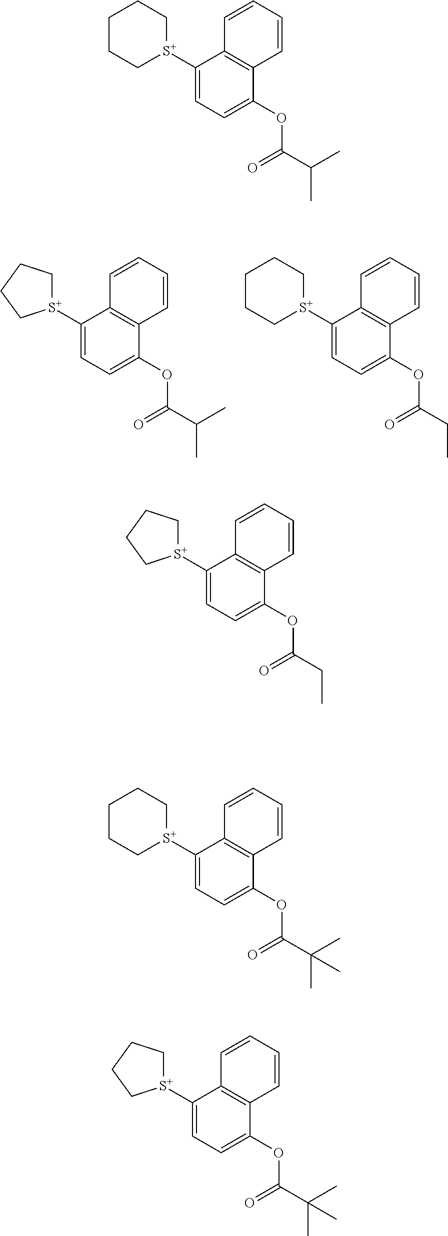

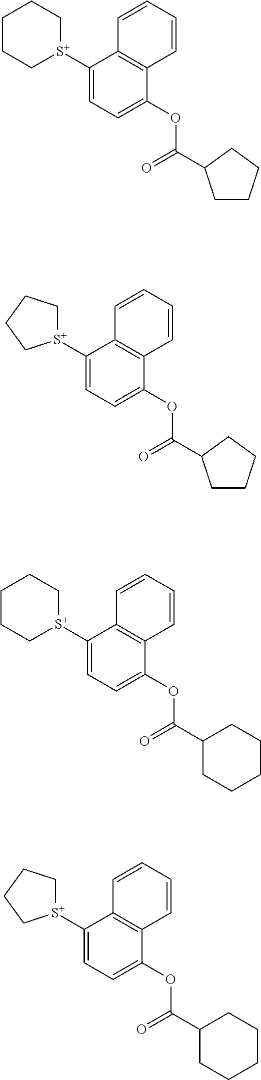

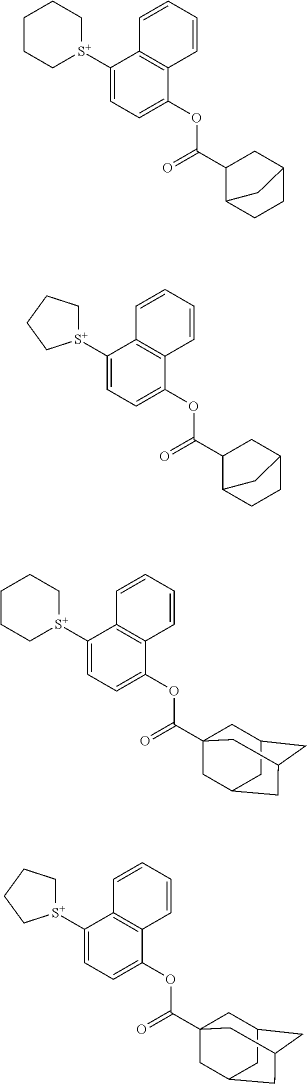

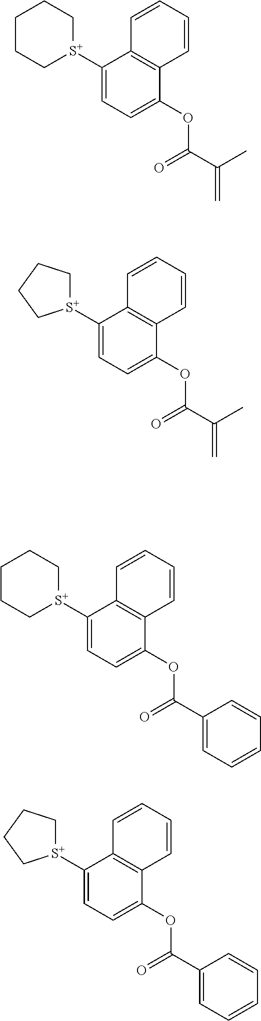

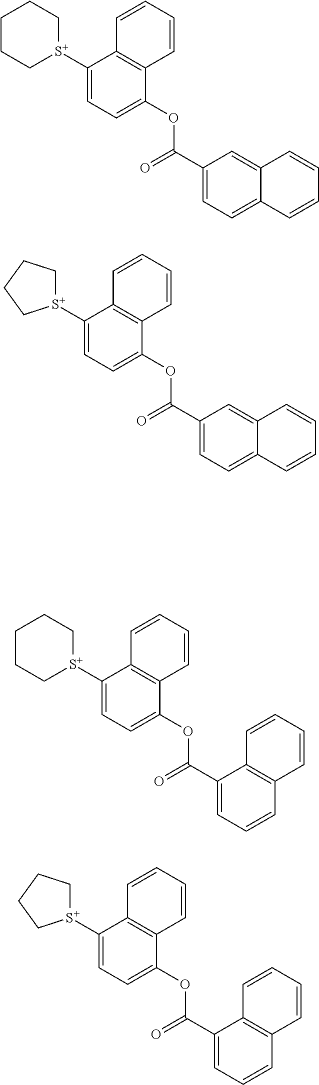

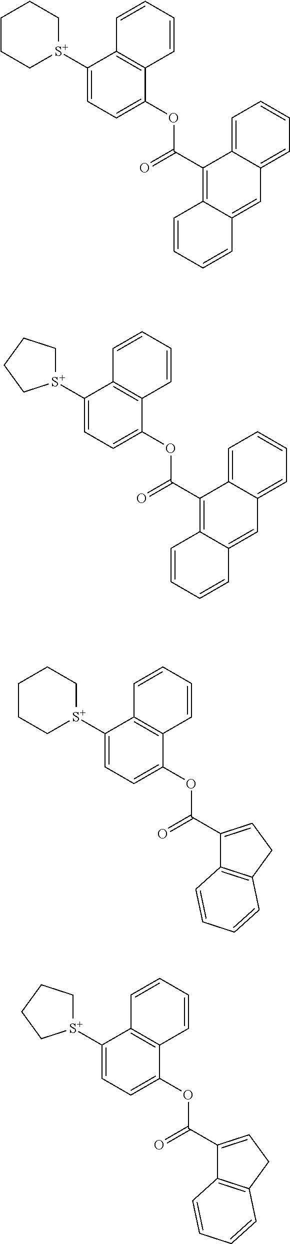

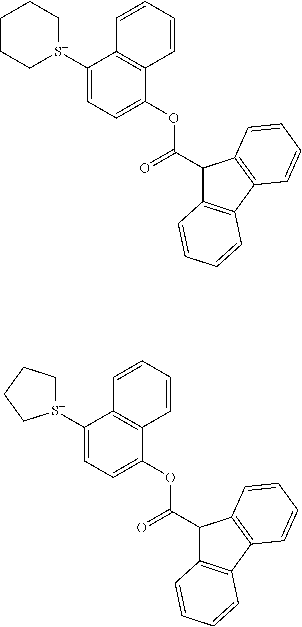

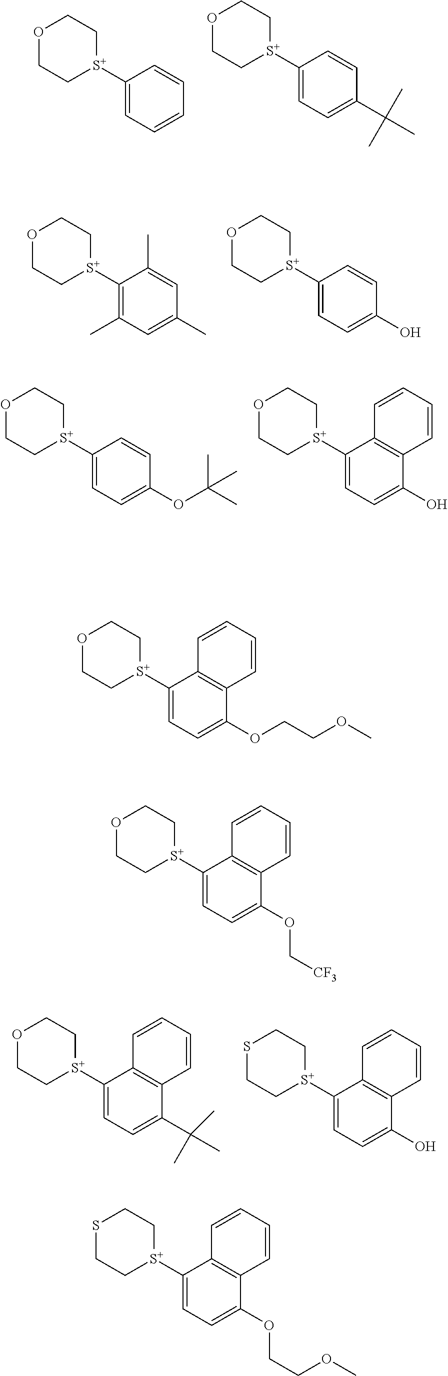

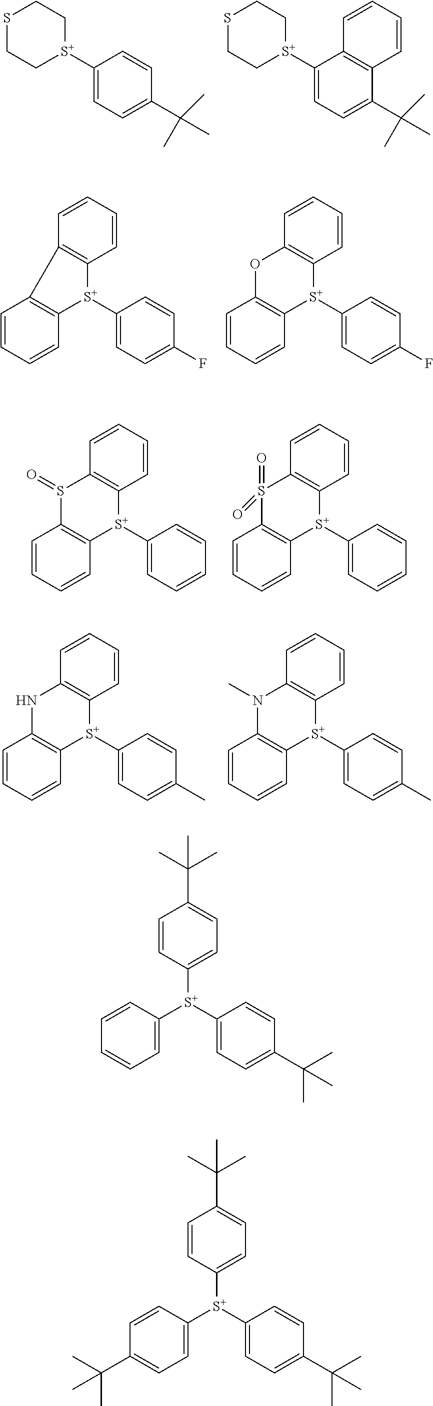

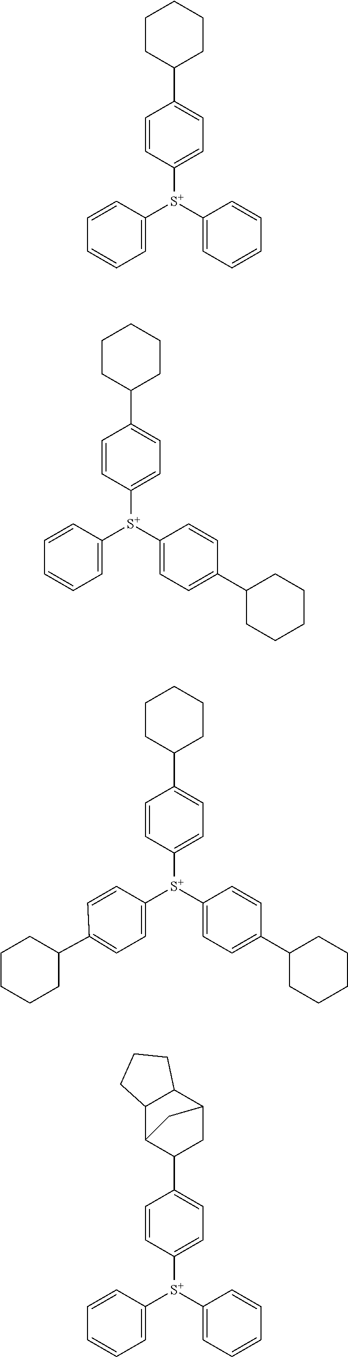

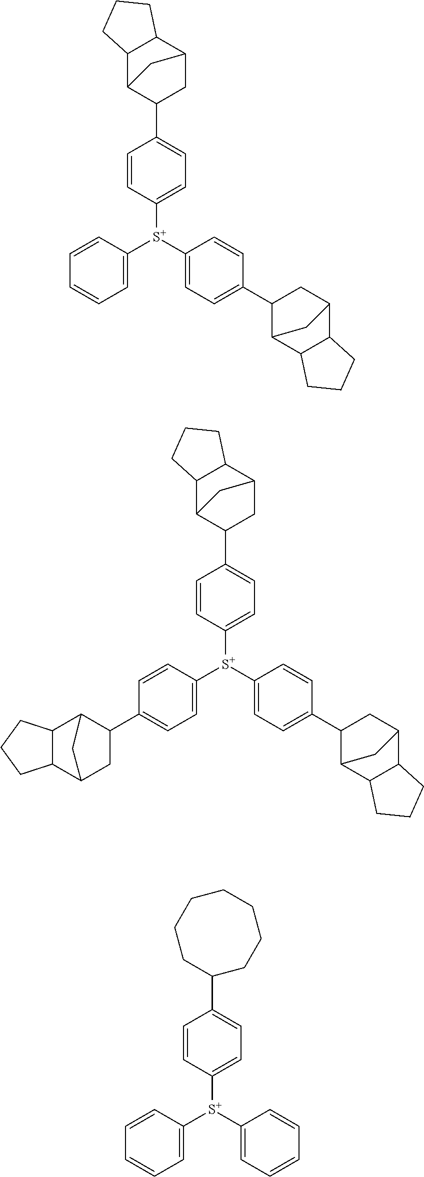

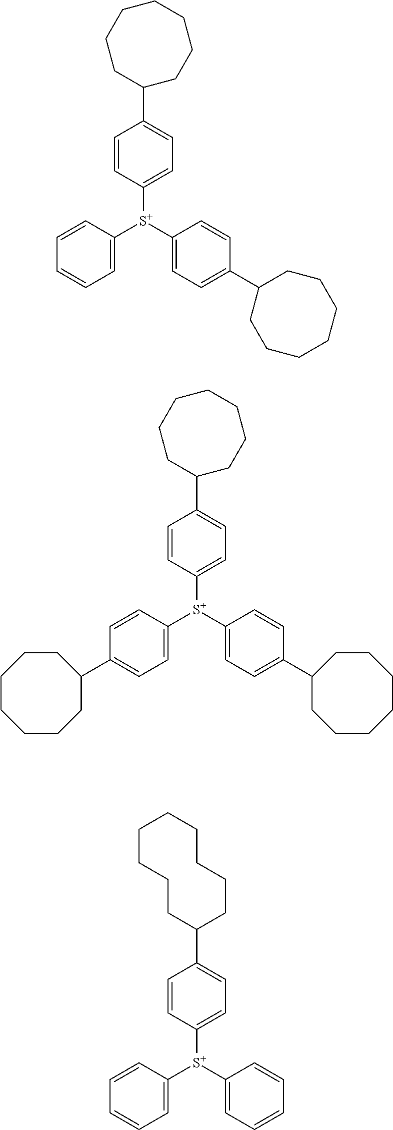

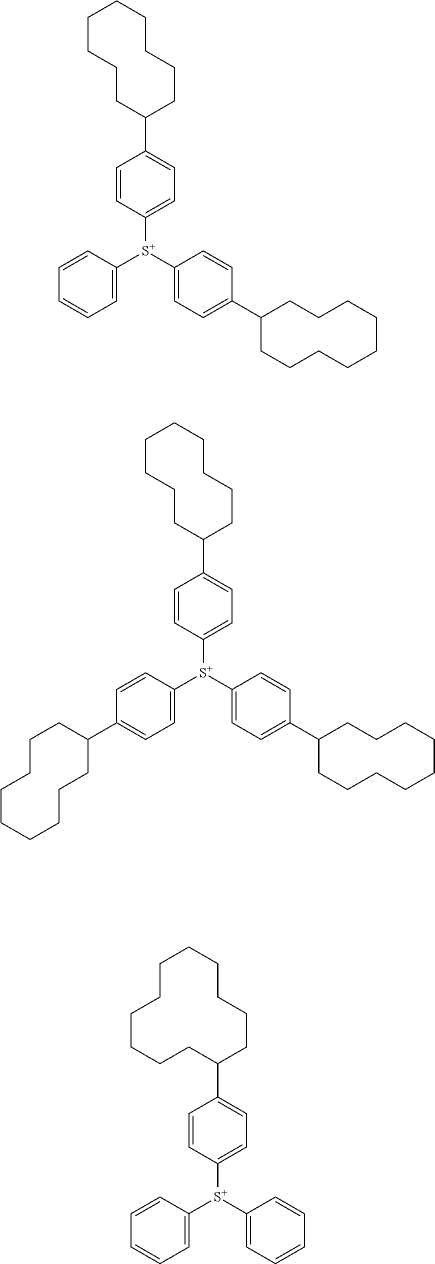

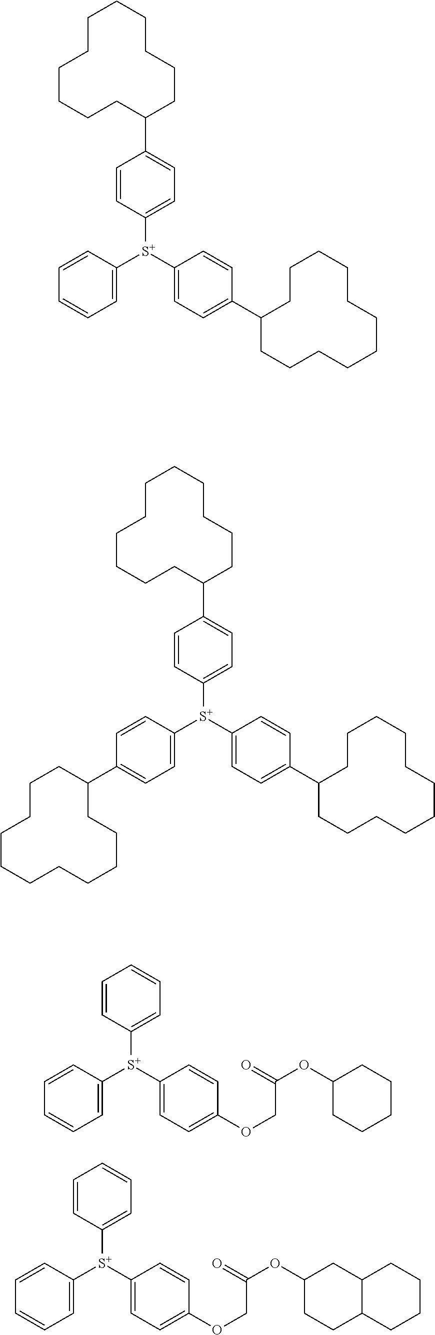

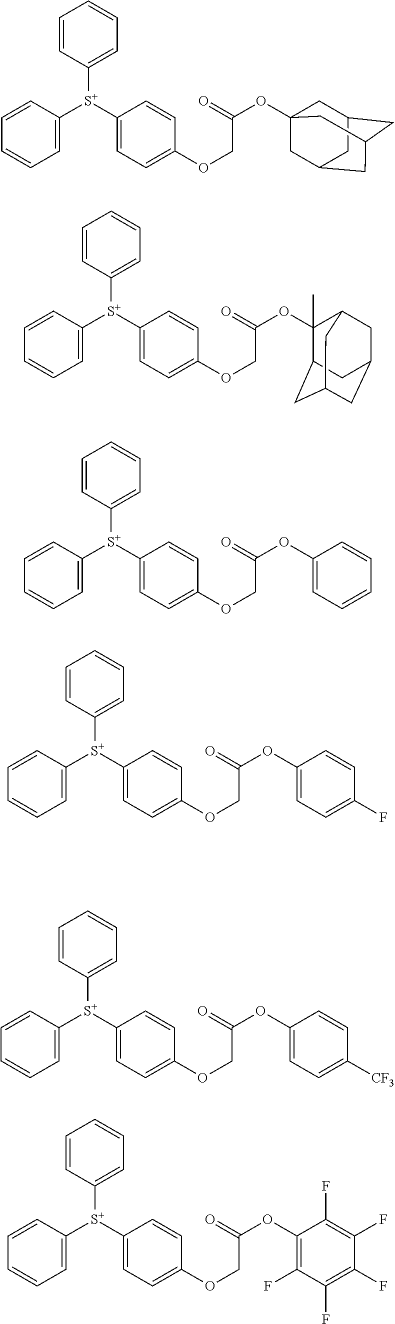

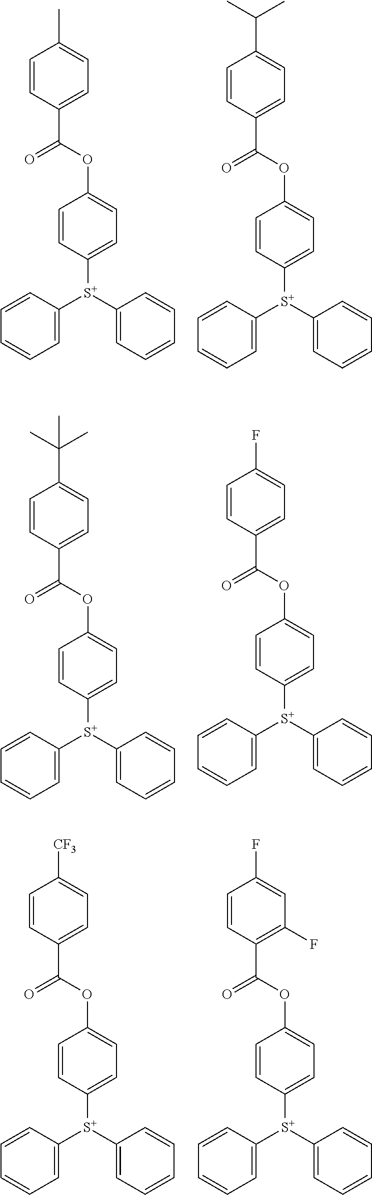

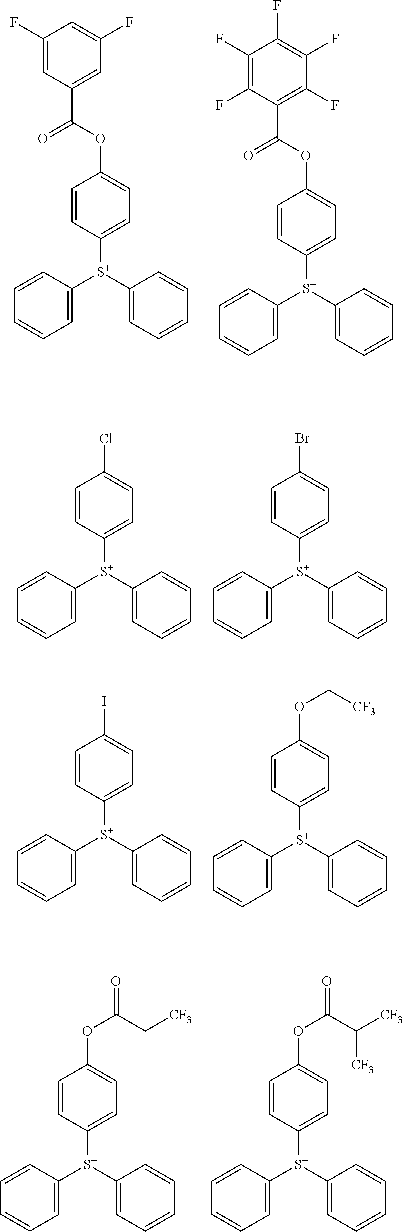

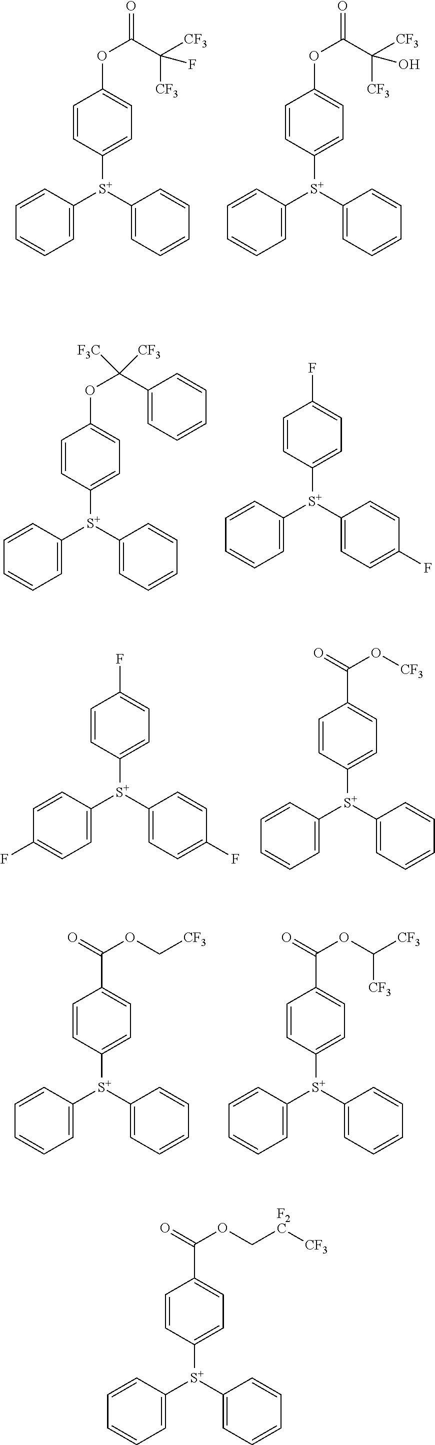

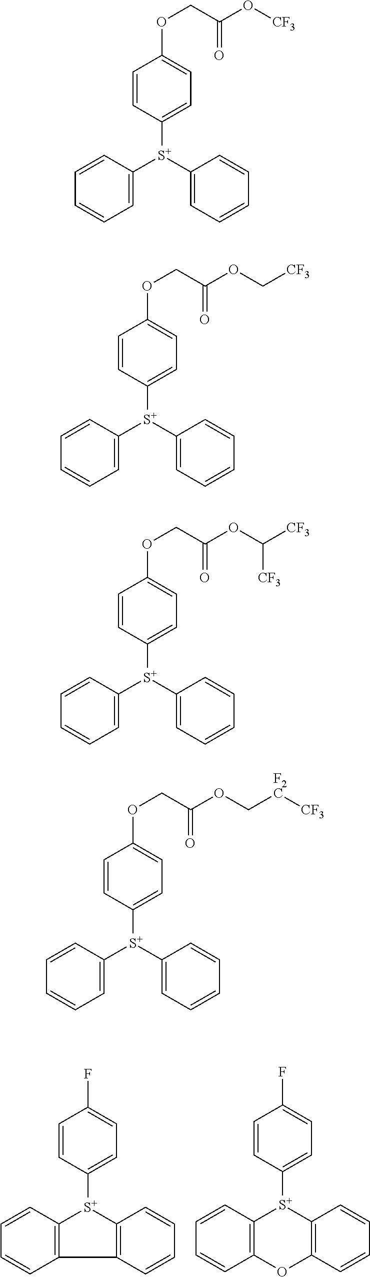

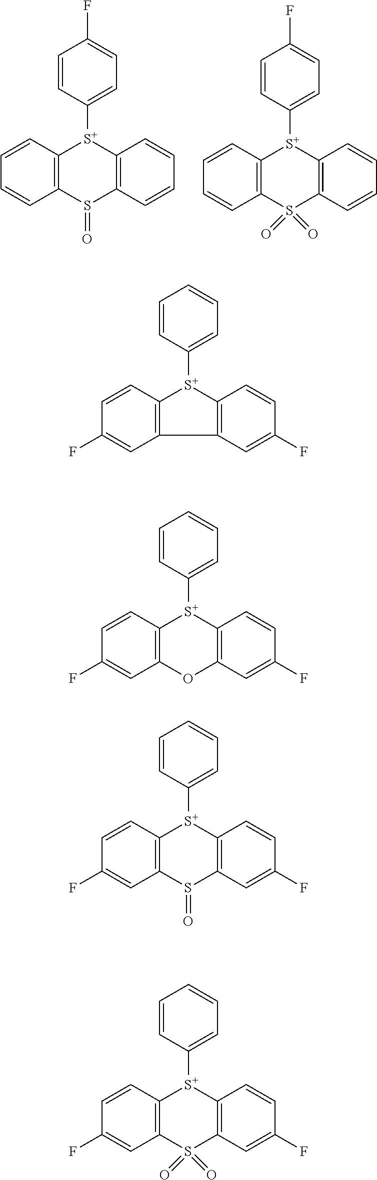

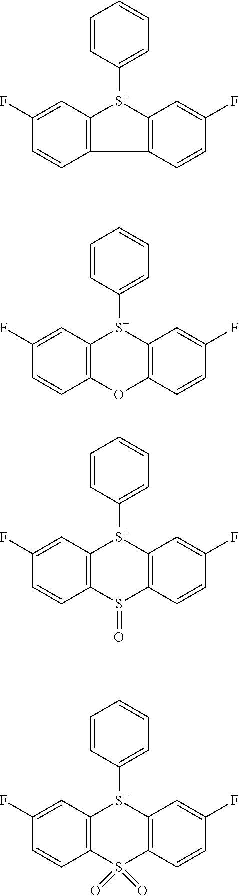

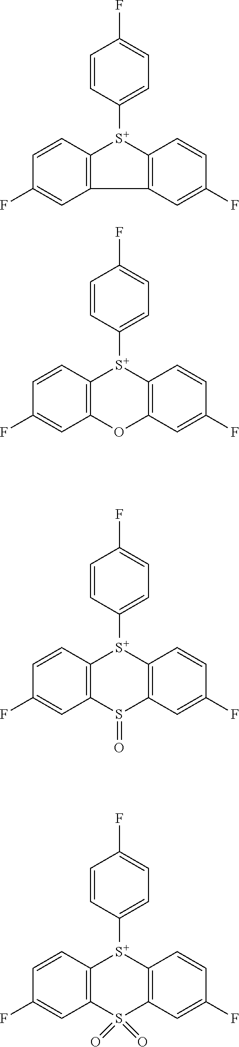

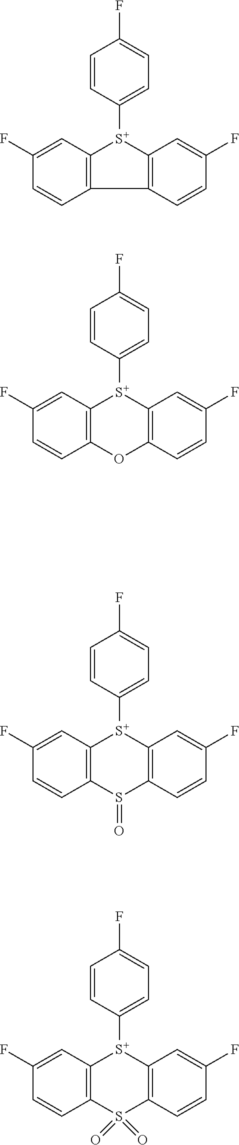

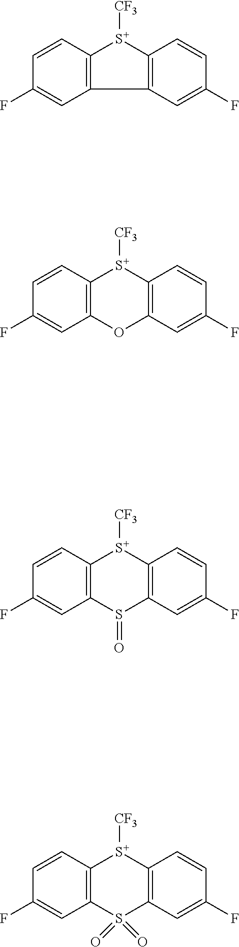

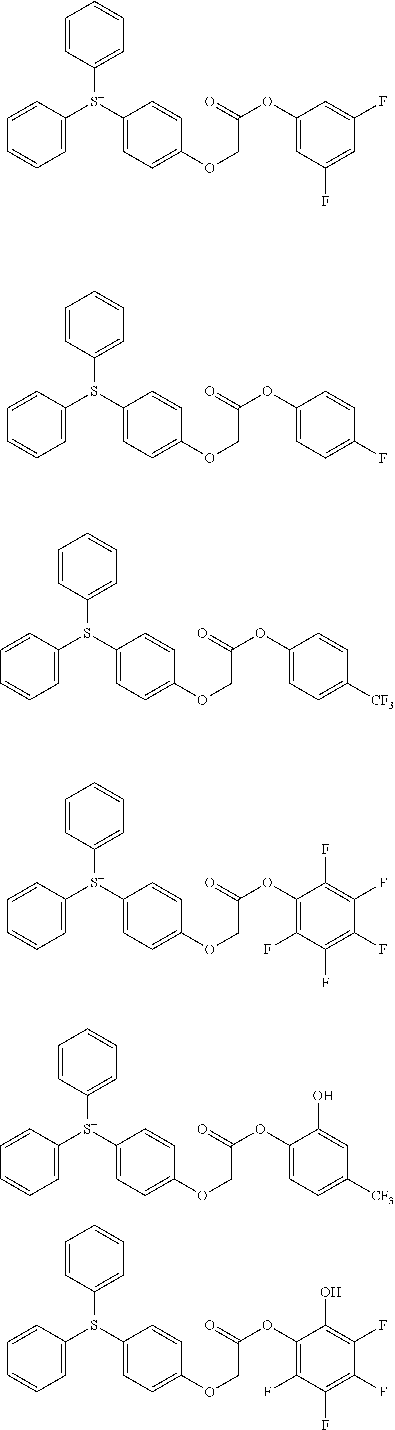

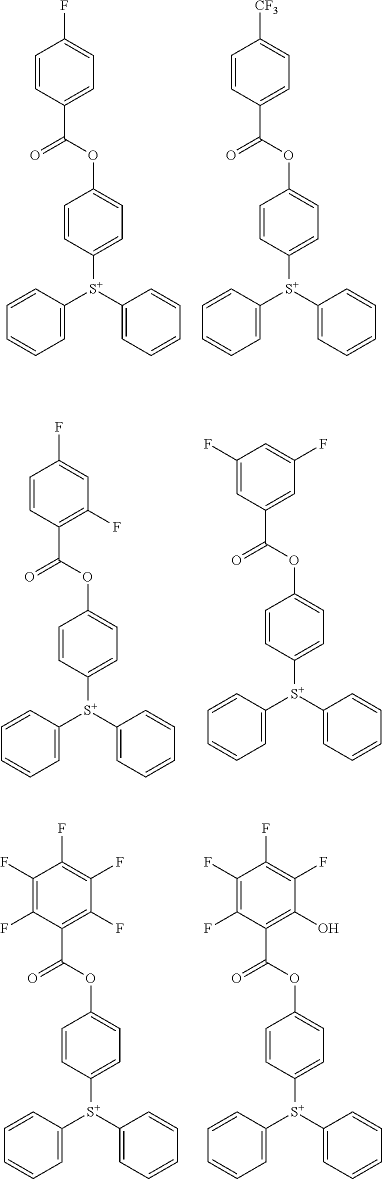

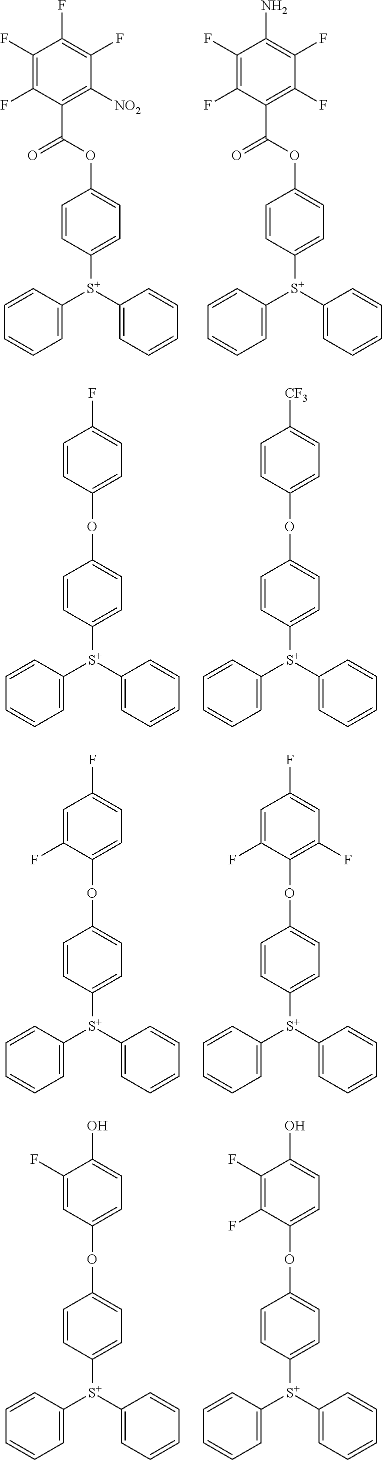

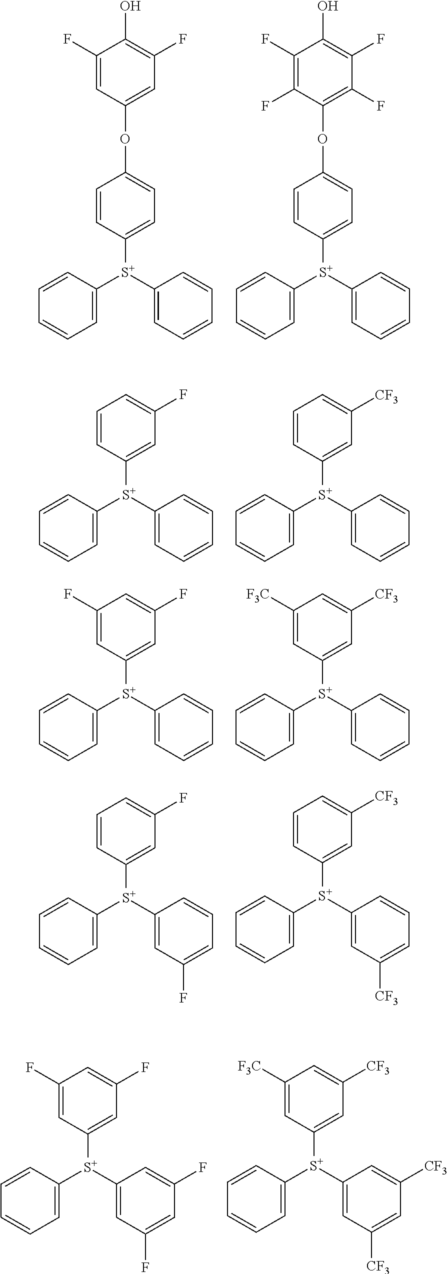

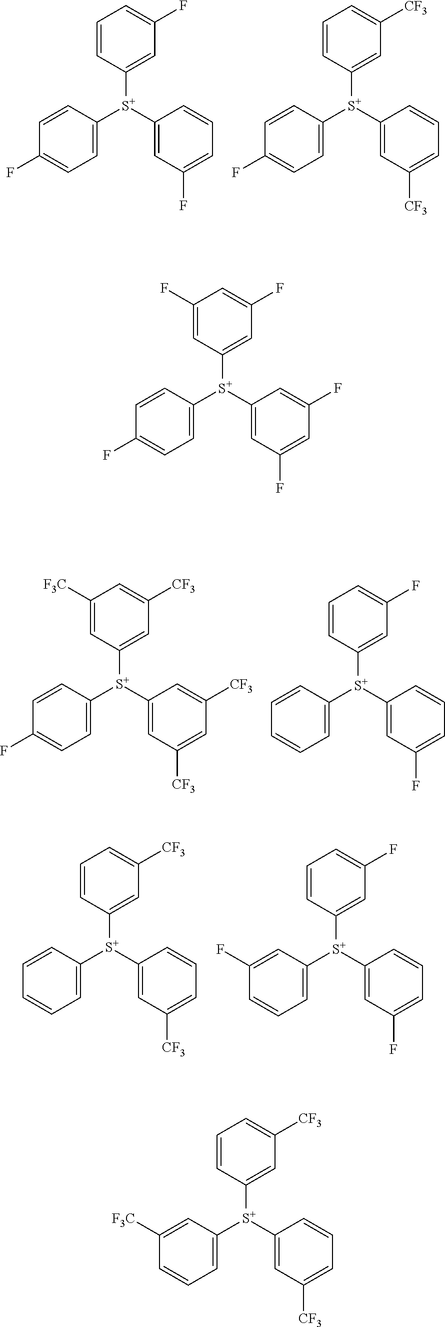

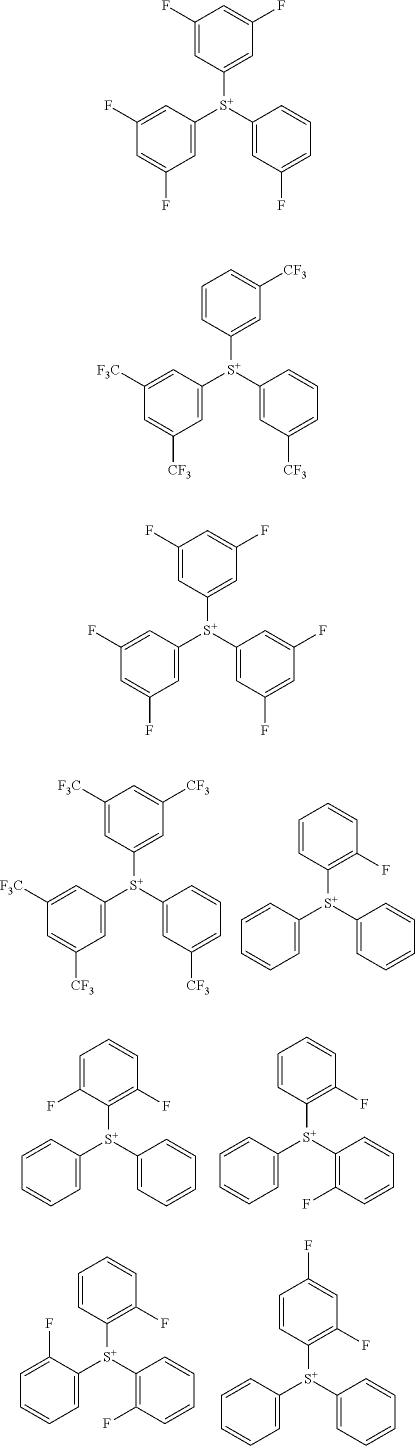

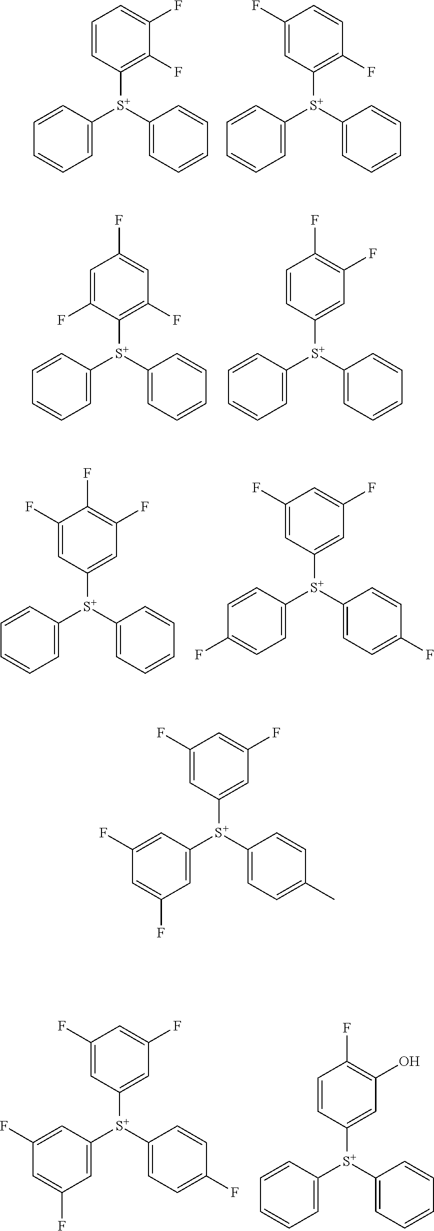

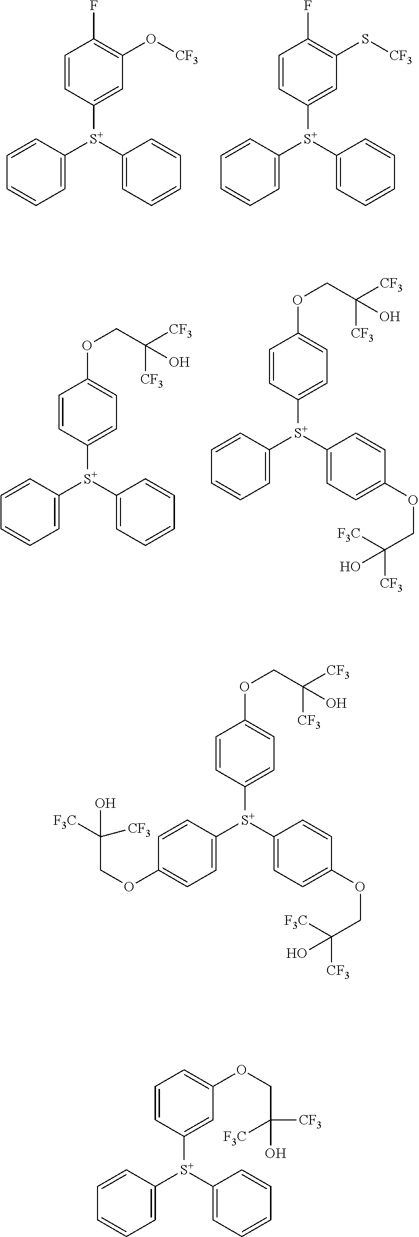

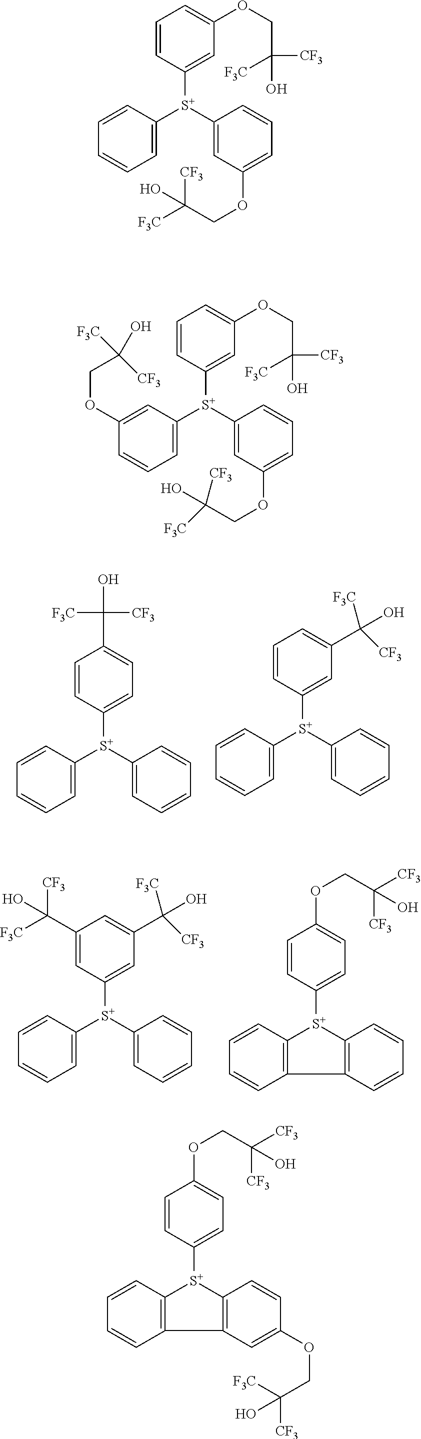

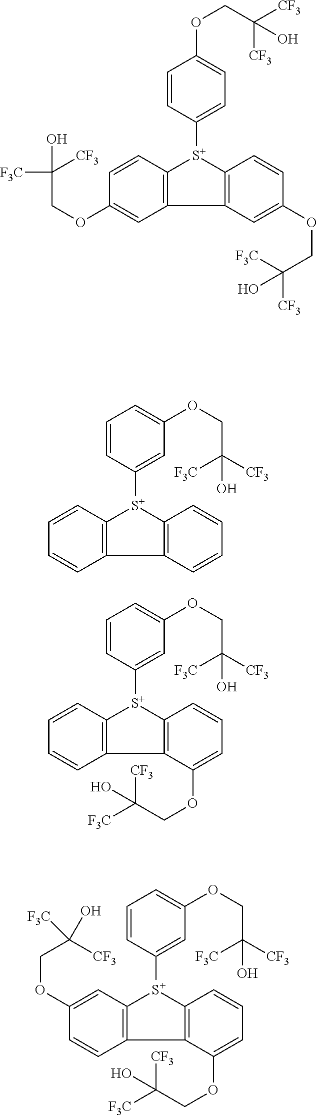

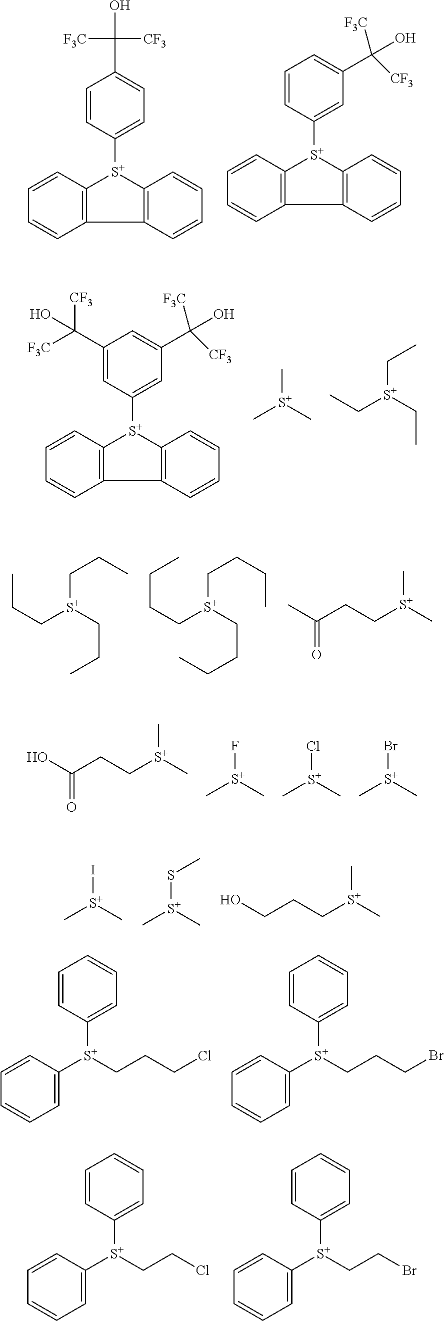

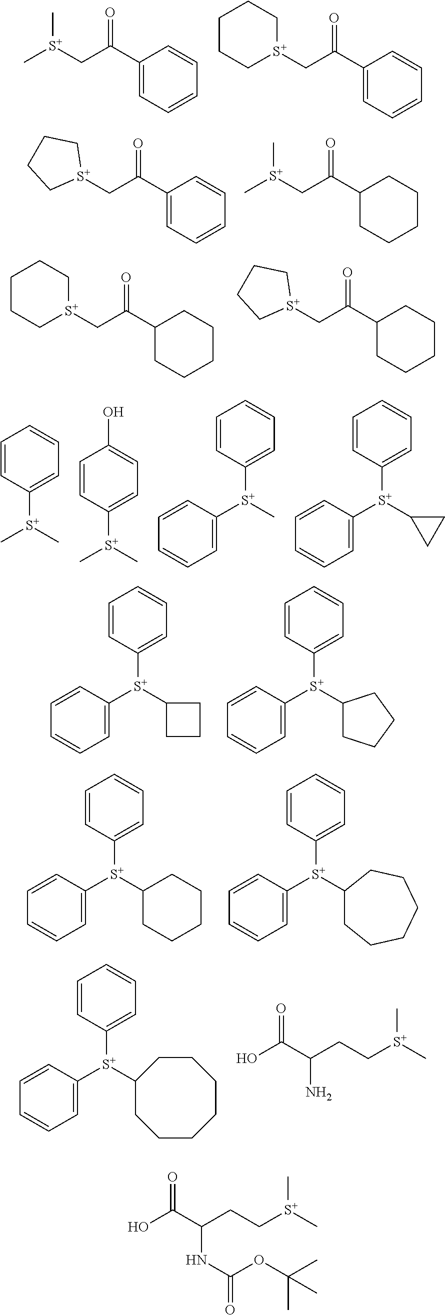

Examples of an iodonium cation in the repeat units (a2) include those shown below, but are not limited thereto.

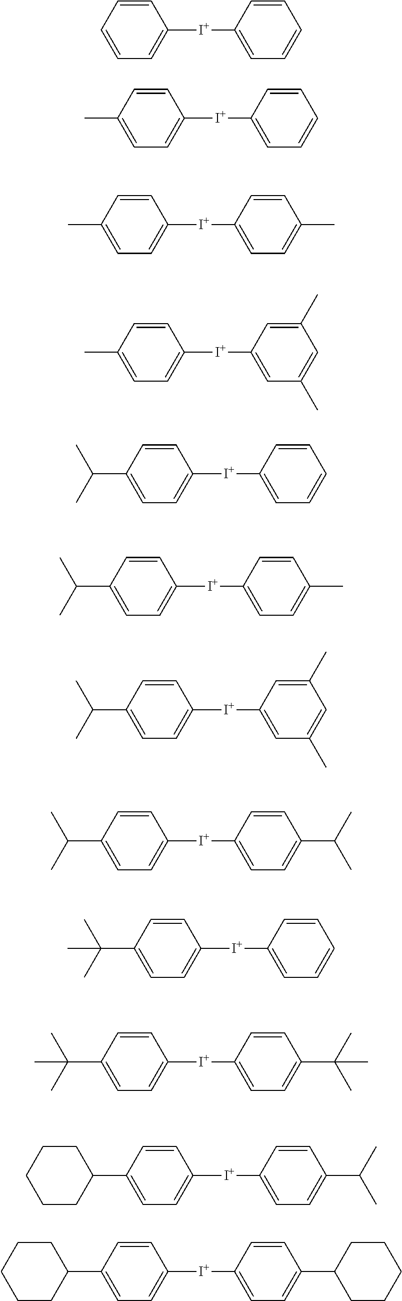

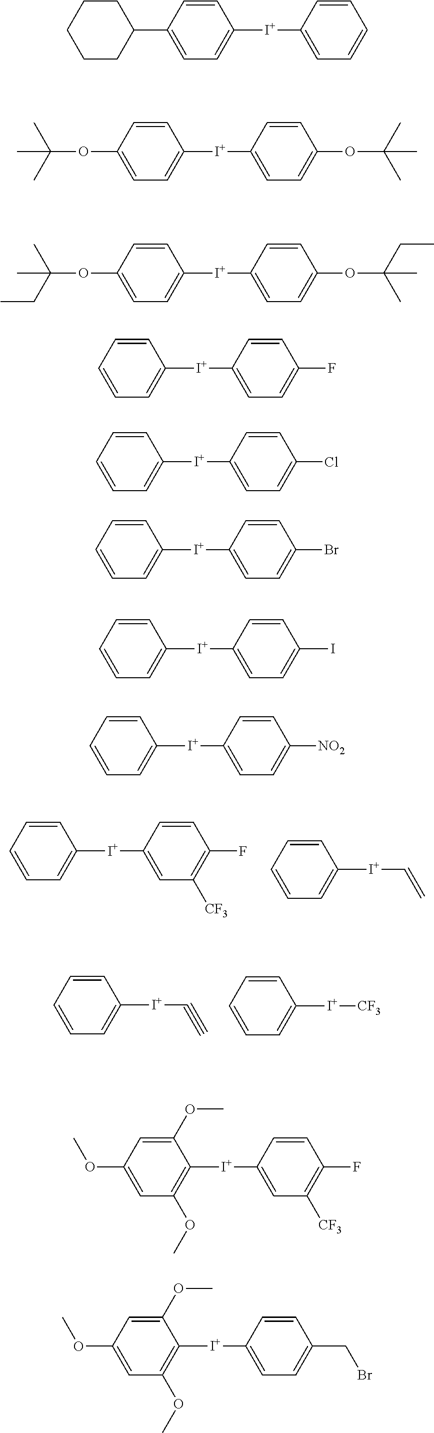

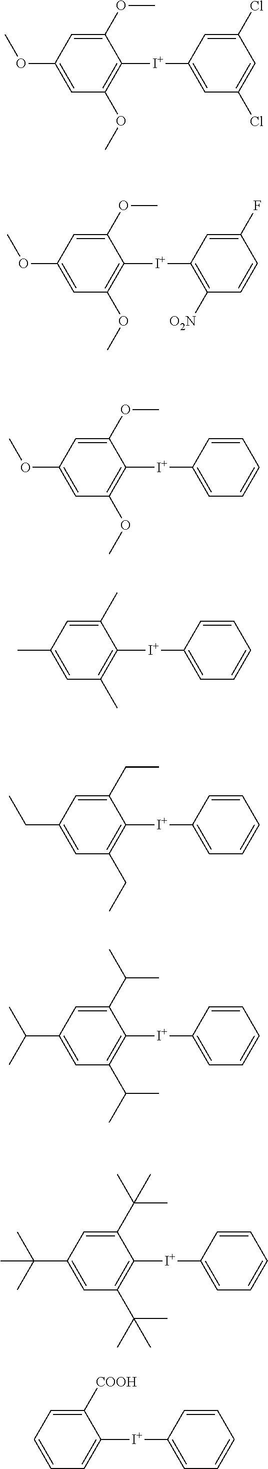

As a method for synthesizing a monomer from which the repeat units (a) are derived, the method described in JP-A 2020-055797 can be employed.

The sulfonium cation or the iodonium cation is decomposed by photolysis to yield trihydrocarbylsulfonylmethide acid free of a fluorine atom on a carbon atom at an α-position of a sulfonyl group bonded to the polymer. The trihydrocarbylsulfonylmethide acid free of a fluorine atom on a carbon atom at an α-position of a sulfonyl group is characterized in that it swells little in an alkaline developer because molecules of the alkaline developer cannot be coordinated to the vicinity of the methide acid that is sterically congested. Due to the low swelling characteristics of the trihydrocarbylsulfonylmethide acid, there is no decrease in CDU due to swelling during development of the contact hole pattern, stress applied to the pattern during spin drying after pure water rinsing of the line-and-space pattern is reduced, and pattern collapse after pattern formation can be reduced.

The repeat units (a) serve as a quencher having a sulfonium salt structure or an iodonium salt structure of trihydrocarbylsulfonylmethide acid free of a fluorine atom on a carbon atom at an α-position of a sulfonyl group, and serve as a quenched-bound polymer. The quenched-bound polymer has a strong effect of reducing acid diffusion, and has excellent resolution as described above. Therefore, high resolution, low LWR, and excellent CDU can be achieved.

In order to increase the dissolution contrast, the base polymer may contain at least one kind selected from repeat units in which a hydrogen atom of a carboxy group is substituted with an acid labile group (hereinafter, the repeat units are also referred to as repeat units (b1)) and repeat units in which a hydrogen atom of a phenolic hydroxy group is substituted with an acid labile group (hereinafter, the repeat units are also referred to as repeat units (b2)).

Examples of the repeat units (b1) and (b2) include those represented by formulae (b1) and (b2), respectively.

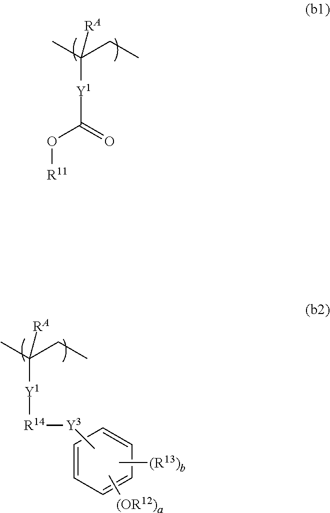

In formulae (b1) and (b2), R^{A} is each independently a hydrogen atom or a methyl group. Y¹ is a single bond, a phenylene group, a naphthylene group, or a C₁-C₁₂ linking group containing at least one moiety selected from an ester bond, an ether bond, and a lactone ring, and the phenylene group, the naphthylene group, and the linking group may have at least one moiety selected from a hydroxy group, a C₁-C₈ saturated hydrocarbyloxy group, and a C₂-C₈ saturated hydrocarbylcarbonyloxy group. Y² is a single bond, an ester bond, or an amide bond. Y³ is a single bond, an ether bond, or an ester bond. R¹¹ and R¹² are acid labile groups. R¹³ is a fluorine atom, a trifluoromethyl group, a cyano group, or a C₁-C₆ saturated hydrocarbyl group. R¹⁴ is a single bond or a C₁-C₆ alkanediyl group in which some constituent —CH₂— may be substituted with an ether bond or an ester bond. a is 1 or 2, and b is an integer of 0 to 4, provided that 1≤ a+b≤5.

Examples of the monomer from which the repeat units (b1) are derived include those shown below, but are not limited thereto. In the formulae, R^{A} and R¹¹ are as defined above.

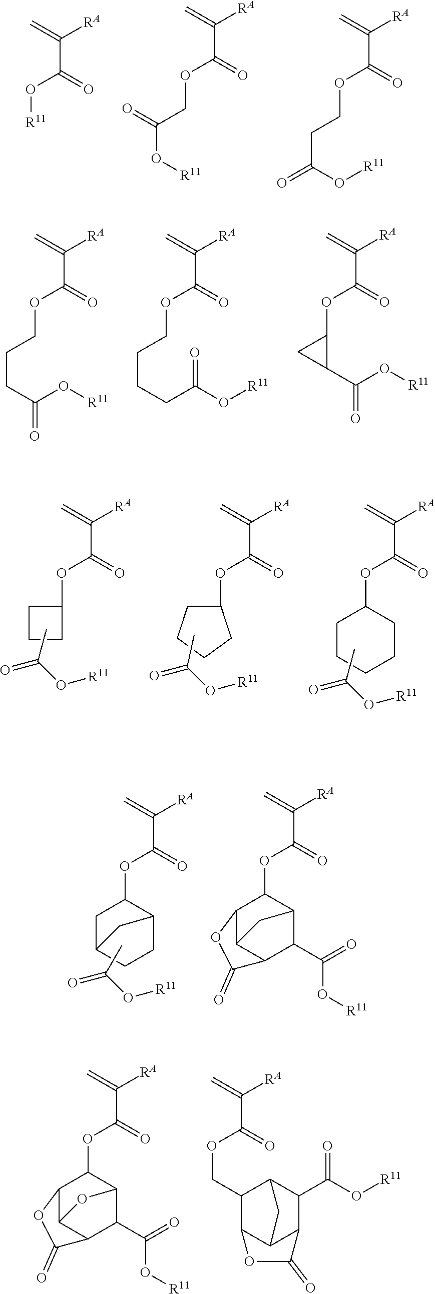

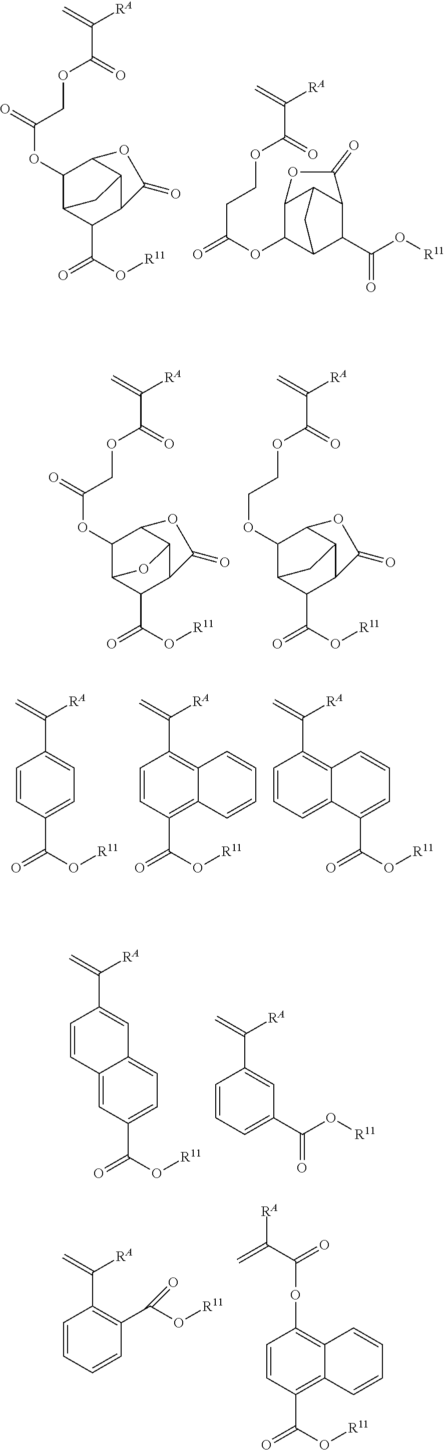

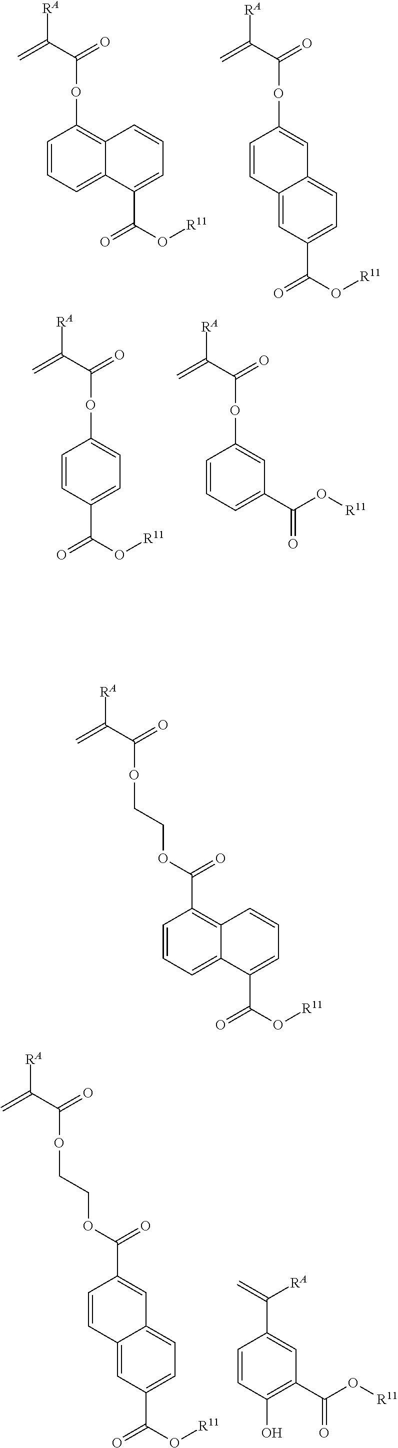

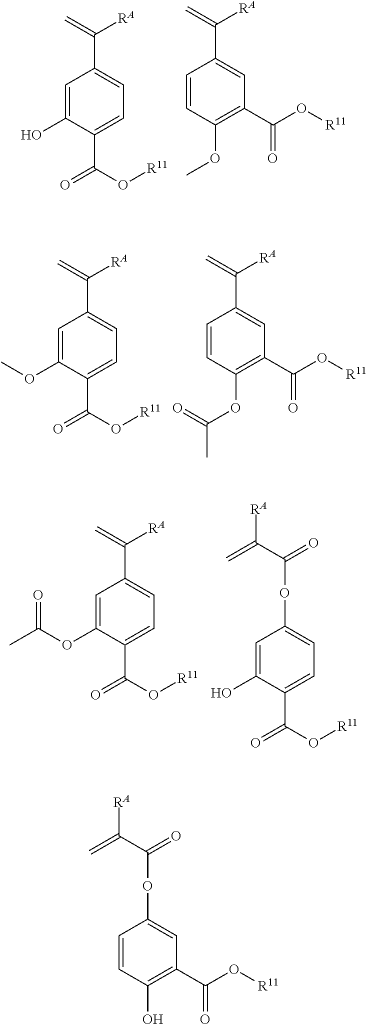

Examples of the monomer from which the repeat units (b2) are derived include those shown below, but are not limited thereto. In the formulae. R^{A} and R¹² are as defined above.

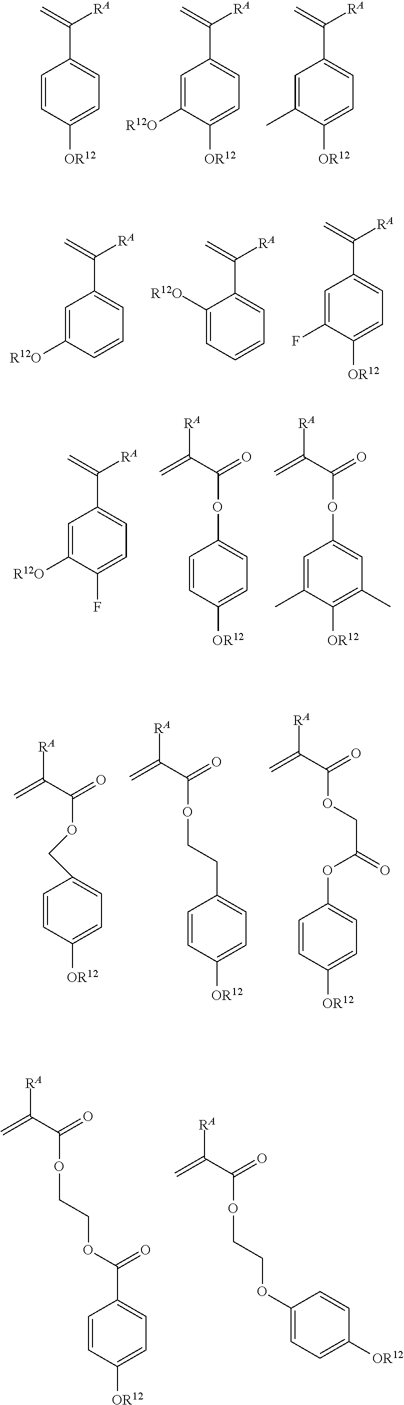

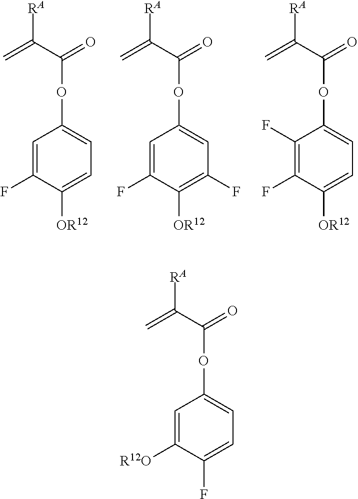

The acid labile group represented by R¹¹ or R¹² may be selected from a variety of groups, and examples thereof include those represented by formulae (AL-1) to (AL-3).

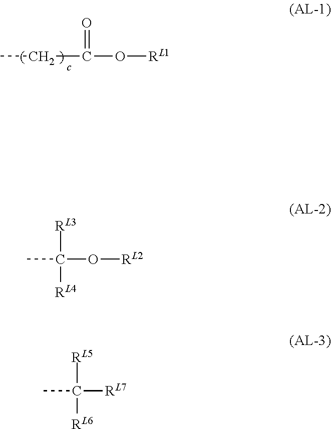

In the formulae, a broken line designates a bond.

In formula (AL-1), c is an integer of 0 to 6. R^{L1} is a C₄-C₂₀, preferably C₄-C₁₅ tertiary hydrocarbyl group, a trihydrocarbylsilyl group in which each hydrocarbyl moiety is a C₁-C₆ saturated hydrocarbyl moiety, a C₄-C₂₀ saturated hydrocarbyl group containing a carbonyl moiety, an ether bond, or an ester bond, or a group having formula (AL-3). It is noted that the tertiary hydrocarbyl group refers to a group obtained by eliminating a hydrogen atom on a tertiary carbon atom from a hydrocarbon.

The tertiary hydrocarbyl group represented by R^{L1} may be saturated or unsaturated, and may be branched or cyclic. Specific examples thereof include a tert-butyl group, a tert-pentyl group, a 1,1-diethylpropyl group, a 1-ethylcyclopentyl group, a 1-butylcyclopentyl group, a 1-ethylcyclohexyl group, a 1-butylcyclohexyl group, a 1-ethyl-2-cyclopentenyl group, a 1-ethyl-2-cyclohexenyl group, and a 2-methyl-2-adamantyl group. Examples of the trihydrocarbylsilyl group include a trimethylsilyl group, a triethylsilyl group, and a dimethyl-tert-butylsilyl group. The saturated hydrocarbyl group containing a carbonyl moiety, an ether bond, or an ester bond may be linear, branched, or cyclic, but is preferably cyclic, and specific examples thereof include a 3-oxocyclohexyl group, a 4-methyl-2-oxooxan-4-yl group, a 5-methyl-2-oxooxolane-5-yl group, a 2-tetrahydropyranyl group, and a 2-tetrahydrofuranyl group.

Examples of the acid labile group represented by formula (AL-1) include a tert-butoxycarbonyl group, a tert-butoxycarbonylmethyl group, a tert-pentyloxycarbonyl group, a tert-pentyloxycarbonylmethyl group, a 1,1-diethylpropyloxycarbonyl group, a 1,1-diethylpropyloxycarbonylmethyl group, a 1-ethylcyclopentyloxycarbonyl group, a 1-ethylcyclopentyloxycarbonylmethyl group, a 1-ethyl-2-cyclopentenyloxycarbonyl group, a 1-ethyl-2-cyclopentenyloxycarbonylmethyl group, a 1-ethoxyethoxycarbonylmethyl group, a 2-tetrahydropyranyloxycarbonylmethyl group, and a 2-tetrahydrofuranyloxycarbonylmethyl group.

Furthermore, examples of the acid labile group represented by formula (AL-1) also include groups represented by formulae (AL-1)-1 to (AL-1)-10.

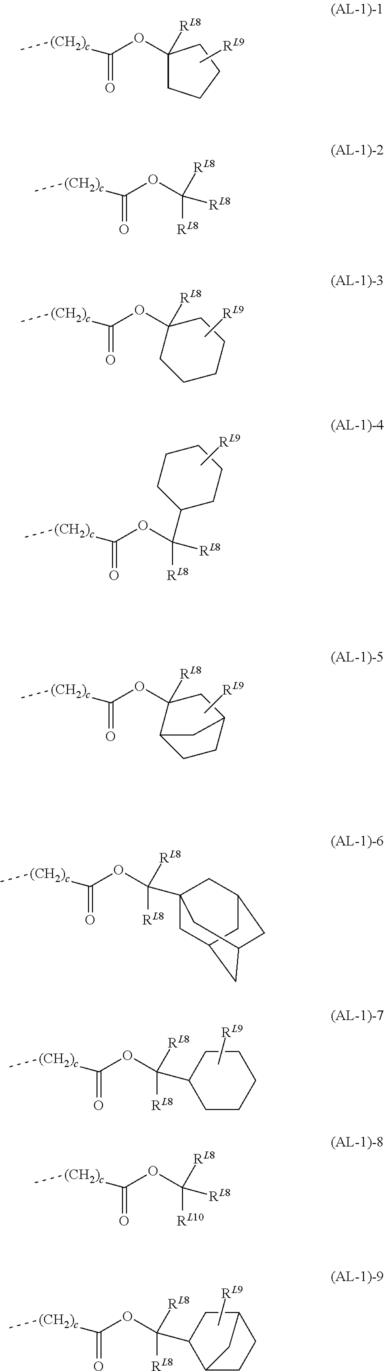

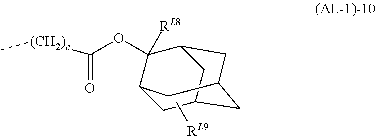

In the formulae, a broken line designates a bond.

In formulae (AL-1)-1 to (AL-1)-10, c is as defined above. R^{L8} is each independently a C₁-C₁₀ saturated hydrocarbyl group or a C₆-C₂₀ aryl group. R^{L9} is a hydrogen atom or a C₁-C₁₀ saturated hydrocarbyl group. R^{L10} is a C₂-C₁₀ saturated hydrocarbyl group or a C₆-C₂₀ aryl group. The saturated hydrocarbyl group may be linear, branched, or cyclic.

In formula (AL-2), R^{L2} and R^{L3} are each independently a hydrogen atom or a C₁-C₁₈, preferably C₁-C₁₀ saturated hydrocarbyl group. The saturated hydrocarbyl group may be linear, branched, or cyclic, and specific examples thereof include a methyl group, an ethyl group, a n-propyl group, an isopropyl group, a n-butyl group, an isobutyl group, a sec-butyl group, a tert-butyl group, a cyclopentyl group, a cyclohexyl group, a 2-ethylhexyl group, and a n-octyl group.

In formula (AL-2), R^{L4} is a C₁-C₁₈, preferably C₁-C₁₀ hydrocarbyl group which may contain a heteroatom. The hydrocarbyl group may be saturated or unsaturated, and may be linear, branched, or cyclic. Examples of the hydrocarbyl group include C₁-C₁₈ saturated hydrocarbyl groups, and some of hydrogen atoms of these groups may be substituted with a hydroxy group, an alkoxy group, an oxo group, an amino group, an alkylamino group, or the like. Examples of such a substituted saturated hydrocarbyl group include those shown below.

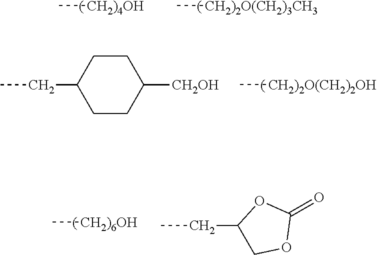

In the formulae, a broken line designates a bond.

R^{L2} and R^{L3}, R^{L2} and R^{L4}, or R^{L3} and RIA may bond together to form a ring with a carbon atom, or a carbon atom and an oxygen atom to which they are bonded, and in this case, R^{L2} and R^{L3}, R^{L2} and R^{L4}, or R^{L3} and R^{L4} involved in the formation of the ring are each independently a C₁-C₁₈, preferably C₁-C₁₀ alkanediyl group. The number of carbon atoms of the ring obtained by bonding of these groups is preferably 3 to 10, and more preferably 4 to 10.

Examples of the linear or branched acid labile group among the acid labile groups represented by formula (AL-2) include those represented by formulae (AL-2)-1 to (AL-2)-69, but are not limited thereto. In the formulae, a broken line designates a bond.

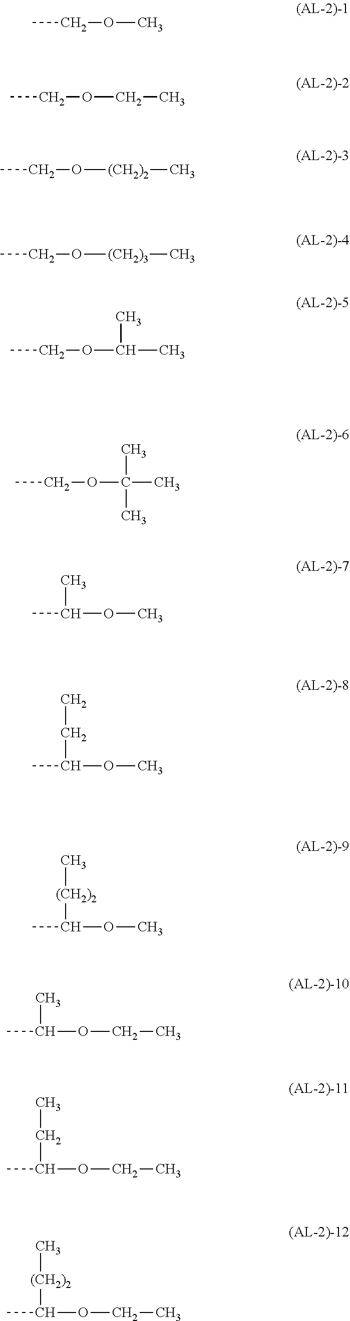

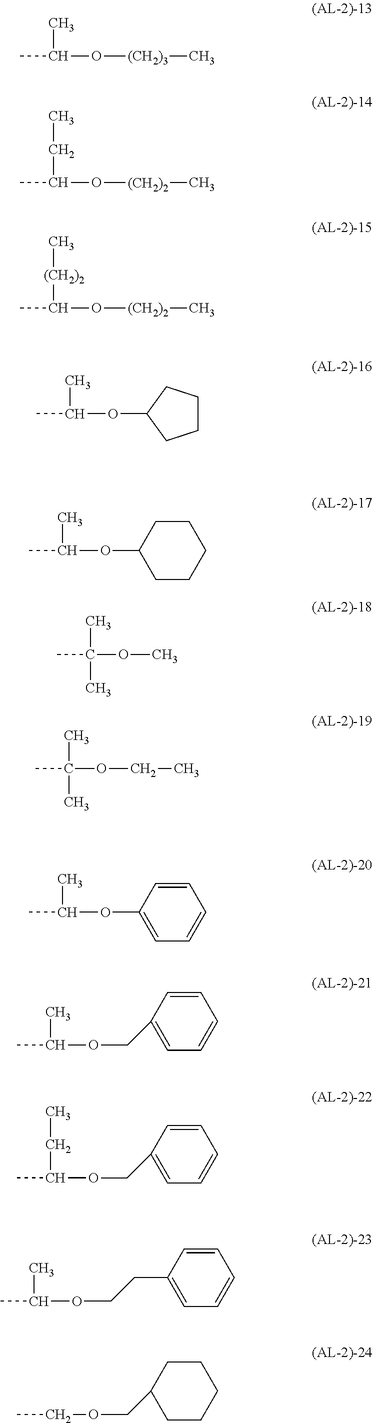

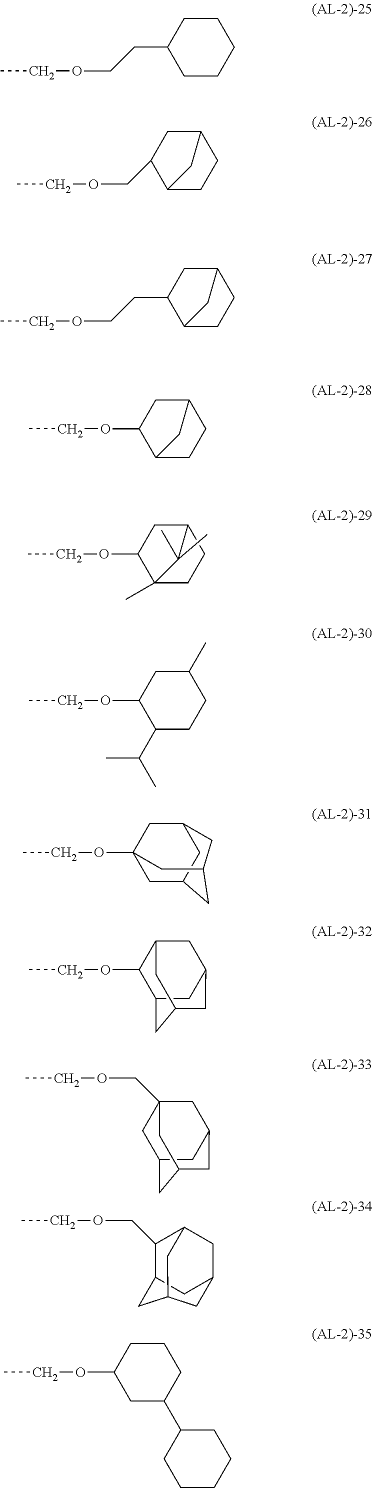

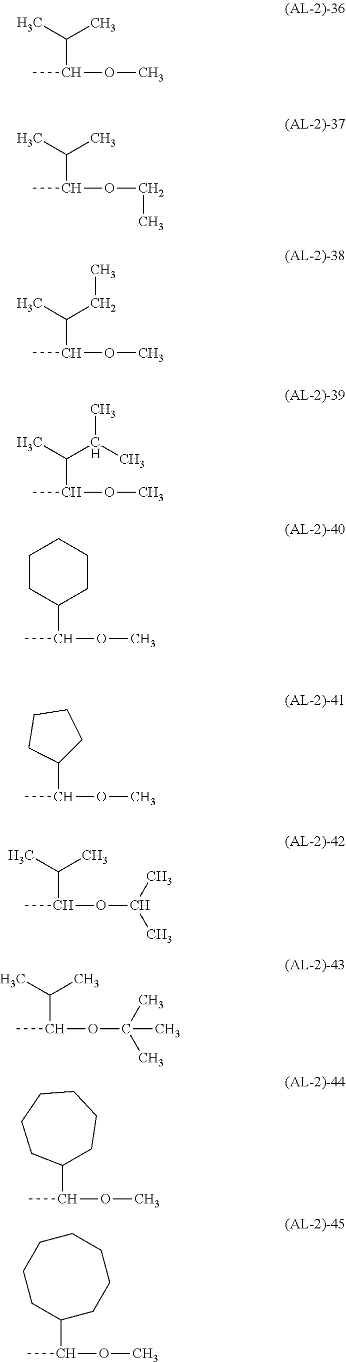

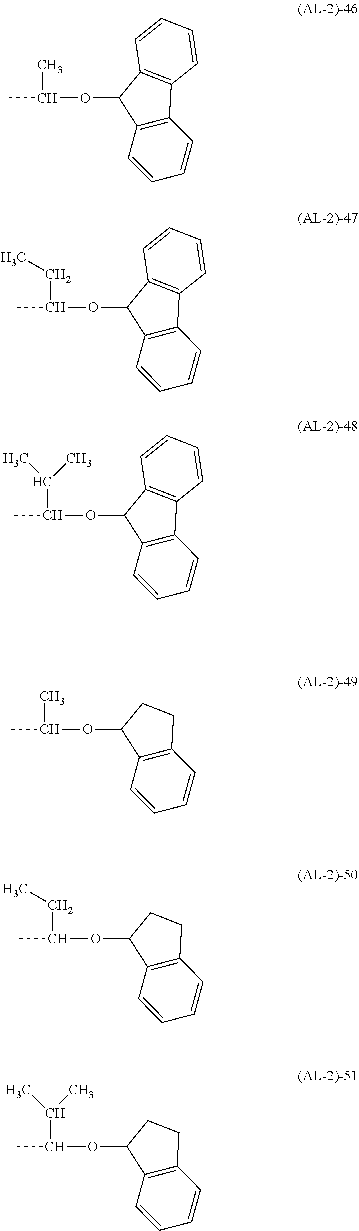

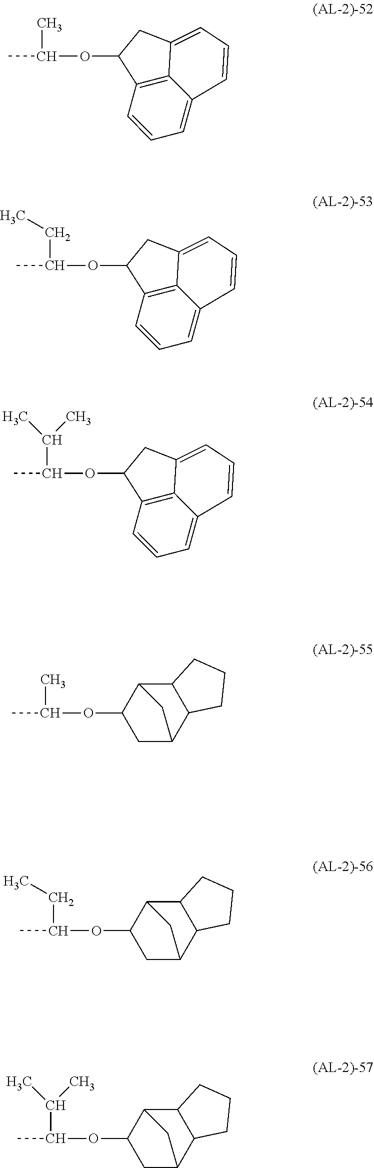

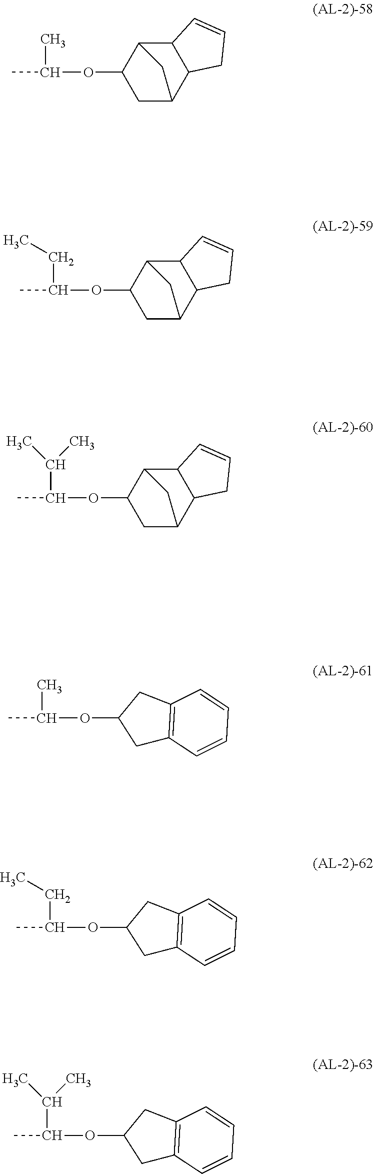

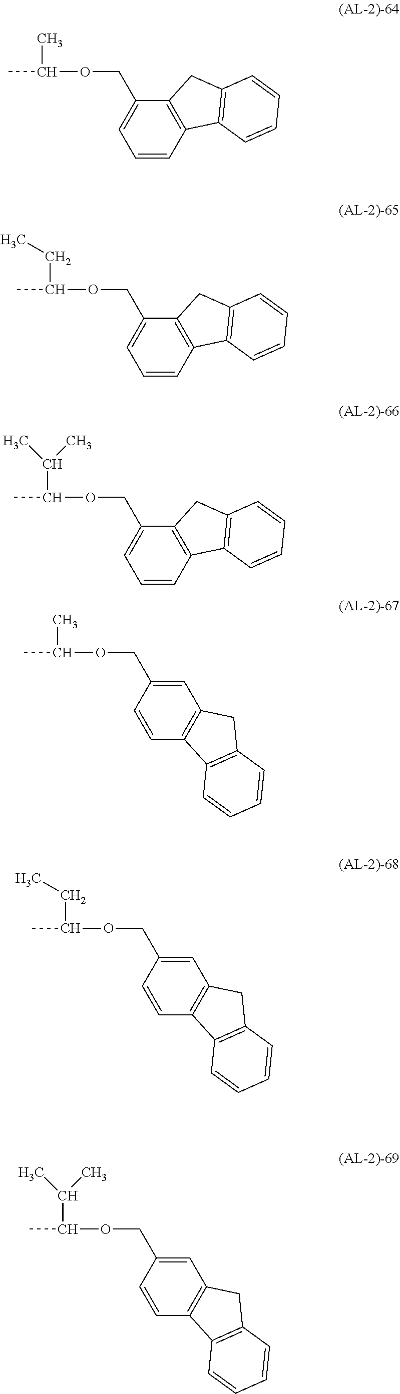

Examples of the cyclic acid labile group among the acid labile groups represented by formula (AL-2) include a tetrahydrofuran-2-yl group, a 2-methyltetrahydrofuran-2-yl group, a tetrahydropyran-2-yl group, and a 2-methyltetrahydropyran-2-yl group.

Examples of the acid labile group also include groups represented by formulae (AL-2a) and (AL-2b). The base polymer may be intermolecularly or intramolecularly crosslinked by the acid labile group.

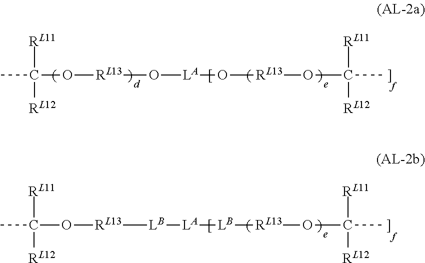

In the formulae, a broken line designates a bond.

In formulae (AL-2a) and (AL-2b), R^{L11} and R^{L12} are each independently a hydrogen atom or a C₁-C₈ saturated hydrocarbyl group. The saturated hydrocarbyl group may be linear, branched, or cyclic. R^{L11} and R^{L12} may bond together to form a ring with a carbon atom to which they are bonded, and in this case, R^{L11} and R^{L12} are each independently a C₁-C₈ alkanediyl group. R^{L13} is each independently a C₁-C₁₀ saturated hydrocarbylene group. The saturated hydrocarbylene group may be linear, branched, or cyclic. d and e are each independently an integer of 0 to 10, preferably an integer of 0 to 5, and f is an integer of 1 to 7, preferably an integer of 1 to 3.

In formulae (AL-2a) and (AL-2b), LA is a C₁-C₅₀ (f+1)-valent aliphatic saturated hydrocarbon group, a C₃-C₅₀ (f+1)-valent alicyclic saturated hydrocarbon group, a C₆-C₅₀ (f+1)-valent aromatic hydrocarbon group, or a C₃-C₅₀ (f+1)-valent heterocyclic group. In addition, some of —CH₂— of these groups may be substituted with a group containing a heteroatom, and some of hydrogen atoms of these groups may be substituted with a hydroxy group, a carboxy group, an acyl group, or a fluorine atom. LA is preferably a C₁-C₂₀ saturated hydrocarbylene group, a saturated hydrocarbon group such as a trivalent saturated hydrocarbon group or a tetravalent saturated hydrocarbon group, a C₆-C₃₀ arylene group, or the like. The saturated hydrocarbon group may be linear, branched, or cyclic. L^{B} is —C(═O)—O—, —N(H)—C(═O)—O— or —N(H)—C(═O)—N(H)—.

Examples of the crosslinking acetal group represented by formula (AL-2a) or (AL-2b) include groups represented by formulae (AL-2)-70 to (AL-2)-77.

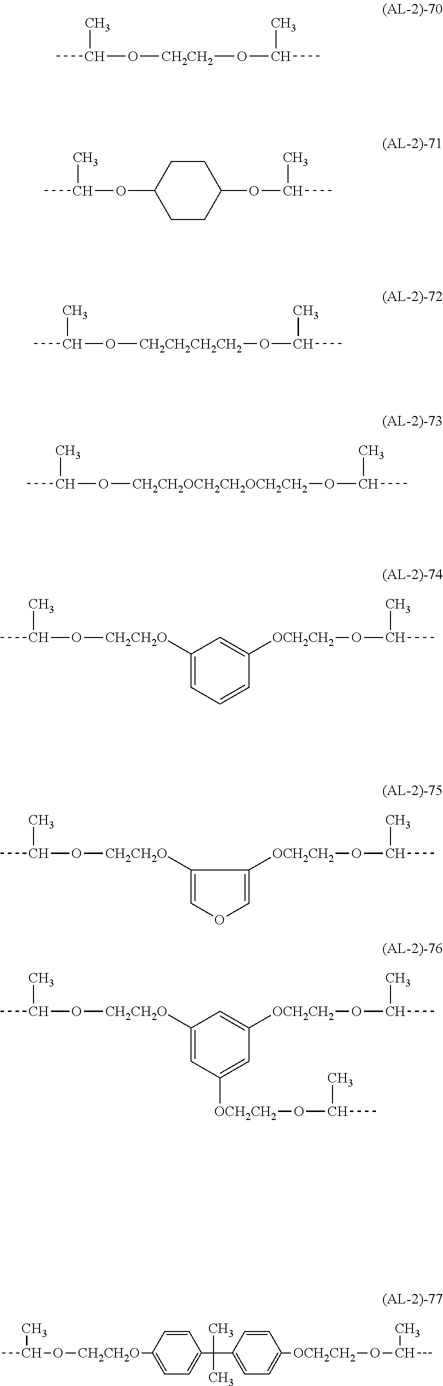

In the formulae, a broken line designates a bond.

In formula (AL-3), R^{L5}, R^{L6}, and R^{L7} are each independently a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be linear, branched, or cyclic. Specific examples thereof include a C₁-C₂₀ alkyl group, a C₃-C₂₀ cyclic saturated hydrocarbyl group, a C₂-C₂₀ alkenyl group, a C₃-C₂₀ cyclic unsaturated hydrocarbyl group, and a C₆-C₁₀ aryl group. R^{L5} and R^{L6}, R^{L5} and R^{L7}, or R^{L6} and R^{L7} may bond together to form a C₃-C₂₀ alicyclic ring with a carbon atom to which they are bonded.

Examples of the group represented by formula (AL-3) include a tert-butyl group, a 1,1-diethylpropyl group, a 1-ethylnorbornyl group, a 1-methylcyclopentyl group, a 1-ethylcyclopentyl group, a 1-isopropylcyclopentyl group, a 1-methylcyclohexyl group, a 2-(2-methyl) adamantyl group, a 2-(2-ethyl) adamantyl group, and a tert-pentyl group.

In addition, examples of the group represented by formula (AL-3) also include groups represented by formulae (AL-3)-1 to (AL-3)-19.

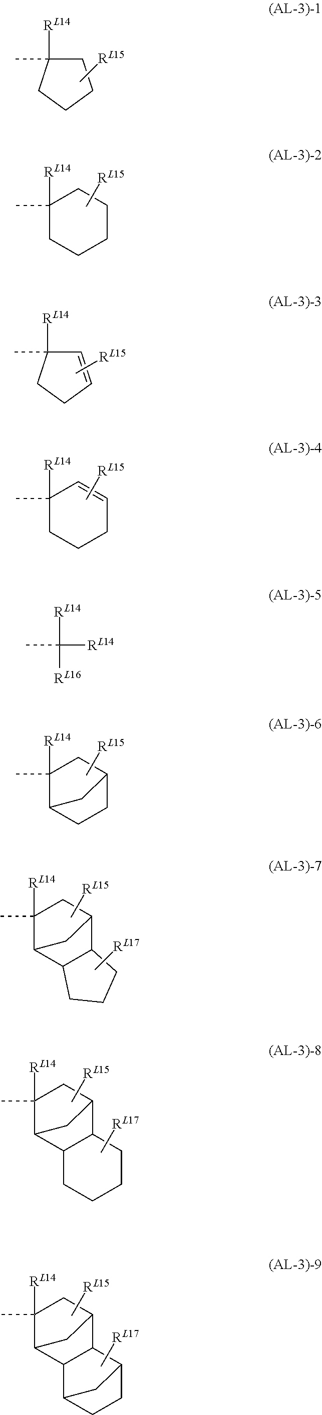

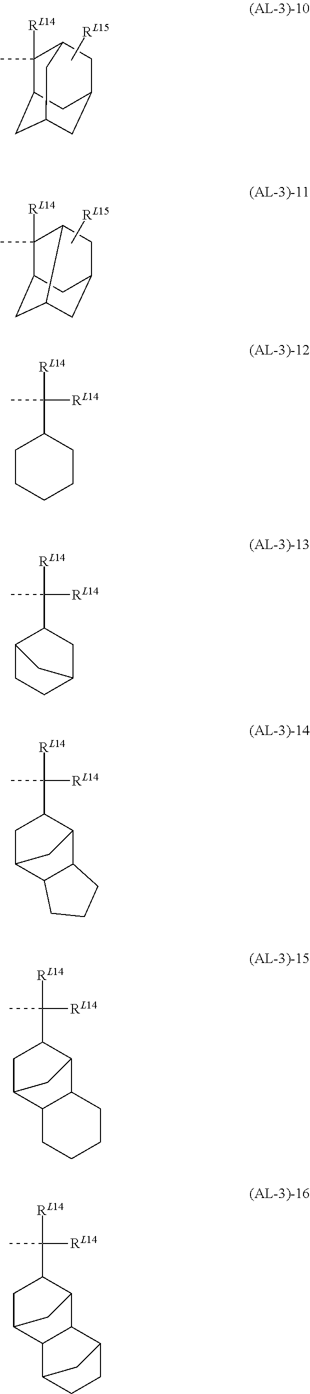

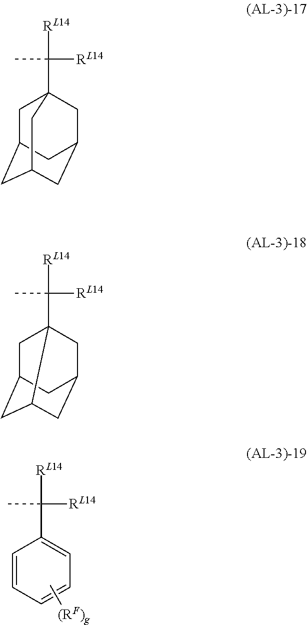

In the formulae, a broken line designates a bond.

In formulae (AL-3)-1 to (AL-3)-19, R^{L14} is each independently a hydrogen atom, a C₁-C₈ saturated hydrocarbyl group, or a C₆-C₂₀ aryl group. R_{L15} and R^{L17} are each independently a hydrogen atom or a C₁-C₂₀ saturated hydrocarbyl group. R^{L16} is a C₆-C₂₀ aryl group. The saturated hydrocarbyl group may be linear, branched, or cyclic. The aryl group is preferably a phenyl group or the like. RF is a fluorine atom or a trifluoromethyl group. g is an integer of 1 to 5.

Examples of the acid labile group also include groups represented by formulae (AL-3)-20 and (AL-3)-21. The polymer may be intramolecularly or intermolecularly crosslinked by the acid labile group.

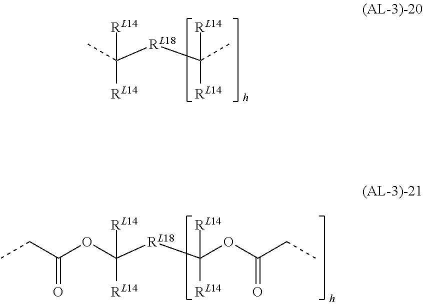

In the formulae, a broken line designates a bond.

In formulae (AL-3)-20 and (AL-3)-21, R^{L14} is as defined above. R^{L18} is a C₁-C₂₀ (h+1)-valent saturated hydrocarbylene group or a C₆-C₂₀ (h+1)-valent arylene group which may contain a heteroatom such as an oxygen atom, a sulfur atom, or a nitrogen atom. The saturated hydrocarbylene group may be linear, branched, or cyclic. h is an integer of 1 to 3.

Examples of the monomer from which the repeat units containing the acid labile group represented by formula (AL-3) are derived include (meth)acrylates (inclusive of exo-form structure) having formula (AL-3)-22.

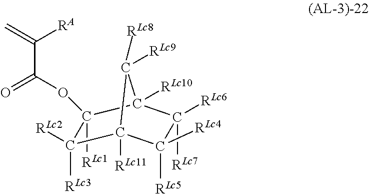

In formula (AL-3)-22, R^{A} is as defined above. R^{Lc1} is a C₁-C₈ saturated hydrocarbyl group or a C₆-C₂₀ aryl group which may be substituted. The saturated hydrocarbyl group may be linear, branched, or cyclic. R^{Lc2} to R^{Lc11} are each independently a hydrogen atom or a C₁-C₁₅ hydrocarbyl group which may contain a heteroatom. Examples of the heteroatom include an oxygen atom. Examples of the hydrocarbyl group include a C₁-C₁₅ alkyl group and a C₆-C₁₅ aryl group. R^{Lc2} and R^{Lc3}, R^{Lc4} and R^{Lc6}, R^{Lc4} and R^{Lc7}, R^{Lc5} and R^{Lc7}, R^{Lc5} and R^{Lc11}, R^{Lc6} and R^{Lc10}, R^{Lc8} and R^{Lc9}, or R^{Lc9} and R^{Lc10} may bond together to form a ring with a carbon atom to which they are bonded, and in this case, the group involved in the bond is a C₁-C₁₅ hydrocarbylene group which may contain a heteroatom. In addition, R_{Lc2} and R^{Lc11}, R^{Lc8} and R^{Lc11}, or R^{Lc4} and R^{Lc6} which are bonded to adjacent carbon atoms may bond together directly to form a double bond. The formula also represents an enantiomer.

Examples of the monomer represented by formula (AL-3)-22 include those described in JP-A 2000-327633. Specific examples thereof include those shown below, but are not limited thereto. In the formulae, R^{A} is as defined above.

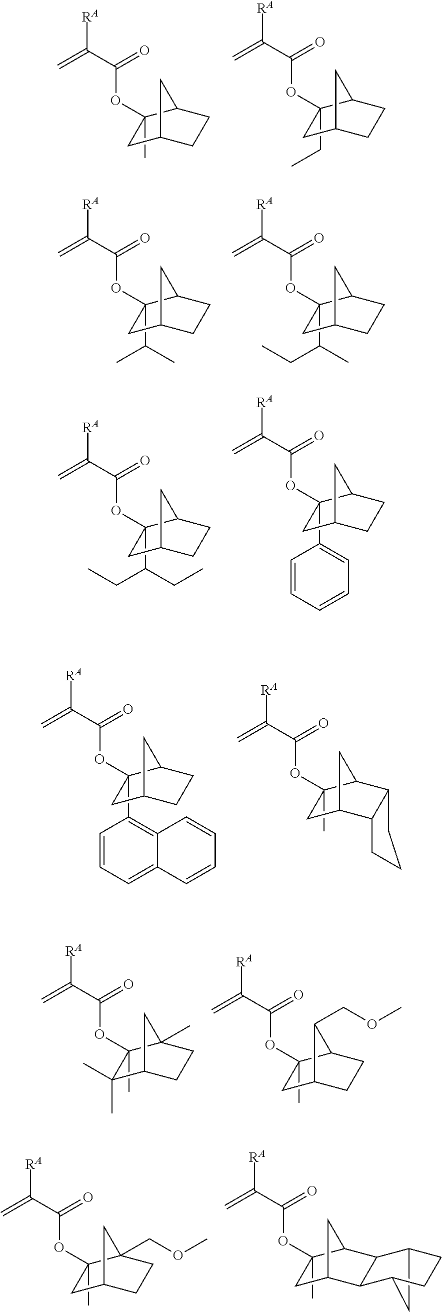

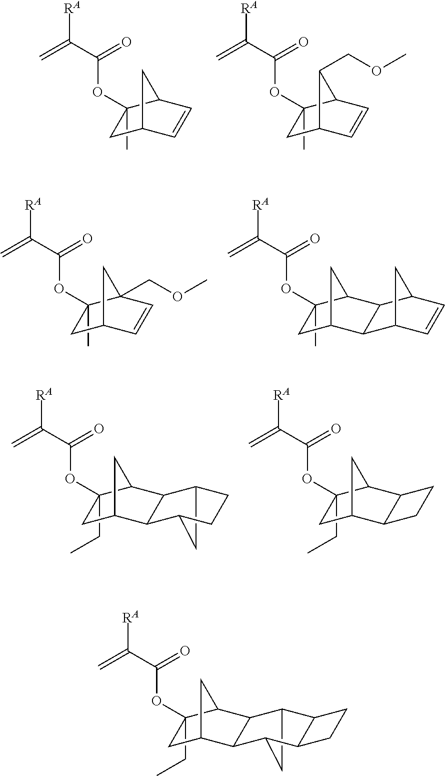

Examples of the monomer from which the repeat units containing the acid labile group represented by formula (AL-3) are derived also include a (meth)acrylate containing a furandiyl group, a tetrahydrofurandiyl group, or an oxanorbornanediyl group, which is represented by formula (AL-3)-23.

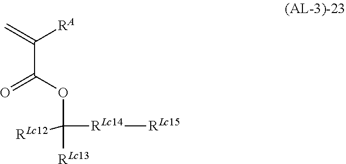

In formula (AL-3)-23, R^{A} is as defined above. R^{Lc12} and R^{Lc13} are each independently a C₁-C₁₀ hydrocarbyl group. R^{Lc12} and R^{Lc13} may bond together to form an alicyclic ring with a carbon atom to which they are bonded. R^{Lc14} is a furandiyl group, a tetrahydrofurandiyl group, or an oxanorbornanediyl group. R^{Lc15} is a hydrogen atom or a C₁-C₁₀ hydrocarbyl group which may contain a heteroatom. The hydrocarbyl group may be linear, branched, or cyclic. Specific examples thereof include a C₁-C₁₀ saturated hydrocarbyl group.

Examples of the monomer represented by formula (AL-3)-23 include those shown below, but are not limited thereto. In the formulae, R^{A} is as defined above, Ac is an acetyl group, and Me is a methyl group.

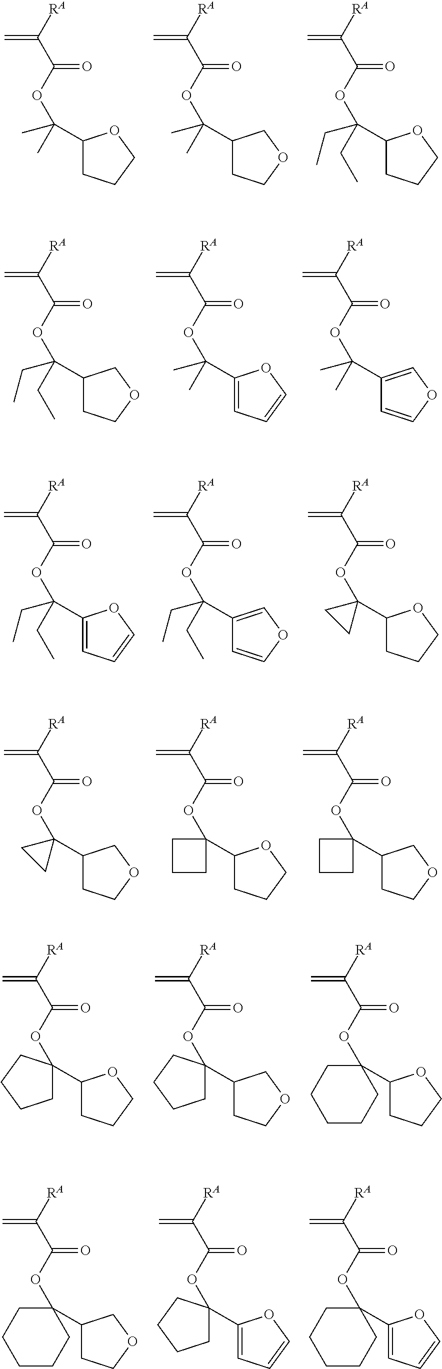

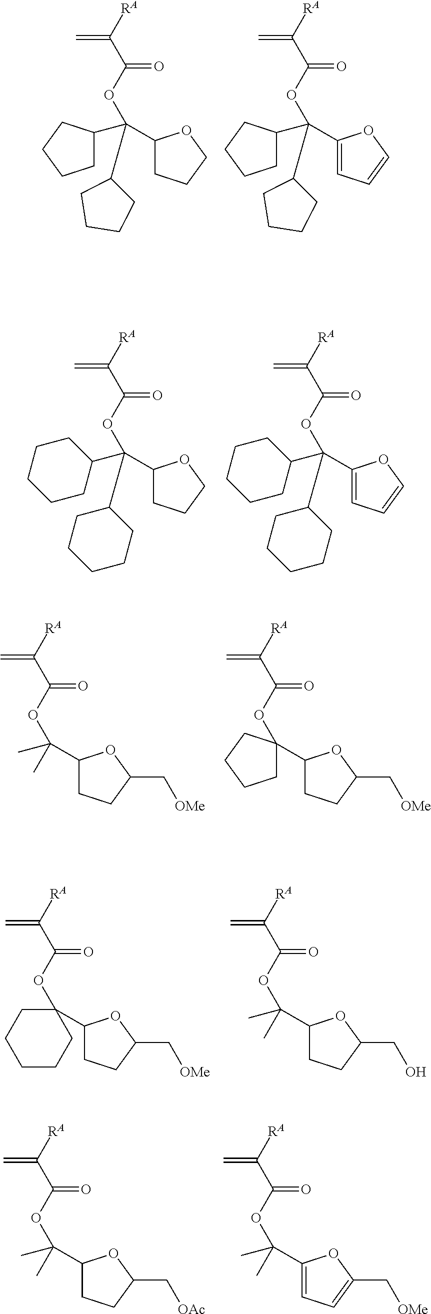

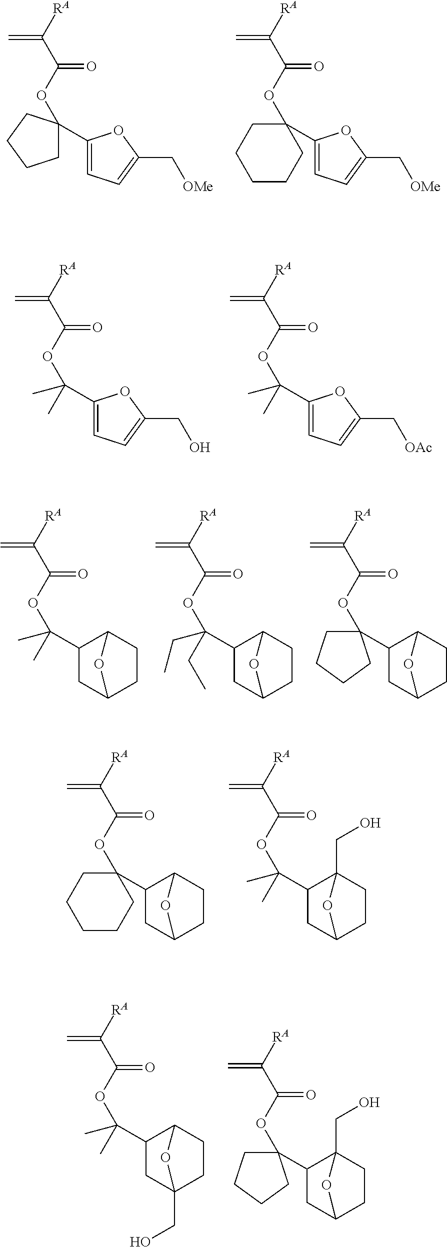

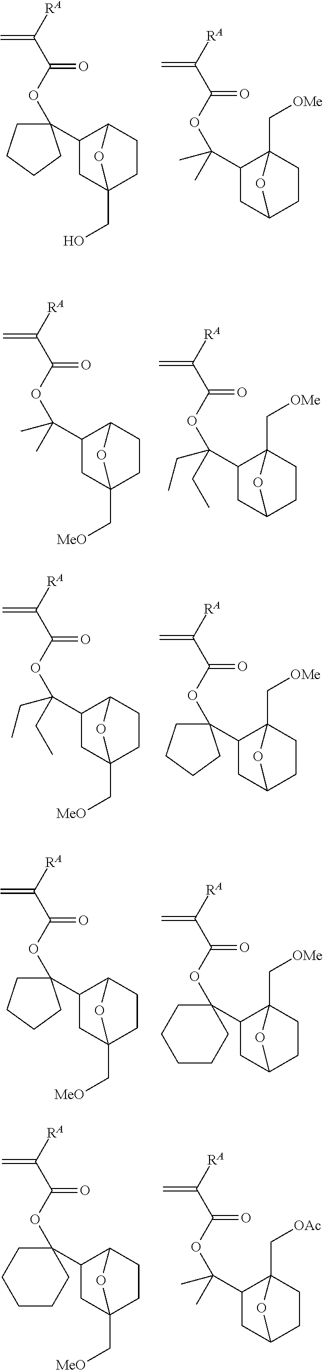

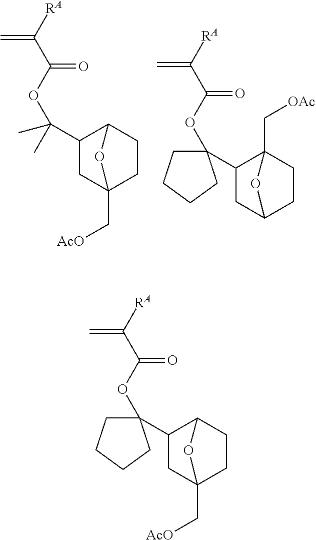

The base polymer may further contain repeat units (c) having an adhesive group selected from a hydroxy group, a carboxy group, a lactone ring, a carbonate bond, a thiocarbonate bond, a carbonyl group, a cyclic acetal group, an ether bond, an ester bond, a sulfonic ester bond, a cyano group, an amide bond, —O—C(═O)—S—, and —O—C(═O)—NH—.

Examples of the monomer from which the repeat units (c) are derived include those shown below, but are not limited thereto. In the formulae, R^{A} is as defined above.

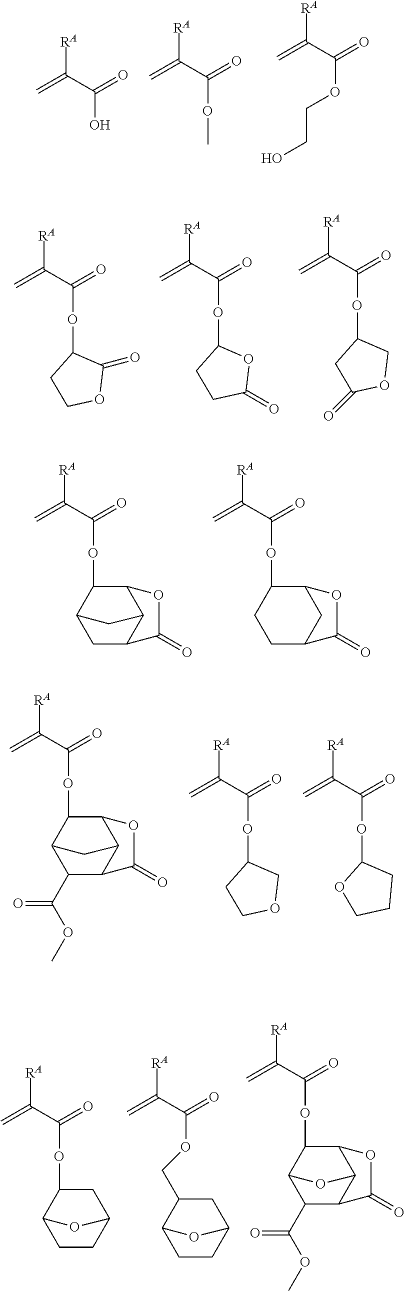

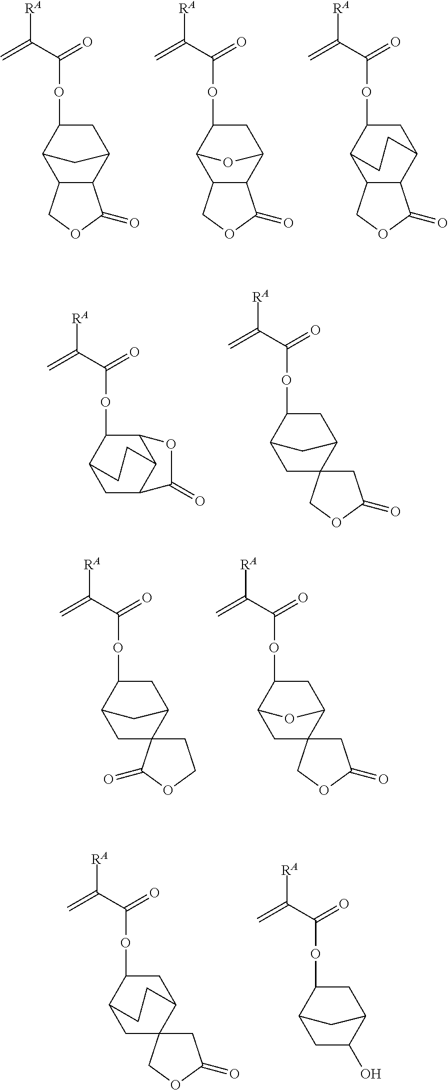

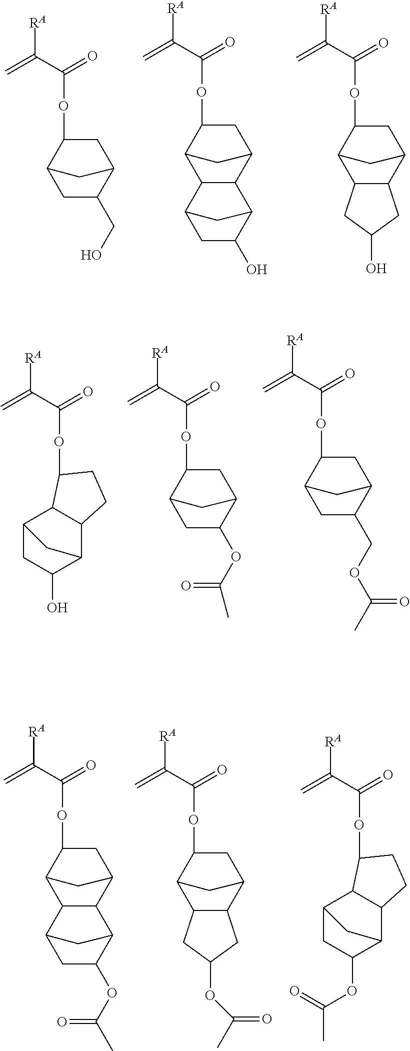

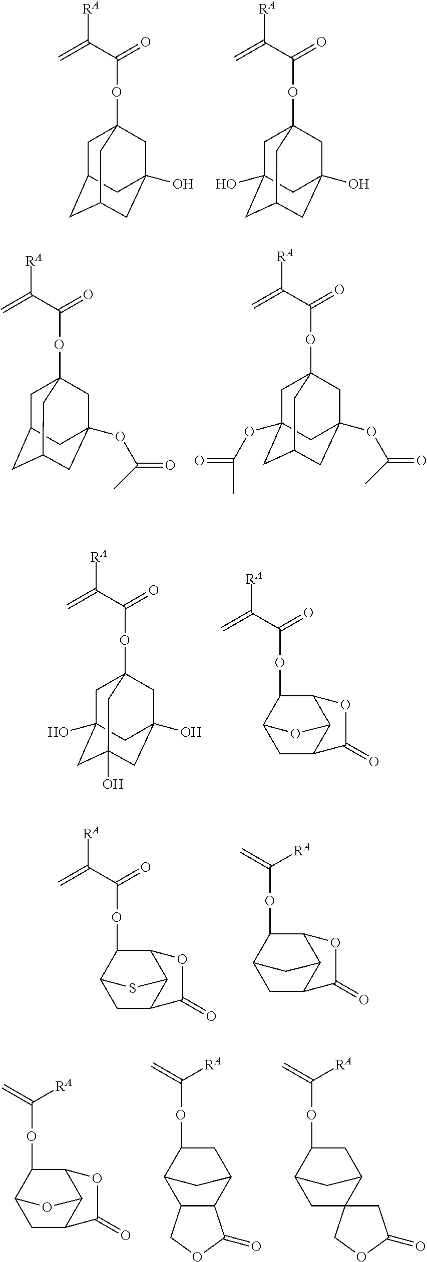

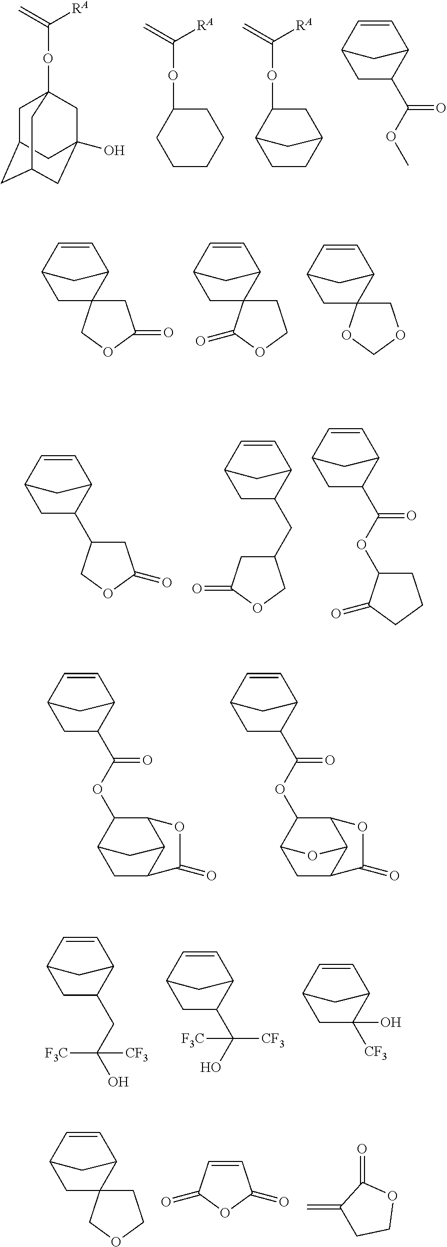

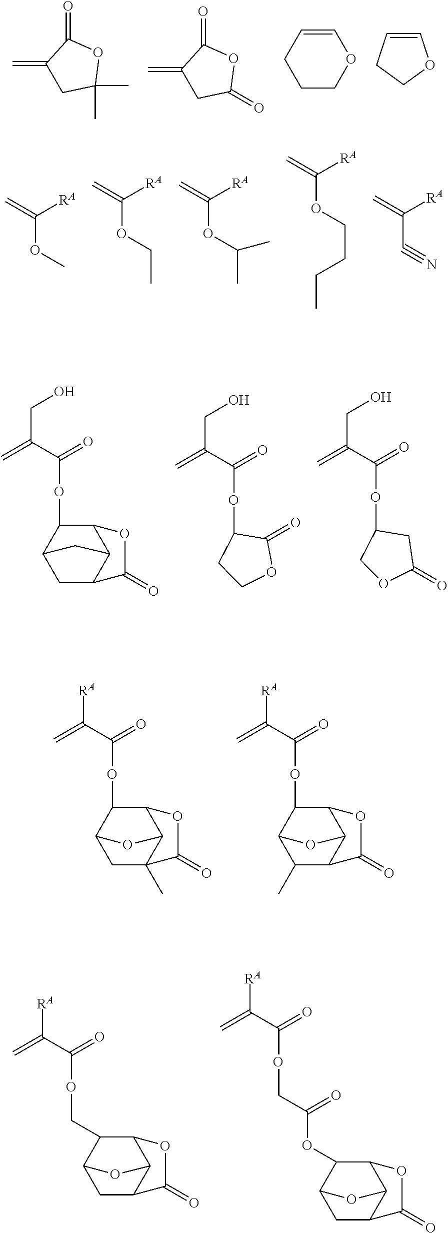

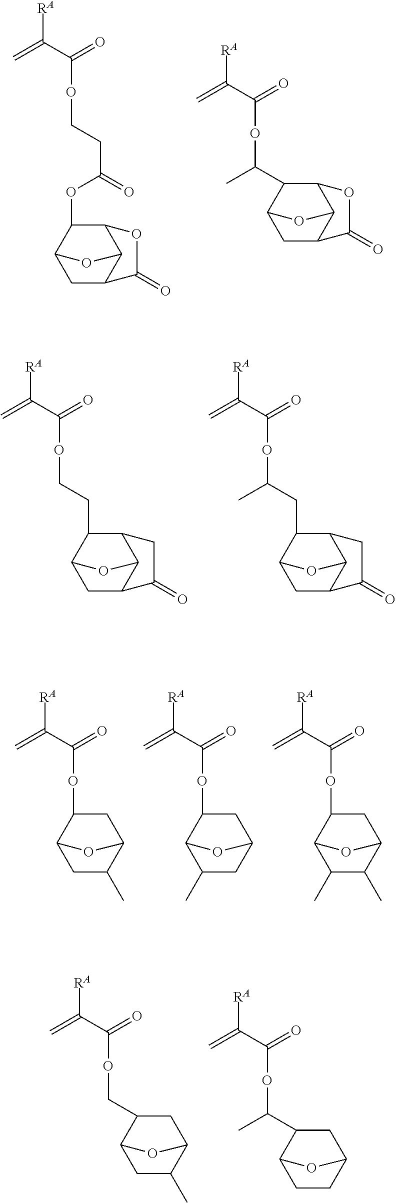

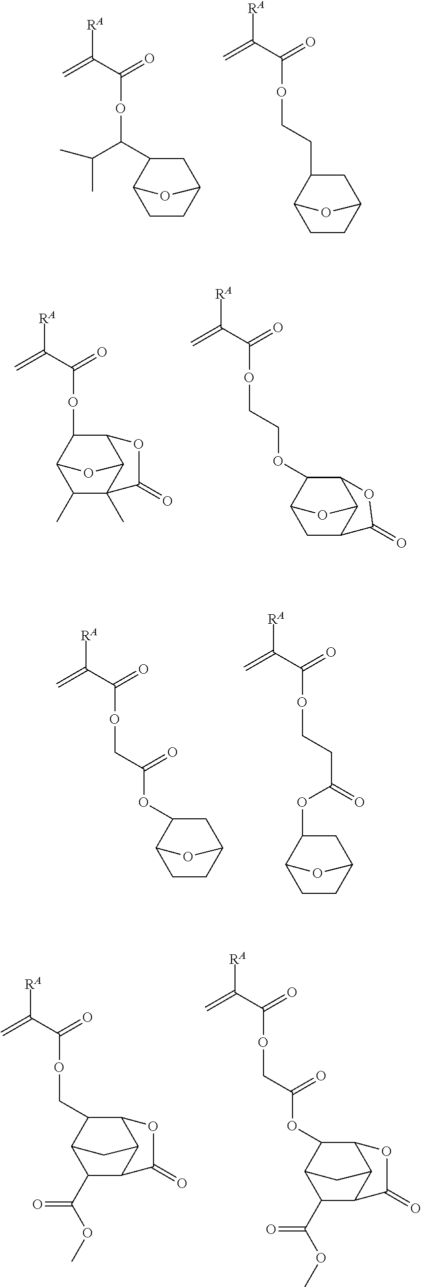

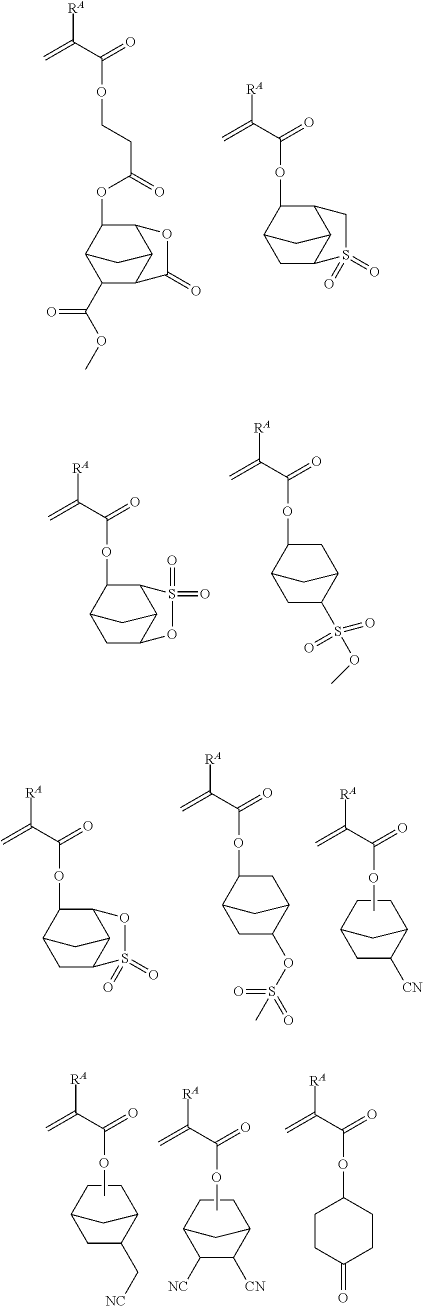

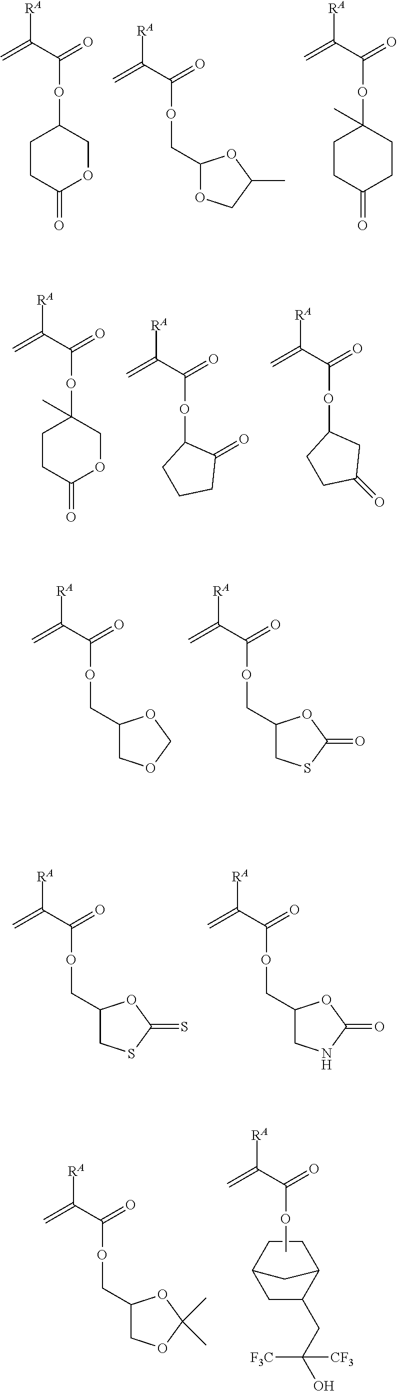

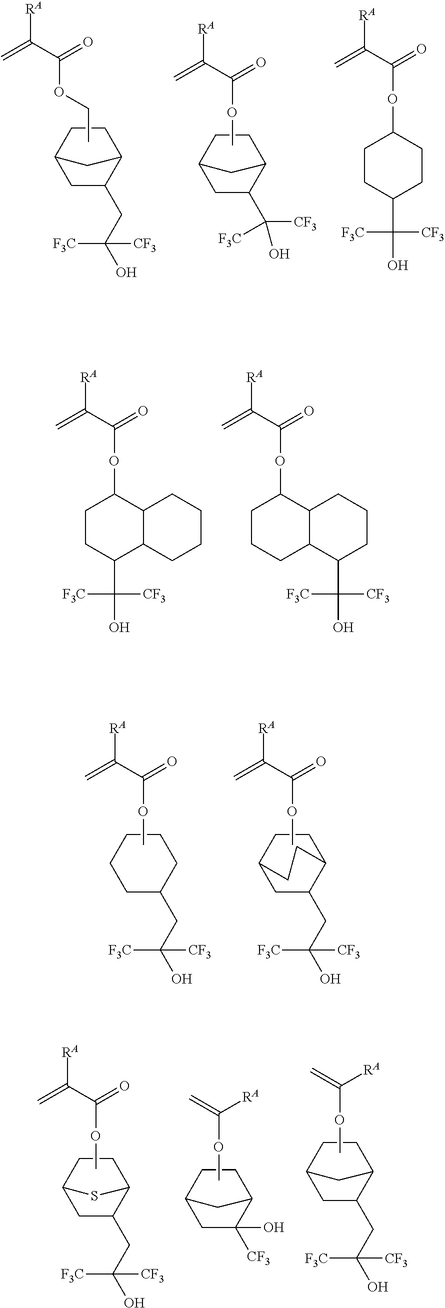

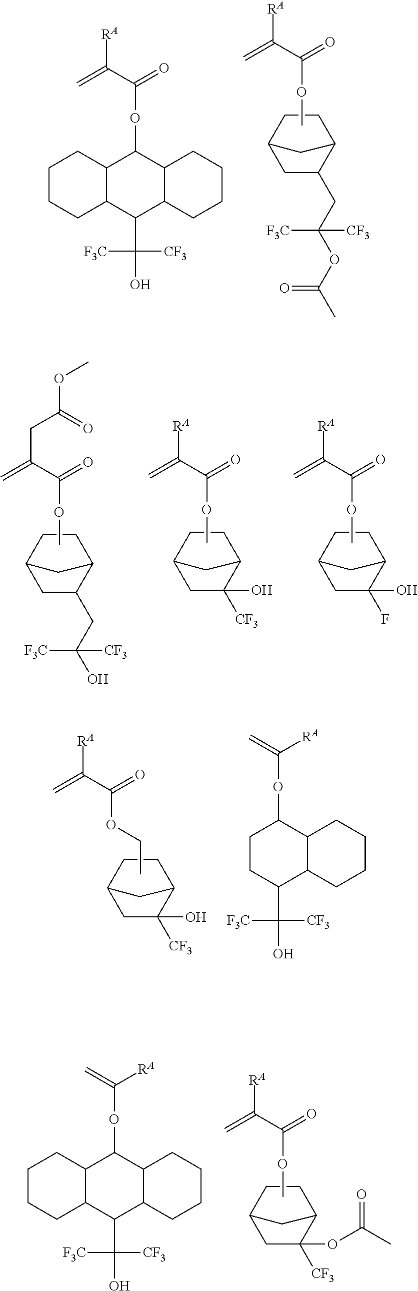

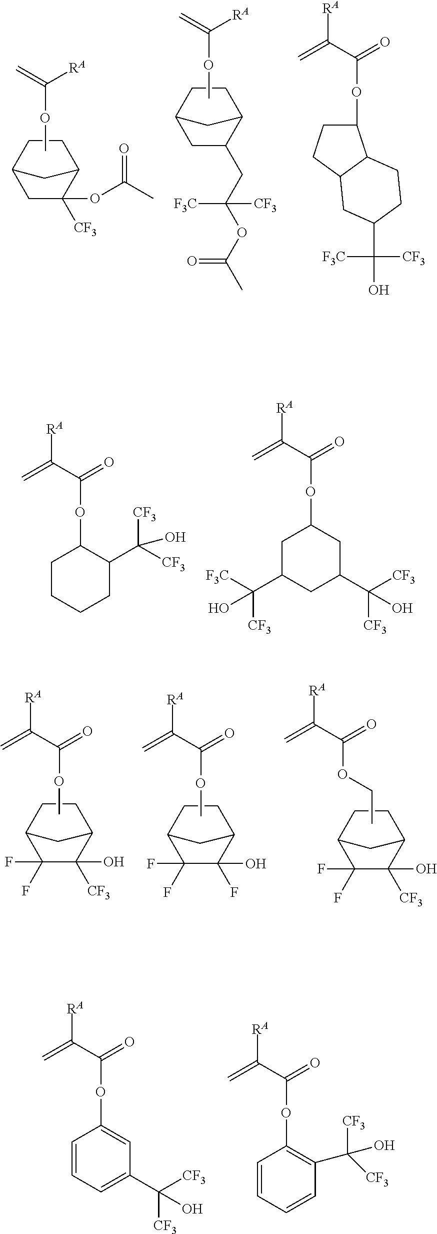

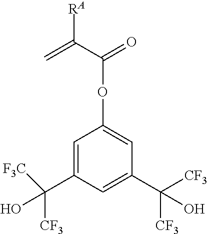

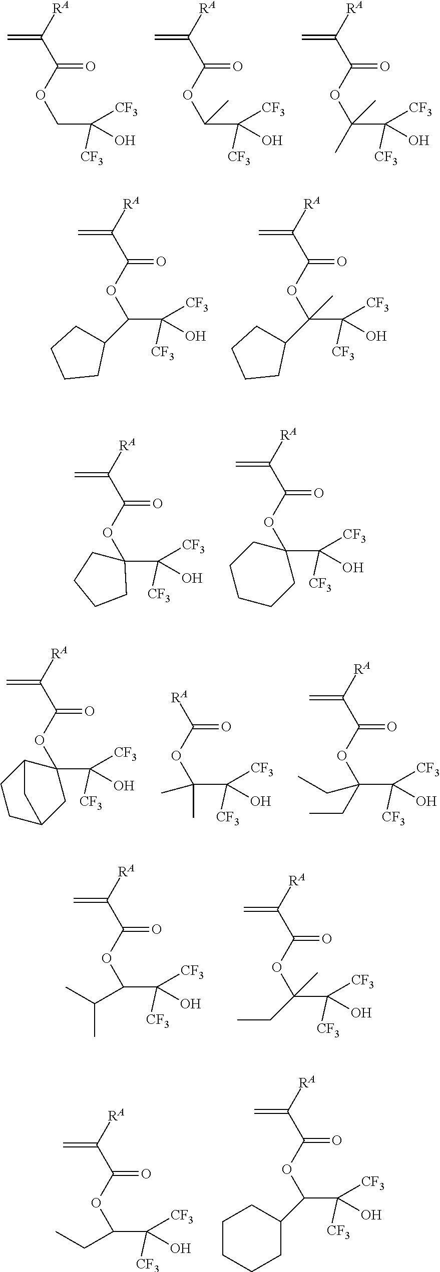

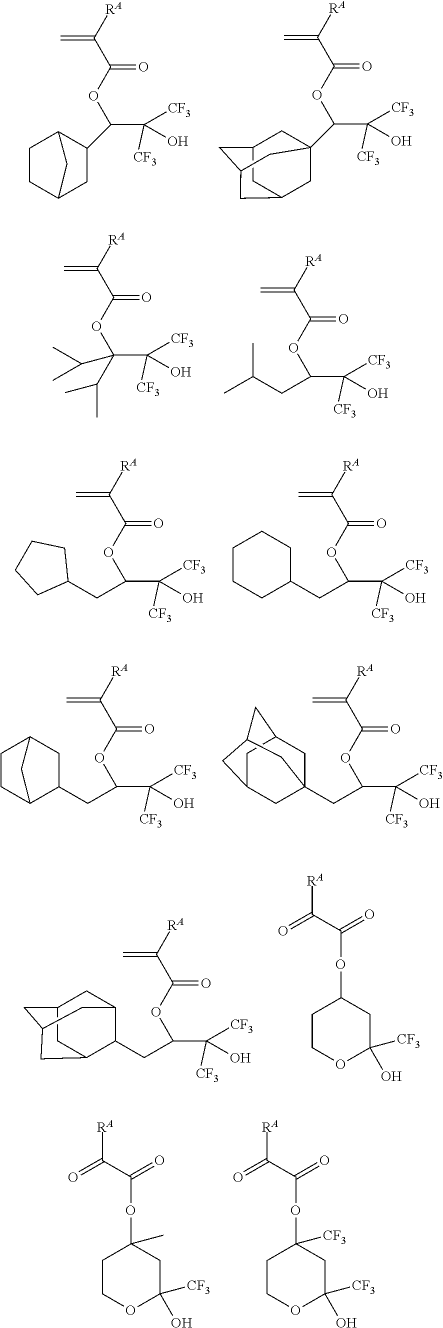

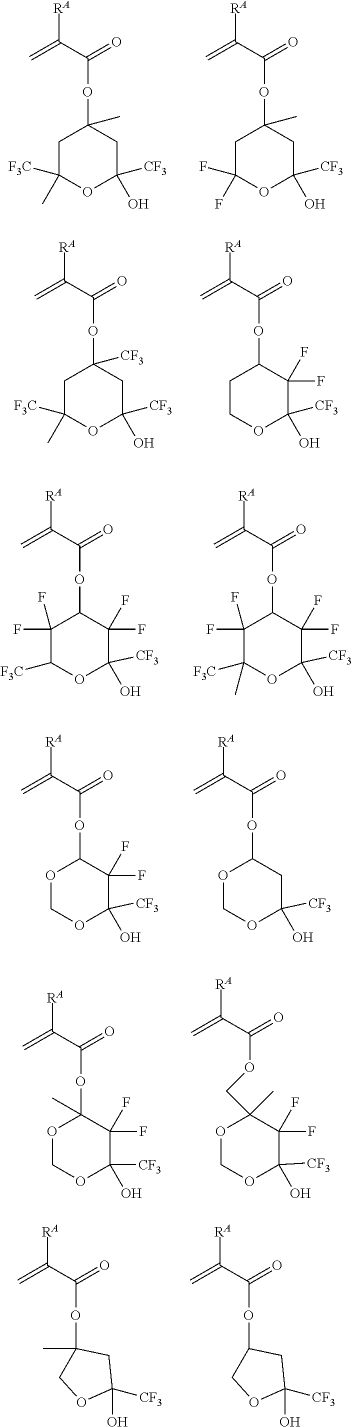

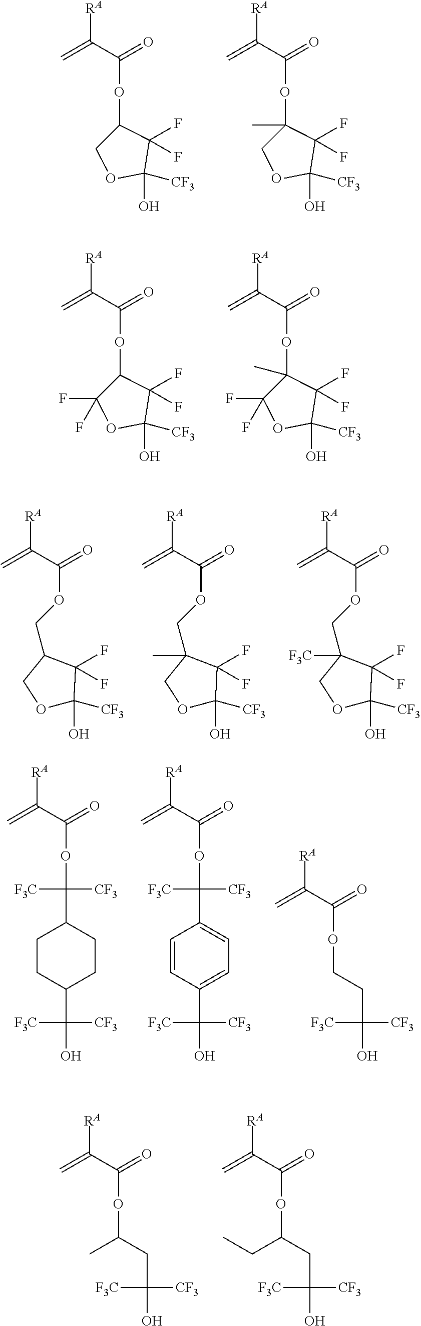

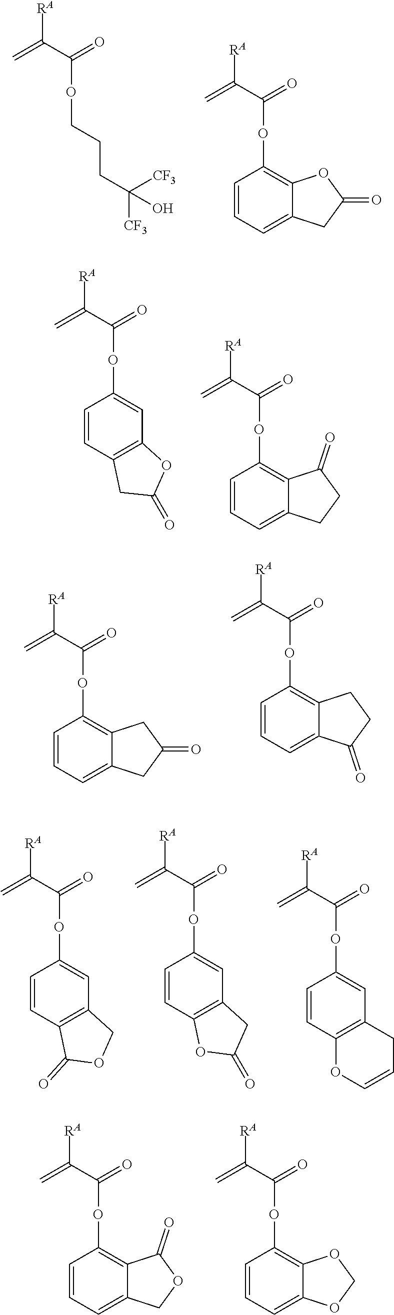

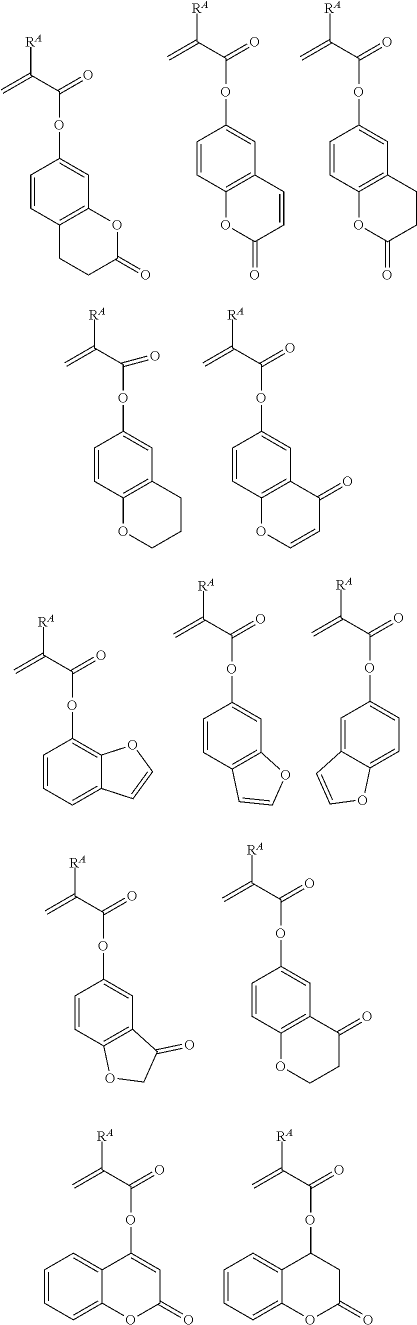

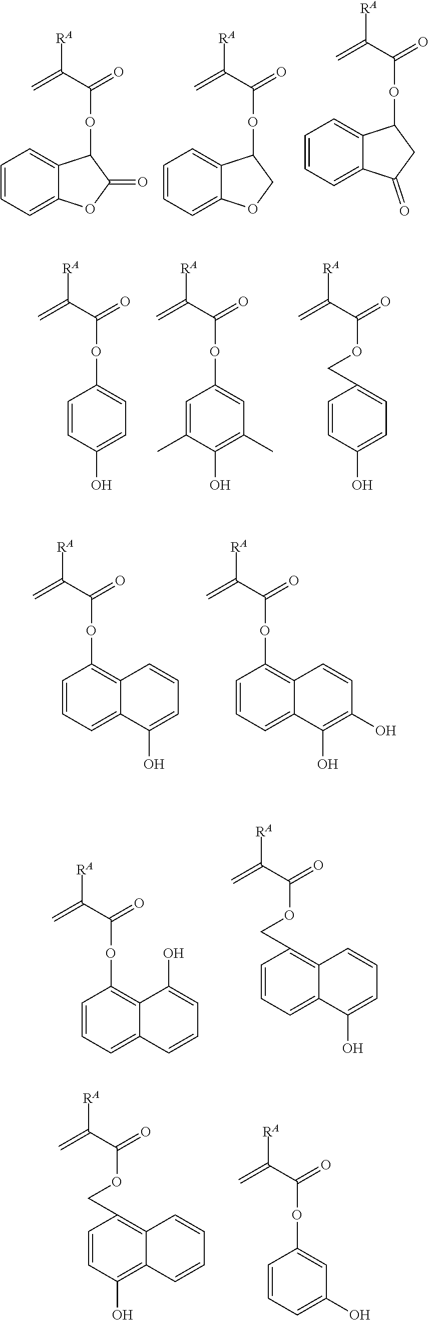

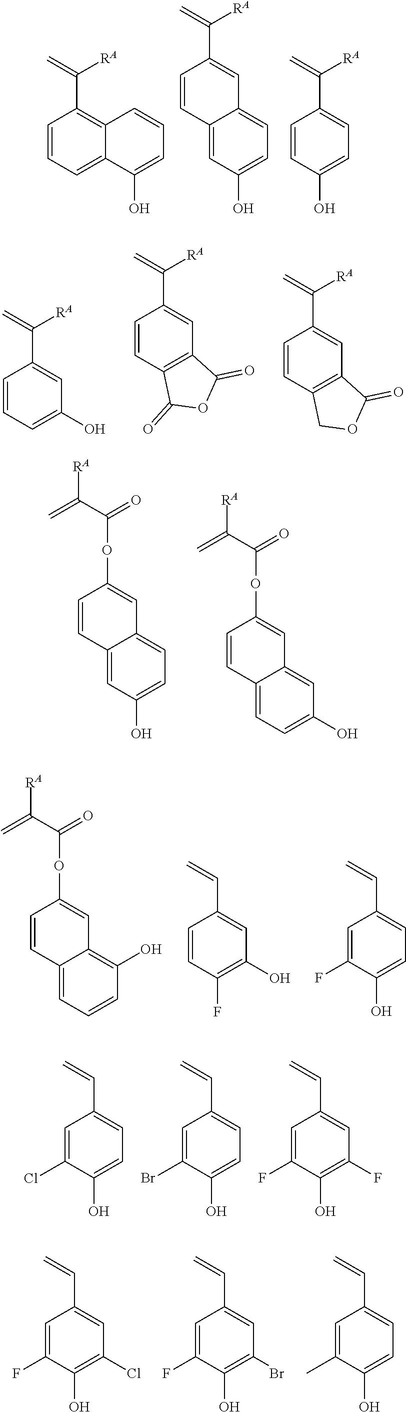

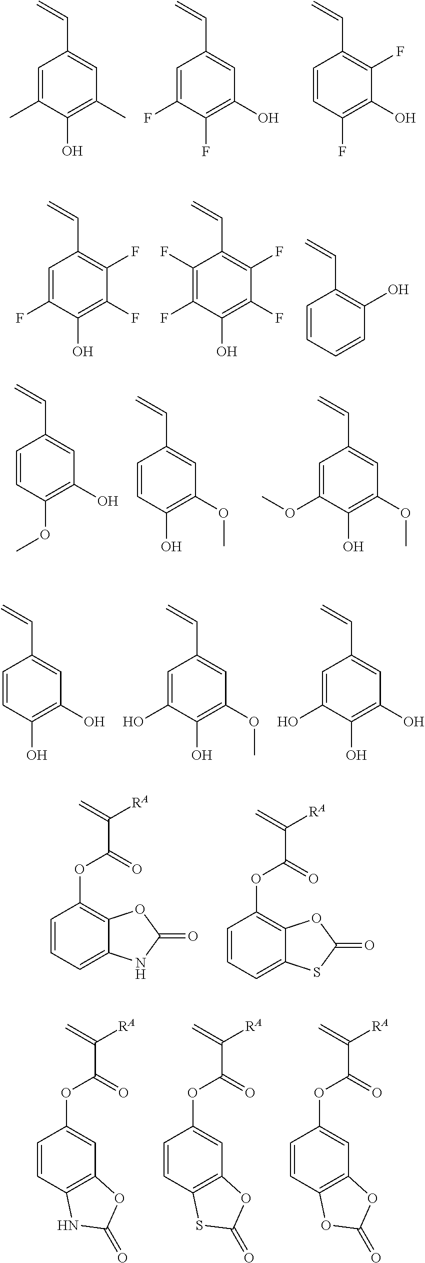

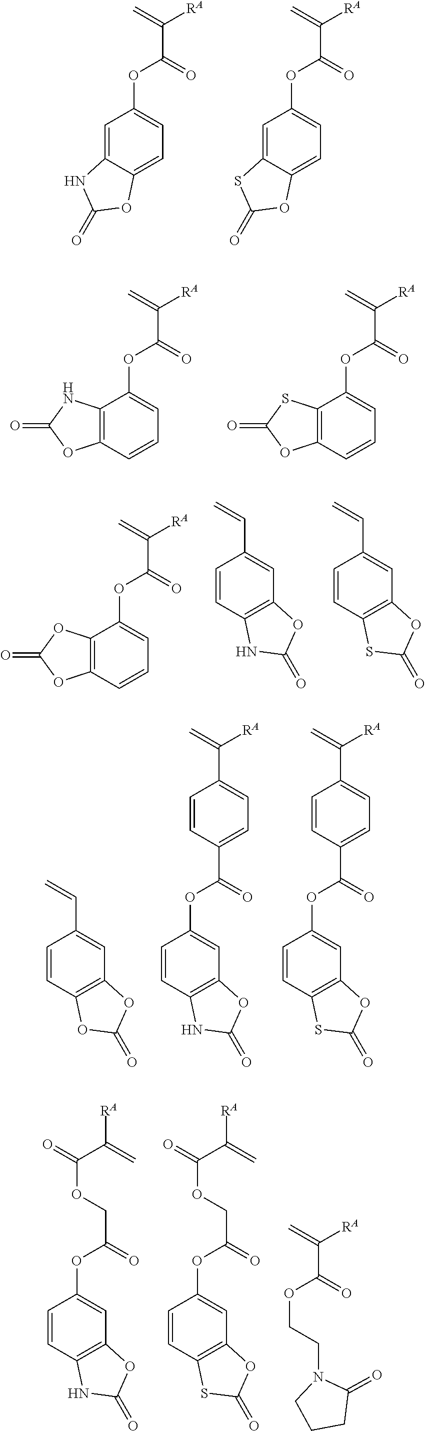

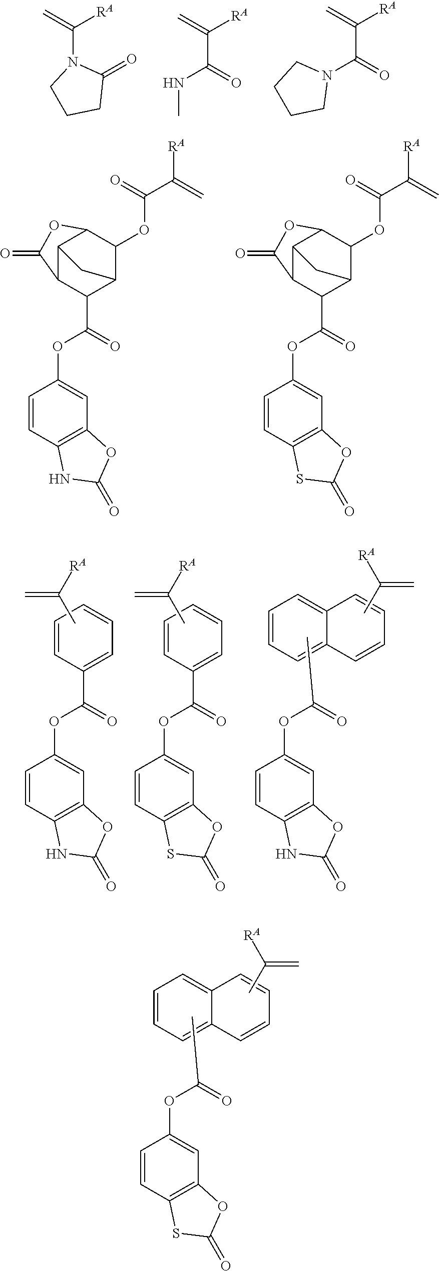

The base polymer may further contain at least one kind selected from repeat units having formula (d1) (hereinafter, the repeat units are also referred to as repeat units (d1)), repeat units having formula (d2) (hereinafter, the repeat units are also referred to as repeat units (d2)), and repeat units having formula (d3) (hereinafter, the repeat units are also referred to as repeat units (d3)).

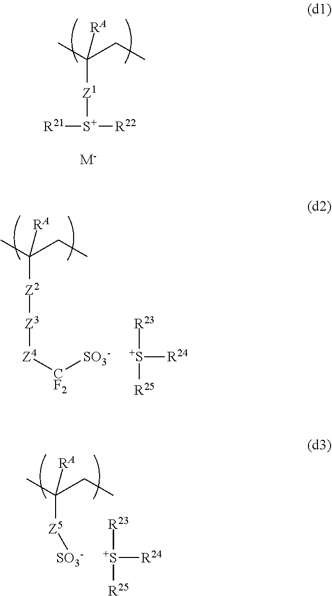

In formulae (d1) to (d3), R^{A} is each independently a hydrogen atom or a methyl group. Z¹ is a single bond, a C₁-C₆ aliphatic hydrocarbylene group, a phenylene group, a naphthylene group, a C₇-C₁₈ group obtained by combining the foregoing, —O—Z¹¹—, —C(═O)—O—Z¹¹—, or —C(═O)—NH—Z¹¹—. Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group. Z² is a single bond or an ester bond. Z³ is a single bond, —Z³¹—C(═O)—O—, —Z³¹—O—, or —Z³¹—O—C(═O)—. Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom. Z⁴ is a methylene group, a 2,2,2-trifluoro-1,1-ethanediyl group, or a carbonyl group. Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—. Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a hydroxy group, or a halogen atom. The aliphatic hydrocarbylene groups represented by Z¹, Z¹¹, Z³¹, and Z⁵¹ may be saturated or unsaturated, and may be linear, branched, or cyclic.

In formulae (d1) to (d3), R²¹ to R²⁸ are each independently a halogen atom or a C₁-C₂₀ hydrocarbyl group which may contain a heteroatom. Examples of the halogen atom include a fluorine atom, a chlorine atom, a bromine atom, and an iodine atom. The hydrocarbyl group may be saturated or unsaturated, and may be linear, branched, or cyclic. Specific examples thereof include those groups mentioned as the hydrocarbyl group represented by R³ to R⁷ in the description of formulae (a1) and (a2). Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. R²³ and R²⁴ or R²⁶ and R²⁷ may bond together to form a ring with a sulfur atom to which they are bonded. Examples of the ring include those rings mentioned as the ring formed by the bond of R³ and R⁴ with a sulfur atom to which they are bonded in the description of formulae (a1) and (a2).

In formula (d1), M⁻ is a non-nucleophilic counter ion. Examples of the non-nucleophilic counter ion include halide ions such as a chloride ion and a bromide ion, fluoroalkylsulfonate ions such as a triflate ion, a 1,1,1-trifluoroethanesulfonate ion, and a nonafluorobutanesulfonate ion, arylsulfonate ions such as a tosylate ion, a benzenesulfonate ion, a 4-fluorobenzenesulfonate ion, and a 1,2,3,4,5-pentafluorobenzenesulfonate ion, alkylsulfonate ions such as a mesylate ion and a butanesulfonate ion, imide ions such as a bis(trifluoromethylsulfonyl)imide ion, a bis(perfluoroethylsulfonyl)imide ion, and a bis(perfluorobutylsulfonyl) imide ion, and methide ions such as a tris(trifluoromethylsulfonyl) methide ion and a tris(perfluoroethylsulfonyl) methide ion.

Examples of the non-nucleophilic counter ion further include sulfonate ions having a fluorine atom substituted at the α-position as represented by formula (d1-1) and sulfonate ions having a fluorine atom substituted at the α-position and a trifluoromethyl group substituted at the β-position as represented by formula (d1-2).

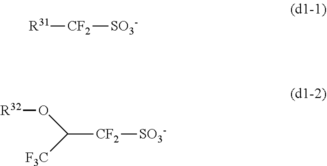

In formula (d1-1), R³¹ is a hydrogen atom or a C₁-C₂₀ hydrocarbyl group which may contain an ether bond, an ester bond, a carbonyl group, a lactone ring, or a fluorine atom. The hydrocarbyl group may be saturated or unsaturated, and may be linear, branched, or cyclic. Specific examples thereof include those groups mentioned as the hydrocarbyl group represented by R^{fa1} in formula (1A′) described later.

In formula (d1-2), R³² is a hydrogen atom, a C₁-C₃₀ hydrocarbyl group, or a C₂-C₃₀ hydrocarbylcarbonyl group, and the hydrocarbyl group and the hydrocarbylcarbonyl group may contain an ether bond, an ester bond, a carbonyl group, or a lactone ring. The hydrocarbyl group and the hydrocarbyl moiety in the hydrocarbylcarbonyl group may be linear, branched, or cyclic. Specific examples thereof include those groups mentioned as the hydrocarbyl group represented by R^{fa1} in formula (1A′) described later.

Examples of a cation in the monomer from which the repeat units (d1) are derived include those shown below, but are not limited thereto. In the formulae, R^{A} and M⁻ are as defined above.

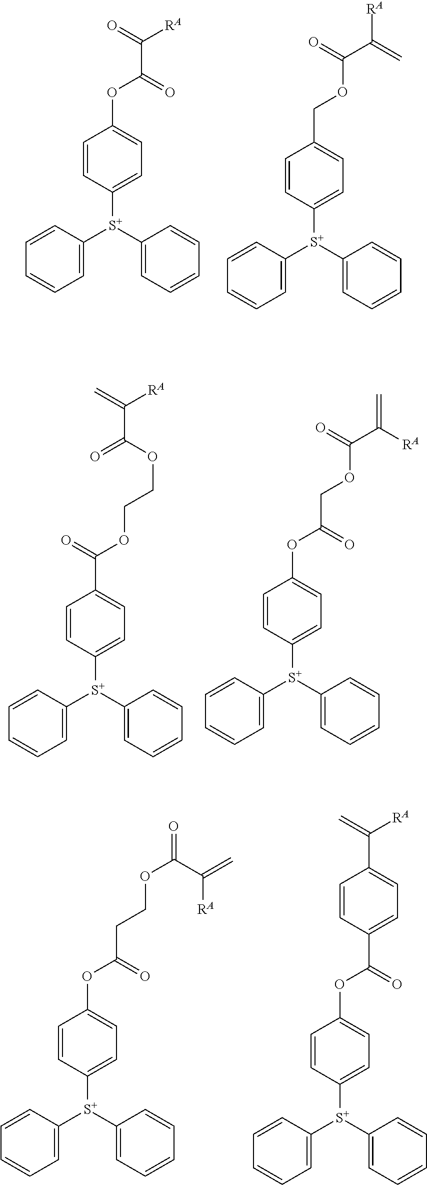

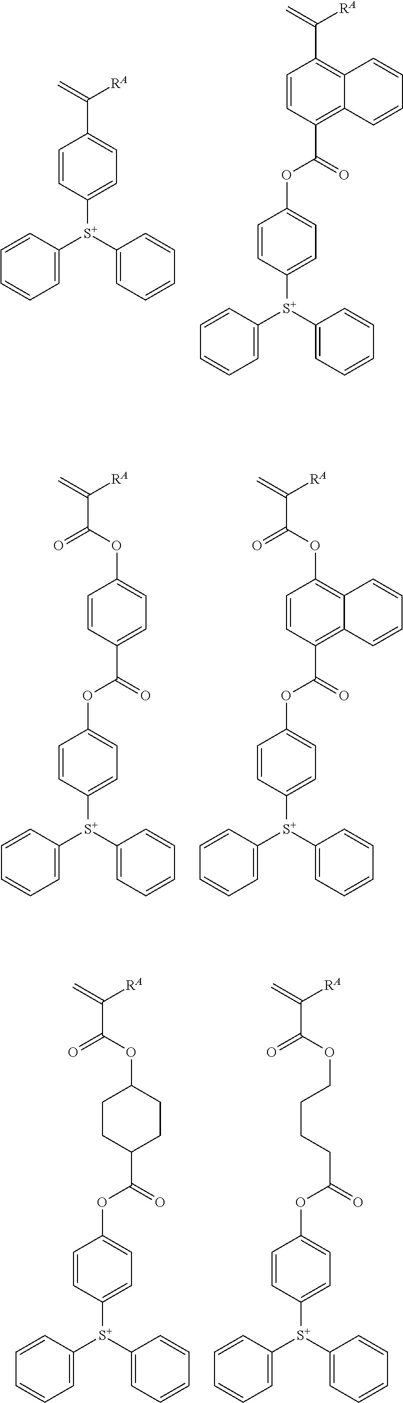

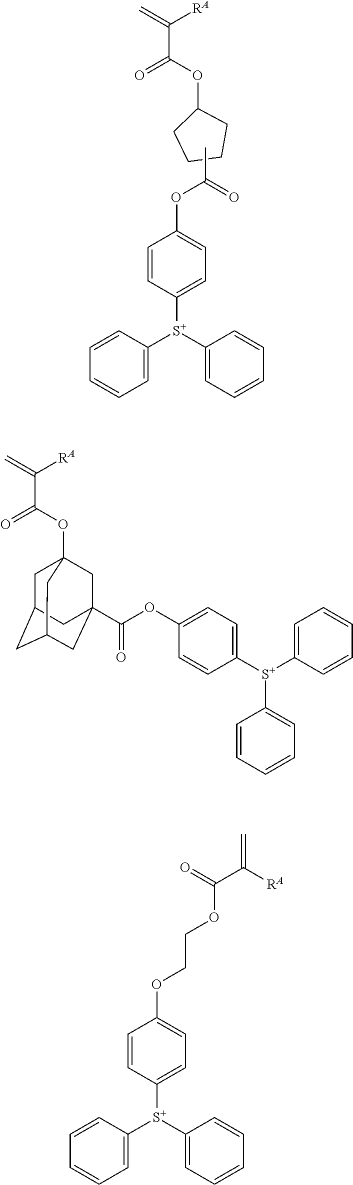

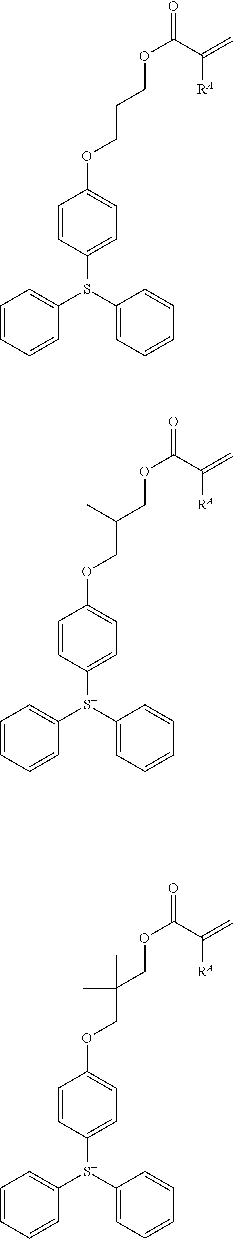

Specific examples of a sulfonium cation in the repeat units (d2) and (d3) include those cations mentioned as the sulfonium cation in the repeat units (a1).

Examples of an anion in the monomer from which the repeat units (d2) are derived include those shown below, but are not limited thereto. In the formulae, R^{A} is as defined above.

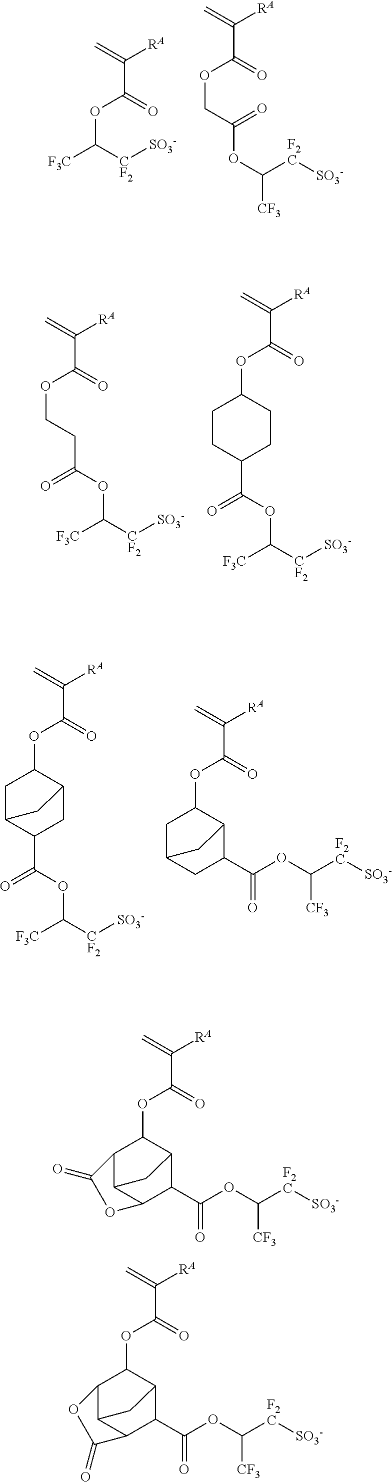

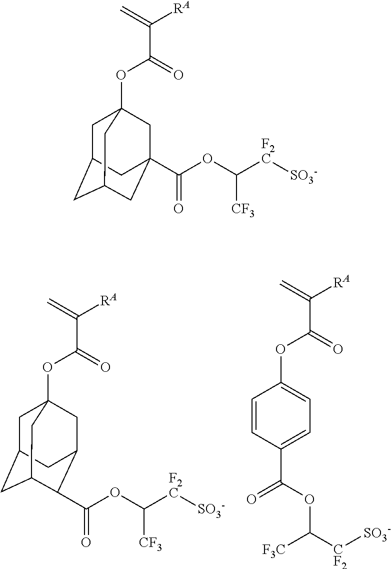

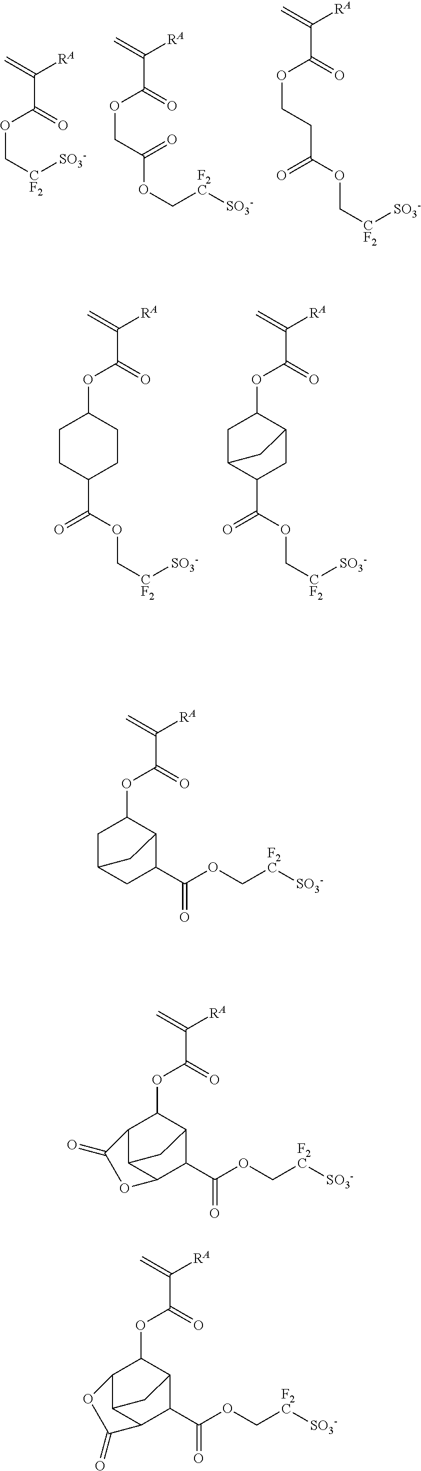

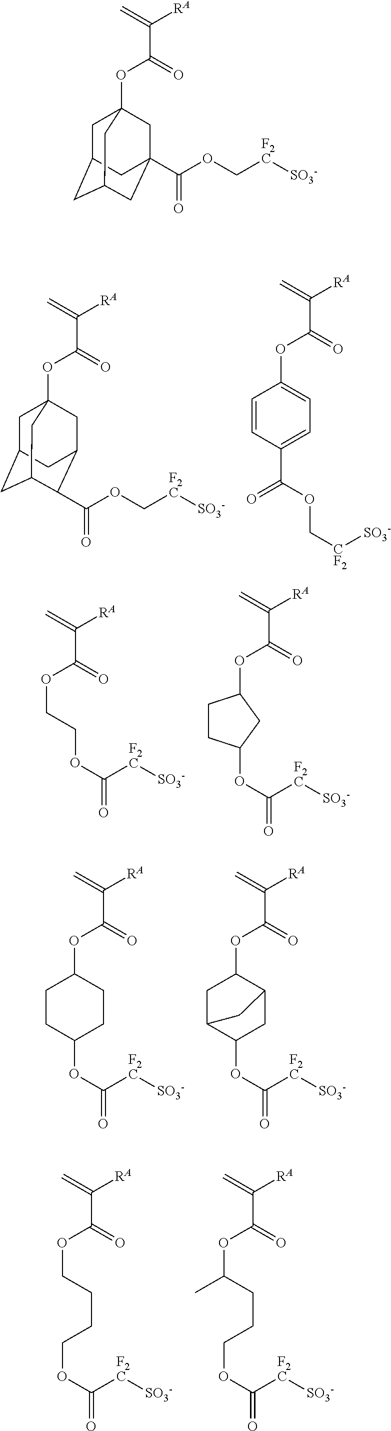

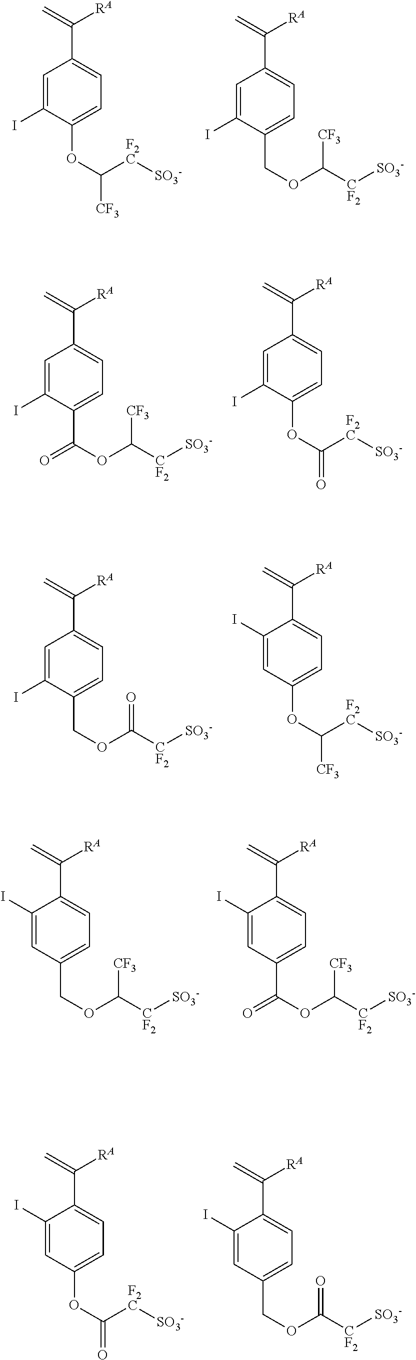

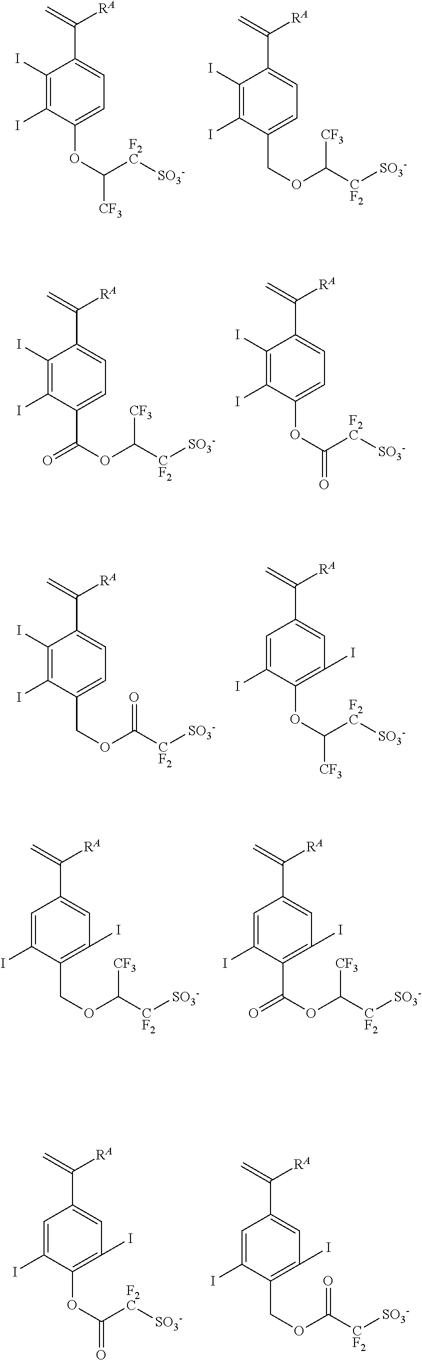

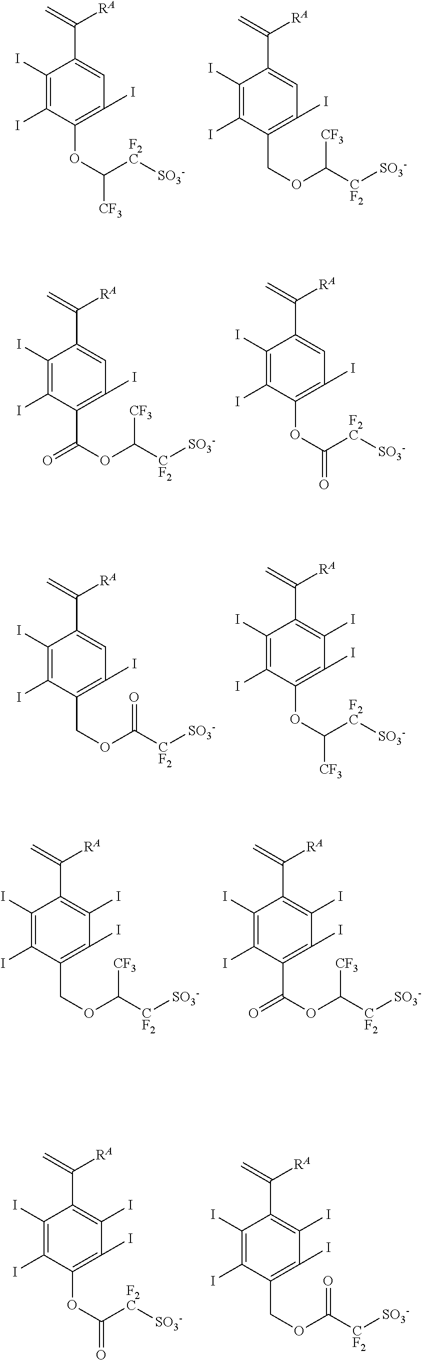

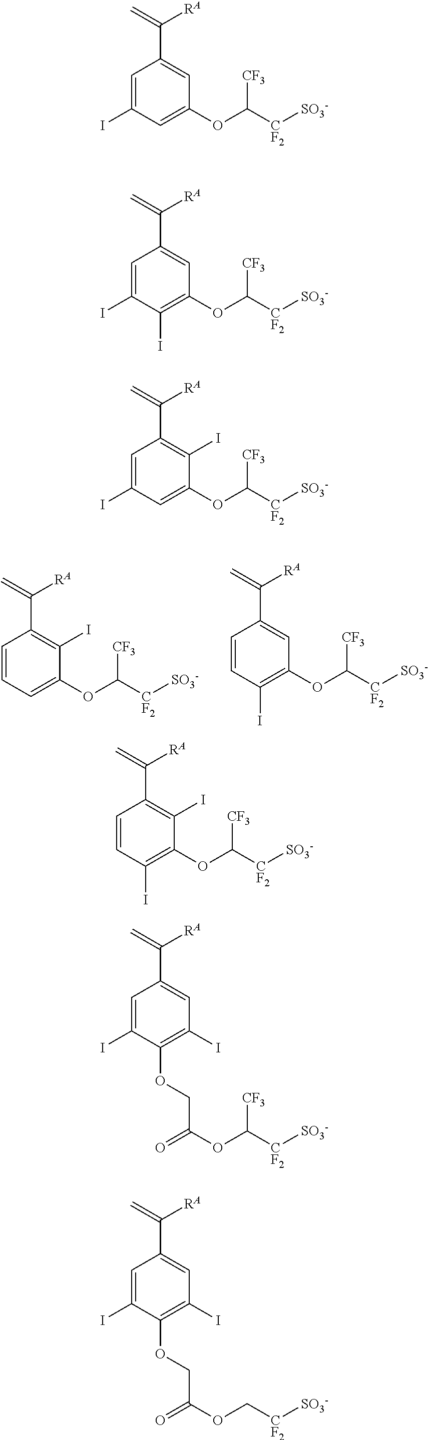

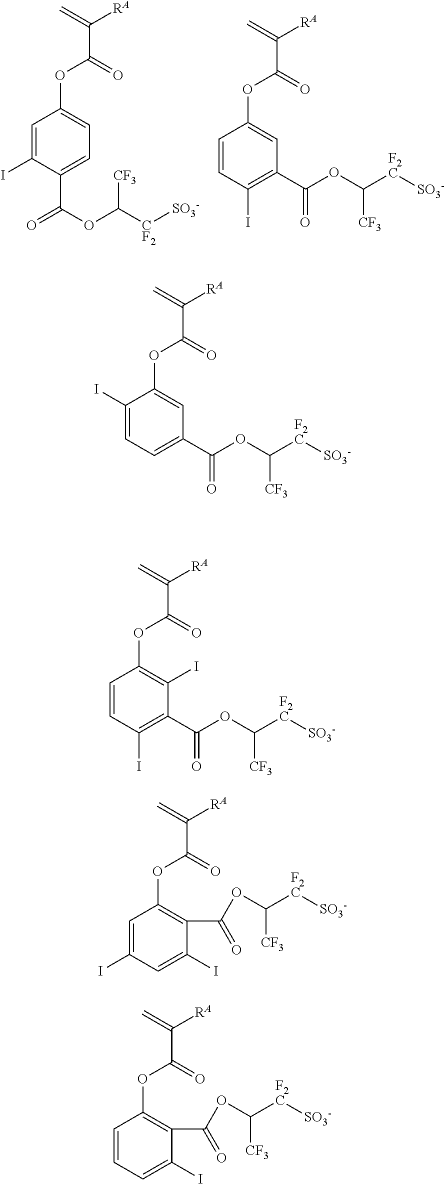

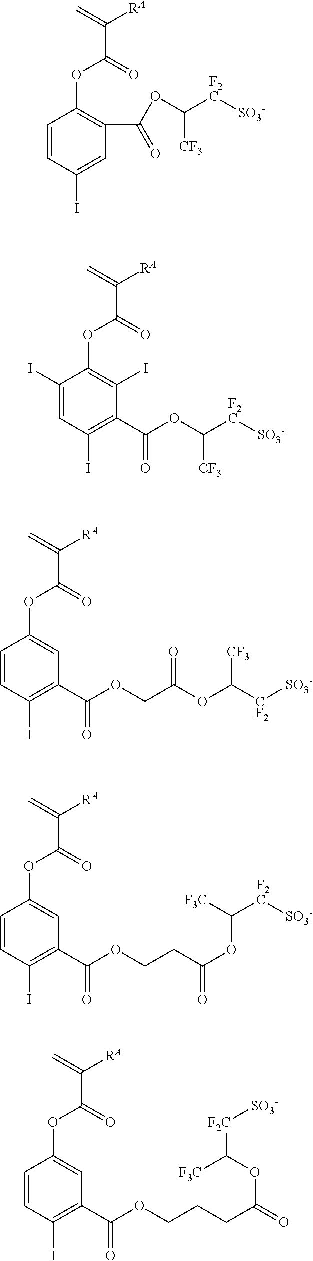

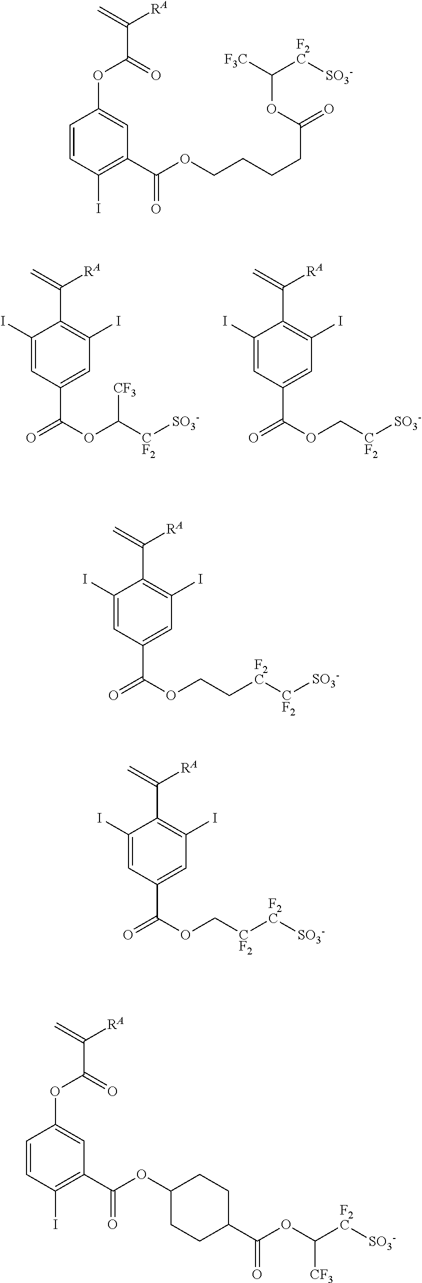

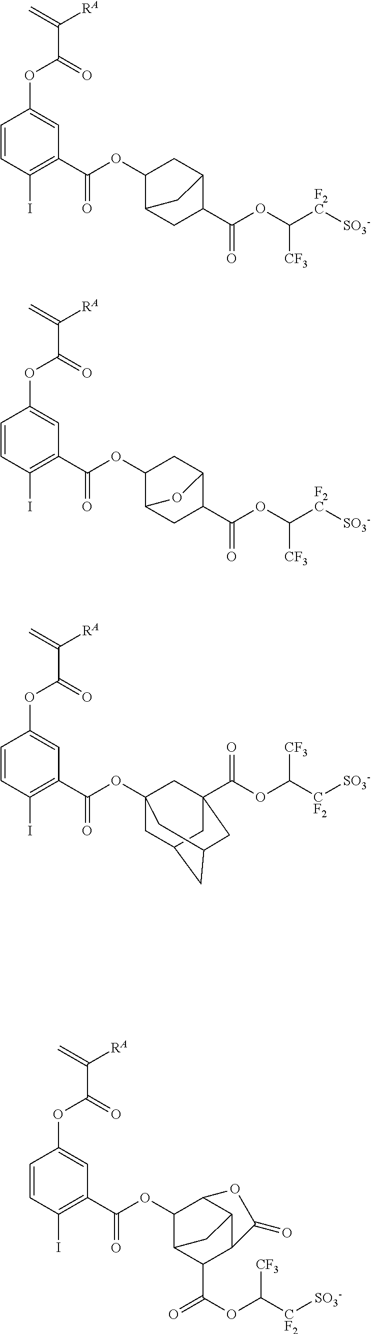

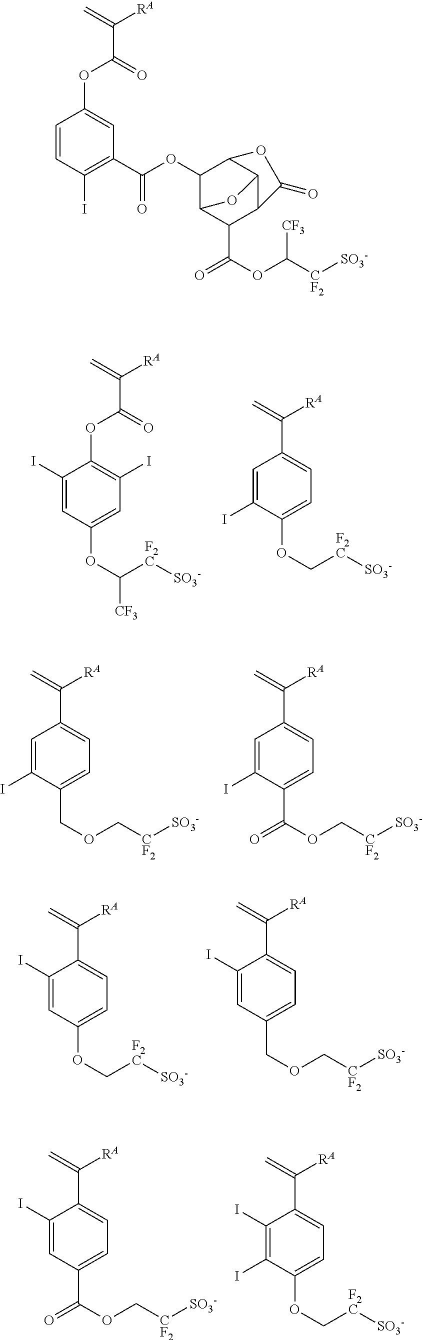

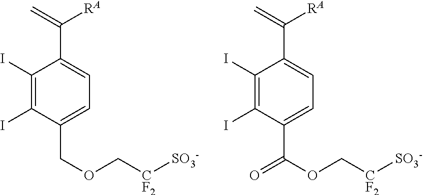

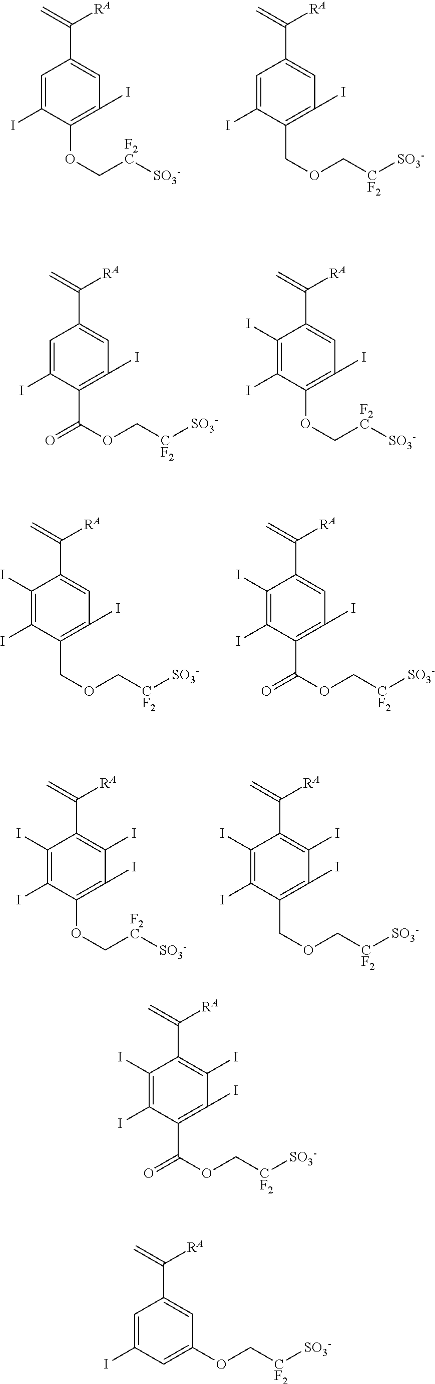

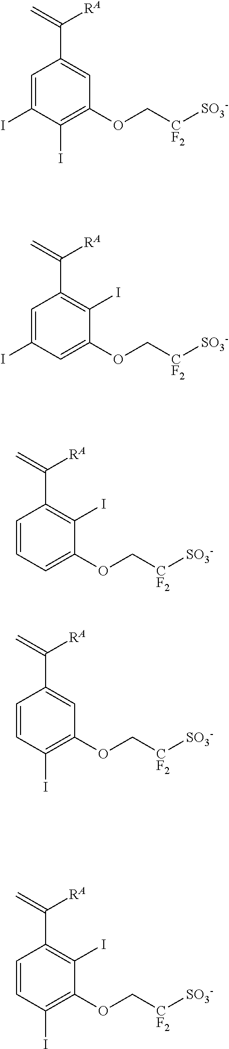

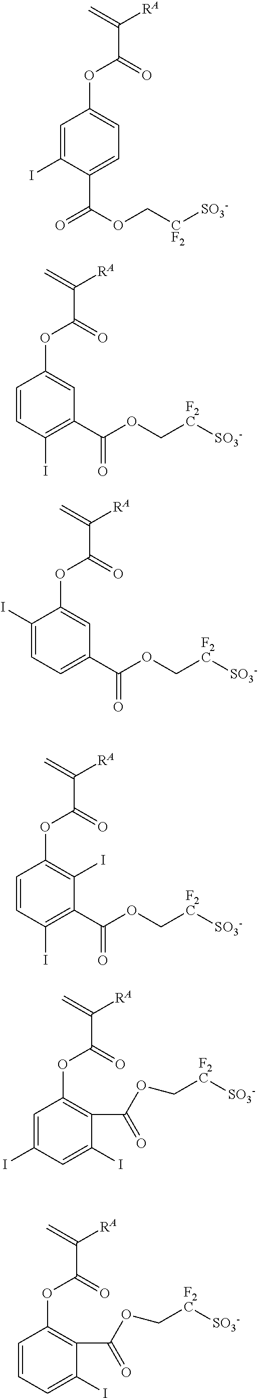

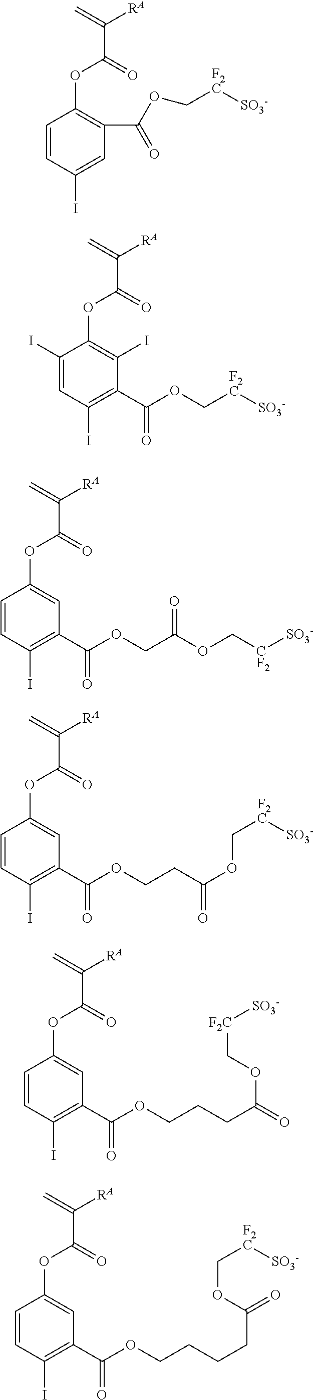

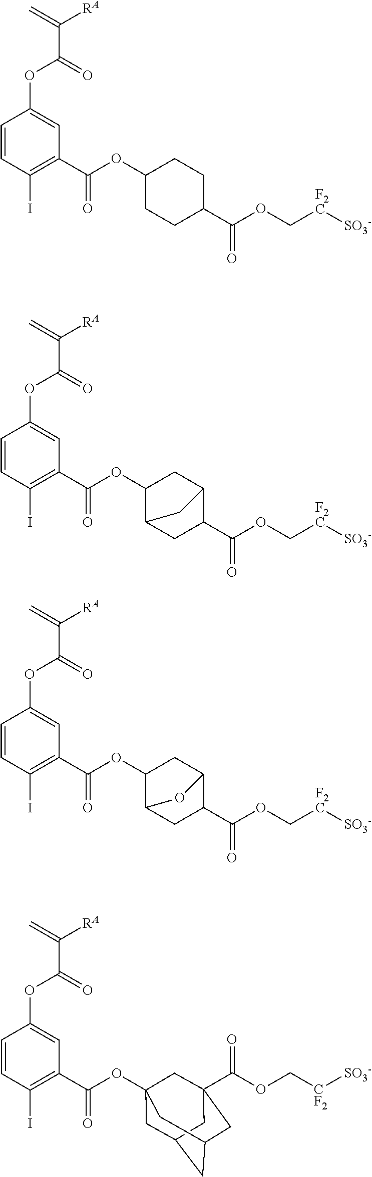

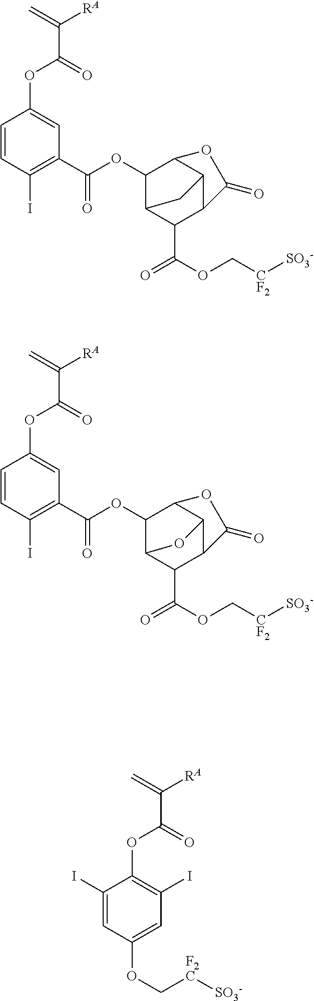

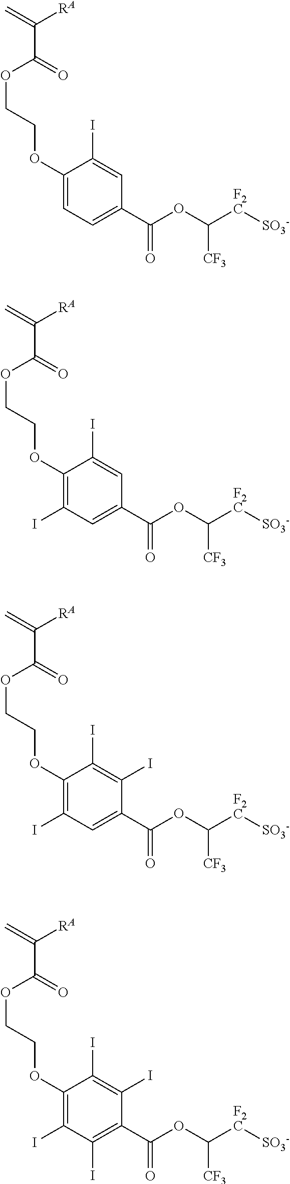

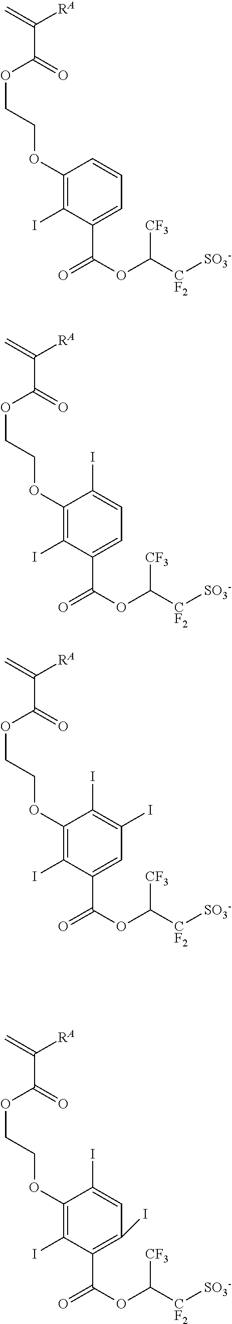

Examples of the monomer from which the repeat units (d3) are derived include those shown below, but are not limited thereto. In the formulae, R^{A} is as defined above.

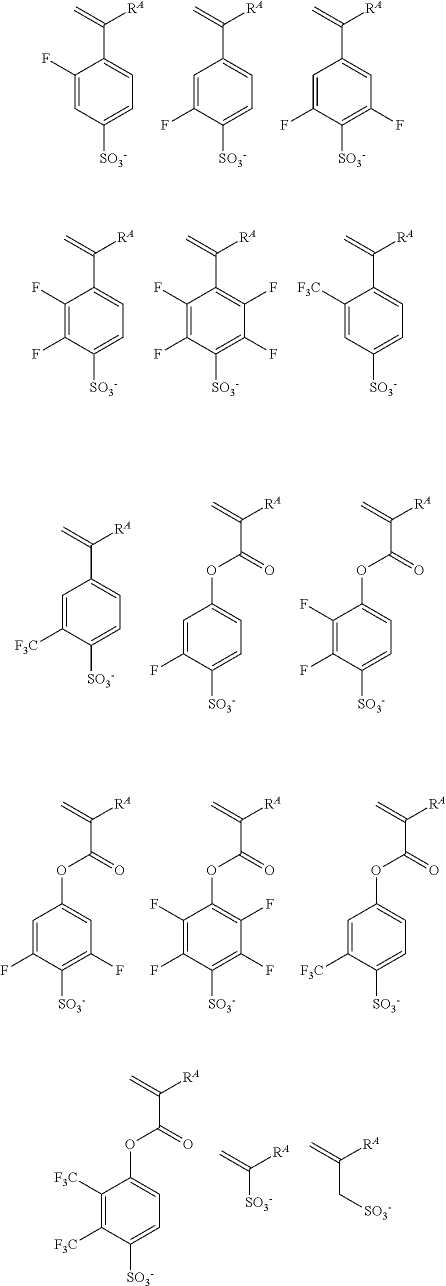

The repeat units (d1) to (d3) function as acid generators. Bonding an acid generator to the polymer backbone is effective in restraining acid diffusion, thereby preventing a reduction of resolution due to blur by acid diffusion. In addition, the LWR and CDU are improved since the acid generator is uniformly distributed. Use of a base polymer containing any of the repeat units (d1) to (d3), that is, use of a polymer-bound acid generator may avoid the necessity for an acid generator of addition type described later.

The base polymer may further contain repeat units (e) free of an amino group and containing an iodine atom. Examples of the monomer from which the repeat units (e) are derived include those shown below, but are not limited thereto. In the formulae, R^{A} is as defined above.

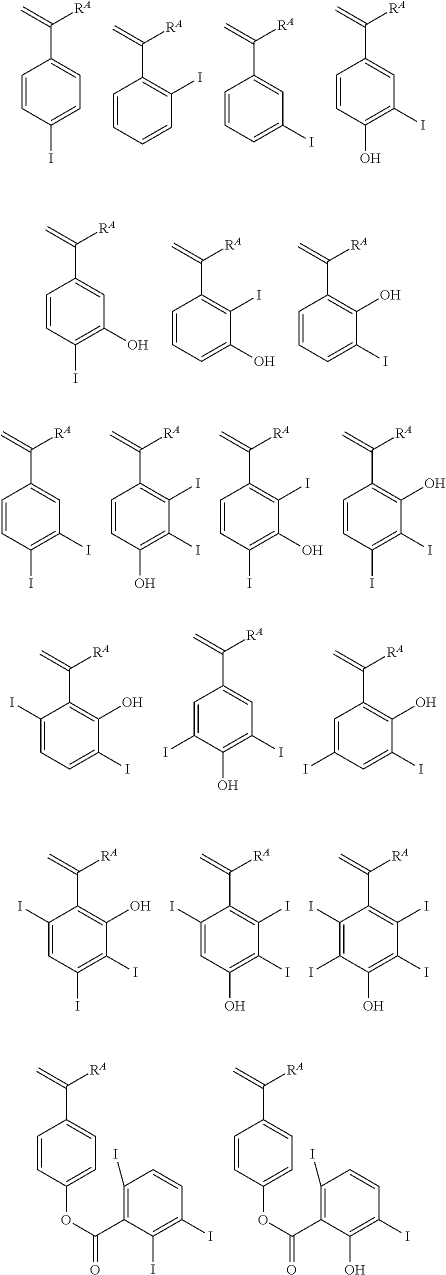

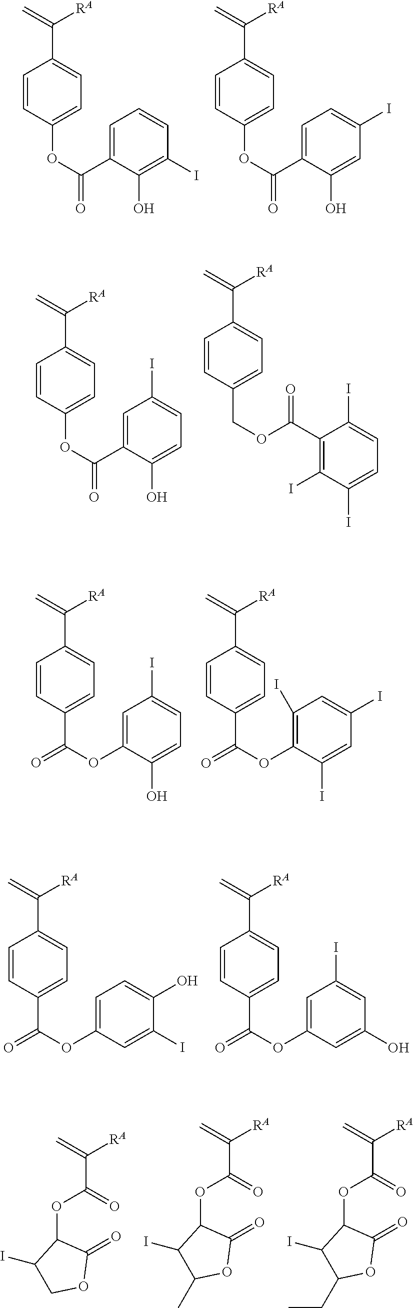

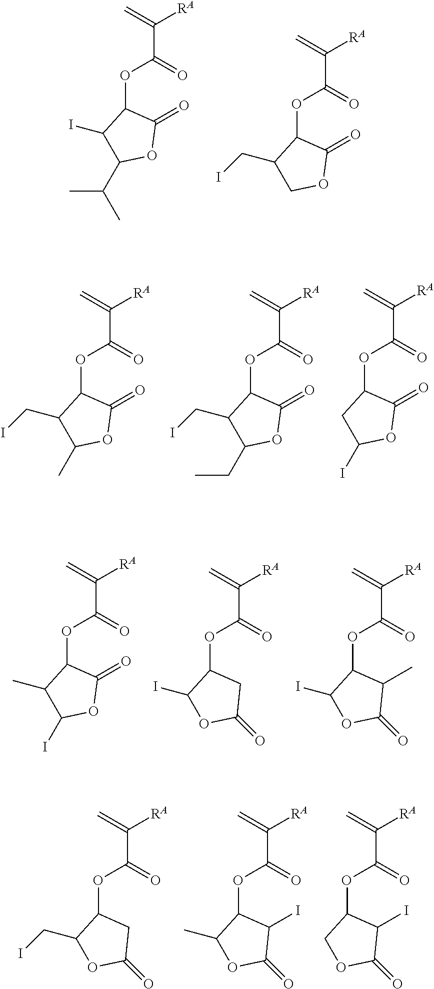

The base polymer may contain repeat units (f) other than the repeat units described above. Examples of the repeat units (f) include those derived from styrene, vinylnaphthalene, indene, acenaphthylene, coumarin, coumarone, or the like.

In the base polymer, the fractions of the repeat units (a1), (a2), (b1), (b2), (c), (d1), (d2), (d3), (e), and (f) are preferably 0≤(a1)<1.0, 0≤(a2)<1.0, 0<(a1)+(a2)<1.0, 0≤(b1)≤0.5, 0≤(b2)≤0.5, 0<(b1)+(b2)≤0.9, 0≤(c)≤0.9, 0≤(d1)≤0.5, 0≤(d2)≤0.5, 0≤(d3)≤0.5, 0≤(d1)+(d2)+(d3)≤0.5, 0≤(e)≤0.5, and 0≤(f)≤0.5, more preferably 0.001≤(a1)≤0.8, 0.001≤(a2)≤0.8, 0.001≤(a1)+(a2)≤0.8, 0≤(b1)≤0.8, 0≤(b2)≤0.8, 0.1≤(b1)+(b2)≤0.8, 0≤(c)≤0.8, 0≤(d1)≤0.4, 0≤(d2)≤0.4, 0≤(d3)≤0.4, 0≤(d1)+(d2)+(d3)≤0.4, 0≤(e)≤0.4, and 0≤(f)≤0.4, and even more preferably 0.005≤(a1)≤0.7, 0.005≤(a2)≤0.7, 0.005≤(a1)+(a2)≤0.7, 0≤(b1)≤0.7, 0≤(b2)≤0.7, 0≤(b1)+(b2)≤0.7, 0≤(c)≤0.7, 0≤(d1)≤0.3, 0≤(d2)≤0.3, 0≤(d3)≤0.3, 0≤(d1)+(d2)+(d3)≤0.3, 0≤(e)≤0.3, and 0≤(f)≤0.3. Note that

$$( a 1 ) + ( a 2 ) + ( b 1 ) + ( b 2 ) + ( c ) + ( d 1 ) + ( d 2 ) + ( d 3 ) + ( e ) + ( f ) = 1. .$$

The base polymer may be synthesized, for example, by heating a monomer from which the repeat units are derived in an organic solvent with the addition of a radical polymerization initiator to perform polymerization.

Examples of the organic solvent used in the polymerization include toluene, benzene, tetrahydrofuran (THF), diethyl ether, and dioxane. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, and lauroyl peroxide. The temperature during polymerization is preferably 50 to 80° C. The reaction time is preferably 2 to 100 hours, and more preferably 5 to 20 hours.

When a monomer having a hydroxy group is copolymerized, the hydroxy group may be substituted with an acetal group susceptible to deprotection with an acid such as an ethoxyethoxy group prior to polymerization, and the polymerization be followed by deprotection with a weak acid and water. Alternatively, the hydroxy group may be substituted with an acetyl group, a formyl group, a pivaloyl group or the like prior to polymerization, and the polymerization be followed by alkaline hydrolysis.

When hydroxystyrene or hydroxyvinylnaphthalene is copolymerized, acetoxystyrene or acetoxyvinylnaphthalene may be used instead of hydroxystyrene or hydroxyvinylnaphthalene, and after polymerization, the acetoxy group may be deprotected by alkaline hydrolysis for converting the polymer product to hydroxystyrene or hydroxyvinylnaphthalene.

For alkaline hydrolysis, a base such as aqueous ammonia or triethylamine may be used. The reaction temperature is preferably-20 to 100° C., and more preferably 0 to 60° C. The reaction time is preferably 0.2 to 100 hours, and more preferably 0.5 to 20 hours.

The base polymer preferably has a weight average molecular weight (Mw) in the range of 1,000 to 500,000, and more preferably 2,000 to 30,000, as measured by gel permeation chromatography (GPC) versus polystyrene standards using a THF solvent. A Mw in the range ensures that the resist film has heat resistance and high solubility in an alkaline developer.

If the base polymer has a wide molecular weight distribution (Mw/Mn), which indicates the presence of lower and higher molecular weight polymer fractions, there is a possibility that foreign matters are left on the pattern or the pattern profile is degraded after exposure. The influences of Mw and Mw/Mn tend to be stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

In order to obtain a polymer having a narrow dispersity, not only normal radical polymerization but also living radical polymerization can be employed. Examples of the living radical polymerization include living radical polymerization using a nitroxide radical (nitroxide-mediated radical polymerization: NMP), atom transfer radical polymerization (ATRP), and reversible addition-fragmentation chain transfer (RAFT) polymerization.

The base polymer may contain two or more polymers having different compositional ratios, Mw, and Mw/Mn. In addition, a polymer containing the repeat units (a) and a polymer free of the repeat units (a) may be blended.

### [Acid Generator]

The positive resist composition of the present invention may contain an acid generator that generates a strong acid (hereinafter, the acid generator is also referred to as acid generator of addition type). The strong acid as used herein means a compound having an acidity sufficient to cause a deprotection reaction of an acid labile group of a base polymer.

Examples of the acid generator include a compound that generates an acid in response to actinic rays or radiation (the compound is referred to as photoacid generator, PAG). Although the photoacid generator may be any compound capable of generating an acid upon exposure to high-energy radiation, those compounds capable of generating a sulfonic acid, an imide acid (imidic acid), or a methide acid are preferred. Suitable photoacid generators include sulfonium salts, iodonium salts, sulfonyldiazomethane, N-sulfonyloxyimide, and oxime-O-sulfonate acid generators. Specific examples of the photoacid generator include those described in paragraphs to of JP-A 2008-111103.

In addition, as the photoacid generator, a sulfonium salt having formula (1-1) and an iodonium salt having formula (1-2) can also be suitably used.

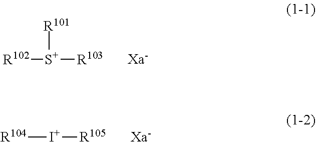

In formulae (1-1) and (1-2), R¹⁰¹ to R¹⁰⁵ are each independently a halogen atom or a C₁-C₂₀ monovalent hydrocarbon group which may contain a heteroatom. The hydrocarbyl group may be saturated or unsaturated, and may be linear, branched, or cyclic. Specific examples thereof include those groups mentioned as the hydrocarbyl group represented by R³ to R⁷ in the description of formulae (a1) and (a2). R¹⁰¹ and R¹⁰² may bond together to form a ring with a sulfur atom to which they are bonded. Examples of the ring include those rings mentioned as the ring formed by the bond of R³ and R⁴ with a sulfur atom to which they are bonded in the description of formulae (a1) and (a2).

Specific examples of a cation of the sulfonium salt having formula (1-1) include those cations mentioned as the cation in the repeat units (a1). Specific examples of a cation of the iodonium salt having formula (1-2) include those cations mentioned as the cation in the repeat units (a2).

In formulae (1-1) and (1-2), Xa⁻ represents an anion selected from formulae (1A) to (1D).

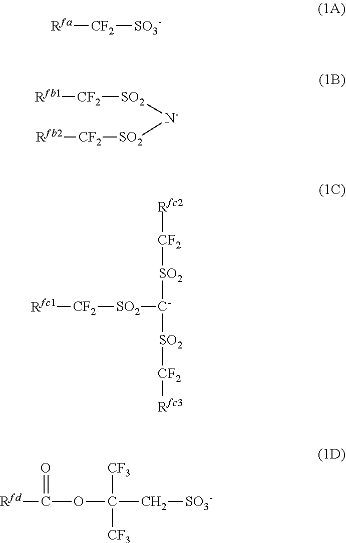

In formula (1A), R^{fa} is a fluorine atom or a C₁-C₄₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (1A′) described later.

The anion having formula (1A) is preferably an anion having formula (1A′).

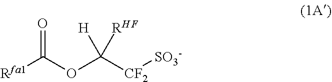

In formula (1A′), R^{HF} is a hydrogen atom or a trifluoromethyl group, and is preferably a trifluoromethyl group. R^{fa1} is a C₁-C₃₈ hydrocarbyl group which may contain a heteroatom. The heteroatom is preferably an oxygen atom, a nitrogen atom, a sulfur atom, a halogen atom, or the like, and more preferably an oxygen atom. The hydrocarbyl group is particularly preferably a C₆-C₃₀ hydrocarbyl group from the viewpoint of obtaining high resolution in fine pattern formation.

The hydrocarbyl group represented by R^{fa1} may be saturated or unsaturated, and may be linear, branched, or cyclic. Specific examples thereof include C₁-C₃₈ alkyl groups such as a methyl group, an ethyl group, a n-propyl group, an isopropyl group, a n-butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosyl group; C₃-C₃₈ cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; C₂-C₃₈ unsaturated aliphatic hydrocarbyl groups such as an allyl group and a 3-cyclohexenyl group; C₆-C₃₈ aryl groups such as a phenyl group, a 1-naphthyl group, and a 2-naphthyl group; C₇-C₃₈ aralkyl groups such as a benzyl group and a diphenylmethyl group; and groups obtained by combining the foregoing.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Examples of the heteroatom-containing hydrocarbyl group include a tetrahydrofuryl group, a methoxymethyl group, an ethoxymethyl group, a methylthiomethyl group, an acetamidomethyl group, a trifluorocthyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

Synthesis of a sulfonium salt containing the anion having formula (1A′) is described in detail in, for example, JP-A 2007-145797, JP-A 2008-106045, JP-A 2009-007327, and JP-A 2009-258695. In addition, sulfonium salts described in, for example, JP-A 2010-215608, JP-A 2012-041320, JP-A 2012-106986, and JP-A 2012-153644 are also suitably used.

Examples of the anion having formula (1A) include those mentioned as the anion having formula (1A) in JP-A 2018-197853.

In formula (1B), R^{fb1} and R^{fb2} are each independently a fluorine atom or a C₁-C₄₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (1A′). Each of R^{fb1} and R^{fb2} is preferably a fluorine atom or a C₁-C₄ linear fluorinated alkyl group. R^{fb1} and R^{fb2} may bond together to form a ring with a group to which they are bonded, that is, the group —CF₂—SO₂—N⁻—SO₂—CF₂—, and in this case, the group obtained by bonding of R^{fb1} and R^{fb2} together is preferably a fluorinated ethylene group or a fluorinated propylene group.

In formula (1C), R^{fc1}, R^{fc2}, and R^{fc3} are each independently a fluorine atom or a C₁-C₄₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (1A′). Each of R^{fc1}, R^{fc2}, and R^{fc3} is preferably a fluorine atom or a C₁-C₄ linear fluorinated alkyl group. R^{fc1} and R^{fce2} may bond together to form a ring with a group to which they are bonded, that is, the group —CF₂—SO₂—C⁻—SO₂—CF₂—, and in this case, the group obtained by bonding of R^{fc1} and R^{fc2} together is preferably a fluorinated ethylene group or a fluorinated propylene group.

In formula (1D), R^{fd} is a C₁-C₄₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (1A′).

Synthesis of a sulfonium salt containing the anion having formula (1D) is described in detail in JP-A 2010-215608 and JP-A 2014-133723.

Examples of the anion having formula (1D) include those mentioned as the anion having formula (1D) in JP-A 2018-197853.

The photoacid generator containing the anion having formula (1D) does not have a fluorine atom at the α-position of the sulfo group, but has two trifluoromethyl groups at the β-position, and thus has an acidity sufficient for cleaving the acid labile group in the base polymer. Therefore, the compound can be used as a photoacid generator.

As the photoacid generator, one having formula (2) can also be suitably used.

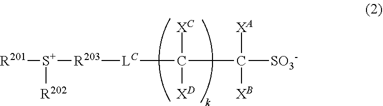

In formula (2), R²⁰¹ and R²⁰² are each independently a halogen atom or a C₁-C₃₀ hydrocarbyl group which may contain a heteroatom. R²⁰³ is a C₁-C₃₀ hydrocarbylene group which may contain a heteroatom. Any two of R²⁰¹, R²⁰², and R²⁰³ may bond together to form a ring with a sulfur atom to which they are bonded. Examples of the ring include those rings mentioned as the ring formed by the bond of R³ and R⁴ with a sulfur atom to which they are bonded in the description of formulae (a1) and (a2).

The hydrocarbyl group represented by R²⁰¹ and R²⁰² may be saturated or unsaturated, and may be linear, branched, or cyclic. Specific examples thereof include C₁-C₃₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₃₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, an oxanorbornyl group, a tricyclo [5.2.1.0^{2,6}]decanyl group, and an adamantyl group; C₆-C₃₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, a tert-butylnaphthyl group, and an anthracenyl group; and groups obtained by combining the foregoing. Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group.

The hydrocarbylene group represented by R²⁰³ may be saturated or unsaturated, and may be linear, branched, or cyclic. Specific examples thereof include C₁-C₃₀ alkanediyl groups such as a methanediyl group, an ethane-1,1-diyl group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; C₃-C₃₀ cyclic saturated hydrocarbylene groups such as a cyclopentanediyl group, a cyclohexanediyl group, a norbornanediyl group, and an adamantanediyl group; C₆-C₃₀ arylene groups such as a phenylene group, a methylphenylene group, an ethylphenylene group, a n-propylphenylene group, an isopropylphenylene group, a n-butylphenylene group, an isobutylphenylene group, a sec-butylphenylene group, a tert-butylphenylene group, a naphthylene group, a methylnaphthylene group, an ethylnaphthylene group, a n-propylnaphthylene group, an isopropylnaphthylene group, a n-butylnaphthylene group, an isobutylnaphthylene group, a sec-butylnaphthylene group, and a tert-butylnaphthylene group; and groups obtained by combining the foregoing. Some or all of hydrogen atoms of the hydrocarbylene group may be substituted with a group containing a heteroatom such as an oxygen atom, a sulfur atom, a nitrogen atom, or a halogen atom, and some of —CH₂— of the hydrocarbylene group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. The heteroatom is preferably an oxygen atom.

In formula (2), L^{C} is a single bond, an ether bond, or a C₁-C₂₀ hydrocarbylene group which may contain a heteroatom. The hydrocarbylene group may be saturated or unsaturated, and may be linear, branched, or cyclic. Specific examples thereof include those groups mentioned as the hydrocarbylene group represented by R²⁰³.

In formula (2), X^{A}, X^{B}, X^{C}, and X^{D} are each independently a hydrogen atom, a fluorine atom, or a trifluoromethyl group. However, at least one of X^{A}, X^{B}, X^{C}, and X^{D} is a fluorine atom or a trifluoromethyl group.

In formula (2), k is an integer of 0 to 3.

The photoacid generator having formula (2) is preferably a photoacid generator having formula (2′).

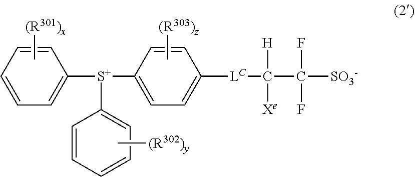

In formula (2′), L^{C} is as defined above. X^{e} is a hydrogen atom or a trifluoromethyl group, and is preferably a trifluoromethyl group. R³⁰¹, R³⁰², and R³⁰³ are each independently a hydrogen atom or a C₁-C₂₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (1A′). x and y are each independently an integer of 0 to 5, and z is an integer of 0 to 4.

Examples of the photoacid generator having formula (2) include those mentioned as the photoacid generator having formula (2) in JP-A 2017-026980.

Among the photoacid generators, those containing the anion having formula (1A′) or (1D) are particularly preferred because they are reduced in acid diffusion and have excellent solubility in solvents. In addition, those having formula (2′) are particularly preferred because they are highly reduced in acid diffusion.

The photoacid generator used can also be a sulfonium or iodonium salt containing an anion having an aromatic ring substituted with an iodine or bromine atom. Examples of such a salt include those having formulae (3-1) and (3-2).

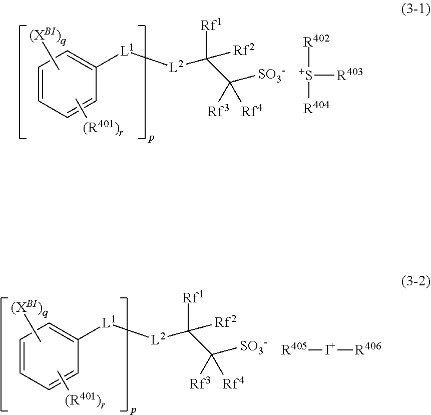

In formulae (3-1) and (3-2), p is an integer satisfying 1≤p≤3. q and r are integers satisfying 1≤q≤5, 0≤r≤3, and 1≤q+r≤5. q is preferably an integer satisfying 1≤ q≤3, and more preferably 2 or 3. r is preferably an integer satisfying 0≤r≤2.

In formulae (3-1) and (3-2), X^{BI} is an iodine atom or a bromine atom, and groups X^{BI} may be identical or different from each other when p and/or q is 2 or more.

In formulae (3-1) and (3-2), L¹ is a single bond, an ether bond, an ester bond, or a C₁-C₆ saturated hydrocarbylene group which may contain an ether bond or an ester bond. The saturated hydrocarbylene group may be linear, branched, or cyclic.

In formulae (3-1) and (3-2), L² is a single bond or a C₁-C₂₀ divalent linking group when p is 1, and a C₁-C₂₀ (p+1)-valent linking group which may contain an oxygen atom, a sulfur atom, or a nitrogen atom when p is 2 or 3.

In formulae (3-1) and (3-2), R⁴⁰¹ is a hydroxy group, a carboxy group, a fluorine atom, a chlorine atom, a bromine atom, an amino group, or a C₁-C₂₀ hydrocarbyl group, a C₁-C₂₀ hydrocarbyloxy group, a C₂-C₂₀ hydrocarbylcarbonyl group, a C₂-C₂₀ hydrocarbyloxycarbonyl group, a C₂-C₂₀ hydrocarbylcarbonyloxy group, or a C₁-C₂₀ hydrocarbylsulfonyloxy group, which may contain a fluorine atom, a chlorine atom, a bromine atom, a hydroxy group, an amino group, or an ether bond, or —N(R^{401A}) (R^{401B}), —N(R^{401C})—C(═O)—R^{401D}, or —N(R^{401C})—C(═O)—O—R^{401D}. R^{401A} and R^{401B} are each independently a hydrogen atom or a C₁-C₆ saturated hydrocarbyl group. R^{401C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{401D} is a C₁-C₁₆ aliphatic hydrocarbyl group, a C₆-C₁₄ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated, and may be linear, branched, or cyclic. The hydrocarbyl group, the hydrocarbyloxy group, the hydrocarbyloxycarbonyl group, the hydrocarbylcarbonyl group, the hydrocarbylcarbonyloxy group, and the hydrocarbylsulfonyloxy group may be linear, branched, or cyclic. Groups R⁴⁰¹ may be identical or different when p and/or r is 2 or more.

Among them, R⁴⁰¹ is preferably a hydroxy group, —N(R^{401C})—C(═O)—R^{401D}, —N(R^{401C})—C(═O)—O—R^{401D}, a fluorine atom, a chlorine atom, a bromine atom, a methyl group, a methoxy group, or the like.

In formulae (3-1) and (3-2), Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may together form a carbonyl group. It is particularly preferred that both Rf³ and Rf⁴ are fluorine atoms.

In formulae (3-1) and (3-2), R⁴⁰² to R⁴⁰⁶ are each independently a halogen atom or a C₁-C₂₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R³ to R⁷ in the description of formulae (a1) and (a2). Some or all of hydrogen atoms of the hydrocarbyl group may be substituted with a hydroxy group, a carboxy group, a halogen atom, a cyano group, a nitro group, a mercapto group, a sultone ring, a sulfo group, or a sulfonium salt-containing group, and some of —CH₂— of the hydrocarbyl group may be substituted with an ether bond, an ester bond, a carbonyl group, an amide bond, a carbonate bond, or a sulfonic ester bond. R⁴⁰² and R⁴⁰³ may bond together to form a ring with a sulfur atom to which they are bonded. Examples of the ring include those rings mentioned as the ring formed by the bond of R³ and R⁴ with a sulfur atom to which they are bonded in the description of formulae (a1) and (a2).

Specific examples of a cation of the sulfonium salt having formula (3-1) include those cations mentioned as the cation in the repeat units (a1). Examples of a cation of the iodonium salt having formula (3-2) include those cations mentioned as the cation in the repeat units (a2).

Examples of an anion of the onium salt having formula (3-1) or (3-2) include those shown below, but are not limited thereto. In the formulae, X^{BI} is as defined above.

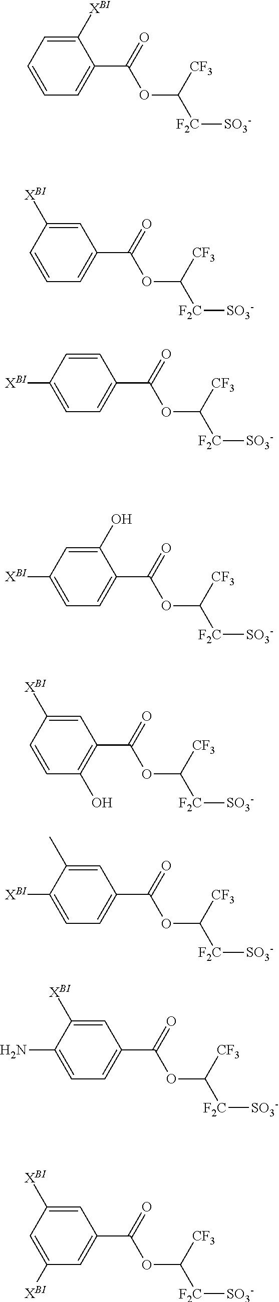

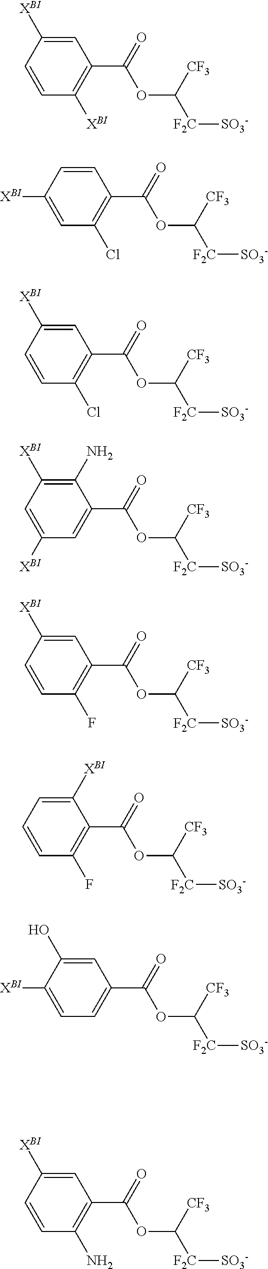

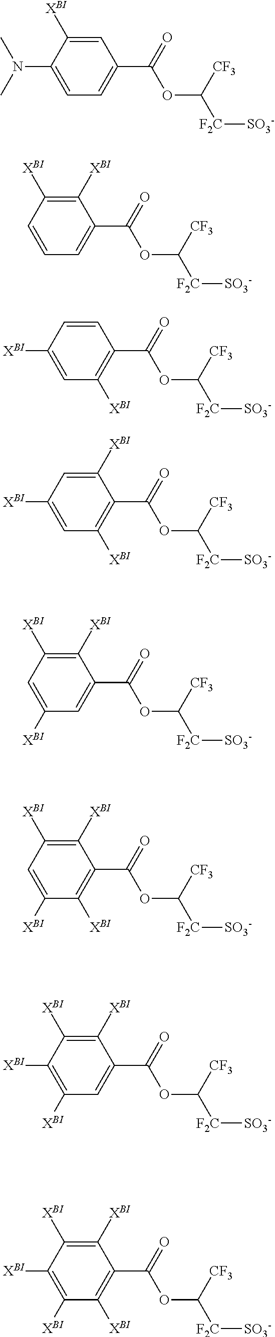

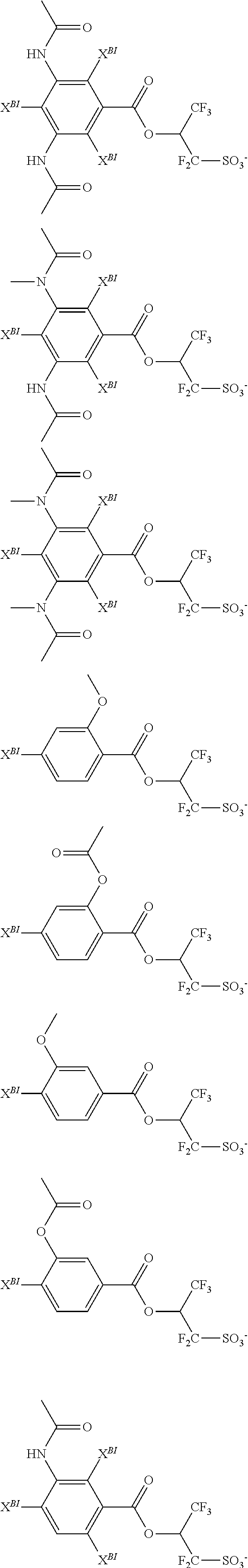

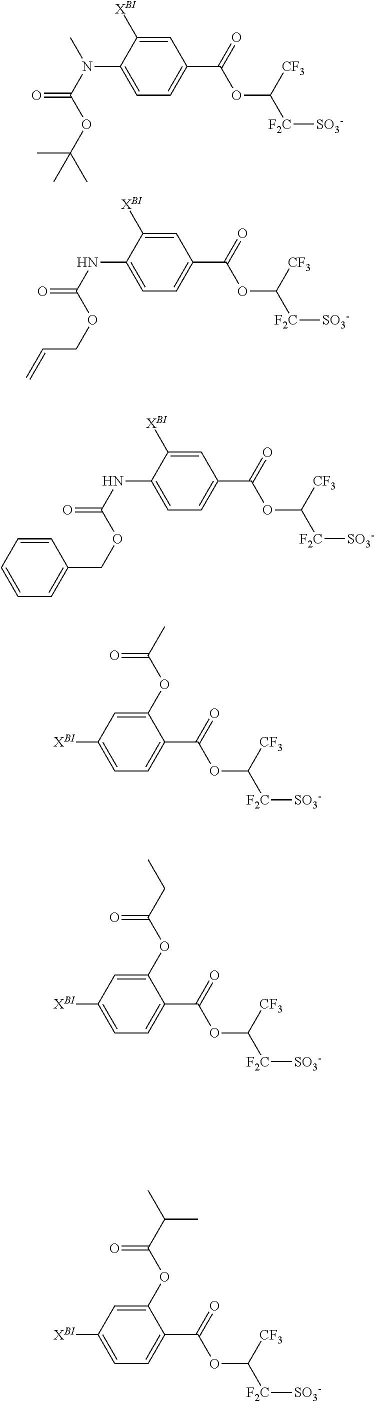

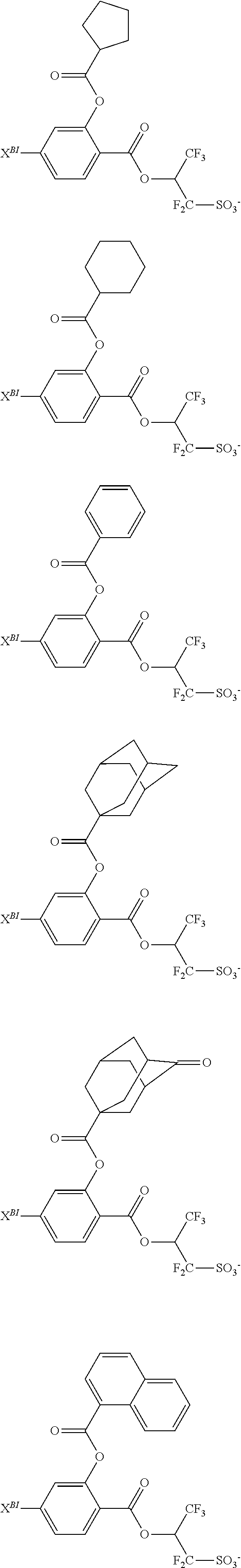

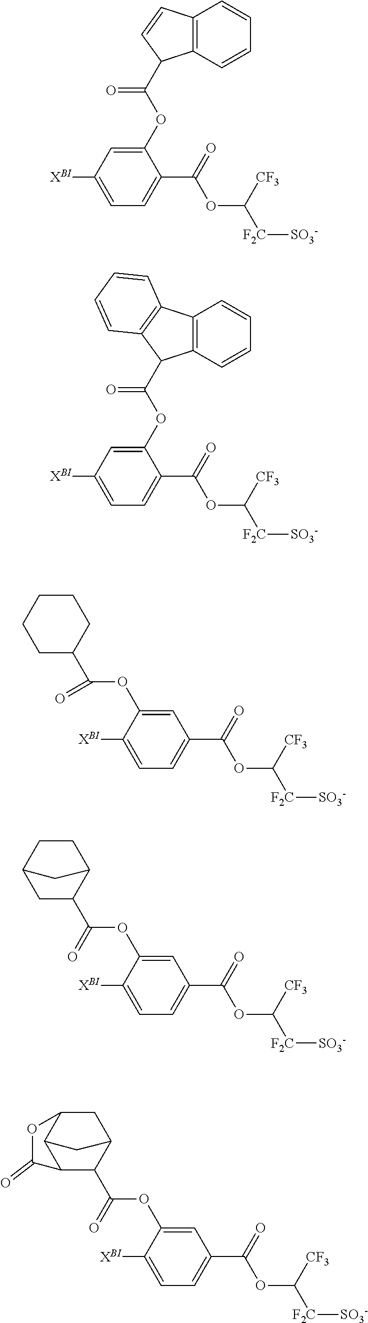

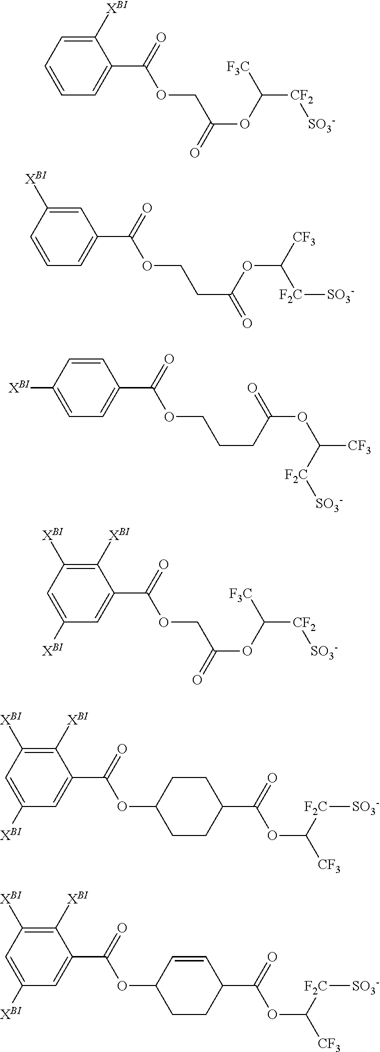

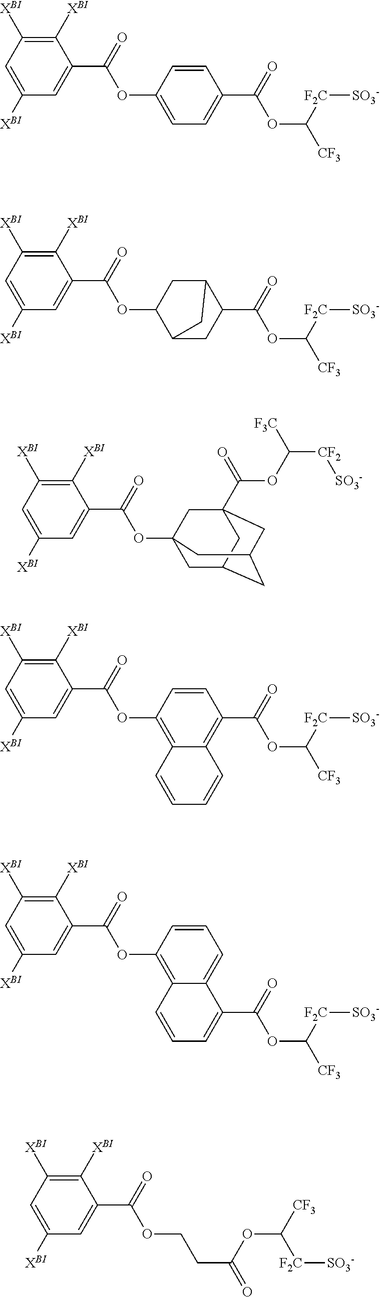

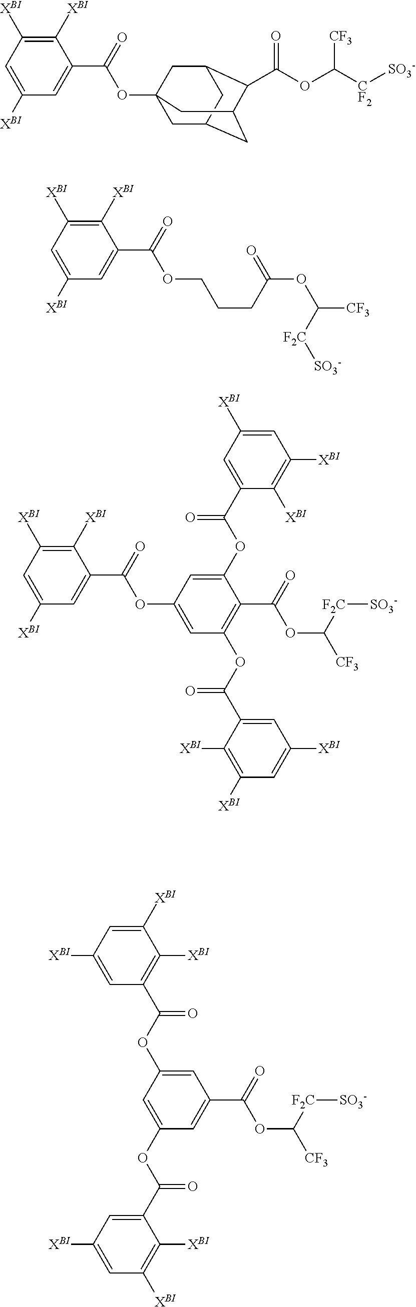

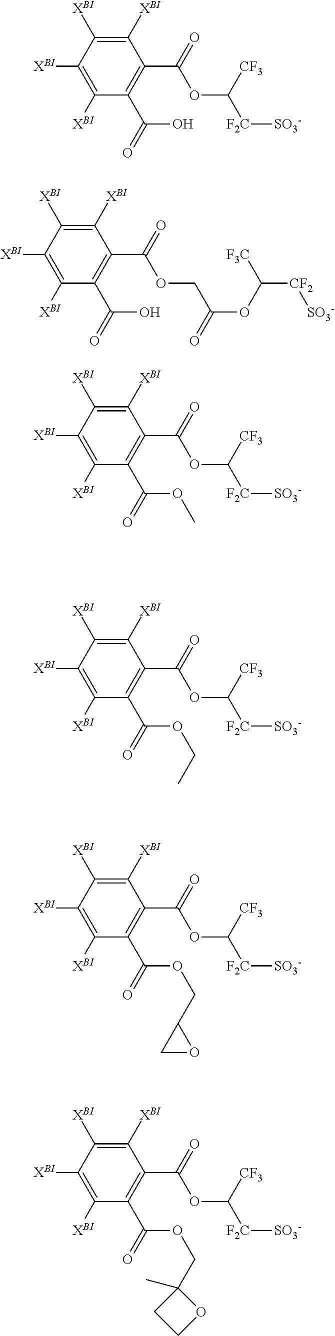

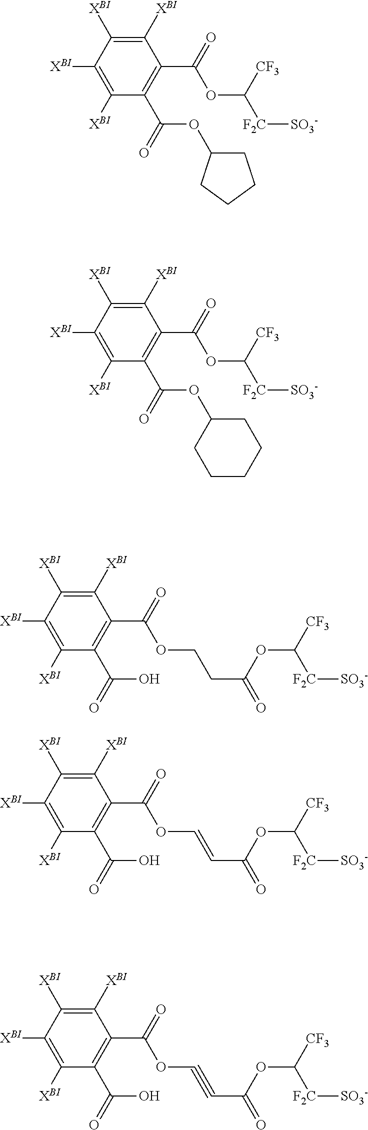

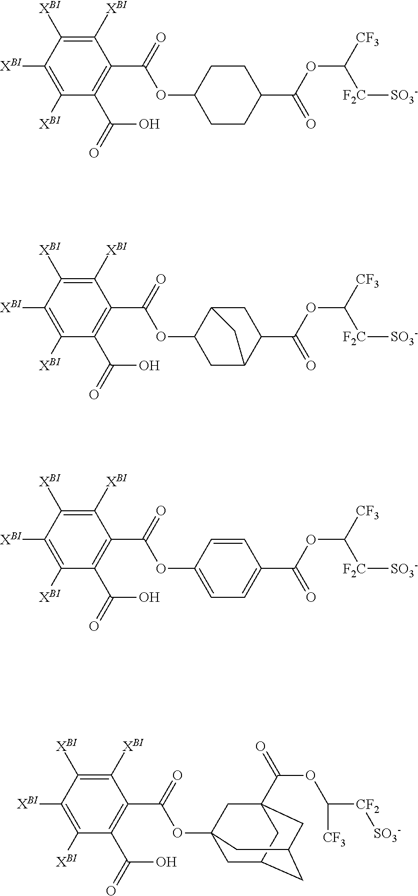

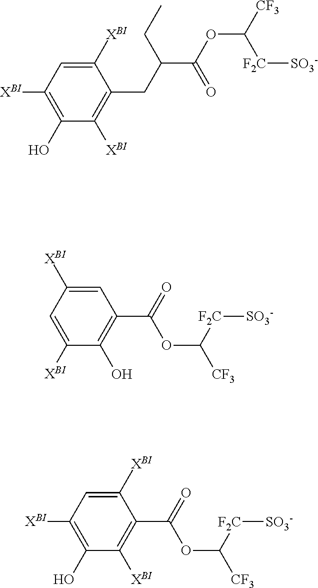

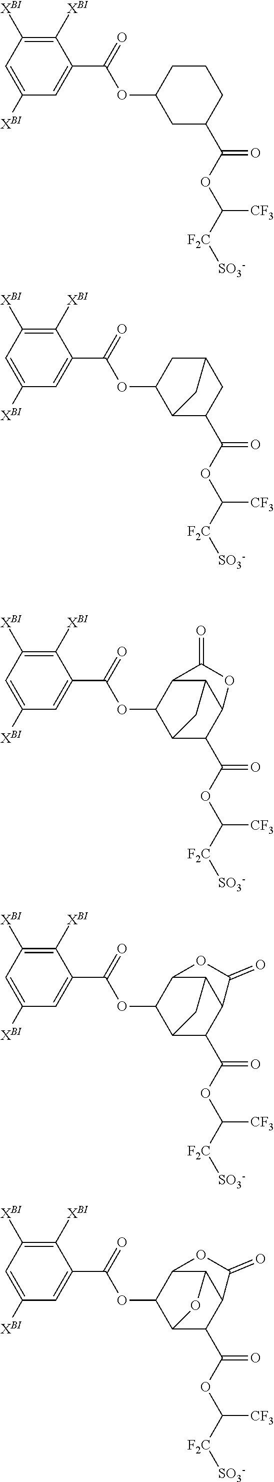

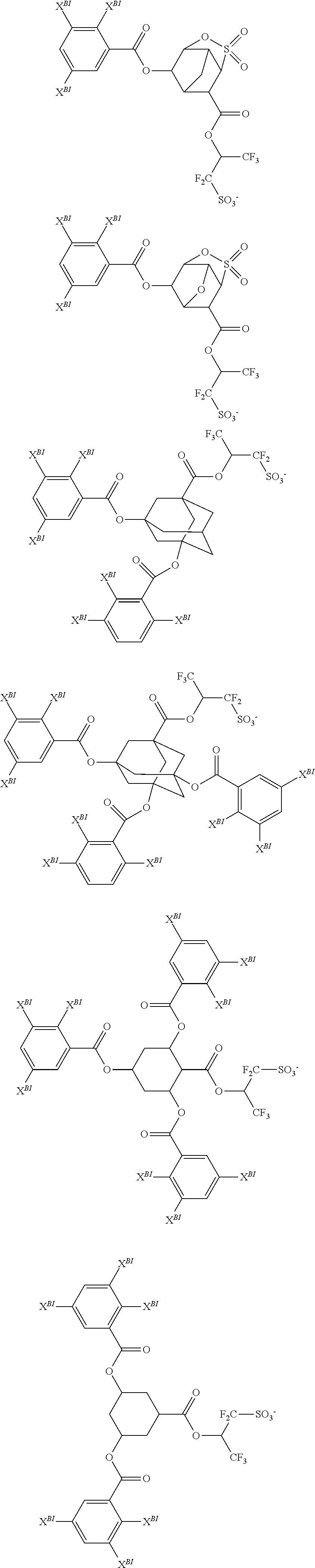

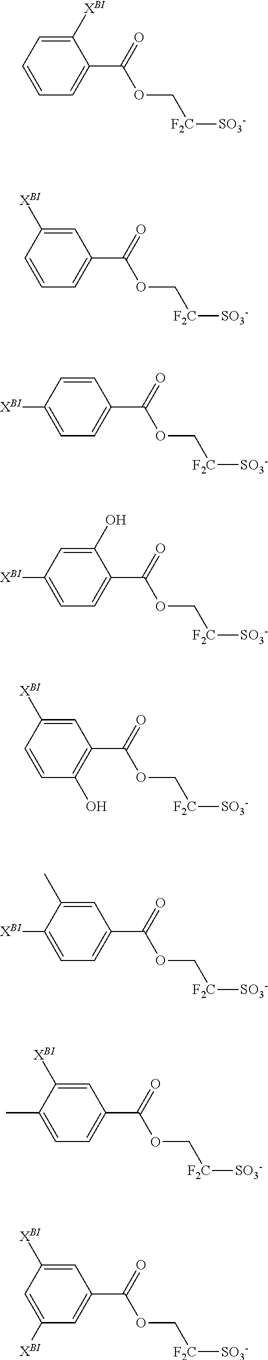

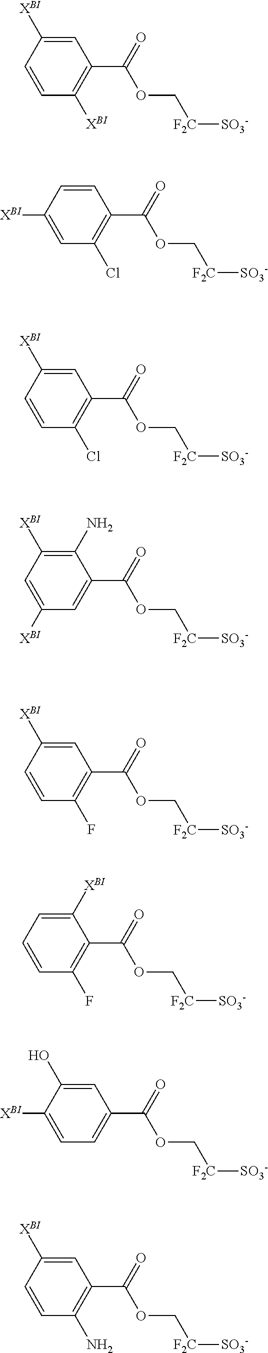

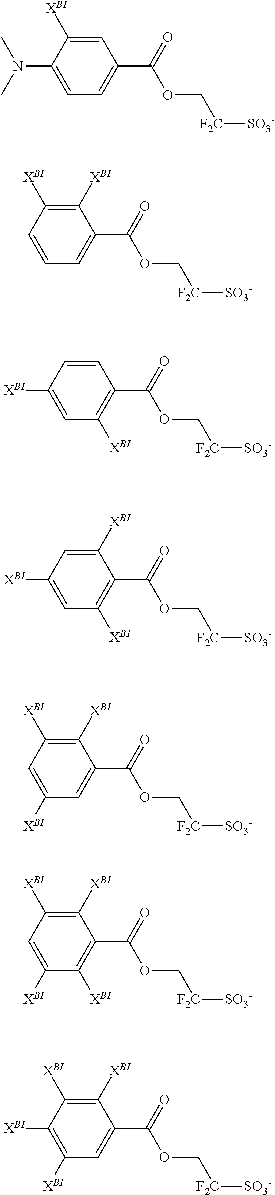

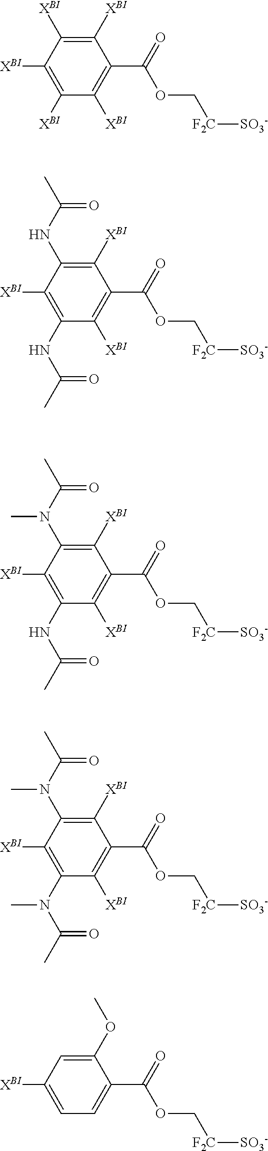

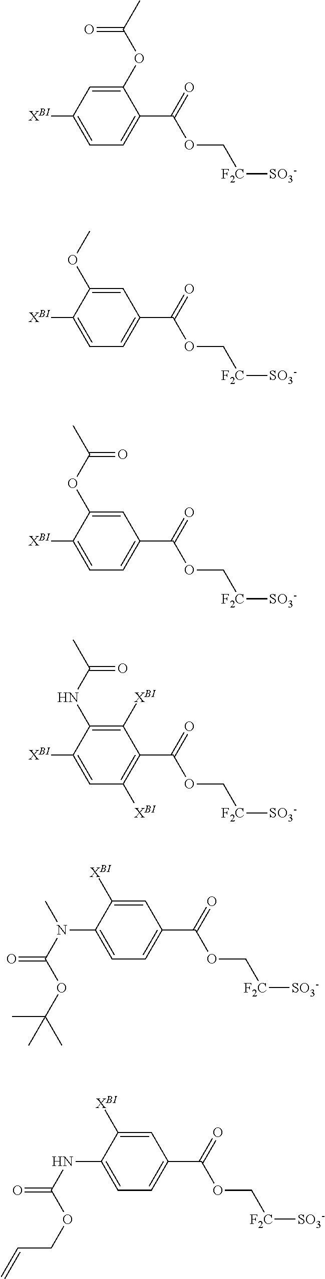

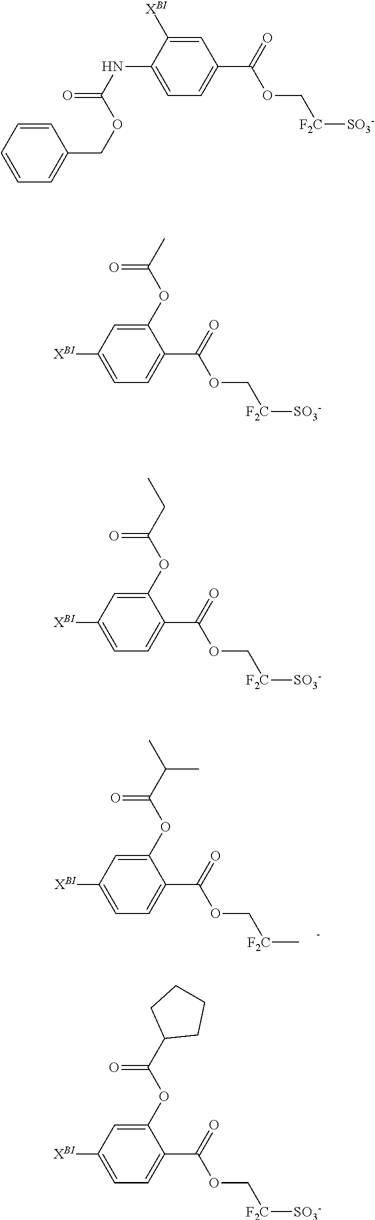

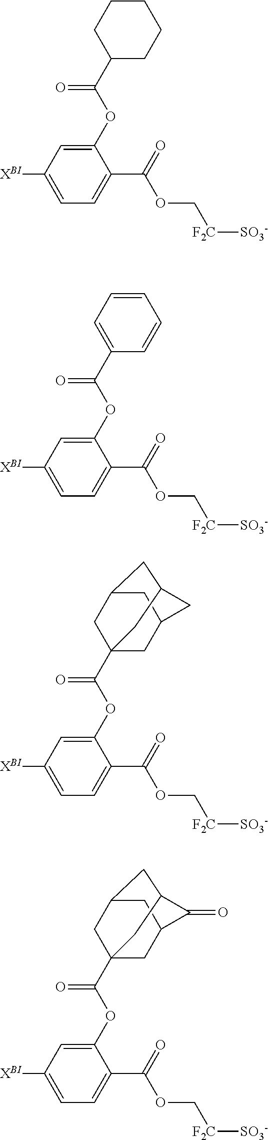

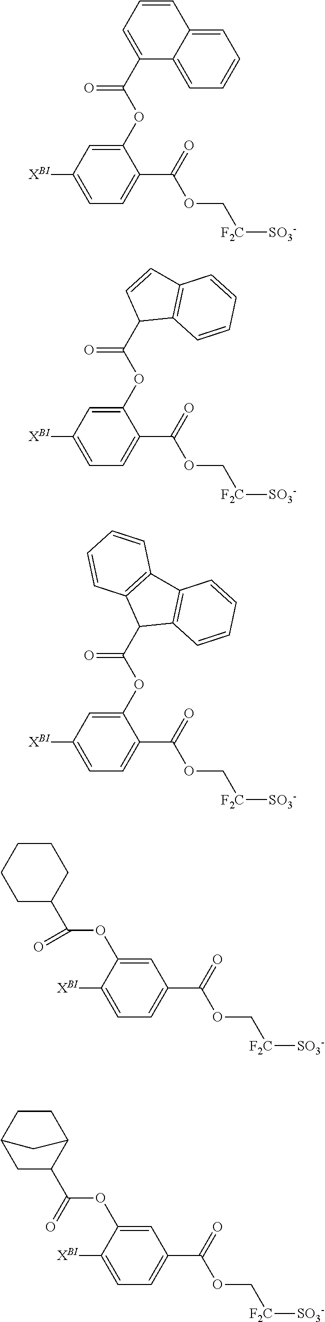

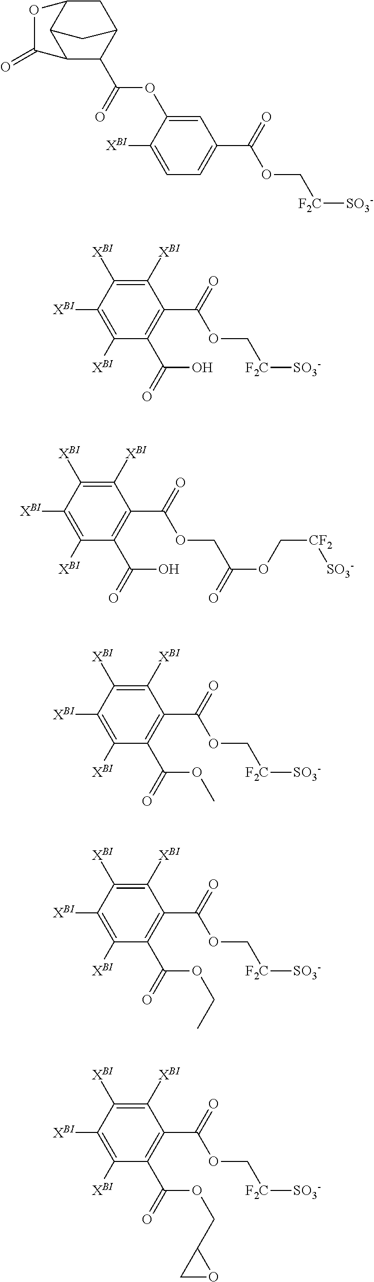

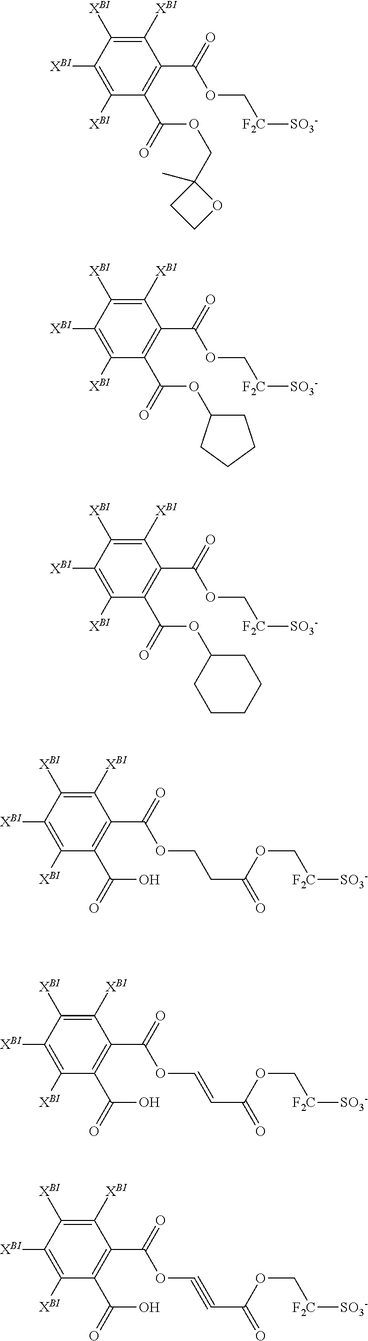

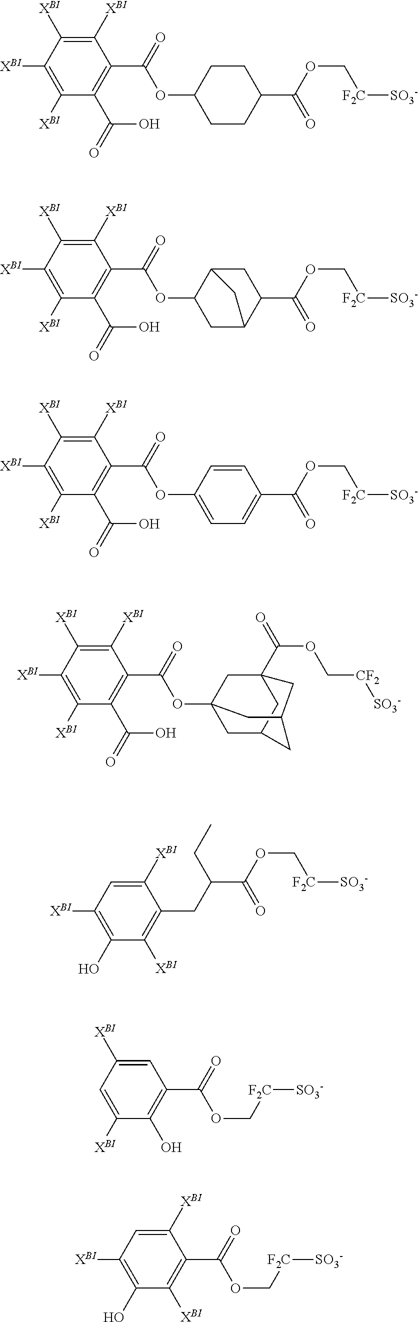

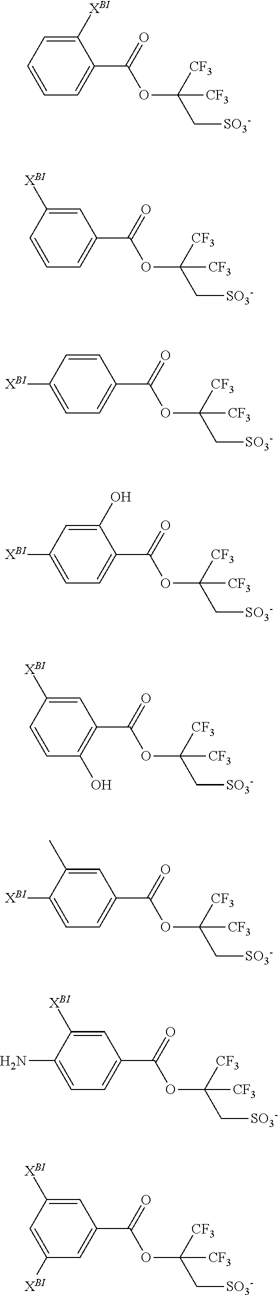

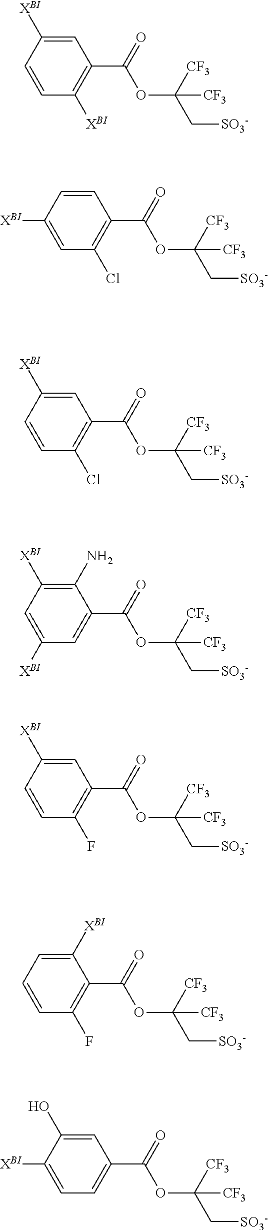

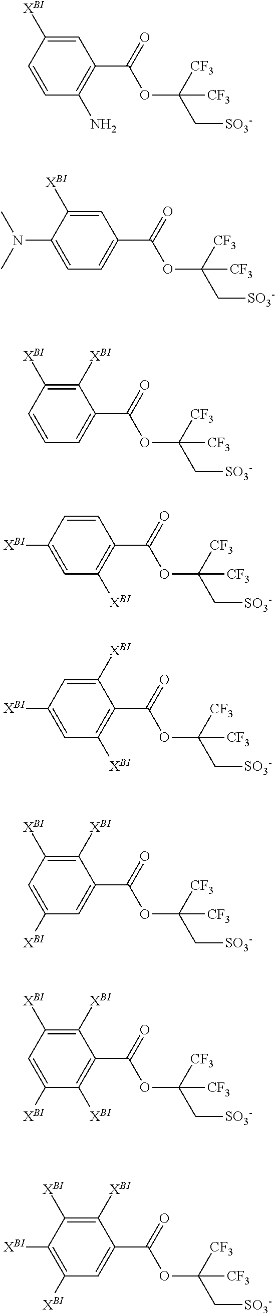

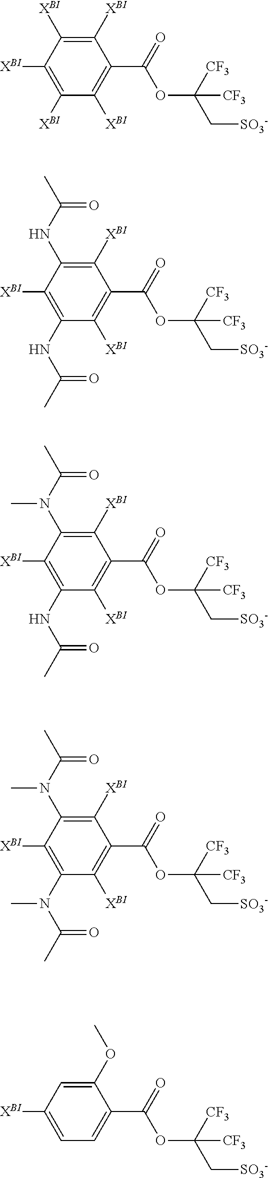

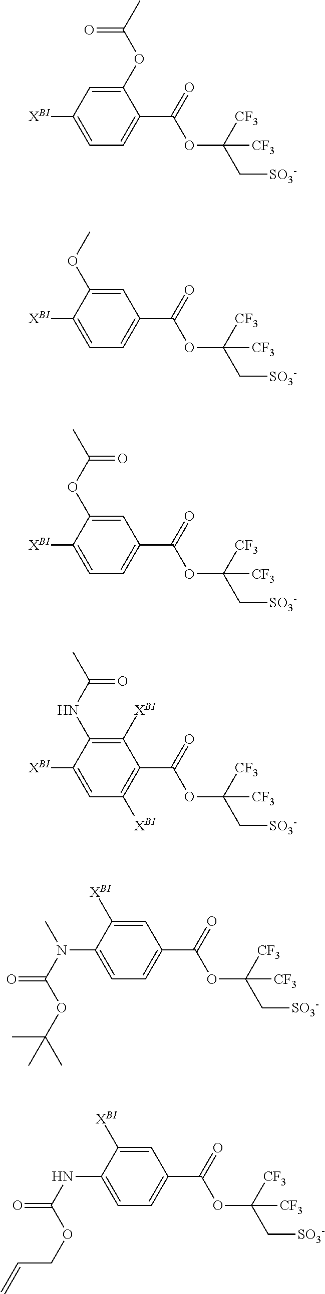

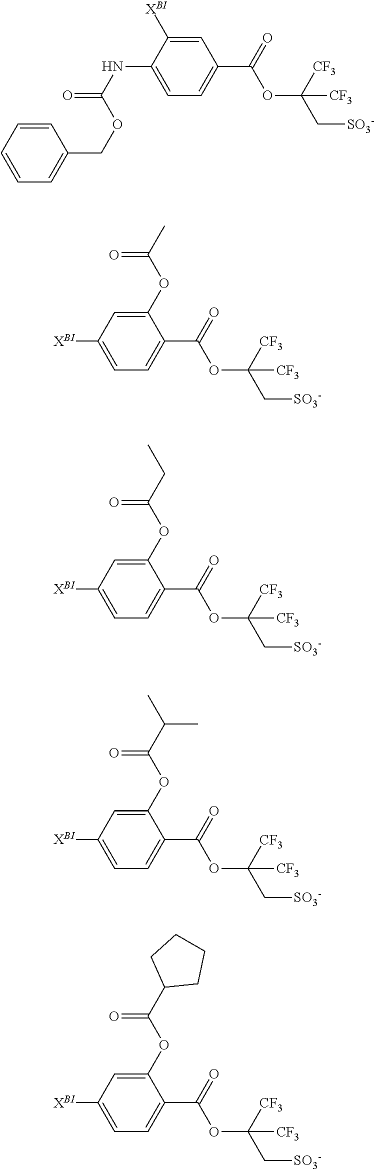

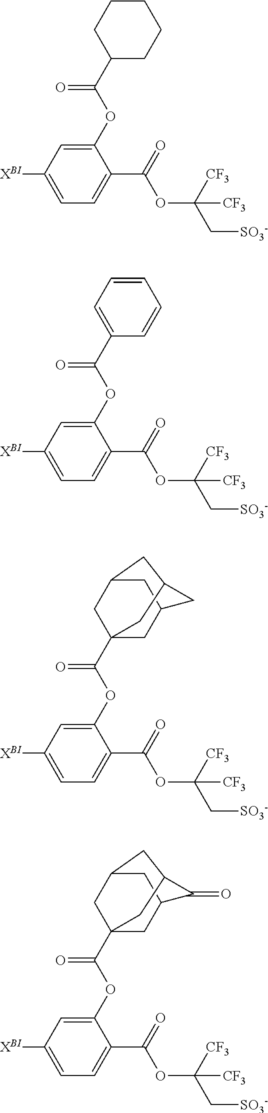

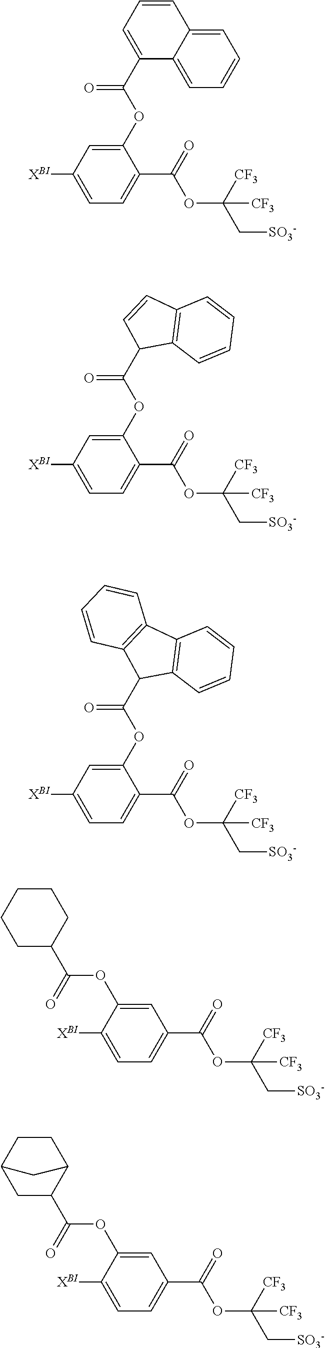

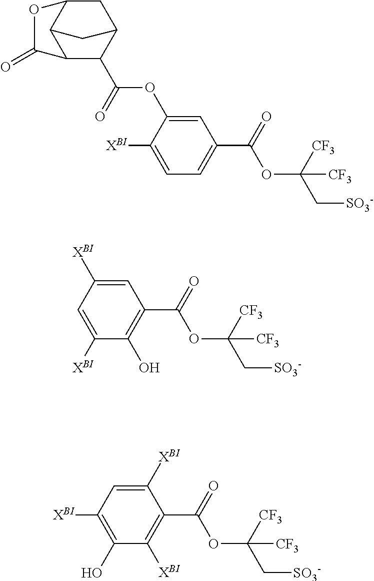

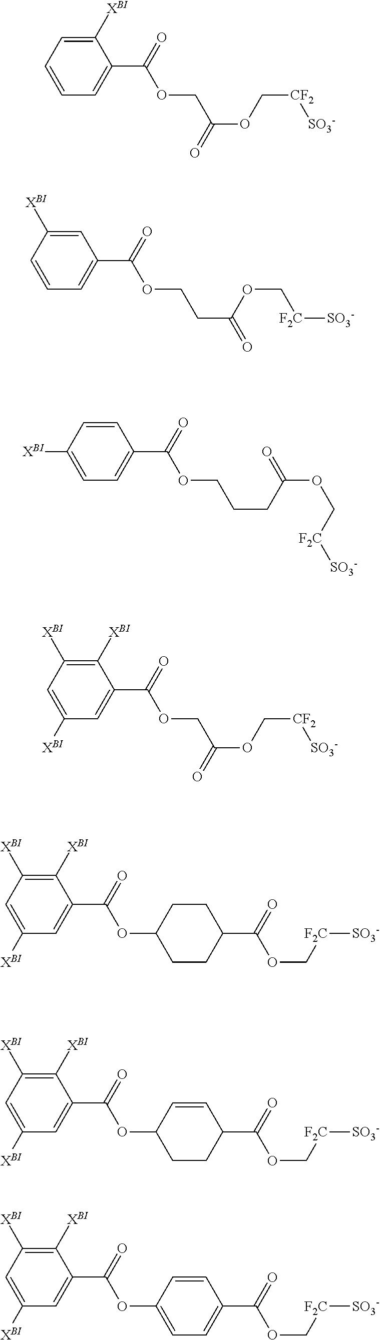

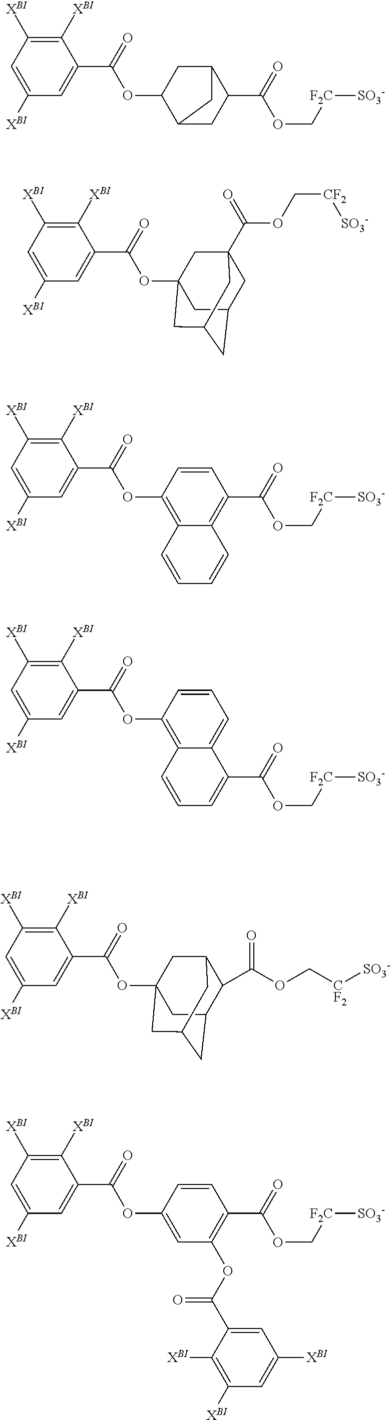

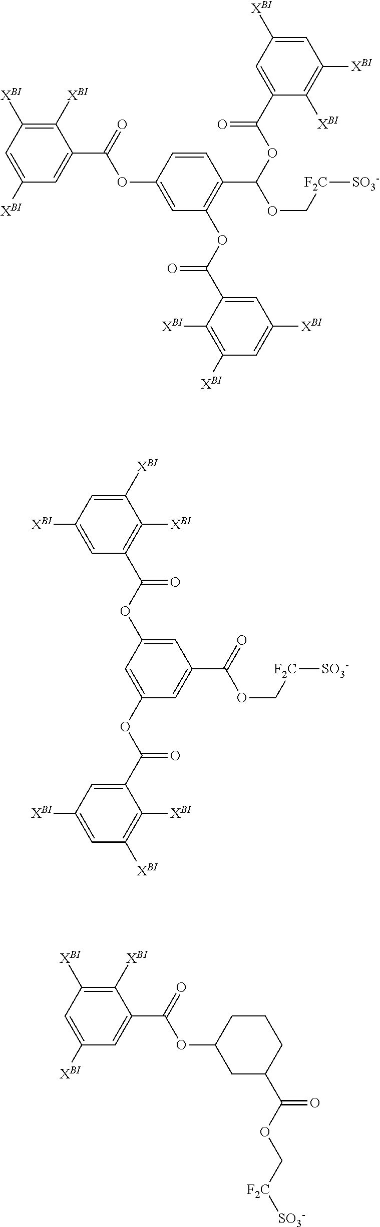

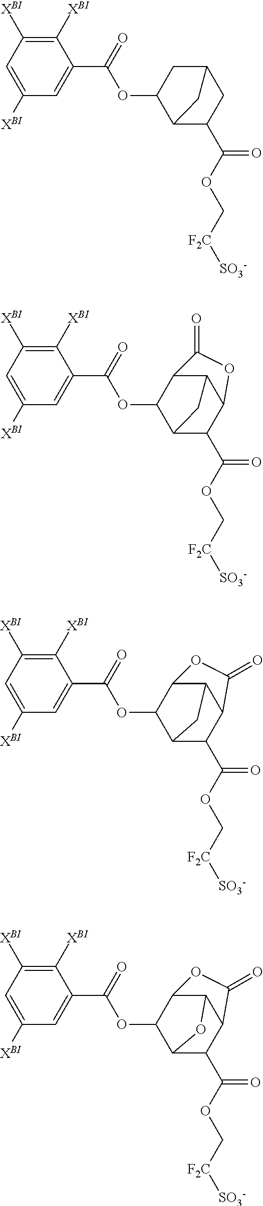

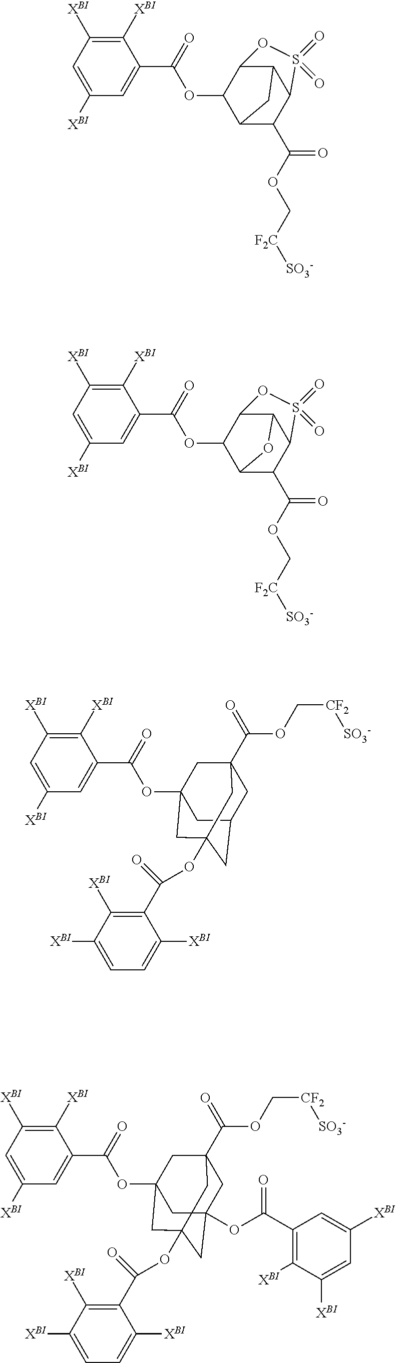

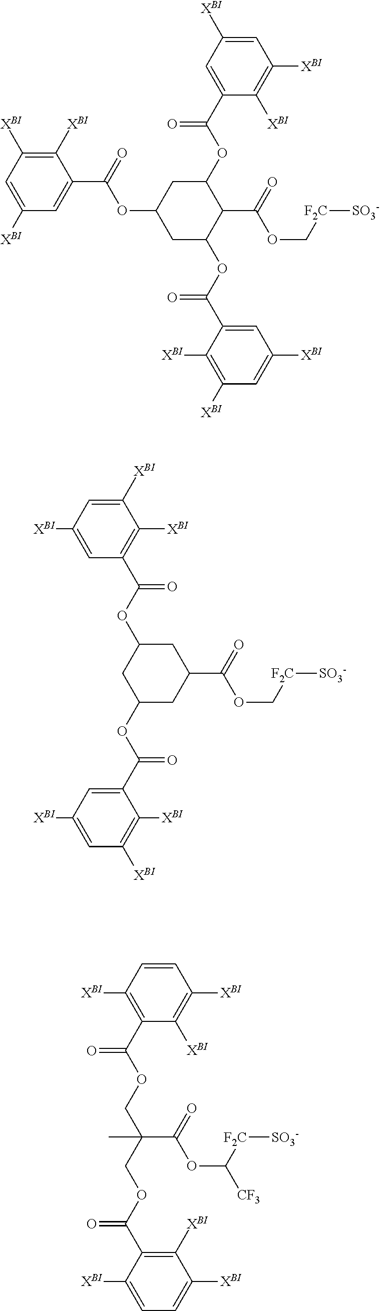

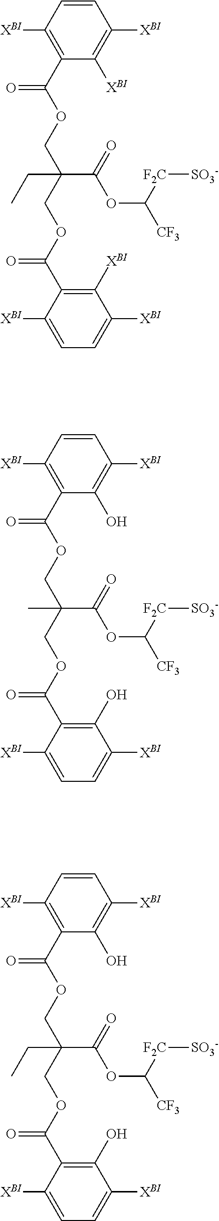

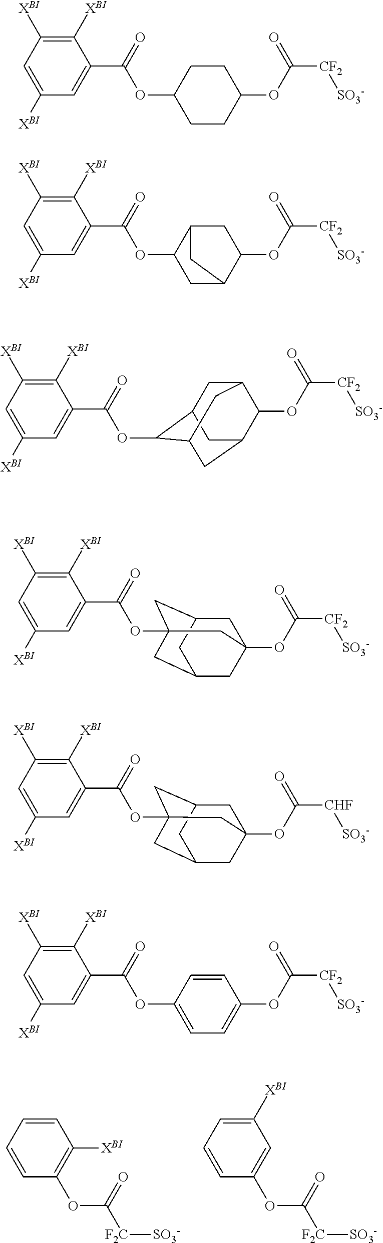

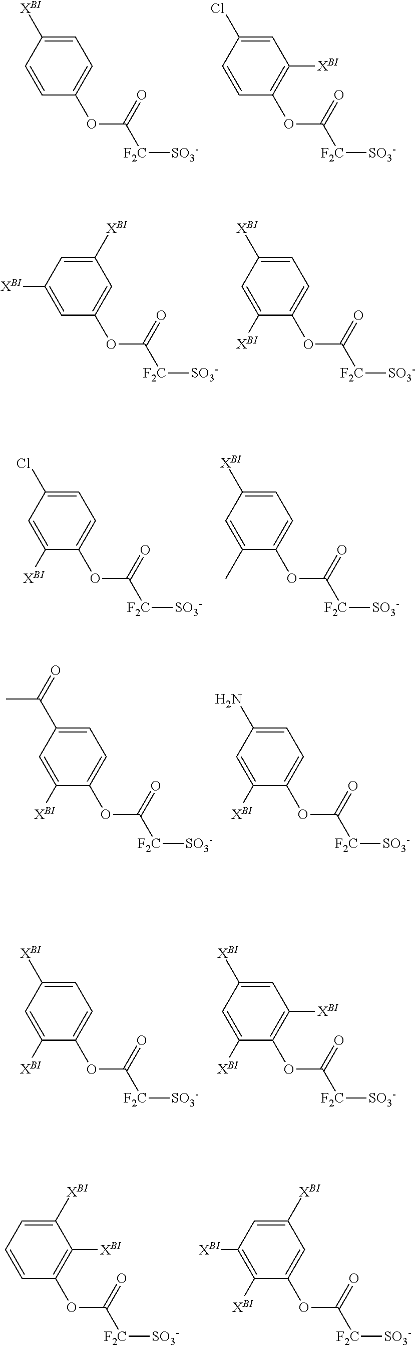

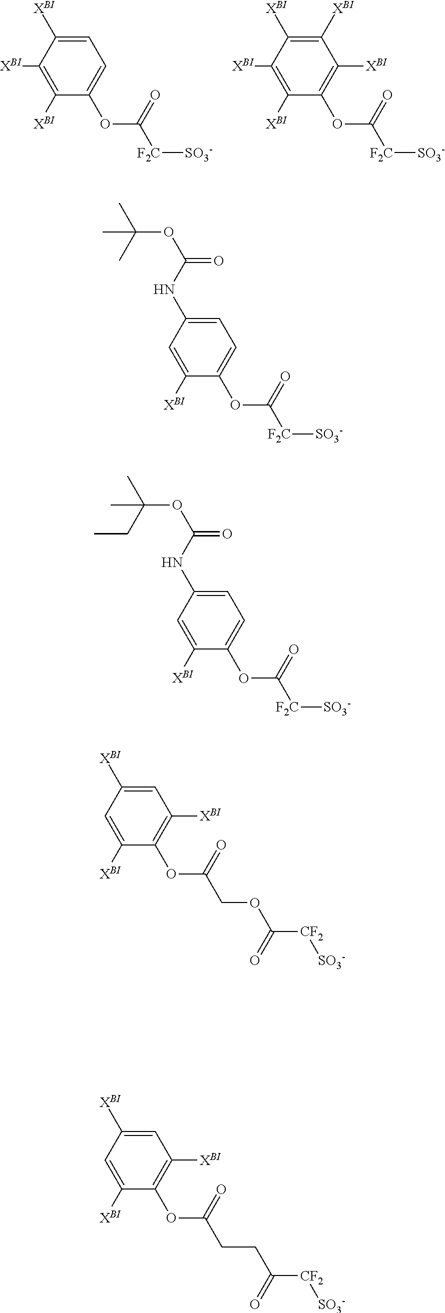

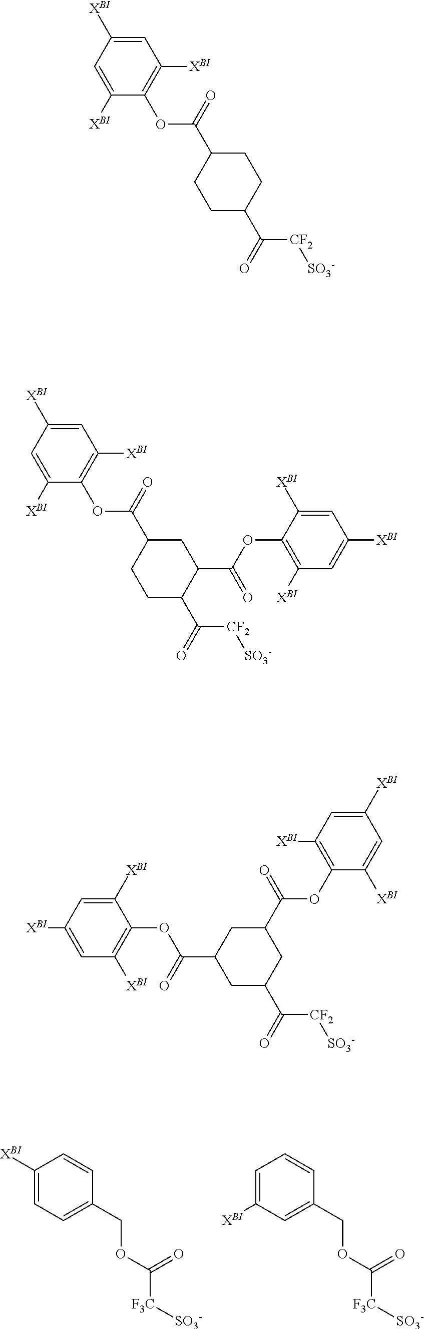

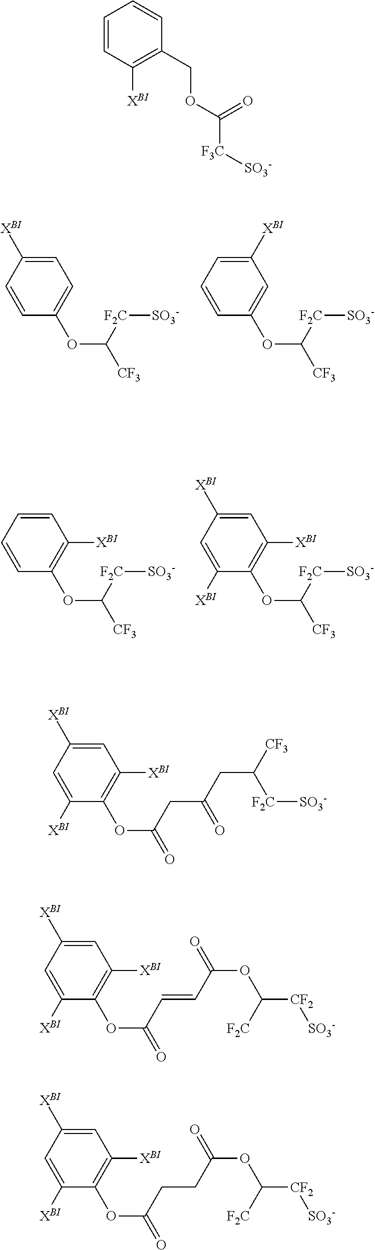

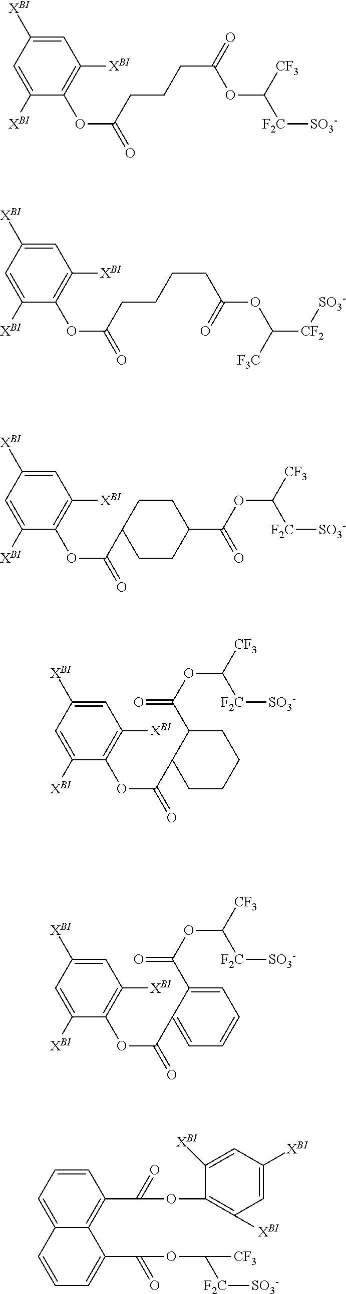

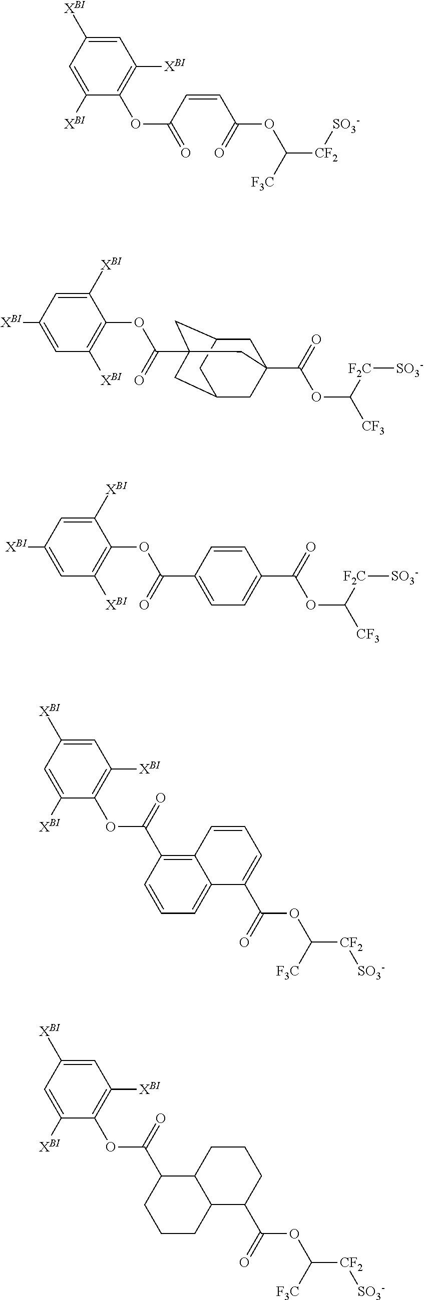

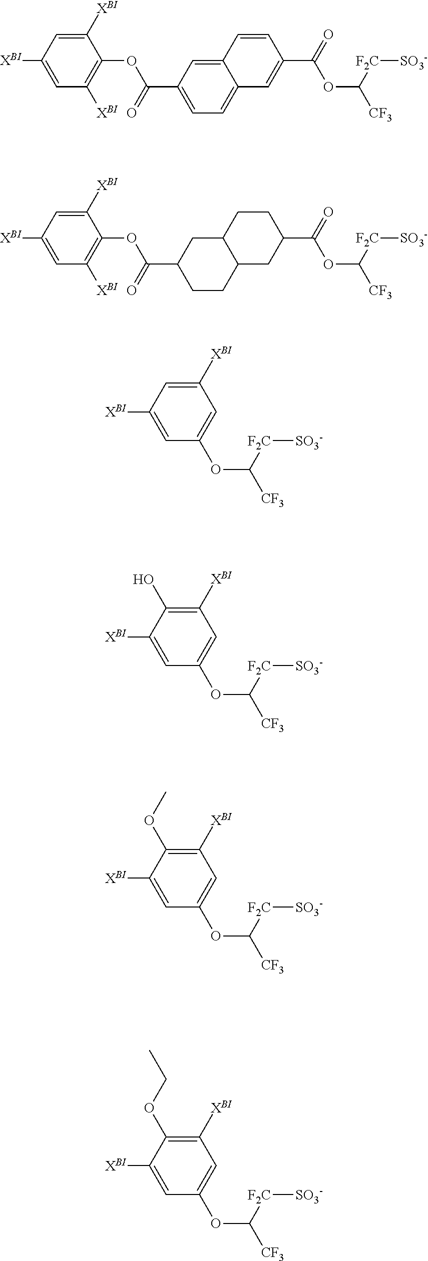

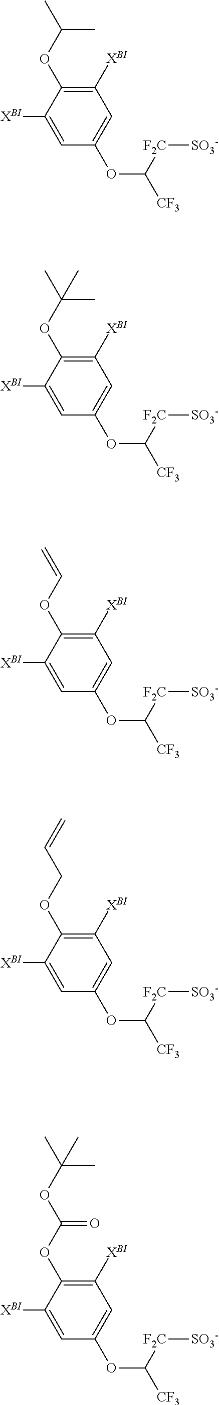

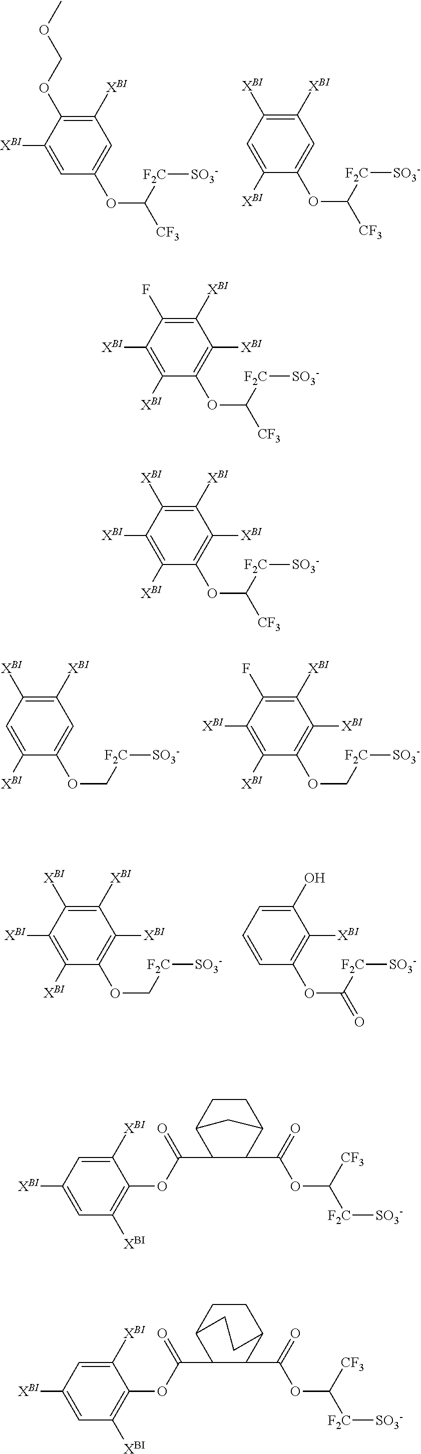

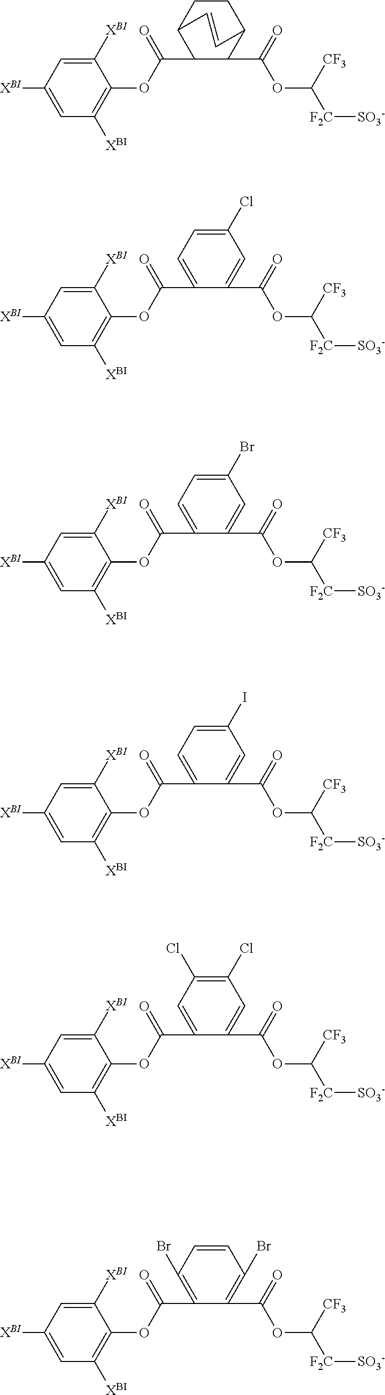

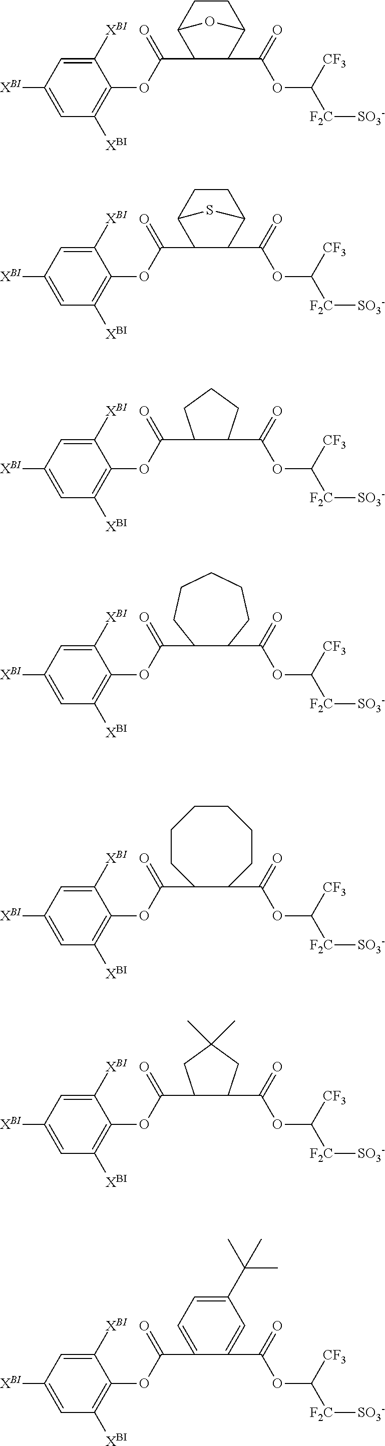

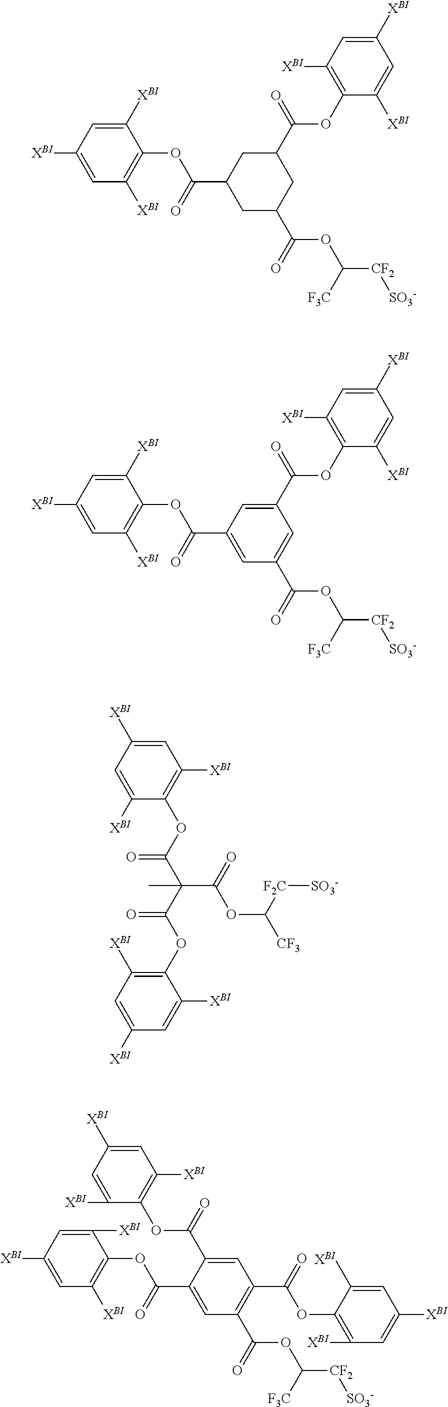

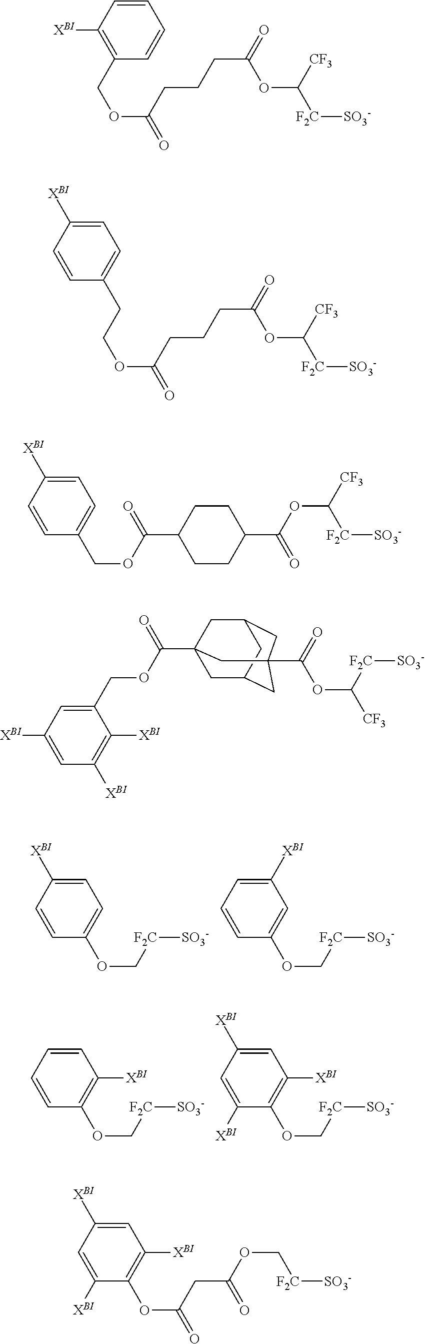

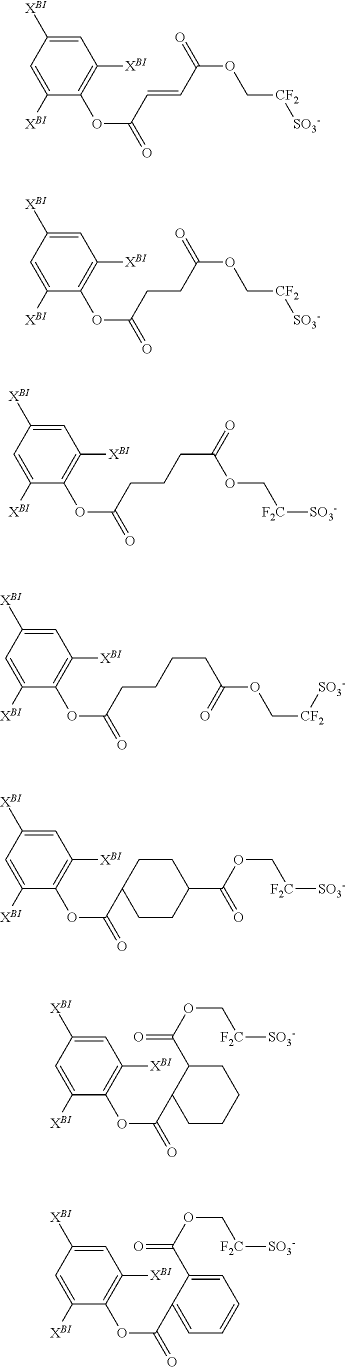

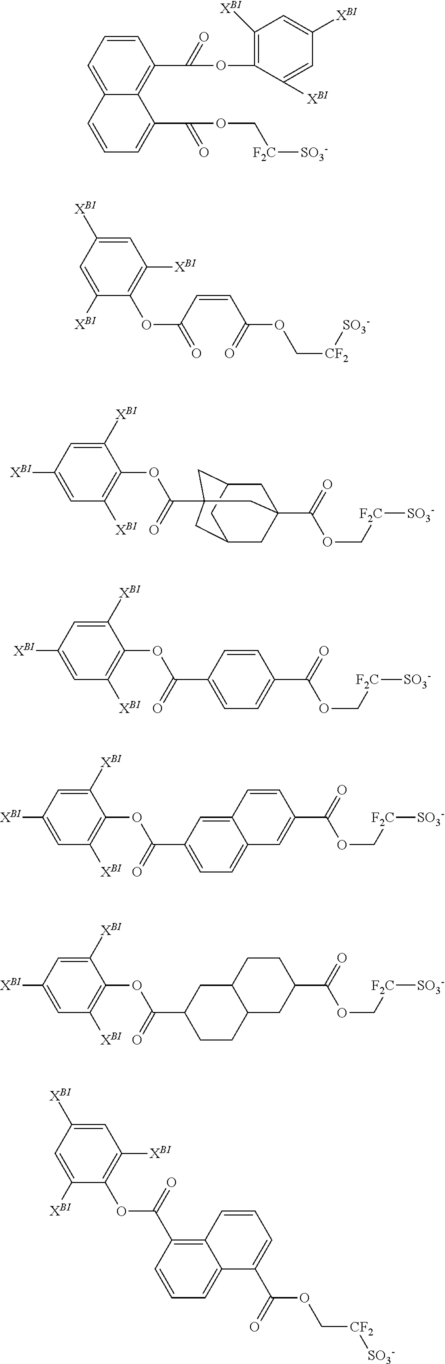

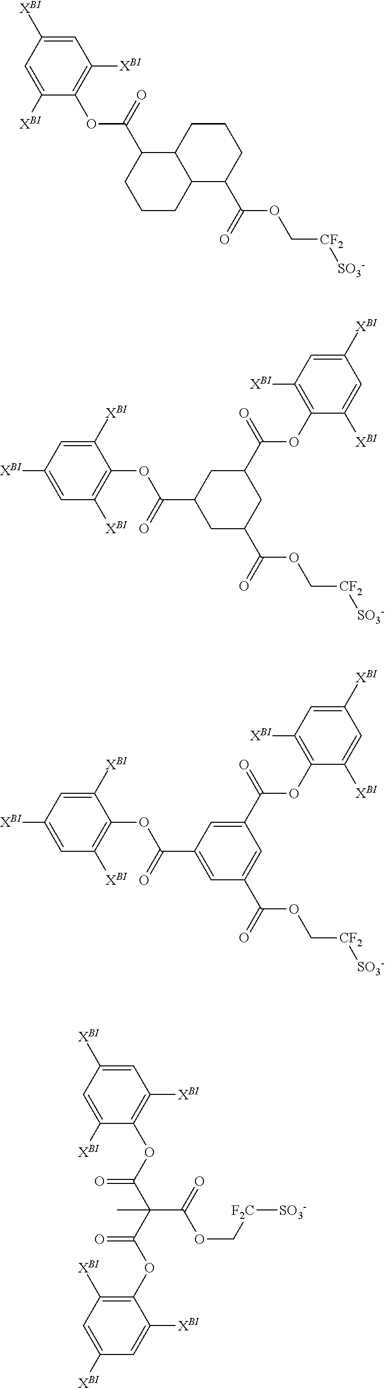

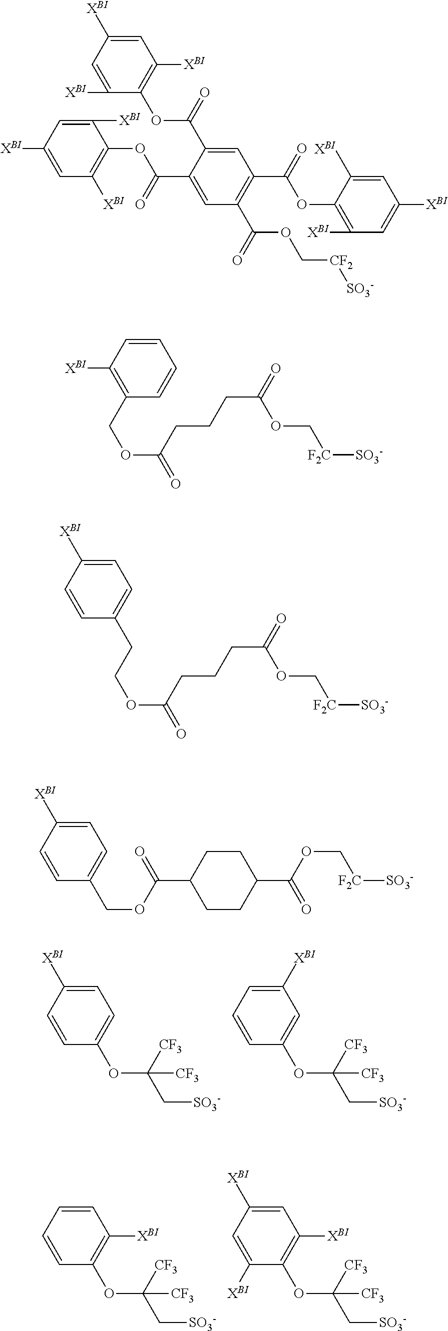

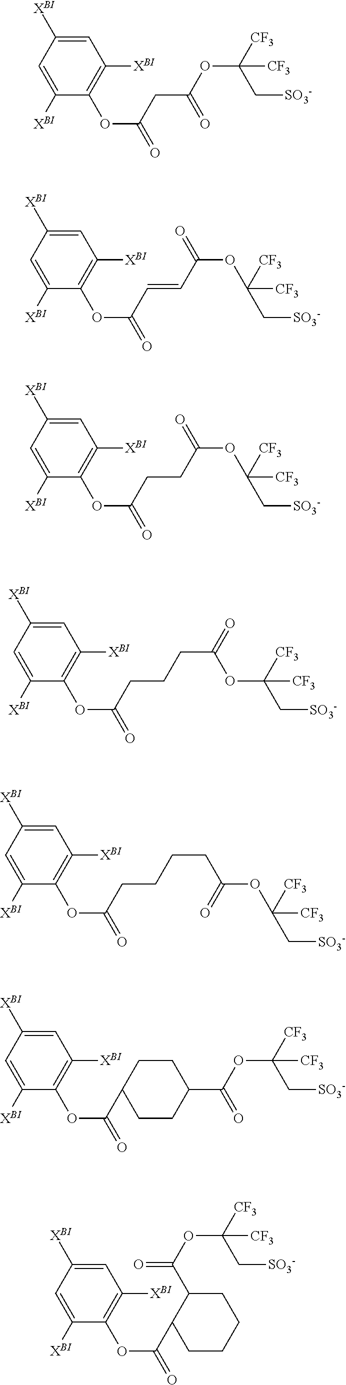

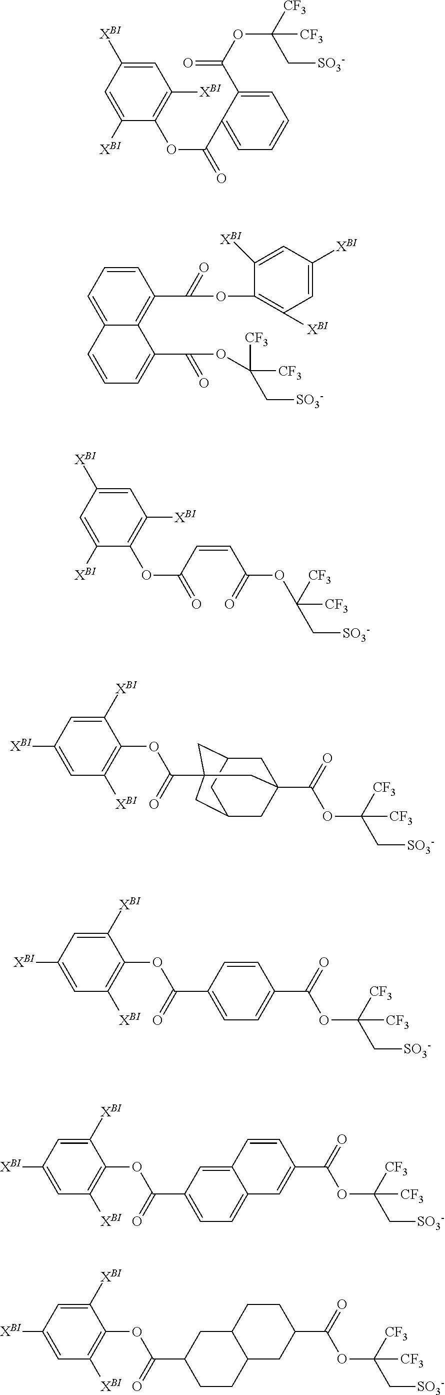

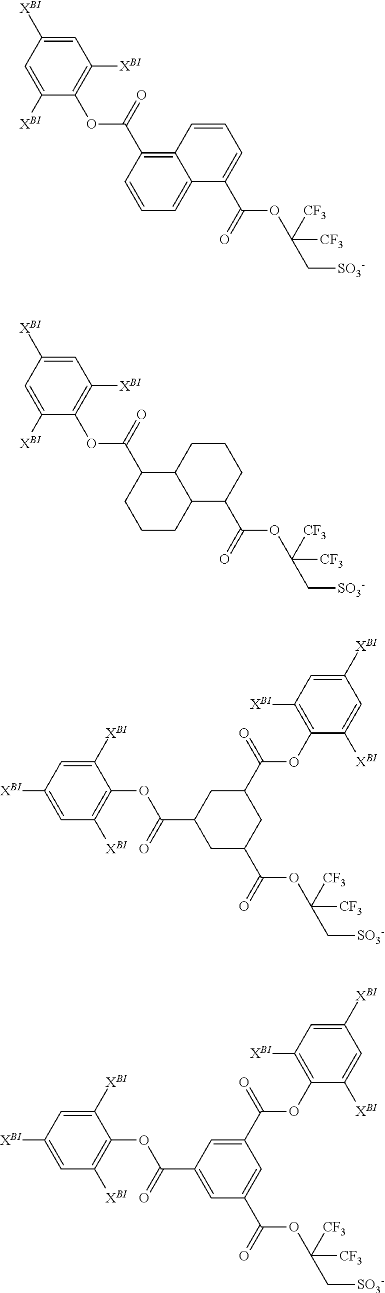

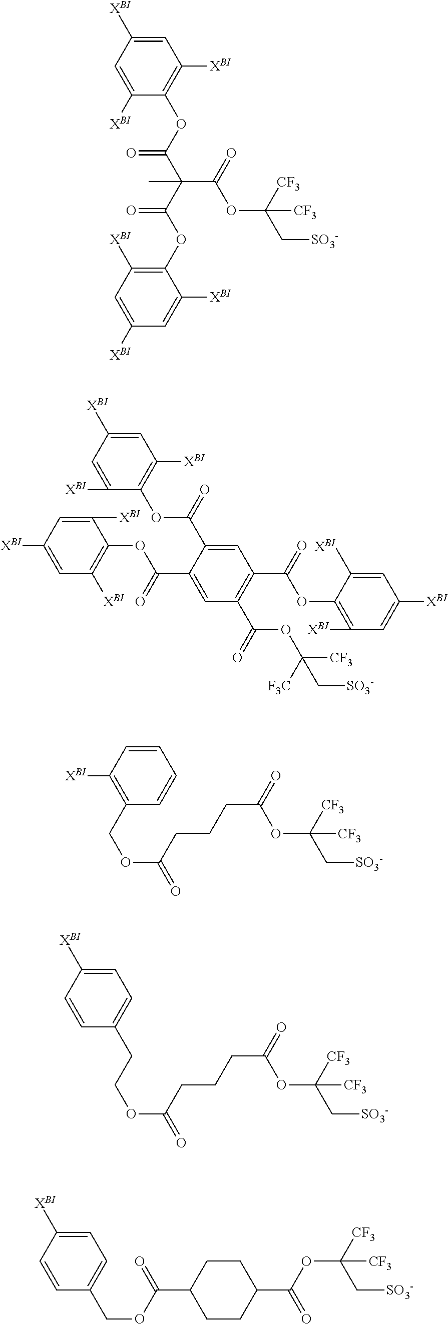

The acid generator of addition type is preferably added to the positive resist composition of the present invention in an amount of 0.1 to 50 parts by weight, and more preferably 1 to 40 parts by weight per 100 parts by weight of the base polymer. The acid generator of addition type may be used singly or in combination of two or more kinds thereof. The positive resist composition of the present invention can function as a chemically amplified positive resist composition when the base polymer contains any of the repeat units (d1) to (d3) and/or the positive resist composition contains an acid generator of addition type.

### [Organic Solvent]

The positive resist composition of the present invention may contain an organic solvent. The organic solvent is not particularly limited as long as the components described above and below are soluble therein. Examples of the organic solvent are described in paragraphs to of JP-A 2008-111103, and include ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone.

The organic solvent is preferably added to the positive resist composition of the present invention in an amount of 100 to 10,000 parts by weight, and more preferably 200 to 8,000 parts by weight per 100 parts by weight of the base polymer. The organic solvent may be used singly or as a mixture of two or more kinds thereof.

### [Other Components]

In addition to the foregoing components, the positive resist composition of the present invention may contain a surfactant, a dissolution inhibitor, a quencher, a water repellency improver, and an acetylene alcohol.

Examples of the surfactant include those described in paragraphs to of JP-A 2008-111103. Addition of a surfactant enables to improve or control the coating characteristics of the resist composition. The surfactant is preferably added to the positive resist composition of the present invention in an amount of 0.0001 to 10 parts by weight per 100 parts by weight of the base polymer. The surfactant may be used singly or in combination of two or more kinds thereof.

The addition of a dissolution inhibitor to the positive resist composition of the present invention may lead to an increased difference in dissolution rate between the exposed region and the unexposed region and a further improvement in resolution. Examples of the dissolution inhibitor include a compound having at least two phenolic hydroxy groups in the molecule, in which 0 to 100 mol % of all the hydrogen atoms in the phenolic hydroxy groups are substituted with acid labile groups, or a compound having at least one carboxy group in the molecule, in which an average of 50 to 100 mol % of all the hydrogen atoms in the carboxy group are substituted with acid labile groups, both the compounds preferably having a molecular weight of 100 to 1,000, and more preferably 150 to 800. Specific examples thereof include bisphenol A, trisphenol, phenolphthalein, cresol novolac, naphthalenecarboxylic acid, adamantanecarboxylic acid, and cholic acid derivatives, in which the hydrogen atom in the hydroxy or carboxy group is substituted with an acid labile group, as described in paragraphs to of JP-A 2008-122932.

The dissolution inhibitor is preferably added to the positive resist composition of the present invention in an amount of 0 to 50 parts by weight, and more preferably 5 to 40 parts by weight per 100 parts by weight of the base polymer. The dissolution inhibitor may be used singly or in combination of two or more kinds thereof.

A quencher (hereinafter, the quencher is referred to as quencher of addition type) may be blended in the resist composition of the present invention. Examples of the quencher of addition type include conventional basic compounds. Examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, imide derivatives, and carbamate derivatives. In particular, primary, secondary, and tertiary amine compounds described in paragraphs to of JP-A 2008-111103, particularly amine compounds having a hydroxy group, an ether bond, an ester bond, a lactone ring, a cyano group, or a sulfonic ester bond, and compounds having a carbamate group described in JP 3790649 are preferred. Addition of a basic compound may be effective for further reducing the diffusion rate of the acid in the resist film or correcting the pattern profile.

Examples of the quencher of addition type also include onium salts such as sulfonium salts, iodonium salts, and ammonium salts of sulfonic acids which are not fluorinated at the α-position, or carboxylic acids, as described in JP-A 2008-158339. While a sulfonic acid which is fluorinated at the α-position, an imide acid, or a methide acid is necessary for deprotecting the acid labile group of a carboxylic acid ester, an α-non-fluorinated sulfonic acid or a carboxylic acid is released by salt exchange with an α-non-fluorinated onium salt. The α-non-fluorinated sulfonic acid and carboxylic acid function as a quencher because they do not induce a deprotection reaction.

Examples of the quencher of addition type further include a polymeric quencher described in JP-A 2008-239918. The polymeric quencher segregates at the resist surface after coating and thus enhances the rectangularity of the patterned resist. When a protective film is applied as is often the case in immersion lithography, the polymeric quencher is also effective for preventing a film thickness loss of the resist pattern or rounding of the pattern top.

The quencher of addition type is preferably added to the positive resist composition of the present invention in an amount of 0 to 5 parts by weight, and more preferably 0 to 4 parts by weight per 100 parts by weight of the base polymer. The quencher of addition type may be used singly or in combination of two or more kinds thereof.

The water repellency improver improves the water repellency of the surface of the resist film, and can be used in the topcoatless immersion lithography. Examples of preferred water repellency improvers include polymers having a fluoroalkyl group and polymers having a specific structure with a 1,1,1,3,3,3-hexafluoro-2-propanol residue, and those described in JP-A 2007-297590 and JP-A 2008-111103, for example, are more preferred. The water repellency improver should be soluble in alkaline developers and organic solvent developers. The water repellency improver having a specific structure with a 1,1,1,3,3,3-hexafluoro-2-propanol residue is well soluble in the developer. A polymer having an amino group or amine salt copolymerized as repeat units may serve as the water repellency improver and is effective for preventing evaporation of the acid during PEB, thus preventing any hole pattern opening failure after development. The water repellency improver is preferably added to the positive resist composition of the present invention in an amount of 0 to 20 parts by weight, and more preferably 0.5 to 10 parts by weight per 100 parts by weight of the base polymer. The water repellency improver may be used singly or in combination of two or more kinds thereof.

Examples of the acetylene alcohol include those described in paragraphs to of JP-A 2008-122932. The acetylene alcohol is preferably added to the positive resist composition of the present invention in an amount of 0 to 5 parts by weight per 100 parts by weight of the base polymer. The acetylene alcohol may be used singly or in combination of two or more kinds thereof.

### [Pattern Forming Process]

The positive resist composition of the present invention is used in the fabrication of various integrated circuits by a well-known lithography technique. Examples of the pattern forming process include a process including the steps of: applying the positive resist composition onto a substrate to form a resist film on the substrate, exposing the resist film to high-energy radiation, and developing the exposed resist film in a developer.

The positive resist composition of the present invention is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying, or doctor coating so that the coating may have a thickness of 0.01 to 2 μm. The coating is prebaked on a hotplate preferably at a temperature of 60 to 150° C. for 10 seconds to 30 minutes, and more preferably at 80 to 120° C. for 30 seconds to 20 minutes to form a resist film.

The resist film is then exposed to high-energy radiation such as UV, deep-UV, EB, EUV having a wavelength of 3 to 15 nm, X-rays, soft X-rays, excimer laser, γ-rays, or synchrotron radiation. When UV, deep-UV, EUV, X-rays, soft X-rays, excimer laser, γ-rays, or synchrotron radiation is used as the high-energy radiation, the resist film is exposed thereto directly or through a mask having a desired pattern preferably at a dose of about 1 to 200 mJ/cm², and more preferably about 10 to 100 mJ/cm². When EB is used as the high-energy radiation, the resist film is exposed thereto directly or through a mask having a desired pattern preferably at a dose of about 0.1 to 100 μC/cm², and more preferably about 0.5 to 50 μC/cm². It is appreciated that the positive resist composition of the present invention is suitable for micropatterning using high-energy radiation such as i-line having a wavelength of 365 nm, KrF excimer laser, ArF excimer laser, EB, EUV, X-rays, soft X-rays, γ-rays, or synchrotron radiation, especially for micropatterning using EB or EUV.

After the exposure, the resist film may be baked (PEB) on a hotplate or in an oven preferably at 50 to 150° C. for 10 seconds to 30 minutes, and more preferably at 60 to 120° C. for 30 seconds to 20 minutes.

After the exposure or PEB, the resist film is developed in a developer in the form of an alkaline aqueous solution for 3 seconds to 3 minutes, preferably 5 seconds to 2 minutes by conventional techniques such as dip, puddle, and spray techniques. In this way, the resist film in the exposed region is dissolved in the developer whereas the resist film in the unexposed region is not dissolved to form a desired positive pattern on the substrate. A preferred developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH).

A negative pattern can be obtained from the positive resist composition by effecting organic solvent development. Examples of the developer used herein include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. The organic solvent may be used singly or as a mixture of two or more kinds thereof.

At the end of development, the resist film is rinsed. The rinsing liquid is preferably a solvent which is miscible with the developer and does not dissolve the resist film. Examples of preferred solvents include alcohols having 3 to 10 carbon atoms, ether compounds having 8 to 12 carbon atoms, alkanes, alkenes, and alkynes each having 6 to 12 carbon atoms, and aromatic solvents.

Examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the alkenes having 6 to 12 carbon atoms include hexene, heptene, octene, cyclohexene, methylcyclohexene, dimethylcyclohexene, cycloheptene, and cyclooctene. Examples of the alkynes having 6 to 12 carbon atoms include hexyne, heptyne, and octyne.

Examples of the aromatic solvents include toluene, xylene, ethylbenzene, isopropylbenzene, tert-butylbenzene, and mesitylene.

Rinsing is effective for reducing the resist pattern collapse and defect formation. However, rinsing is not essential. If rinsing is omitted, the amount of solvent used may be reduced.

A hole or trench pattern after development may be shrunk by the thermal flow, RELACS®, or DSA process. A hole pattern is shrunk by applying a shrink agent thereto, and baking the resist composition such that the shrink agent may undergo crosslinking at the resist film surface due to diffusion of the acid catalyst from the resist film during baking, and the shrink agent may attach to the sidewall of the hole pattern. The baking temperature is preferably 70 to 180° C., more preferably 80 to 170° C., and the baking time is preferably 10 to 300 seconds to remove the excess shrink agent and shrink the hole pattern.

### EXAMPLES

Hereinafter, the present invention is specifically described with reference to Synthesis Examples, Examples, and Comparative Examples, but the present invention is not limited to the following Examples.

### [1] Synthesis of Monomers

### Synthesis Examples 1-1 to 1-12 and Comparative Synthesis Example 1-1

Monomers M-1 to M-12 and Comparative Monomer cM-1 shown below were synthesized by ion exchange between a sulfonium salt chloride and trihydrocarbylsulfonylmethide acid free of a fluorine atom on a carbon atom at an α-position of a sulfonyl group and having a polymerizable double bond.

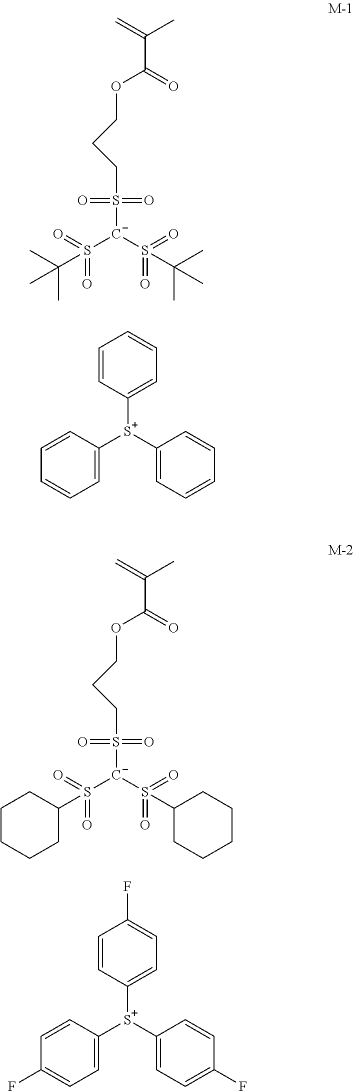 [SMILES: C=C(C)C(=O)OCCCS(=O)(=O)[C-](S(=O)(=O)C(C)(C)C)S(=O)(=O)C(C)(C)C ; c1ccc([S+](c2ccccc2)c2ccccc2)cc1 ; C=C(C)C(=O)OCCCS(=O)(=O)[C-](S(=O)(=O)C1CCCCC1)S(=O)(=O)C1CCCCC1 ; Fc1ccc([S+](c2ccc(F)cc2)c2ccc(F)cc2)cc1]

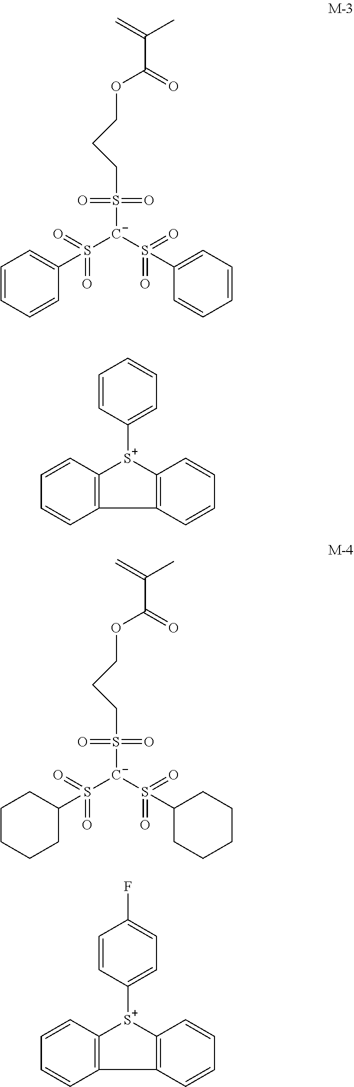 [SMILES: C=C(C)C(=O)OCCCS(=O)(=O)[C-](S(=O)(=O)c1ccccc1)S(=O)(=O)c1ccccc1 ; c1ccc(-[s+]2c3ccccc3c3ccccc32)cc1 ; C=C(C)C(=O)OCCCS(=O)(=O)[C-](S(=O)(=O)C1CCCCC1)S(=O)(=O)C1CCCCC1 ; Fc1ccc(-[s+]2c3ccccc3c3ccccc32)cc1]

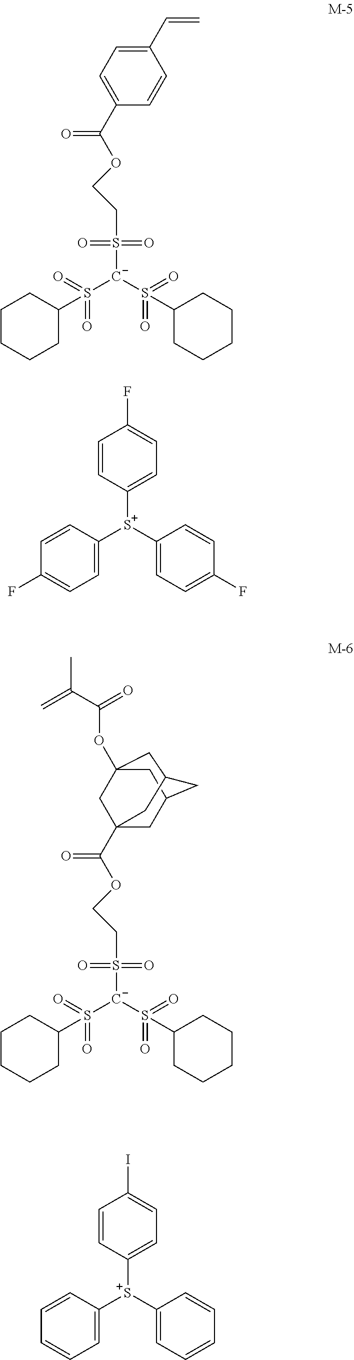 [SMILES: C=Cc1ccc(C(=O)OCCS(=O)(=O)[C-](S(=O)(=O)C2CCCCC2)S(=O)(=O)C2CCCCC2)cc1 ; Fc1ccc([S+](c2ccc(F)cc2)c2ccc(F)cc2)cc1 ; C=C(C)C(=O)OC12CC3CC(C1)CC(C(=O)OCCS(=O)(=O)[C-](S(=O)(=O)C1CCCCC1)S(=O)(=O)C1CCCCC1)(C3)C2 ; Ic1ccc([S+](c2ccccc2)c2ccccc2)cc1]

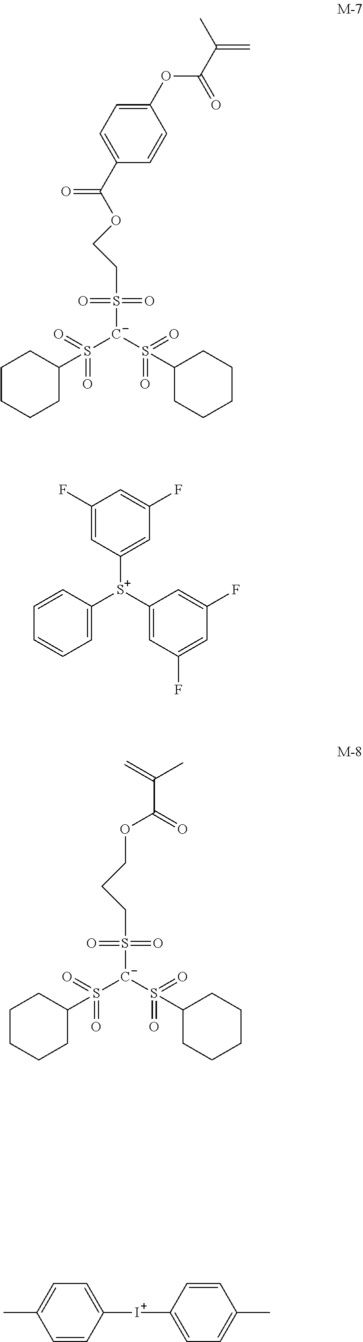

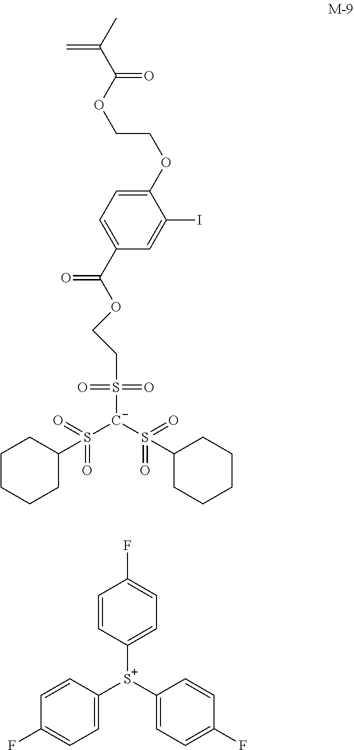 [SMILES: C=C(C)C(=O)OCCOc1ccc(C(=O)OCCS(=O)(=O)[C-](S(=O)(=O)C2CCCCC2)S(=O)(=O)C2CCCCC2)cc1I ; Fc1ccc([S+](c2ccc(F)cc2)c2ccc(F)cc2)cc1]

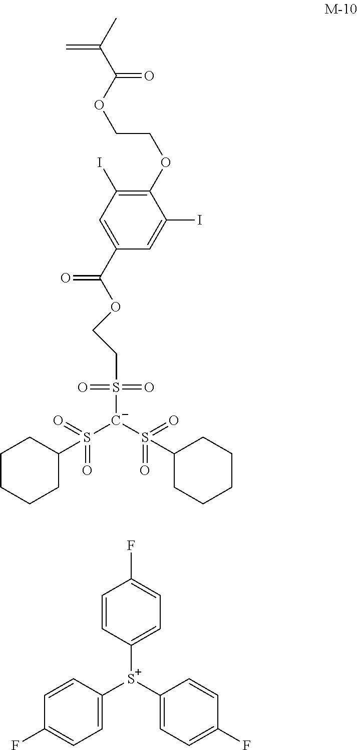 [SMILES: C=C(C)C(=O)OCCOc1c(I)cc(C(=O)OCCS(=O)(=O)[C-](S(=O)(=O)C2CCCCC2)S(=O)(=O)C2CCCCC2)cc1I ; Fc1ccc([S+](c2ccc(F)cc2)c2ccc(F)cc2)cc1]

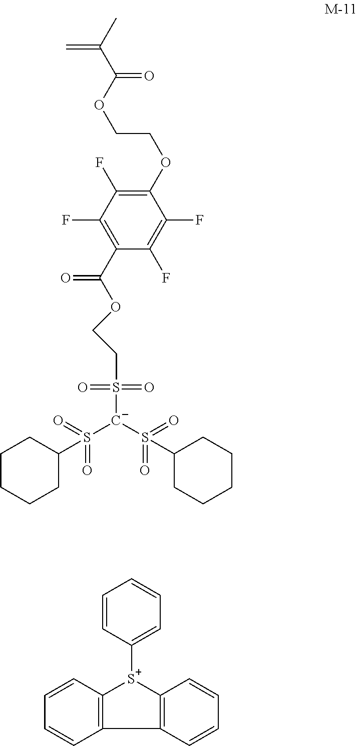 [SMILES: C=C(C)C(=O)OCCOc1c(F)c(F)c(C(=O)OCCS(=O)(=O)[C-](S(=O)(=O)C2CCCCC2)S(=O)(=O)C2CCCCC2)c(F)c1F ; c1ccc(-[s+]2c3ccccc3c3ccccc32)cc1]

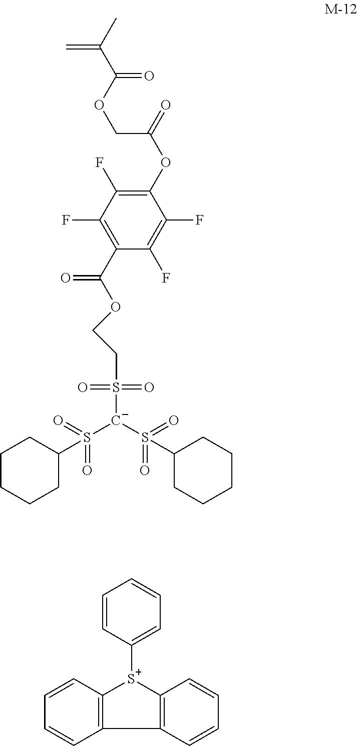 [SMILES: C=C(C)C(=O)OCC(=O)Oc1c(F)c(F)c(C(=O)OCCS(=O)(=O)[C-](S(=O)(=O)C2CCCCC2)S(=O)(=O)C2CCCCC2)c(F)c1F ; c1ccc(-[s+]2c3ccccc3c3ccccc32)cc1]

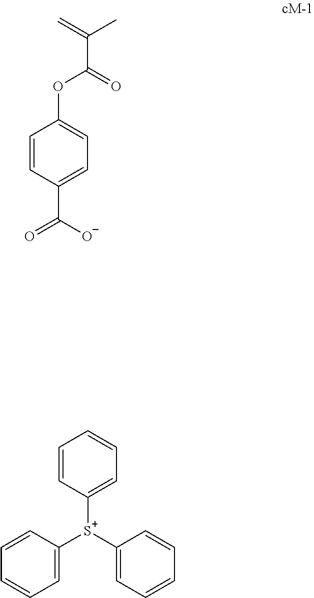 [SMILES: C=C(C)C(=O)Oc1ccc(C(=O)[O-])cc1 ; c1ccc([S+](c2ccccc2)c2ccccc2)cc1]

### [2] Synthesis of Polymers

Monomer AM-1 and Monomers PM-1 to PM-6 used in the synthesis of polymers are shown below. The Mw of a polymer is determined by GPC versus polystyrene standards using a THF solvent.

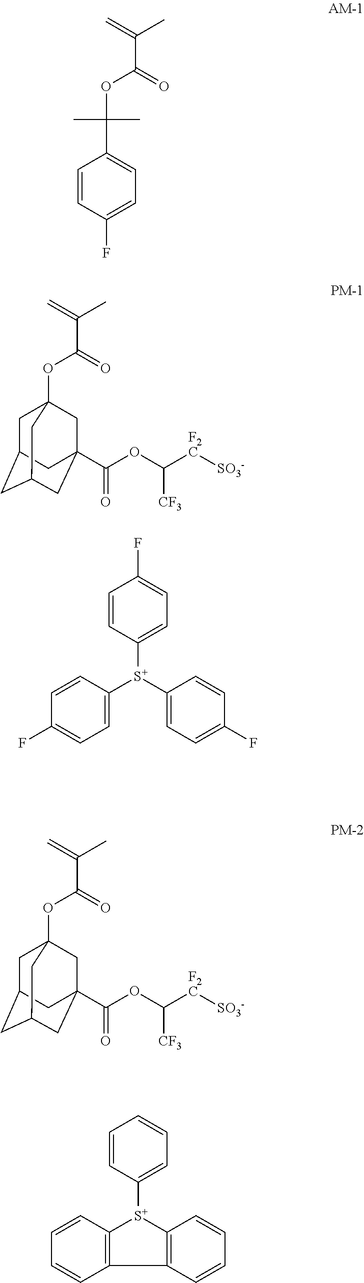

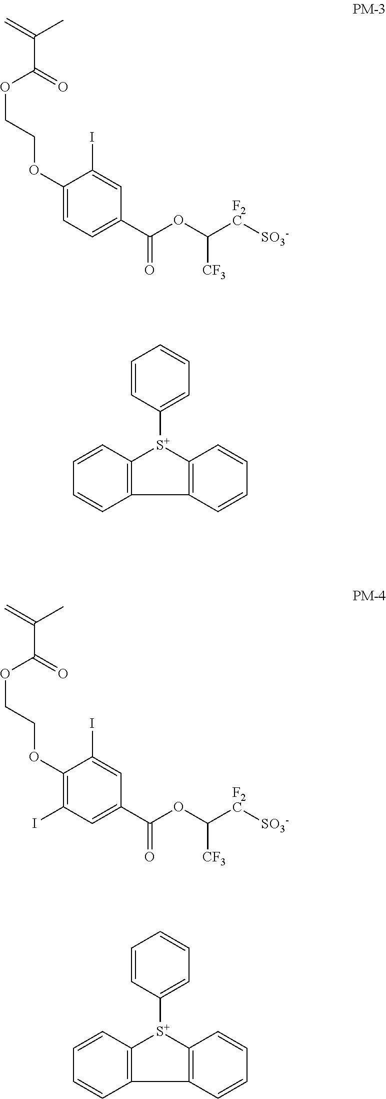

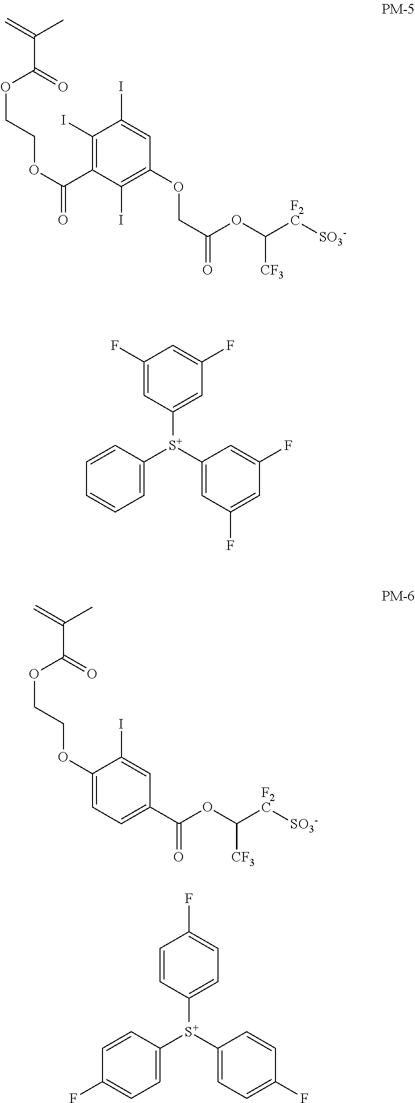

### [Synthesis Example 2-1] Synthesis of Polymer P-1

A 2-L flask was charged with 3.5 g of Monomer M-1, 8.4 g of 1-methyl-1-cyclopentyl methacrylate, 5.4 g of 4-hydroxystyrene, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of isopropyl alcohol (IPA), and the precipitated white solid was collected by filtration. The resulting white solid was vacuum dried at 60° C., yielding Polymer P-1. Polymer P-1 was analyzed for composition by ¹³C-NMR and ¹H-NMR and for Mw and Mw/Mn by GPC.

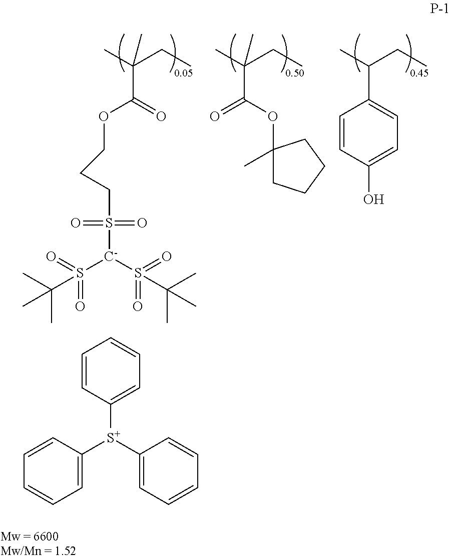

### [Synthesis Example 2-2] Synthesis of Polymer P-2

A 2-L flask was charged with 4.1 g of Monomer M-2, 7.3 g of 1-methyl-1-cyclohexyl methacrylate, 4.8 g of 4-hydroxystyrene, 11.0 g of Monomer PM-2, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-2. Polymer P-2 was analyzed for composition by ¹³C-NMR and ¹H-NMR and for Mw and Mw/Mn by GPC.

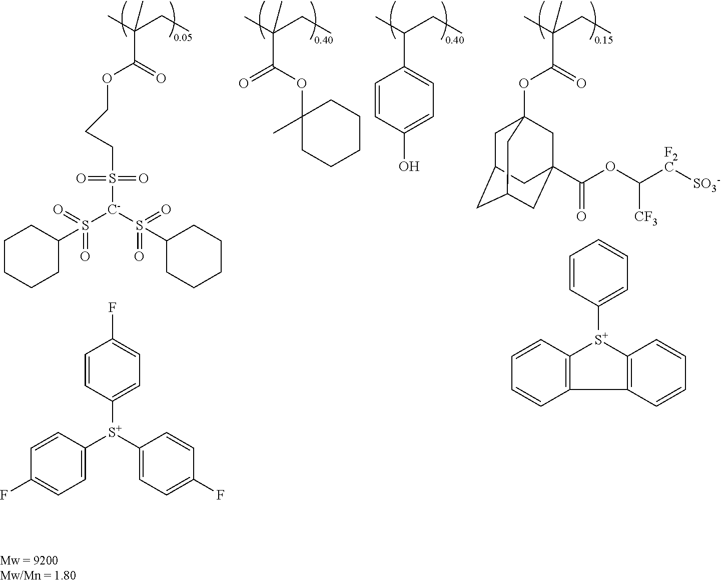

### [Synthesis Example 2-3] Synthesis of Polymer P-3

A 2-L flask was charged with 3.7 g of Monomer M-3, 8.4 g of 1-methyl-1-cyclopentyl methacrylate, 3.6 g of 4-hydroxystyrene, 11.9 g of Monomer PM-1, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-3. Polymer P-3 was analyzed for composition by ¹³C-NMR and ¹H-NMR and for Mw and Mw/Mn by GPC.

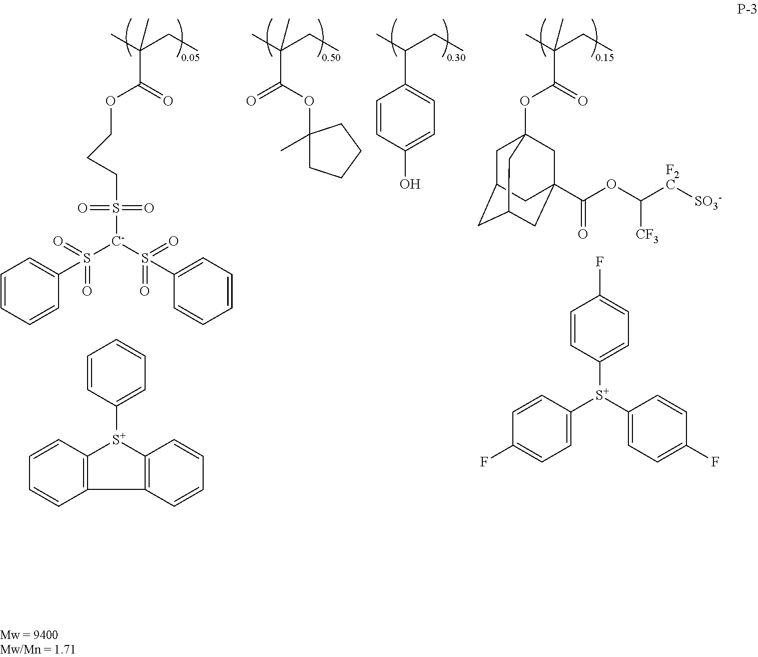

### [Synthesis Example 2-4] Synthesis of Polymer P-4

A 2-L flask was charged with 4.1 g of Monomer M-4, 8.4 g of 1-methyl-1-cyclopentyl methacrylate, 3.6 g of 3-hydroxystyrene, 11.0 g of Monomer PM-2, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-4. Polymer P-4 was analyzed for composition by ¹³C-NMR and ¹H-NMR and for Mw and Mw/Mn by GPC.

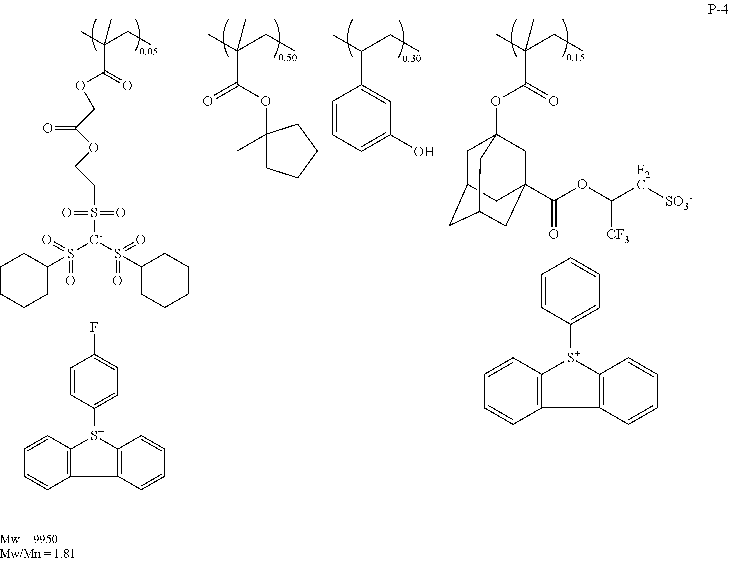

### [Synthesis Example 2-5] Synthesis of Polymer P-5

A 2-L flask was charged with 4.3 g of Monomer M-5, 8.4 g of 1-methyl-1-cyclopentyl methacrylate, 4.2 g of 4-hydroxystyrene, 8.5 g of Monomer PM-3, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-5. Polymer P-5 was analyzed for composition by ¹³C-NMR and ¹H-NMR and for Mw and Mw/Mn by GPC.

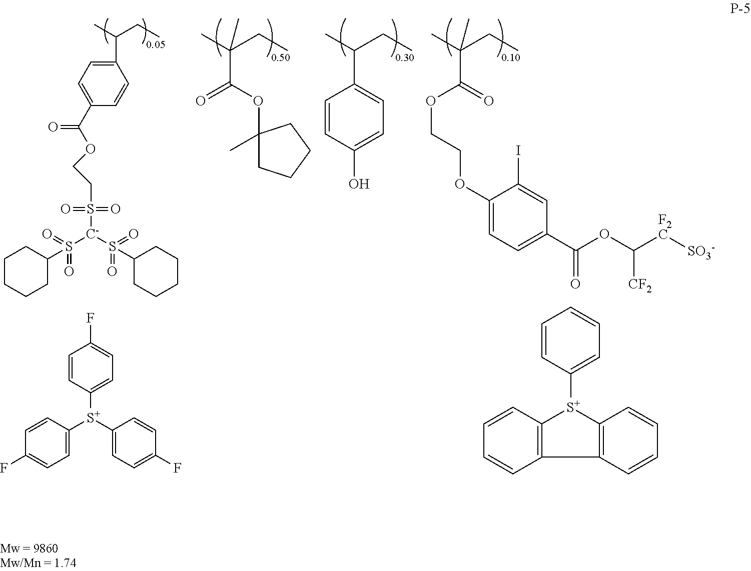

### [Synthesis Example 2-6] Synthesis of Polymer P-6

A 2-L flask was charged with 5.2 g of Monomer M-6, 8.9 g of Monomer AM-1, 5.4 g of 4-hydroxystyrene, 10.2 g of Monomer PM-4, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-6. Polymer P-6 was analyzed for composition by 13C-NMR and ¹H-NMR and for Mw and Mw/Mn by GPC.

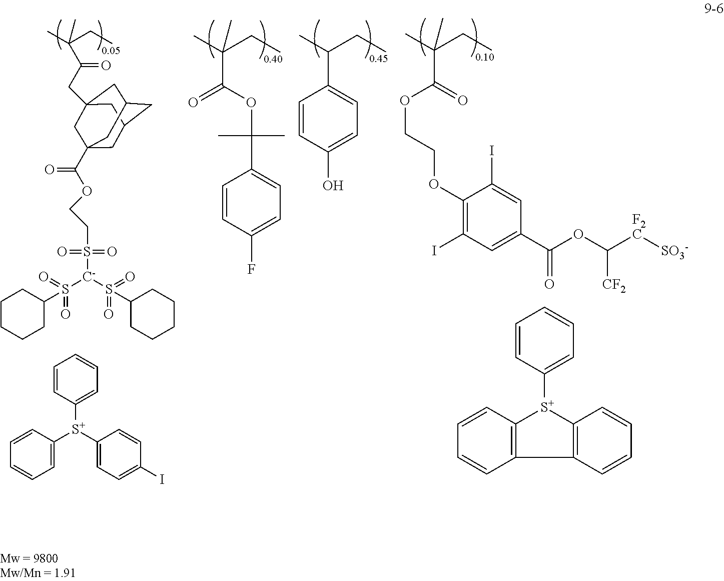

### [Synthesis Example 2-7] Synthesis of Polymer P-7

A 2-L flask was charged with 3.8 g of Monomer M-7, 8.4 g of 1-methyl-1-cyclopentyl methacrylate, 4.8 g of 4-hydroxystyrene, 6.1 g of Monomer PM-5, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-7. Polymer P-7 was analyzed for composition by ¹³C-NMR and ¹H-NMR and for Mw and Mw/Mn by GPC.

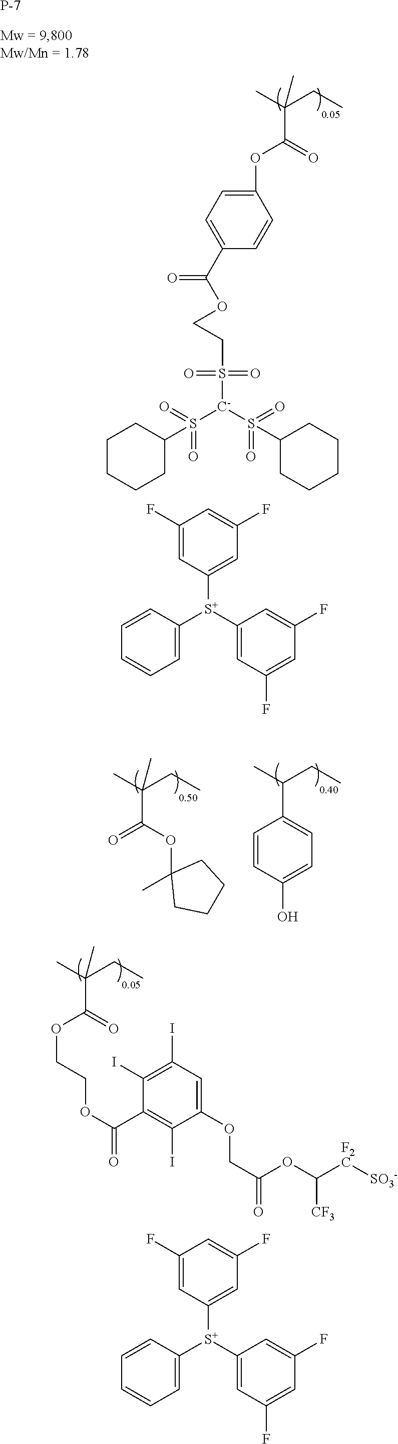

### [Synthesis Example 2-8] Synthesis of Polymer P-8

A 2-L flask was charged with 4.0 g of Monomer M-8, 8.9 g of Monomer AM-1, 5.4 g of 4-hydroxystyrene, 9.7 g of Monomer PM-4, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-8. Polymer P-8 was analyzed for composition by ¹³C-NMR and ¹H-NMR and for Mw and Mw/Mn by GPC.

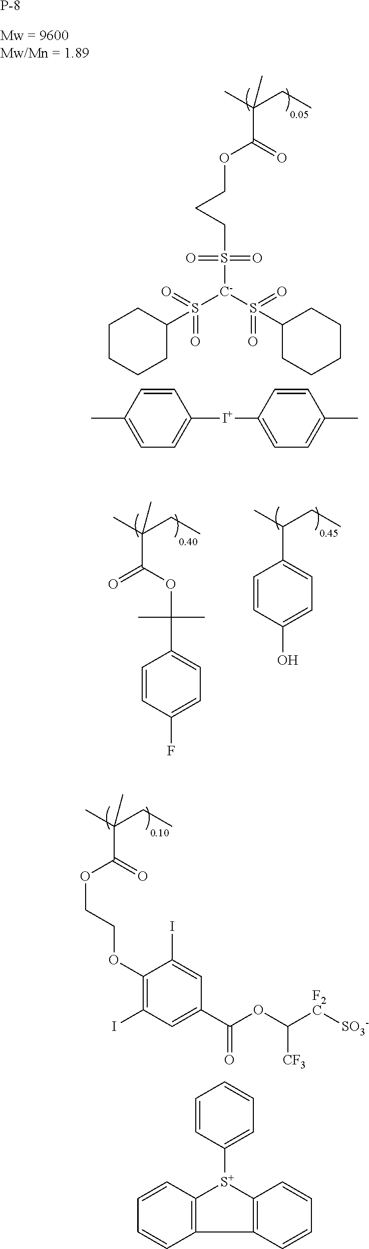

### [Synthesis Example 2-9] Synthesis of Polymer P-9

A 2-L flask was charged with 4.1 g of Monomer M-2, 8.4 g of 1-methyl-1-cyclopentyl methacrylate, 4.2 g of 4-hydroxystyrene, 9.4 g of Monomer PM-6, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-9. Polymer P-9 was analyzed for composition by ¹³C-NMR and ¹H-NMR and for Mw and Mw/Mn by GPC.

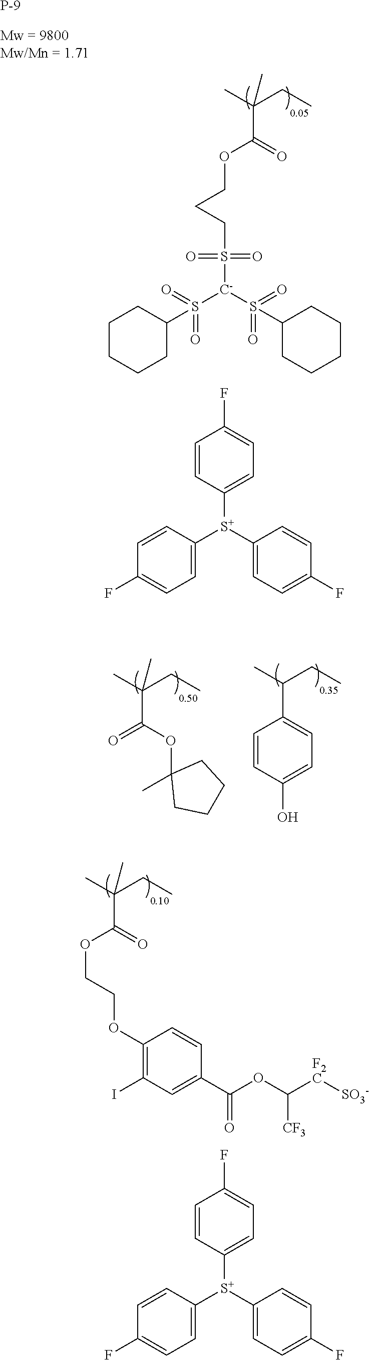

### [Synthesis Example 2-10] Synthesis of Polymer P-10

A 2-L flask was charged with 5.5 g of Monomer M-9, 8.4 g of 1-methyl-1-cyclopentyl methacrylate, 4.2 g of 4-hydroxystyrene, 9.4 g of Monomer PM-6, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-10. Polymer P-10 was analyzed for composition by ¹³C-NMR and ¹H-NMR and for Mw and Mw/Mn by GPC.

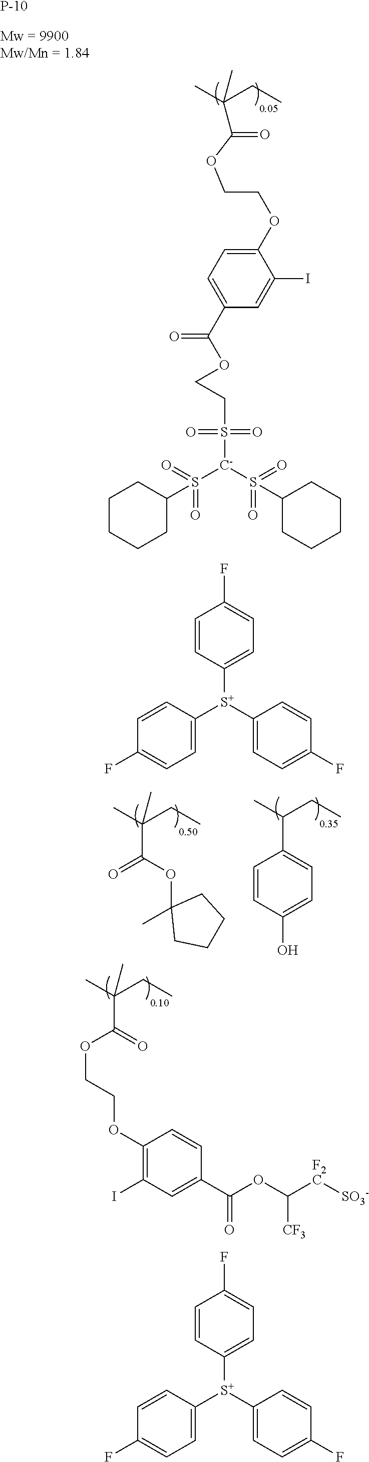

### [Synthesis Example 2-11] Synthesis of Polymer P-11

A 2-L flask was charged with 6.1 g of Monomer M-10, 8.4 g of 1-methyl-1-cyclopentyl methacrylate, 4.2 g of 4-hydroxystyrene, 9.4 g of Monomer PM-6, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-11. Polymer P-11 was analyzed for composition by ¹³C-NMR and ¹H-NMR and for Mw and Mw/Mn by GPC.

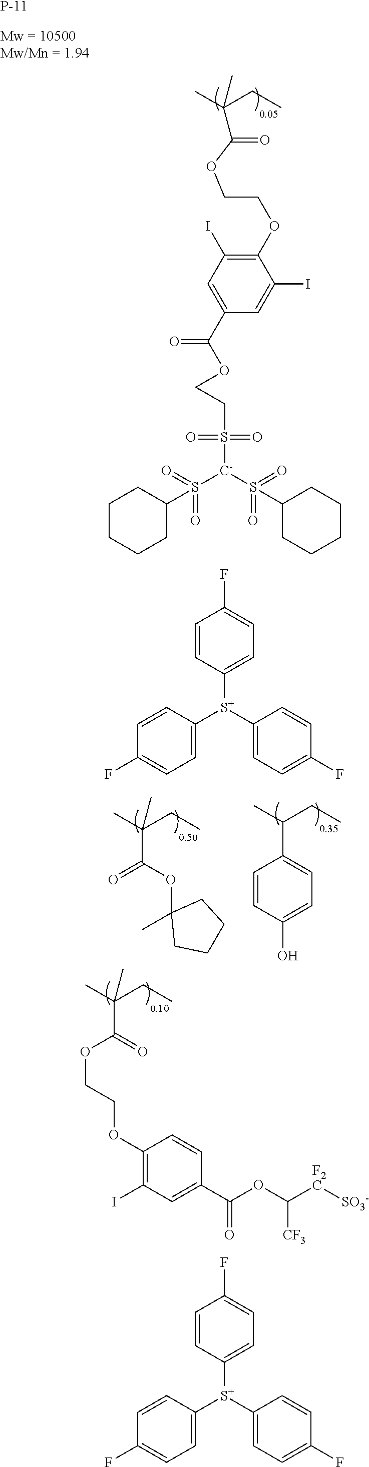

### [Synthesis Example 2-12] Synthesis of Polymer P-12

A 2-L flask was charged with 4.9 g of Monomer M-11, 8.4 g of 1-methyl-1-cyclopentyl methacrylate, 4.2 g of 4-hydroxystyrene, 8.5 g of Monomer PM-3, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-12. Polymer P-12 was analyzed for composition by ¹³C-NMR and ¹H-NMR and for Mw and Mw/Mn by GPC.

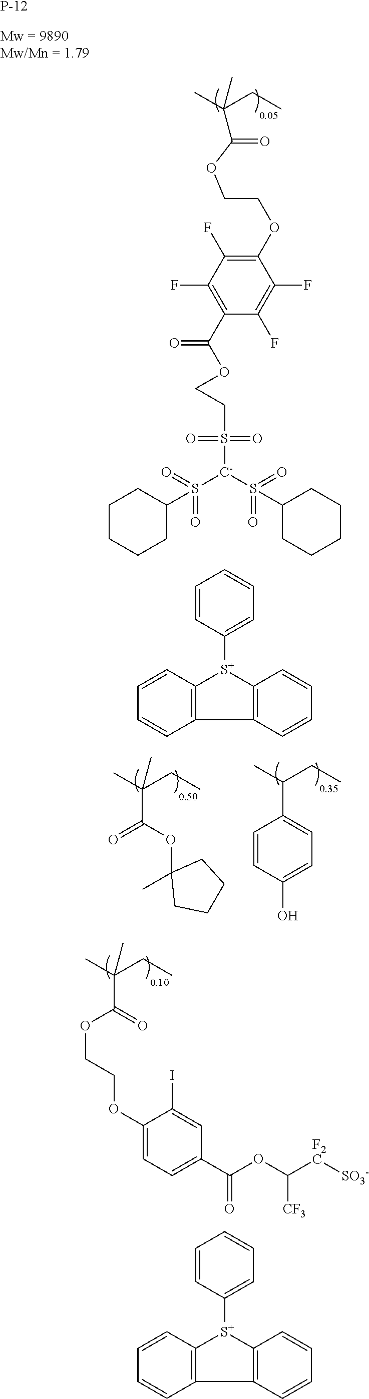

### [Synthesis Example 2-13] Synthesis of Polymer P-13

A 2-L flask was charged with 5.0 g of Monomer M-12, 8.4 g of 1-methyl-1-cyclopentyl methacrylate, 4.2 g of 4-hydroxystyrene, 8.5 g of Monomer PM-3, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-13. Polymer P-13 was analyzed for composition by ¹³C-NMR and ¹H-NMR and for Mw and Mw/Mn by GPC.

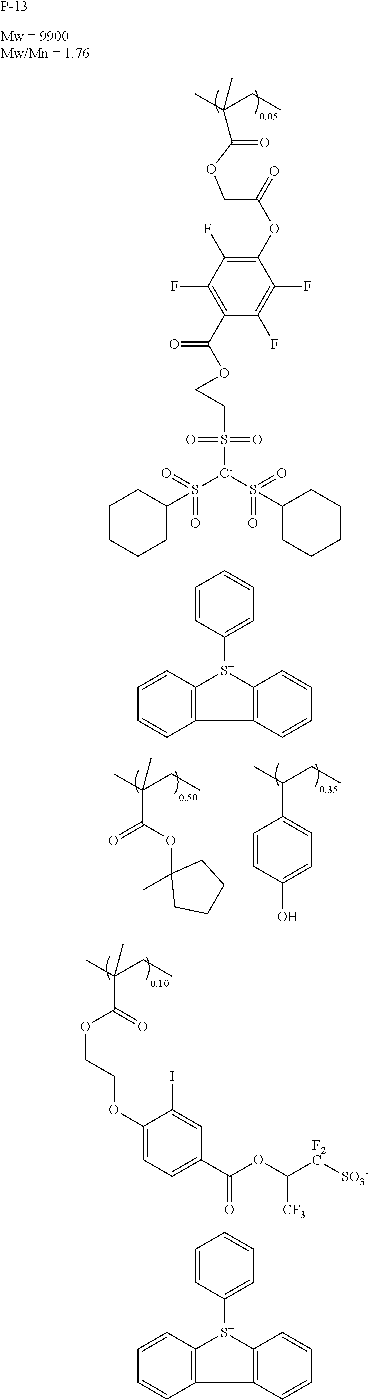

### [Comparative Synthesis Example 1] Synthesis of Comparative Polymer cP-1

Comparative Polymer cP-1 was obtained in the same manner as in Synthesis Example 2-1 except that Comparative Monomer cM-1 was used instead of Monomer M-1. Comparative Polymer cP-1 was analyzed for composition by ¹³C-NMR and ¹H-NMR and for Mw and Mw/Mn by GPC.

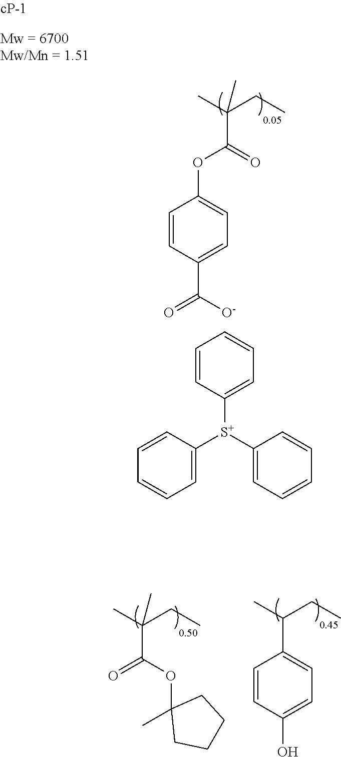

### [Comparative Synthesis Example 2] Synthesis of Comparative Polymer cP-2

Comparative Polymer cP-2 was obtained in the same manner as in Synthesis Example 2-1 except that Monomer M-1 was not used. Comparative Polymer cP-2 was analyzed for composition by ¹³C-NMR and ¹H-NMR and for Mw and Mw/Mn by GPC.

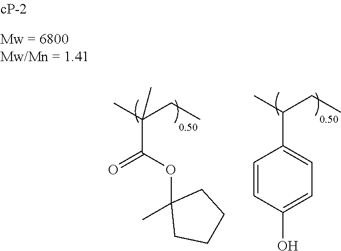

### [Comparative Synthesis Example 3] Synthesis of Comparative Polymer cP-3

Comparative Polymer cP-3 was obtained in the same manner as in Synthesis Example 2-4 except that Monomer M-4 was not used. Comparative Polymer cP-3 was analyzed for composition by ¹³C-NMR and ¹H-NMR and for Mw and Mw/Mn by GPC.

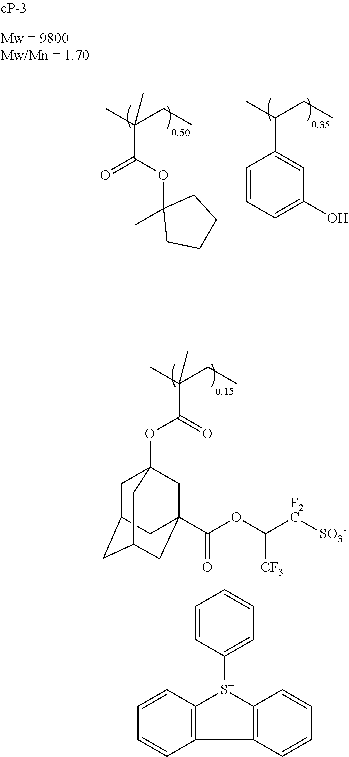

### [3] Preparation and Evaluation of Resist Compositions

### Examples 1 to 15 and Comparative Examples 1 to 3

### (1) Preparation of Resist Compositions

In a solvent in which 50 ppm of a surfactant Polyfox 636 manufactured by Omnova Solutions, Inc. was dissolved, the components having the composition shown in Table 1 were dissolved. The resulting solution was filtered through a filter having a pore size of 0.2 μm to prepare a positive resist composition.

The components in Table 1 are as follows.

### Organic Solvents:

PGMEA (propylene glycol monomethyl ether acetate)
DAA (diacetone alcohol)
EL (ethyl lactate)

### Acid Generator: PAG-1

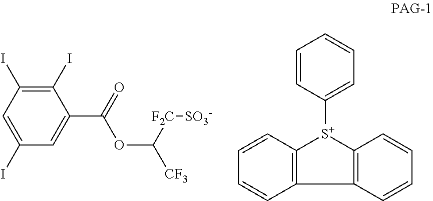

### Quenchers: Q-1 and Q-2

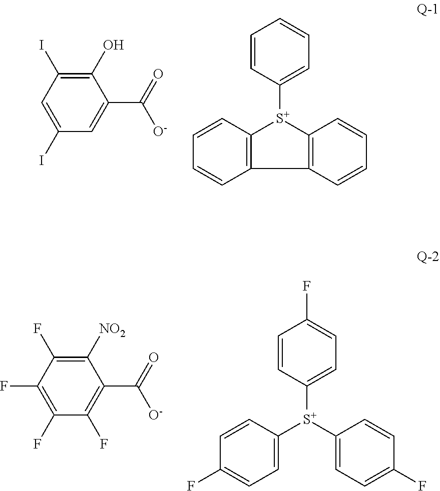 [SMILES: O=C([O-])c1cc(I)cc(I)c1O ; c1ccc(-[s+]2c3ccccc3c3ccccc32)cc1 ; O=C([O-])c1c(F)c(F)c(F)c(F)c1[N+](=O)[O-] ; Fc1ccc([S+](c2ccc(F)cc2)c2ccc(F)cc2)cc1]

### (2) EUV Lithography Evaluation

Each of the resist compositions shown in Table 1 was applied by spin coating to a silicon substrate having a 20-nm coating of silicon-containing spin-on hard mask SHB-A940 (Si content 43 wt %) and prebaked on a hotplate at 105° C. for 60 seconds to form a 50 nm-thick resist film. Using an EUV scanner NXE3400 (ASML, NA 0.33, σ0.9/0.6, quadrupole illumination), the resist film was exposed to EUV through a mask bearing a hole pattern at a pitch of 46 nm (on-wafer size) and +20% bias. The resist film was baked (PEB) on a hotplate at the temperature shown in Table 1 for 60 seconds and developed in a 2.38 wt % TMAH aqueous solution for 30 seconds to form a hole pattern having a size of 23 nm.

The exposure dose that provides a hole pattern of 23 nm size is reported as sensitivity. The size of 50 holes was measured using CD-SEM (CG6300, Hitachi High-Technologies Corp.), from which a 3-fold value (3σ) of the standard deviation (σ) was computed and reported as CDU. The results are collectively shown in Tables 1 and 2.

TABLE 1

| | | Polymer | Acid generator | Quencher | Organic solvent | PEB temp. | Sensitivity | CDU |
|---|---|---|---|---|---|---|---|---|
| | | (pbw) | (pbw) | (pbw) | (pbw) | (° C.) | (mJ/cm²) | (nm) |
| Example | 1 | P-1 | PAG-1 | — | PGMEA (2000) | 80 | 35 | 2.6 |
| | | (100) | (25.0) | | DAA (500) | | | |
| | 2 | P-2 | — | — | PGMEA (2000) | 80 | 34 | 2.3 |
| | | (100) | | | DAA (500) | | | |
| | 3 | P-3 | — | — | PGMEA (2000) | 80 | 34 | 2.3 |
| | | (100) | | | DAA (500) | | | |
| | 4 | P-4 | — | — | PGMEA (2000) | 80 | 36 | 2.3 |
| | | (100) | | | DAA (500) | | | |
| | 5 | P-5 | — | — | PGMEA (2000) | 80 | 34 | 2.4 |
| | | (100) | | | DAA (500) | | | |
| | 6 | P-6 | — | — | PGMEA (2000) | 80 | 36 | 2.3 |
| | | (100) | | | DAA (500) | | | |
| | 7 | P-7 | PAG-1 | — | EL (2000) | 80 | 30 | 2.6 |
| | | (100) | (10.0) | | PGMEA (500) | | | |
| | 8 | P-7 | PAG-1 | Q-1 | EL (2000) | 80 | 32 | 2.5 |
| | | (100) | (15.0) | (3.25) | PGMEA (500) | | | |
| | 9 | P-7 | PAG-1 | Q-2 | EL (2000) | 80 | 30 | 2.6 |
| | | (100) | (15.0) | (2.78) | PGMEA (500) | | | |
| | 10 | P-8 | — | — | PGMEA (2000) | 80 | 32 | 2.3 |
| | | (100) | | | DAA (500) | | | |
| | 11 | P-9 | — | — | PGMEA (2000) | 80 | 35 | 2.4 |
| | | (100) | | | DAA (500) | | | |
| | 12 | P-10 | — | — | PGMEA (2000) | 80 | 37 | 2.2 |
| | | (100) | | | DAA (500) | | | |
| | 13 | P-11 | — | — | PGMEA (2000) | 80 | 36 | 2.2 |
| | | (100) | | | DAA (500) | | | |
| | 14 | P-11 | — | — | PGMEA (2000) | 80 | 36 | 2.2 |
| | | (100) | | | DAA (500) | | | |
| | 15 | P-13 | — | — | PGMEA (2000) | 80 | 35 | 2.2 |
| | | (100) | | | DAA (500) | | | |

TABLE 2

| | | Polymer | Acid generator | Quencher | Organic solvent | PEB temp. | Sensitivity | CDU |
|---|---|---|---|---|---|---|---|---|
| | | (pbw) | (pbw) | (pbw) | (pbw) | (° C.) | (mJ/cm²) | (nm) |
| Comparative | 1 | cP-1 | PAG-1 | — | PGMEA (2000) | 80 | 45 | 4.1 |
| Example | | (100) | (25.0) | | DAA (500) | | | |
| | 2 | cP-2 | PAG-1 | Q-1 | PGMEA (2000) | 80 | 41 | 4.0 |
| | | (100) | (25.0) | (3.25) | DAA (500) | | | |
| | 3 | cP-3 | — | Q-1 | PGMEA (2000) | 80 | 34 | 3.3 |
| | | (100) | | (3.25) | DAA (500) | | | |

From the results shown in Tables 1 and 2, it was found that the resist composition of the present invention, which contains a polymer containing repeat units having a sulfonium salt structure or an iodonium salt structure of trihydrocarbylsulfonylmethide acid free of a fluorine atom on a carbon atom at an α-position of a sulfonyl group, has sufficient sensitivity and dimensional uniformity.

Japanese Patent Application No. 2023-068697 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

The invention claimed is:

1. A positive resist composition comprising a base polymer containing repeat units (a) having a sulfonium salt structure or an iodonium salt structure of trihydrocarbylsulfonylmethide acid free of a fluorine atom on a carbon atom at an α-position of a sulfonyl group.

2. The positive resist composition of claim 1, wherein the repeat units (a) are repeat units (a1) having formula (a1) or repeat units (a2) having formula (a2): 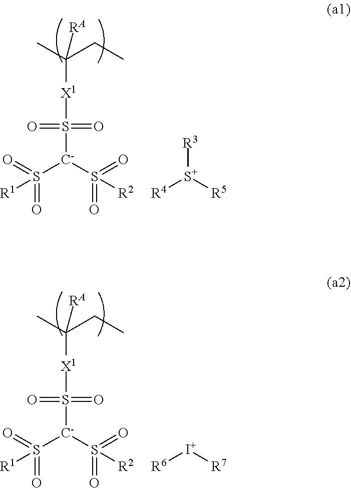
wherein R^{A} is a hydrogen atom or a methyl group,
X¹ is each independently a single bond, a phenylene group, or a C₁-C₂₀ linking group containing at least one moiety selected from an ester bond, an ether bond, a urethane bond, a lactone ring, and a halogen atom,
R¹ and R² are each independently a C₁-C₂₀ hydrocarbyl group which may contain a heteroatom, but are free of a fluorine atom on a carbon atom bonded to a sulfonyl group, and
R³ to R⁷ are each independently a halogen atom or a C₁-C₂₀ hydrocarbyl group which may contain a heteroatom, and R³ and R⁴ may bond together to form a ring with a sulfur atom to which they are bonded.

3. The positive resist composition of claim 1, further comprising at least one kind selected from repeat units (b1) in which a hydrogen atom of a carboxy group is substituted with an acid labile group and repeat units (b2) in which a hydrogen atom of a phenolic hydroxy group is substituted with an acid labile group.

4. The positive resist composition of claim 3, wherein the repeat units (b1) have formula (b1) and the repeat units (b2) have formula (b2): 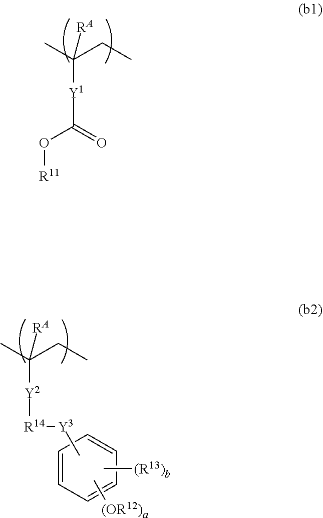
wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, and a lactone ring, and the phenylene group, the naphthylene group, and the linking group may have at least one moiety selected from a hydroxy group, a C₁-C₈ saturated hydrocarbyloxy group, and a C₂-C₈ saturated hydrocarbylcarbonyloxy group,
Y² is a single bond, an ester bond, or an amide bond,
Y³ is a single bond, an ether bond, or an ester bond,
R¹¹ and R¹² are acid labile groups,
R¹³ is a fluorine atom, a trifluoromethyl group, a cyano group, or a C₁-C₆ saturated hydrocarbyl group,
R¹⁴ is a single bond or a C₁-C₆ alkanediyl group in which some constituent-CH₂— may be substituted with an ether bond or an ester bond, and
a is 1 or 2, and b is an integer of 0 to 4, provided that 1≤a+b≤5.

5. The positive resist composition of claim 1, wherein the base polymer further contains repeat units (c) having an adhesive group selected from a hydroxy group, a carboxy group, a lactone ring, a carbonate bond, a thiocarbonate bond, a carbonyl group, a cyclic acetal group, an ether bond, an ester bond, a sulfonic ester bond, a cyano group, an amide bond, —O—C(═O)—S—, and —O—C(═O)—NH—.

6. The positive resist composition of claim 1, wherein the base polymer further contains at least one kind selected from repeat units having formulae (d1) to (d3): 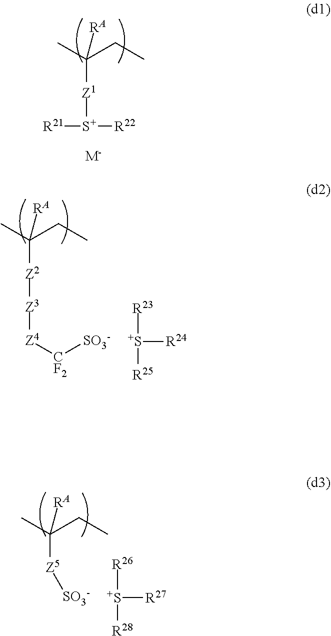
wherein R^{A} is each independently a hydrogen atom or a methyl group,
Z¹ is a single bond, a C₁-C₆ aliphatic hydrocarbylene group, a phenylene group, a naphthylene group, a C₇-C₁₈ group obtained by combining the foregoing, —O—Z¹¹—, —C(═O)—O—Z¹¹—, or —C(═O)—NH—Z¹¹, wherein Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group,
Z² is a single bond or an ester bond,
Z³ is a single bond, —Z³¹—C(═O)—O—, —Z³¹—O—, or —Z³¹—O—C(═O)—, wherein Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom,
Z⁴ is a methylene group, a 2,2,2-trifluoro-1,1-ethanediyl group, or a carbonyl group,
Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—, wherein Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a hydroxy group, or a halogen atom,
R²¹ to R²⁸ are each independently a halogen atom or a C₁-C₂₀ hydrocarbyl group which may contain a heteroatom, and R²³ and R²⁴ or R²⁶ and R²⁷ may bond together to form a ring with a sulfur atom to which they are bonded, and
M⁻ is a non-nucleophilic counter ion.

7. The positive resist composition of claim 1, further comprising an acid generator.

8. The positive resist composition of claim 1, further comprising an organic solvent.

9. The positive resist composition of claim 1, further comprising a quencher.

10. The positive resist composition of claim 1, further comprising a surfactant.

11. A pattern forming process comprising the steps of:
applying the positive resist composition of claim 1 onto a substrate to form a resist film on the substrate,
exposing the resist film to high-energy radiation, and
developing the exposed resist film in a developer.

12. The pattern forming process of claim 11, wherein the high-energy radiation is i-line, KrF excimer laser, ArF excimer laser, electron beam, or extreme ultraviolet having a wavelength of 3 to 15 nm.
